(19) United States
(12) Patent Application Publication
(10) Pub. No.: US 2025/0048826 A1
(43) Pub. Date: Feb. 6, 2025

(54) MATERIAL FOR EMISSION LAYER OF ORGANIC ELECTROLUMINESCENT ELEMENT, COMPOSITION FOR FORMING EMISSION LAYER, ORGANIC ELECTROLUMINESCENT ELEMENT, AND METHOD FOR PRODUCING ORGANIC ELECTROLUMINESCENT ELEMENT

(71) Applicant: Mitsubishi Chemical Corporation, Tokyo (JP)

(72) Inventors: Kazuki OKABE, Tokyo (JP); Yuki OHSHIMA, Tokyo (JP); Tsukasa HASEGAWA, Tokyo (JP); Yanjun LI, Tokyo (JP)

(73) Assignee: Mitsubishi Chemical Corporation, Tokyo (JP)

(21) Appl. No.: 18/894,064

(22) Filed: Sep. 24, 2024

Related U.S. Application Data
(63) Continuation of application No. PCT/JP2022/044299, filed on Nov. 30, 2022.

(30) Foreign Application Priority Data
Mar. 25, 2022 (JP) 2022-050624
Jun. 1, 2022 (JP) 2022-089930

(51) Int. Cl. H10K 50/11; H10K 71/13; H10K 85/30; H10K 85/60

(52) U.S. Cl. CPC H10K 50/11; H10K 71/135; H10K 85/342; H10K 85/622; H10K 85/654; H10K 85/6572; H10K 85/658

(57) ABSTRACT

The present invention relates to a material for an emission layer of an organic electroluminescent element, including at least a luminescent material and at least two kinds of compounds respectively selected from at least any two groups among three groups represented by the following (group A), (group B), and (group C). (Group A): a group consisting of a compound represented by the following formula (1-A) and a compound represented by the following formula (1-B); (group B): a compound represented by the following formula (2); and (group C): a group consisting of a compound represented by the following formula (3), a compound represented by the following formula (1-1), and a compound represented by the following formula (1-2) (details of each formula included in (group A) to (group C) are as described in the description).

### CROSS-REFERENCE TO RELATED APPLICATIONS

This application is a continuation of International Application No. PCT/JP2022/044299, filed on Nov. 30, 2024, and claims the benefit of priority to Japanese Application No. 2022-050624 filed on Mar. 25, 2022 and Japanese Application No. 2022-089930 filed on Jun. 1, 2022. The content of each of these applications is hereby incorporated by reference in its entirety.

### TECHNICAL FIELD

A first aspect of the present invention relates to a composition for layer formation; a method for producing an organic electroluminescent element, a display device, and an illuminator; as well as an organic electroluminescent element, a display device, and an illuminator.

A second aspect of the present invention relates to a composition for forming an emission layer of an organic electroluminescent element, a method for producing an organic electroluminescent element; as well as an organic electroluminescent element, a display device, and an illuminator.

### BACKGROUND ART

Production of an organic electroluminescent element, a display device, and an illuminator using a coating method is preferable from the viewpoint that a large substrate can be used, and development thereof has been carried out actively. Among coating methods, in production of a display device using an inkjet method, development has been carried out particularly actively.

At the time of producing an organic electroluminescent element, a display device, and an illuminator using a coating method, it is obviously necessary that a lower layer is not eluted when an upper layer is coated. For example, a crosslinking group is introduced into a hole transport layer and a hole injection layer corresponding to a lower layer when an emission layer is formed by coating, and after the coating, crosslinking is performed by ways such as heating or exposure to ultraviolet rays to obtain resistance to a solvent when the emission layer is formed by coating.

As a method used when an upper layer is formed by coating, there is a method in which a solvent that does not dissolve a material of the lower layer is used in addition to the introduction of the crosslinking group into the lower layer. An example of preparing an organic electroluminescent element using methanol, ethanol, isopropyl alcohol, and the like has been reported.

Patent Literature 1 reports an example in which an electron transport layer on an emission layer is coated and formed by an inkjet method using a composition containing 1-butanol as a solvent to prepare an organic electroluminescent element.

Non-Patent Document 1 reports an example in which an electron transport layer on an emission layer is coated and formed by a spin coating method from a composition containing methanol or 2-propanol as a solvent to prepare an organic electroluminescent element.

### CITATION LIST

### Patent Literature

Patent Literature 1: Japanese Patent No. 5381719

### Non-Patent Literature

Non Patent Literature 1: Nat.Commun. 2014, Vol. 5,5756

### SUMMARY OF INVENTION

### Technical Problem

Patent Literature 1 discloses an example in which a layer of an organic electroluminescent element is formed by coating by an inkjet method using a composition containing 1-butanol as a solvent. However, there is no description relating to clogging of an inkjet head, and there is no clear description relating to whether the method is suitable for continuously performing inkjet coating.

Non-Patent Document 1 discloses an example in which a layer of an organic electroluminescent element is formed by a spin casting method using a composition containing methanol or 2-propanol as a solvent. However, it is unclear whether the composition can be applied to the inkjet method.

In addition, a method of introducing a crosslinking group into an emission layer when an electron transport layer on the emission layer is formed by coating is known. However, the above method is not considered to be a useful method because there is a concern that the compound contained in the emission layer may have resistance to a crosslinking treatment such as heating or exposure to ultraviolet rays, and there is a concern that an unreacted crosslinking group remaining in the emission layer and the compound contained in the emission layer may react with each other by energization during driving to cause a decrease in luminance.

Under such circumstances, even in a case of producing an organic electroluminescent element by a coating method, layers are formed at most up to the emission layer by the coating method, and it is exclusive to study using a vacuum deposition method for layers above the emission layer. Therefore, it cannot be said that an advantage of using the coating method is sufficiently utilized.

The present invention has been made in view of the above circumstances in the related art, and an object of the present invention is to provide a material for an emission layer of an organic electroluminescent element (hereinafter, also referred to as a “material for an emission layer”) capable of providing an organic electroluminescent element exhibiting high luminescent efficiency in order to achieve a wide energy gap and appropriate charge transportability. In addition, an object of the present invention is to provide a composition for layer formation capable of suitably coating and forming an upper layer of an emission layer using an inkjet method.

Further, an object of the present invention is to provide a method for producing an organic electroluminescent element, a display device, and an illuminator using the material for an emission layer, as well as an organic electroluminescent element, a display device, and an illuminator obtained by the production method.

### Solution to Problem

As a result of intensive studies, the present inventors have found that the above problems can be solved by at least a luminescent material as well as a material for an emission layer containing at least two kinds of compounds respectively selected from specific groups, thereby achieving the present invention.

That is, the gist of the present invention is as follows.

According to a first aspect of the present invention,

there is provided a material for an emission layer of an organic electroluminescent element, including

at least a luminescent material and at least two kinds of compounds respectively selected from at least any two groups among three groups represented by the following (group A), (group B), and (group C):
(group A): a group consisting of a compound represented by the following formula (1-A) and a compound represented by the following formula (1-B);
(group B): a compound represented by the following formula (2); and
(group C): a group consisting of a compound represented by the following formula (3), a compound represented by the following formula (1-1), and a compound represented by the following formula (1-2).

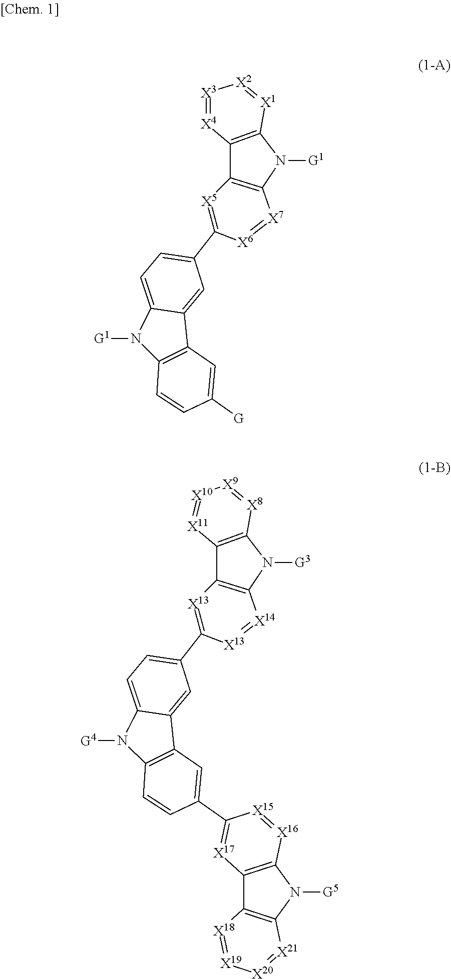

(In the formula (1-A), G¹ and G² each independently represent an aromatic hydrocarbon group, and the total carbon atom number of the number of carbon atoms of G¹ and the number of carbon atoms of G² is 42 or more and 240 or less, or at least one of the number of carbon atoms of G¹ and G² is 54 or more and 240 or less. X¹ to X⁷ each independently represent CR^{1A} or a nitrogen atom, and R^{1A} each independently represent, for each occurrence, a hydrogen atom, a deuterium atom, CN, or an aromatic hydrocarbon group having 6 to 30 carbon atoms which may have a substituent. G represents a hydrogen atom, a deuterium atom, CN, or an aromatic hydrocarbon group having 6 to 30 carbon atoms which may have a substituent.

In the formula (1-B), G³, G⁴, and G⁵ each independently represent an aromatic hydrocarbon group, and the total carbon atom number of the number of carbon atoms of G³, the number of carbon atoms of G⁴, and the number of carbon atoms of G⁵ is 42 or more and 240 or less, or at least one of the number of carbon atoms of G³, G⁴, and G⁵ is 28 or more and 240 or less; and X⁸ to X²¹ each independently represent a CR^{1B} or a nitrogen atom, and R^{1B} each independently represent, for each occurrence, a hydrogen atom, a deuterium atom, a CN, or an aromatic hydrocarbon group having 6 to 30 carbon atoms which may have a substituent).

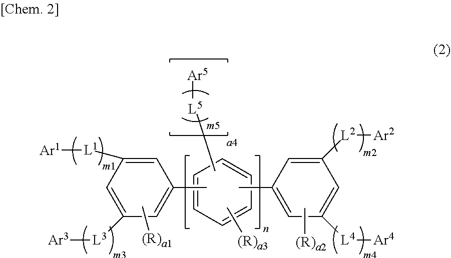

(In the formula (2),

Ar¹ to Ar⁵ each independently represent a hydrogen atom or a monovalent aromatic hydrocarbon group having 6 or more and 60 or less carbon atoms which may have a substituent,

at least one of Ar¹, Ar², and Ar⁵ is represented by the following formula (4) or the following formula (5),

Ar³ and Ar⁴ each independently represent a hydrogen atom or a monovalent aromatic hydrocarbon group having 6 or more and 60 or less carbon atoms which may have a substituent,

L¹ to L⁵ each independently represent a divalent aromatic hydrocarbon group having 6 or more and 60 or less carbon atoms which may have a substituent,

R each independently represents a substituent,
m1, m2, and m5 each independently represent an integer of 0 to 5,
m3 and m4 each independently represent an integer of 1 to 5,
n represents an integer of 0 to 10,
a1 and a2 each independently represent an integer of 0 to 3,
a3 represents an integer of 0 to 4, and
a4 represents an integer of 0 or 1.

Here, when a3 is 4, a4 is 0.

In the formula (2), Ar¹—(L¹)ₘ₁—, Ar²—(L²)ₘ₂—, Ar³—(L³)ₘ₃—, and Ar⁴—(L⁴)ₘ₄— do not become hydrogen atoms).

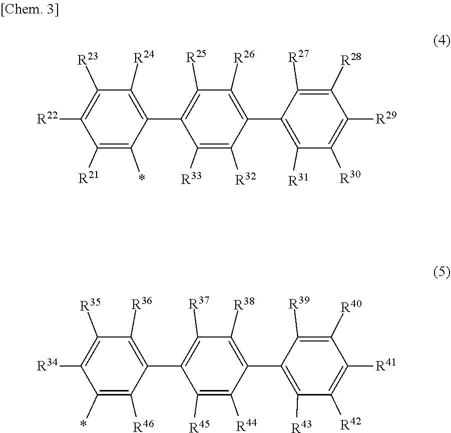

(In the formula (4) or the formula (5),

an asterisk (*) represents a bond to the formula (2), and

R²¹ to R⁴⁶ each independently represent a hydrogen atom or a substituent).

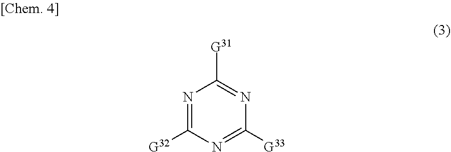

(In the formula (3), G³¹ and G³² each independently represent the following formula (7), and G³³ represents the following formula (8)).

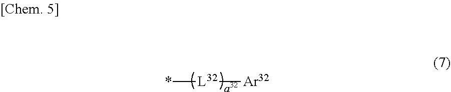

(In the formula (7), an asterisk (*) represents a bond to the formula (3),
L³² represents a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked, Ar³² represents a monovalent aromatic hydrocarbon group having 60 or less carbon atoms which may have a substituent, a monovalent heteroaromatic group having 60 or less carbon atoms which may have a substituent, or a group in which a plurality of groups selected from the monovalent aromatic hydrocarbon group having 60 or less carbon atoms which may have a substituent and the monovalent heteroaromatic group having 60 or less carbon atoms which may have a substituent are linked, and

a³² represents an integer of 0 to 5).

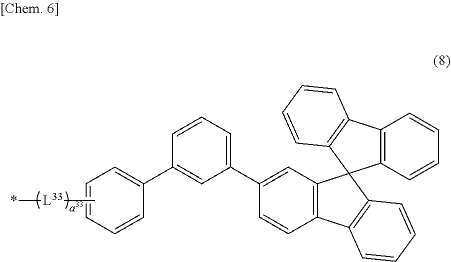

(In the formula (8), an asterisk (*) represents a bond to the formula (3),

L³³ represents a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked, and

a³³ represents an integer of 0 to 5).

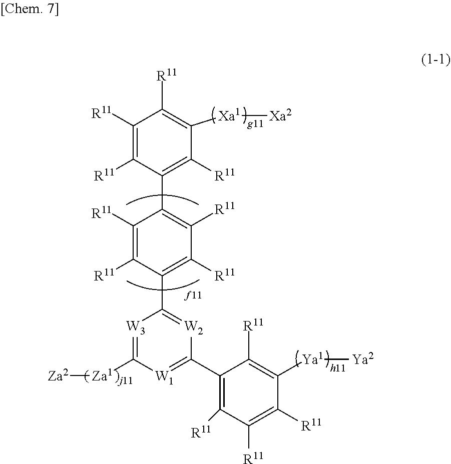

(In the formula (1-1),
W₁, W₂, and W₃ each independently represent —CH or a nitrogen atom, and at least one of W₁, W₂, and W₃ represents a nitrogen atom,
Xa¹, Ya¹, and Za¹ each independently represent a 1,3-phenylene group which may have a substituent, or a 1,4-phenylene group which may have a substituent,
at least one of Za¹ is a 1,3-phenylene group,
Xa² and Ya² each independently represent a phenyl group which may have a substituent,
Za² represents an N-carbazolyl group which may have a substituent,
f11 is 1 or 2,
g11 is an integer of 1 to 5,
h11 is an integer of 2 to 5,
j11 is an integer of 1 to 6,
f11+g11+h11+j11 is 5 or more, and
R¹¹ each independently represents a hydrogen atom or a substituent).

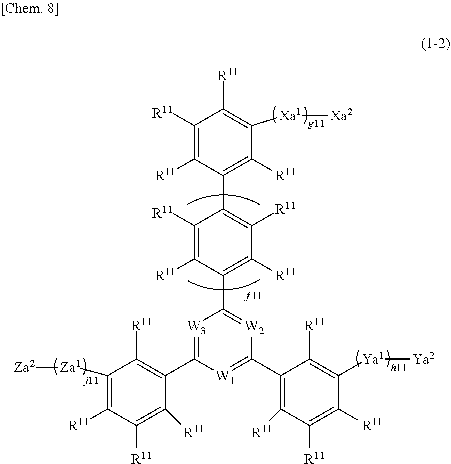

(In the formula (1-2),
W₁, W₂, and W₃ each independently represent —CH or a nitrogen atom, and at least one of W₁, W₂, and W₃ is a nitrogen atom,
Xa¹, Ya¹, and Za¹ each independently represent a 1,3-phenylene group which may have a substituent, or a 1,4-phenylene group which may have a substituent,
at least one of Yaⁱ and Za¹ is a 1,3-phenylene group which may have a substituent,
Xa² represents a phenyl group which may have a substituent,
Ya² and Za² each independently represent an N-carbazolyl group which may have a substituent,
f11 is 1 or 2,
g11 is an integer of 1 to 5,
h11 is an integer of 2 to 5,
j11 is an integer of 2 to 5,
f11+g11+h11+j11 is 6 or more, and
R¹¹ each independently represents a hydrogen atom or a substituent).

According to a second aspect of the present invention,
there is provided the material for an emission layer according to the first aspect, in which
at least one of G¹ to G⁵ in the formula (1-A) and the formula (1-B) includes at least one substructure selected from the following formulae (11) to (16).

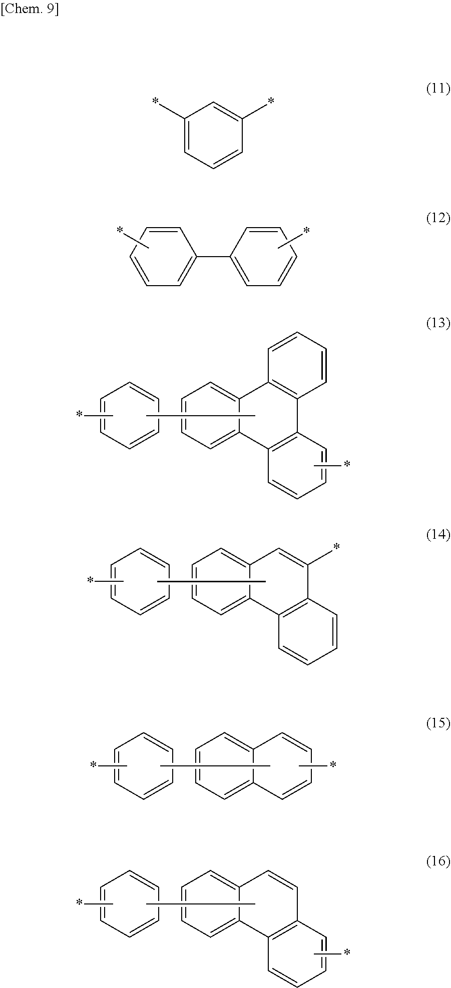

(In each of the formulae (11) to (16), an asterisk (*) represents a bond to an adjacent structure or a hydrogen atom, and at least one of two present *s represents a bonding site to the adjacent structure).

According to a third aspect of the present invention,

there is provided the material for an emission layer according to the first aspect or the second aspect, in which L¹ to L⁵ in the formula (2) each independently represent a phenylene group or a group in which two or more phenylene groups are linked in a directly bonded manner, which may have a substituent.

According to a fourth aspect of the present invention,

there is provided the material for an emission layer according to any of the first to third aspects, in which

L¹ to L⁵ in the formula (2) each independently represent a 1,3-phenylene group which may have a substituent.

According to a fifth aspect of the present invention,

there is provided the material for an emission layer according to any of the first to fourth aspects, in which

the compound represented by the formula (2) has a substructure represented by at least one selected from the following formulae (17) to (19), (21), and (22).

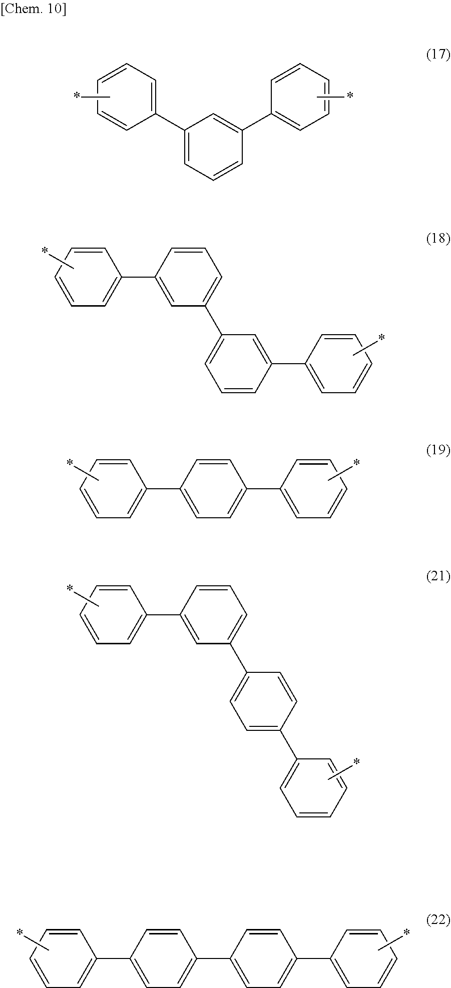

(In each of the formulae (17) to (19), (21), and (22), an asterisk (*) represents a bond to an adjacent structure or a hydrogen atom, and at least one of two present *s represents a bond representing a bonding site to an adjacent structure).

According to a sixth aspect of the present invention,

there is provided the material for an emission layer according to any of the first to fifth aspects, in which

G³¹ in the formula (3) is represented by the following formula (6).

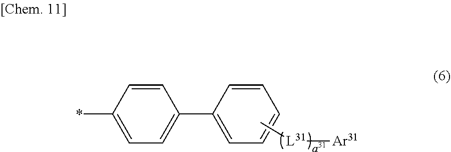

(In the formula (6), an asterisk (*) represents a bond to the formula (3),
L³¹ represents a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked,

Ar³¹ represents a monovalent aromatic hydrocarbon group having 60 or less carbon atoms which may have a substituent, a monovalent heteroaromatic group having 60 or less carbon atoms which may have a substituent, or a group in which a plurality of groups selected from the monovalent aromatic hydrocarbon group having 60 or less carbon atoms which may have a substituent and the monovalent heteroaromatic group having 60 or less carbon atoms which may have a substituent are linked, and

a³¹ represents an integer of 0 to 5).

According to a seventh aspect of the present invention,

there is provided the material for an emission layer according to any of the first to sixth aspects, in which

L³² and L³³ in the formula (7) and the formula (8) each independently represent a phenylene group or a group in which a plurality of phenylene groups are linked in a directly bonded manner.

According to an eighth aspect of the present invention,

there is provided the material for an emission layer according to the sixth aspect, in which

L³² and L³³ in the formula (7) and the formula (8), as well as L³¹ in the formula (6) each independently represent a phenylene group or a group in which a plurality of phenylene groups are linked in a directly bonded manner.

According to a ninth aspect of the present invention,

there is provided the material for an emission layer according to any of the first to eighth aspects, in which

the compound represented by the formula (3) has a substructure represented by at least one selected from the following formulae (17) to (19), (21), and (22).

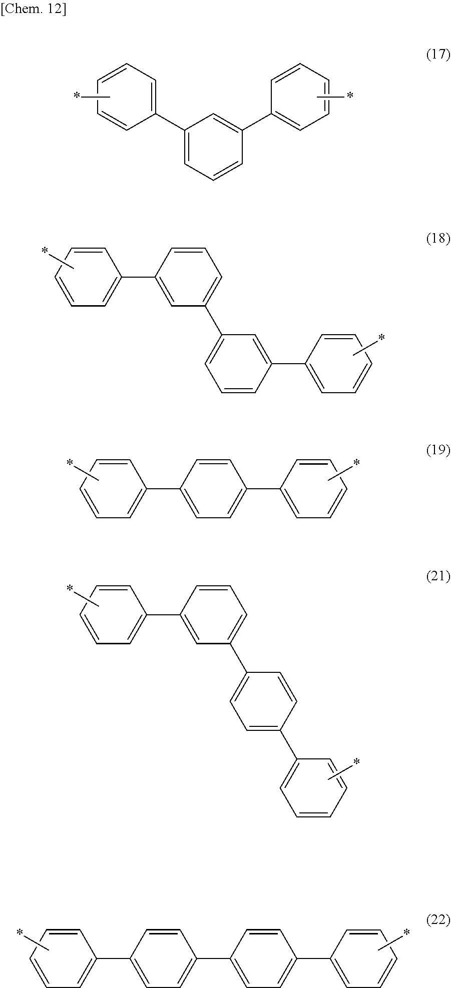

(In each of the formulae (17) to (19), (21), and (22), an asterisk (*) represents a bond to an adjacent structure or a hydrogen atom, and at least one of two present *s represents a bond representing a bonding site to an adjacent structure).

According to a tenth aspect of the present invention,

there is provided the material for an emission layer according to any of the first to ninth aspects, in which

at least one of Yaⁱ in the formula (1-2) is a 1,3-phenylene group, and at least one of Za¹ is a 1,3-phenylene group.

According to an eleventh aspect of the present invention,

there is provided the material for an emission layer according to any of the first to tenth aspects, in which at least one of Xaⁱ in the formula (1-2) is a 1,3-phenylene group.

According to a twelfth aspect of the present invention,

there is provided the material for an emission layer according to any of the first to eleventh aspects, in which

in the formula (1-1), —(Xa¹)_{g11}—Xa² is selected from the structure group of the following formula (Xa-1), —(Ya¹)ₕ₁₁-Ya² is selected from the structure group of the following formula (Ya-1), and —(Za¹)ⱼ₁₁—Za² is selected from the structure group of the following formula (Za-1), and

in the formula (1-2), —(Xa¹)_{g11}—Xa² is selected from the structure group of the following formula (Xa-2), —(Ya¹)ₕ₁₁—Ya² is selected from the structure group of the following formula (Ya-2), and —(Za¹)ⱼ₁₁—Za² is selected from the structure group of the following formula (Za-2).

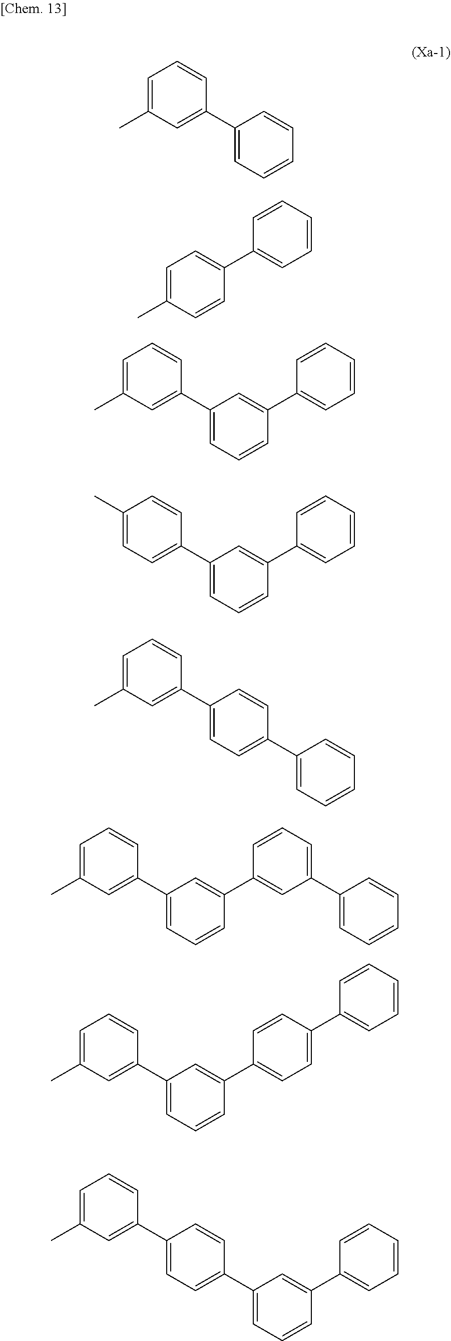

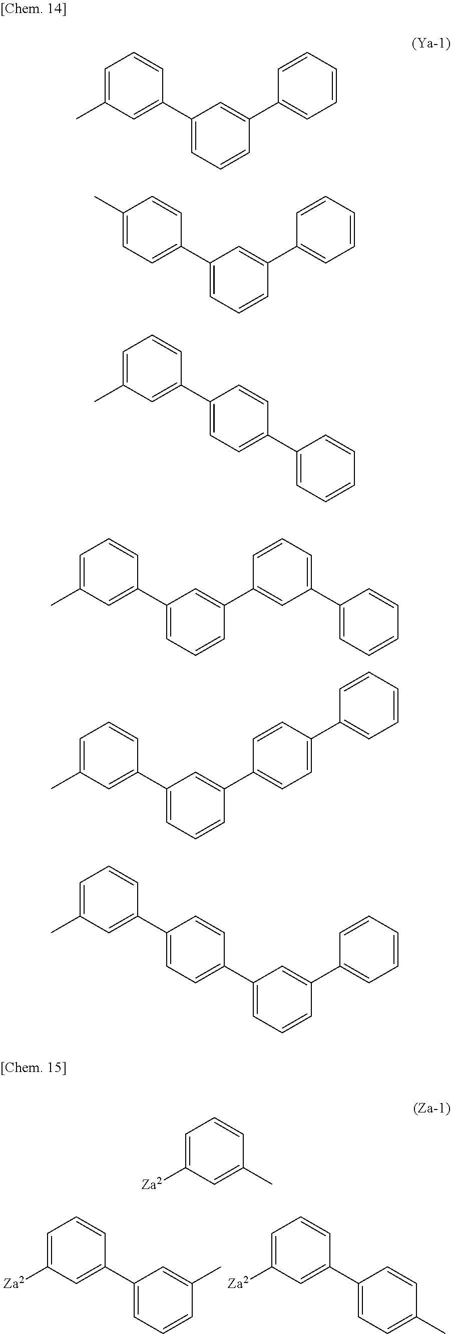

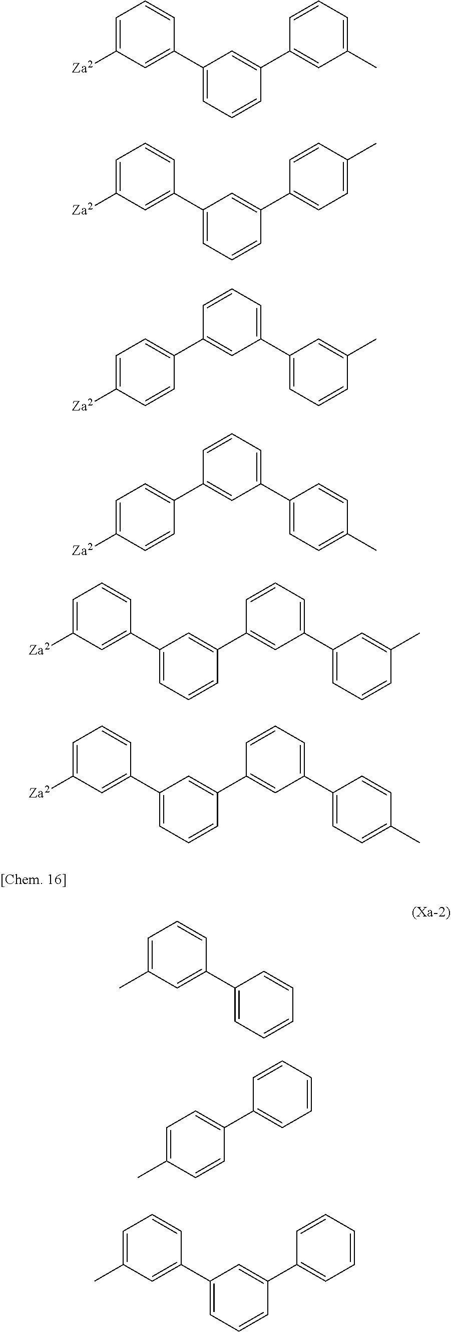

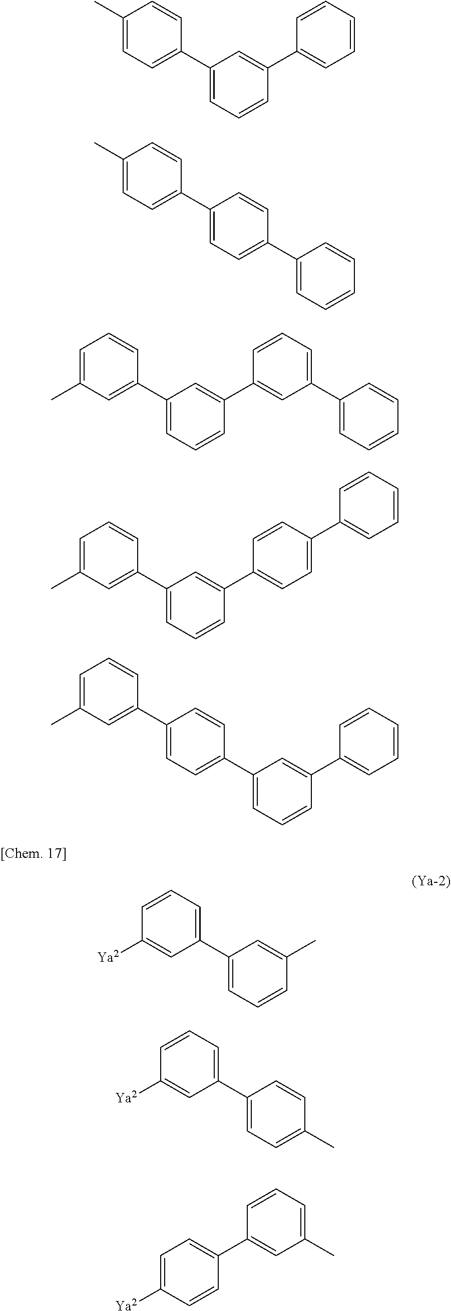

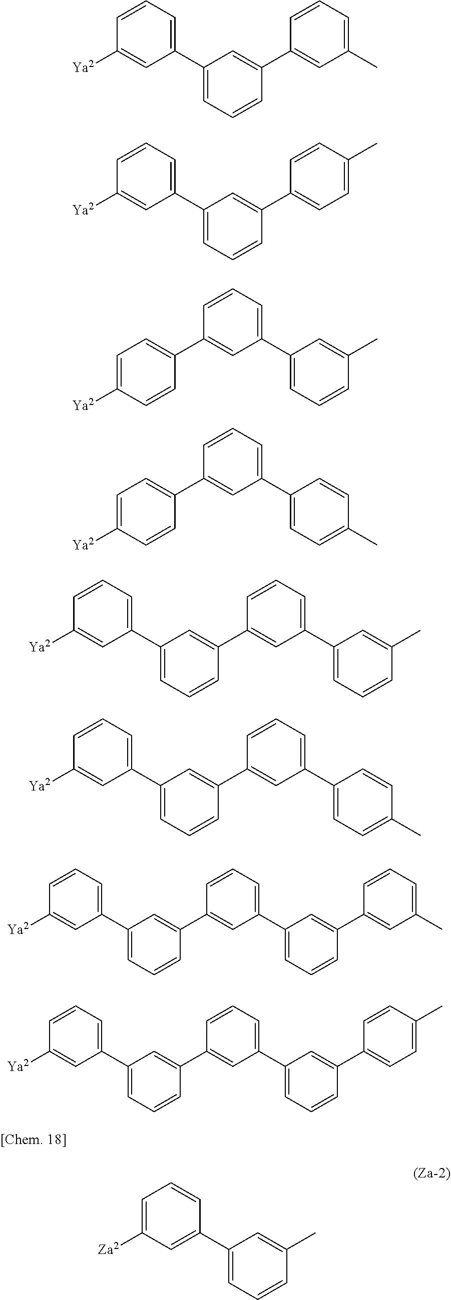

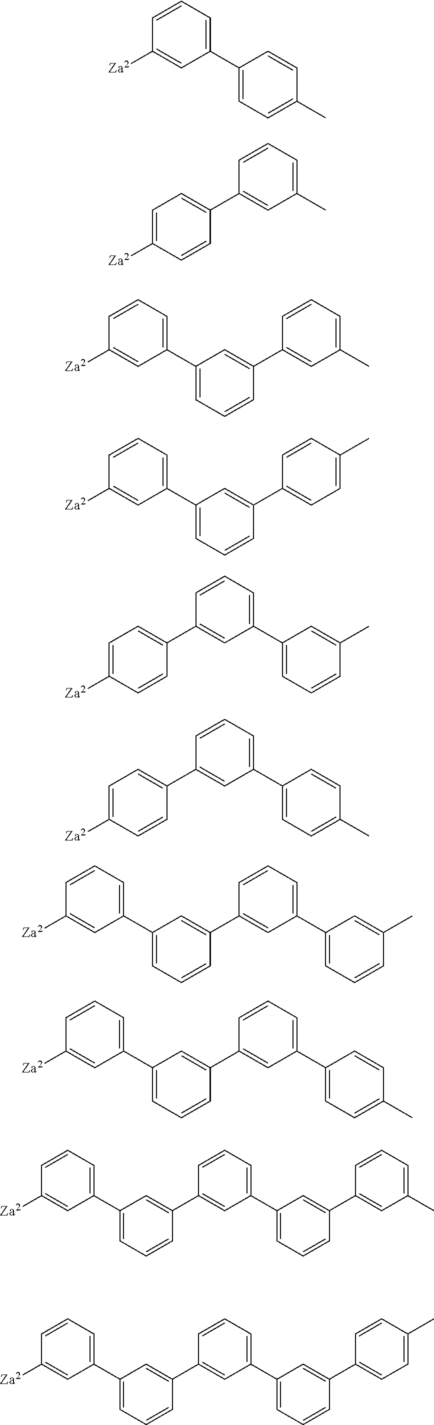

According to a thirteenth aspect of the present invention,

there is provided the material for an emission layer according to any of the first to twelfth aspects, including:

at least one compound selected from the compound represented by the formula (1-1) and the compound represented by the formula (1-2), in which all of W₁, W₂, and W₃ in the at least one compound are nitrogen atoms.

According to a fourteenth aspect of the present invention,

there is provided the material for an emission layer according to any of the first to thirteenth aspects, in which

a compound contained as the compound of (group A), (group B), or (group C) and the luminescent material all have a molecular weight of 1,200 or more.

According to a fifteenth aspect of the present invention,

there is provided an organic electroluminescent element including:

at least an anode, a cathode, and an emission layer located between the anode and the cathode, in which

the emission layer contains the material for an emission layer according to any of the first to fourteenth aspects.

According to a sixteenth aspect of the present invention,

there is provided a composition for forming an emission layer, including:

the material for an emission layer according to any of the first to fourteenth aspects, and

a second organic solvent.

According to a seventeenth aspect of the present invention,

there is provided the composition for forming an emission layer according to the sixteenth aspect, in which

the second organic solvent contains at least two kinds of organic solvents, and

a boiling point of at least one kind of the organic solvents is 200° C. or higher.

According to an eighteenth aspect of the present invention,

there is provided a method for producing an organic electroluminescent element including at least an anode, a cathode, and an emission layer located between the anode and the cathode, the method including:

a step of forming the emission layer by a wet-process film formation method using the composition for forming an emission layer according to the sixteenth or seventeenth aspect.

According to a nineteenth aspect of the present invention,

there is provided a method for producing an organic electroluminescent element including at least an anode, a cathode, an emission layer located between the anode and the cathode, and a layer in contact with a cathode side of the emission layer, in which

the emission layer is formed by a wet-process film formation method using the composition for forming an emission layer according to the sixteenth or seventeenth aspect, and

a step of forming the layer in contact with the cathode side of the emission layer includes

a step of forming the layer in contact with the cathode side of the emission layer by applying a composition for layer formation to a surface of the emission layer by an inkjet method and a step of drying the layer in contact with the cathode side of the emission layer in this order, the composition for layer formation containing a functional material and a first organic solvent, the first organic solvent containing at least two kinds of organic solvents, and a boiling point of at least one kind of the organic solvents contained in the first organic solvent being 200° C. or higher.

According to a twentieth aspect of the present invention,

there is provided the method for producing an organic electroluminescent element according to the nineteenth aspect, in which

the functional material is an electron-transporting compound.

According to a twenty-first aspect of the present invention,

there is provided the method for producing an organic electroluminescent element according to the nineteenth or twentieth aspect, in which the boiling point of at least one kind of the organic solvents contained in the first organic solvent is 230° C. or higher.

According to a twenty-second aspect of the present invention,

there is provided the method for producing an organic electroluminescent element according to any of the nineteenth to twenty-first aspects, in which

the boiling point of at least one kind of the organic solvents contained in the first organic solvent is lower than 200° C.

According to a twenty-third aspect of the present invention,

there is provided the method for producing an organic electroluminescent element according to any of the nineteenth to twenty-second aspects, in which

at least one kind of the organic solvents contained in the first organic solvent is a protic polar organic solvent.

According to a twenty-fourth aspect of the present invention,

there is provided the method for producing an organic electroluminescent element according to any of the nineteenth to twenty-third aspects, in which

at least one kind of the organic solvents contained in the first organic solvent is an alcohol-based organic solvent.

### Advantageous Effects of Invention

According to the present invention, it is possible to provide a material for an emission layer capable of providing an organic electroluminescent element exhibiting high luminescent efficiency in order to achieve a wide energy gap and appropriate charge transportability.

Further, according to the present invention, it is possible to provide a method for producing an organic electroluminescent element, a display device, and an illuminator using the material for an emission layer, as well as an organic electroluminescent element, a display device, and an illuminator obtained by the production method.

### BRIEF DESCRIPTION OF DRAWINGS

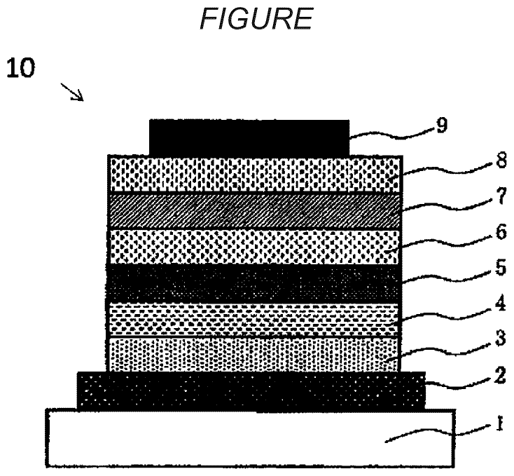

The FIG. 1s a cross-sectional view schematically showing an example of a structure of an organic electroluminescent element according to the present invention.

### DESCRIPTION OF EMBODIMENTS

Hereinafter, embodiments of the present invention will be described in detail, but the present invention is not limited to the following embodiments, and can be implemented with various modifications within the scope of a gist thereof. When the expression “to” is used in the present description, it is used as an expression including numerical values or physical property values before and after it.

### [Composition for Layer Formation]

The composition for layer formation according to the present invention is a composition for layer formation for forming an organic layer in contact with a cathode side of an emission layer by coating using an inkjet method, the composition for layer formation containing a functional material and a first organic solvent, the first organic solvent containing at least two kinds of organic solvents, and a boiling point of at least one kind of the organic solvents contained in the first organic solvent being 200° C. or higher. In the present description, the organic solvent contained in the composition for layer formation is referred to as the first organic solvent.

The “boiling point” mentioned in the present description refers to a boiling point measured under a normal pressure (1 atm) unless otherwise noted.

### (First Organic Solvent)

The composition for layer formation according to the present invention contains at least two kinds of organic solvents as the first organic solvent, and the boiling point of at least one kind of the organic solvents is 200° C. or higher.

An organic solvent that can be used in the present invention and has a boiling point of 200° C. or higher is not particularly limited as long as the boiling point thereof is 200° C. or higher. From the viewpoint of preventing clogging of the inkjet head, the boiling point of at least one kind of the organic solvents contained in the first organic solvent is preferably 230° C. or higher, and more preferably 240° C. or higher.

In addition, examples of the organic solvent that can be used as the first organic solvent according to the present invention and has a boiling point of 200° C. or higher include alcohol-based organic solvents, aromatic organic solvents, halogen-containing organic solvents, aliphatic ether-based organic solvents, aromatic ether-based organic solvents, aliphatic ester-based organic solvents, and aromatic ester-based organic solvents. Among those, from the viewpoint of well dissolving an electron transport material and hardly dissolving a material of the emission layer, a protic polar organic solvent is preferable, and a protic polar organic solvent having a hydrogen atom bonded to oxygen or nitrogen is more preferable. Examples of such a protic polar organic solvent include alcohol-based organic solvents, amide-based organic solvents, and phenol-based organic solvents. Among those, alcohol-based organic solvents and amide-based organic solvents are preferable, and alcohol-based organic solvents are more preferable.

Specific examples of the alcohol-based organic solvent that can be used as the first organic solvent according to the present invention and has a boiling point of 200° C. or higher include 2-butyl-1-n-octanol, nonanol, decanol, benzyl alcohol, diethylene glycol, phenoxyethanol, diethylene glycol monobutyl ether, and phenoxyethoxy ethanol. Among those, in terms of viscosity, 2-butyl-1-n-octanol, decanol, and diethylene glycol are preferable, 2-butyl-1-n-octanol and diethylene glycol are more preferable, and 2-butyl-1-n-octanol is still more preferable.

Specific examples of the aromatic organic solvent that can be used as the first organic solvent according to the present invention and has a boiling point of 200° C. or higher include cyclohexylbenzene and methylnaphthalene.

Specific examples of the halogen-containing organic solvent that can be used as the first organic solvent according to the present invention and has a boiling point of 200° C. or higher include 1,2,4-trichlorobenzene.

Specific examples of the aliphatic ether-based organic solvent that can be used as the first organic solvent according to the present invention and has a boiling point of 200° C. or higher include ethylene glycol dibutyl ether.

Specific examples of the aromatic ether-based organic solvent that can be used as the first organic solvent according to the present invention and has a boiling point of 200° C. or higher include 1,2-dimethoxybenzene.

Specific examples of the aliphatic ester-based organic solvent that can be used as the first organic solvent according to the present invention and has a boiling point of 200° C. or higher include propylene carbonate.

Specific examples of the aromatic ester-based organic solvent that can be used as the first organic solvent according to the present invention and has a boiling point of 200° C. or higher include phenyl propionate, ethyl benzoate, isopropyl benzoate, propyl benzoate, and n-butyl benzoate.

The at least two kinds of organic solvents contained as the first organic solvent in the composition for layer formation according to the present invention may both be organic solvents having a boiling point of 200° C. or higher, or may include at least one kind of organic solvent having a boiling point of lower than 200° C.

Examples of the organic solvent that may be contained as the first organic solvent in the composition for layer formation according to the present invention and of which boiling point is lower than 200° C. include alcohol-based organic solvents, aromatic organic solvents, halogen-containing organic solvents, aliphatic ether-based organic solvents, aromatic ether-based organic solvents, aliphatic ester-based organic solvents, and aromatic ester-based organic solvents. Among those, from the viewpoint of well dissolving an electron transport material and hardly dissolving a material of the emission layer, a protic polar organic solvent having a hydrogen atom bonded to oxygen or nitrogen is preferable. Examples of such a protic polar organic solvent include alcohol-based organic solvents, amide-based organic solvents, and phenol-based organic solvents. Among those, alcohol-based organic solvents and amide-based organic solvents are preferable, and alcohol-based organic solvents are more preferable.

Specific examples of the alcohol-based organic solvent that can be used as the first organic solvent according to the present invention and has a boiling point of lower than 200° C. include 1-propanol, 2-propanol, 1-butanol, 2-butanol, iso-butyl alcohol, tert-butyl alcohol, 1-pentanol, 2-pentanol, 3-pentanol, iso-pentyl alcohol, tert-pentyl alcohol, 3-methyl-2-butanol, neopentyl alcohol, 1-hexanol, 2-methyl-1-pentanol, 4-methyl-2-pentanol, 2-ethyl-1-butanol, 1-heptanol, 2-heptanol, 3-heptanol, 4-heptanol, 2-methyl-1-hexanol, and ethylene glycol. Among those, 1-butanol, 1-heptanol, 1-octanol, and ethylene glycol are preferable, 1-butanol, 1-heptanol, and ethylene glycol are more preferable, and 1-butanol and 1-heptanol are still more preferable because they are less likely to dissolve a material for an emission layer.

Specific examples of the aromatic organic solvent that can be used as the first organic solvent according to the present invention and has a boiling point of lower than 200° C. include toluene, xylene, and mesitylene.

Specific examples of the halogen-containing organic solvent that can be used as the first organic solvent according to the present invention and has a boiling point of lower than 200° C. include 1,2-dichloroethane, chlorobenzene, and o-dichlorobenzene.

Specific examples of the aliphatic ether-based organic solvent that can be used as the first organic solvent according to the present invention and has a boiling point of lower than 200° C. include ethylene glycol dimethyl ether and propylene glycol-1-monomethyl ether acetate (PGMEA).

Specific examples of the aromatic ether-based organic solvent that can be used as the first organic solvent according to the present invention and has a boiling point of lower than 200° C. include 1,3-dimethoxybenzene, anisole, phenetole, 2-methoxytoluene, 3-methoxytoluene, 4-methoxytoluene, and 2,4-dimethylanisole.

Specific examples of the aliphatic ester-based organic solvent that can be used as the first organic solvent according to the present invention and has a boiling point of lower than 200° C. include ethyl acetate, n-butyl acetate, ethyl lactate, n-butyl lactate, and the like.

Specific examples of the aromatic ester-based organic solvent that can be used as the first organic solvent according to the present invention and has a boiling point of lower than 200° C. include phenyl acetate and methyl benzoate.

Since a boiling point of at least one kind of the at least two kinds of organic solvents contained as the first organic solvent in the composition for layer formation according to the present invention is 200° C. or higher, in a case where an organic layer in contact with a cathode side of the emission layer is formed by an inkjet method using the composition for layer formation, ejection performance is good, clogging of the inkjet head is avoided, and the possibility of deterioration due to partial dissolution of the emission layer can be reduced.

The reason why the use of the composition for layer formation according to the present invention makes it possible to obtain good ejection performance, avoid clogging of the inkjet head, and reduce the possibility of deterioration due to partial dissolution of the emission layer is unclear, but is considered to be as follows.

First, it is considered that the good ejection performance and the avoidance of clogging of the inkjet head are achieved because the first organic solvent contained in the composition for layer formation according to the present invention is less likely to evaporate. More specifically, it is considered that since at least one kind of organic solvent having a boiling point of 200° C. or higher as the first organic solvent is contained, evaporation of the organic solvent from the composition for layer formation at the time of coating by the inkjet method is avoided, and thus an increase in concentration of the functional material due to the evaporation of the organic solvent, as well as an increase in viscosity of the composition for layer formation and partial precipitation of the functional material accompanying the increase in concentration can be prevented. In addition, it is considered that it is possible to prevent deterioration of the ejection performance and clogging of the inkjet due to the composition for layer formation having an increased viscosity and the precipitated functional material.

In addition, it is considered that the reduction of the possibility of deterioration due to partial dissolution of the emission layer is achieved because the first organic solvent contained in the composition for layer formation according to the present invention has relatively high viscosity.

In general, as an interaction between organic solvent molecules increases, the boiling point and the viscosity tend to increase, and as the viscosity of the organic solvent is higher, the more difficult it tends to be for the organic solvent to permeate into a base to which the organic solvent is coated. It is considered that the organic solvent having a boiling point of 200° C. or higher contained as the first organic solvent in the composition for layer formation according to the present invention tends to have higher viscosity than an organic solvent having a boiling point lower than that of the first organic solvent, and permeation of the organic solvent into the emission layer corresponding to the base and deterioration due to partial dissolution of the emission layer accompanying the permeation are prevented.

In a case where the first organic solvent of the composition for layer formation according to the present invention contains an organic solvent having a boiling point of lower than 200° C., the organic solvent having a boiling point of lower than 200° C. is dried relatively quickly in a micro droplet state after inkjet coating. Accordingly, it is considered that when the concentration of the functional material in the composition for layer formation after inkjet coating is increased, the viscosity of the composition for layer formation is increased, and the possibility of deterioration due to partial dissolution of the emission layer can be reduced more effectively.

The number of kinds of the organic solvents contained in the composition for layer formation according to the present invention as the first organic solvent may be at least two, and is preferably 2 to 5, more preferably 2 to 4, and still more preferably 2 to 3 because the viscosity and a vapor pressure can be adjusted.

In a case where the organic solvent contained in the composition for layer formation according to the present invention as the first organic solvent is composed of both an organic solvent having a boiling point of 200° C. or higher and an organic solvent having a boiling point of lower than 200° C., a composition ratio (vol.:vol.) of the organic solvent having a boiling point of 200° C. or higher to the organic solvent having a boiling point of lower than 200° C. is not particularly limited. In terms of the viewpoint that the possibility of deterioration due to partial dissolution of the emission layer can be reduced, the composition ratio is preferably 20:80 to 90:10, more preferably 40:60 to 80:20, and still more preferably 50:50 to 70:30. In the first organic solvent, in a case where the organic solvent having a boiling point of 200° C. or higher is composed of two or more kinds of organic solvents, the above composition ratio is obtained based on a sum of volumes of these organic solvents. The same applies to a case where the organic solvent having a boiling point of lower than 200° C. is composed of two or more kinds of organic solvents.

As described above, at least one kind of the organic solvents contained in the composition for layer formation according to the present invention as the first organic solvent is preferably a protic polar organic solvent. Regardless of whether a boiling point of the protic polar organic solvent is 200° C. or higher or lower than 200° C., by containing such an organic solvent, an effect of making the material of the emission layer less likely to dissolve is obtained. Examples of such a protic polar organic solvent include alcohol-based organic solvents, amide-based organic solvents, and phenol-based organic solvents. Among those, alcohol-based organic solvents and amide-based organic solvents are preferable, and alcohol-based organic solvents are more preferable.

### (Functional Material)

The composition for layer formation according to the present invention contains a functional material. The functional material is not particularly limited as long as it can be used for the organic layer in contact with the cathode side of the emission layer, and examples thereof include an electron-transporting compound and a hole blocking compound. Among those, from the viewpoint of efficiently transporting electrons from the cathode to the emission layer, an electron-transporting compound and a hole blocking compound are preferable, and an electron-transporting compound is more preferable.

In the present description, the electron-transporting compound and the hole blocking compound are also referred to as an electron transport material and a hole blocking material, respectively.

The functional material in the present invention is not particularly limited and may be a low molecular weight compound having a single structure or a polymer compound having a repeating unit.

A molecular weight of the functional material of a low molecular weight compound in the present invention is not particularly limited, and may be, for example, 300 to 10,000. Among those, in terms of solubility and heat resistance, the molecular weight is preferably 400 to 5,000, more preferably 500 to 4,000, and still more preferably 700 to 3,000.

In addition, a molecular weight of the functional material of a polymer compound in the present invention is not particularly limited, and may be, for example, 5,000 to 1,000,000. Among those, the molecular weight is preferably 10,000 to 500,000, more preferably 12,000 to 100,000, and still more preferably 15,000 to 50,000. When an average weight molecular weight of the polymer compound of the present invention is equal to or less than the above upper limit, solubility in the first organic solvent is easily obtained, and when an average weight molecular weight of the polymer compound of the present invention is equal to or greater than the upper limit, heat resistance of the organic layer is improved.

In a case where the compound used in the present description is a polymer compound, the molecular weight refers to a weight average molecular weight (Mw) unless otherwise noted.

As the functional material in the present invention, a hole blocking compound and an electron-transporting compound to be described later can be used, and an electron-transporting compound is preferable.

The composition for layer formation according to the present invention may contain only one kind of functional material, or may contain two or more kinds of functional materials.

The concentration of the functional material contained in the composition for layer formation according to the present invention is not particularly limited, and may be, for example, 0.1 mg/mL to 50 mg/mL with respect to a total amount of the first organic solvent contained in the composition for layer formation. In terms of viscosity of the composition, the concentration is preferably 0.5 mg/mL to 30 mg/mL, more preferably 1 mg/mL to 25 mg/mL, and still more preferably 5 mg/mL to 20 mg/mL.

### (Use)

In one aspect, the composition for layer formation according to the present invention can be a composition for forming the organic layer in contact with the cathode side of the emission layer by coating with an inkjet method. More specifically, the composition for layer formation is preferably a composition for forming the organic layer in contact with the cathode side of the emission layer of the organic electroluminescent element by coating with an inkjet method, is preferably a composition for forming the electron transport layer or the hole blocking layer of the organic electroluminescent element by coating with an inkjet method, and is more preferably a composition for forming the electron transport layer of the organic electroluminescent element by coating with an inkjet method.

### [Organic Layer]

The organic layer formed by coating with an inkjet method using the composition for layer formation according to the present invention is the organic layer in contact with the cathode side of the emission layer. Since the organic layer is a layer formed in contact with the cathode side of the emission layer, it preferably has a function of efficiently transporting electrons from the cathode to the emission layer and preventing an excited state generated in the emission layer from escaping to the outside of the emission layer.

A thickness (film thickness) of the organic layer formed by coating with an inkjet method using the composition for layer formation according to the present invention is not particularly limited, and may be, for example, 1 nm to 100 nm. In terms of the viewpoint of power consumption of an element, the thickness is preferably 2 nm to 80 nm, more preferably 5 nm to 50 nm, and still more preferably 10 nm to 30 nm.

[Formation of Organic Layer by Coating with Inkjet Method]

The emission layer according to the present invention generally has a minute region in which emission pixels are partitioned by a partition called a bank on a substrate provided with an electrode. The composition for layer formation according to the present invention is coated by an inkjet method in the minute region partitioned by the bank and dried to form an organic layer.

The inkjet method is a method of ejecting droplets smaller than the minute region partitioned by the bank from a minute nozzle of an inkjet head, and it is preferable that the minute region partitioned by the bank is filled with the composition for layer formation by ejecting a plurality of droplets.

For example, the minute region partitioned by the bank is filled with the composition for layer formation, and then dried. As an example of drying, for example, vacuum drying in which an organic solvent is volatilized by reducing a pressure can be adopted.

An inkjet device that can be used in the present invention is not particularly limited as long as it is used in the technical field, and examples thereof include a material printer DMP-2831 made of FUJIFILM, and a PJ-1080A made by CANON INC.

### [Method for Producing Organic Electroluminescent Element and Organic Electroluminescent Element]

### (Method for Producing Organic Electroluminescent Element)

A method for producing an organic electroluminescent element according to the present invention is a method for producing an organic electroluminescent element including at least an anode, a cathode, an emission layer located between the anode and the cathode, and a layer in contact with a cathode side of the emission layer, including a step of forming a layer in contact with the cathode side of the emission layer by applying a composition for layer formation to a surface of the emission layer by an inkjet method and a step of drying the layer in contact with the cathode side of the emission layer in this order, the layer in contact with the cathode side of the emission layer including a functional material and a first organic solvent, the first organic solvent containing at least two kinds of organic solvents, and a boiling point of at least one kind of the organic solvents contained in the first organic solvent being 200° C. or higher. The emission layer in the production method is preferably formed by a wet-process film formation method using a composition for forming an emission layer to be described later.

Specific examples and preferred embodiments of the first organic solvent and the functional material used in the method for producing an organic electroluminescent element according to the present invention are as described above.

Hereinafter, a preferred example of a layer structure of the organic electroluminescent element produced using the composition for layer formation according to the present invention will be described with reference to the FIGURE.

The FIG. 1s a schematic cross-sectional view showing a structural example of an organic electroluminescent element 10 according to the present invention. In the FIGURE, 1 denotes a substrate, 2 denotes an anode, 3 denotes a hole injection layer, 4 denotes a hole transport layer, 5 denotes an emission layer, 6 denotes a hole blocking layer, 7 denotes an electron transport layer, 8 denotes an electron injection layer, and 9 denotes a cathode. In this case, in a method for producing the organic electroluminescent element 10 according to the present invention, a layer in contact with a cathode 9 side of the emission layer 5 corresponds to the hole blocking layer 6.

In the organic electroluminescent element 10 according to the present invention, the hole blocking layer 6 may be omitted and the electron transport layer 7 may be formed in contact with the emission layer 5. In this case, in the method for producing the organic electroluminescent element 10 according to the present invention, the layer in contact with the cathode 9 side of the emission layer 5 corresponds to the electron transport layer 7.

In the method for producing an organic electroluminescent element according to the present invention, the layer in contact with the cathode side of the emission layer is preferably an electron transport layer. In addition, the functional material is preferably an electron-transporting compound.

The organic electroluminescent element according to the present invention includes the anode, the emission layer, the layer in contact with the cathode side of the emission layer, and the cathode as essential constituent layers, but as necessary, other functional layers may be provided between the anode 2 and the emission layer 5 and between the cathode 9 and the emission layer 5 as shown in the FIGURE.

### (Substrate)

The substrate 1 serves as a support of the organic electroluminescent element. As the substrate 1, a plate of quartz or glass, a metal plate, a metal foil, a plastic film, a sheet, or the like is used. In particular, a glass plate, and a plate of a transparent synthetic resin such as polyester, polymethacrylate, polycarbonate, and polysulfone are preferable. In a case where a synthetic resin substrate is used, it is preferable to pay attention to a gas barrier property. The gas barrier property of the substrate is preferably large such that the organic electroluminescent element is hardly deteriorated by an outside air passing through the substrate. Therefore, a method of providing a dense silicon oxide film or the like on at least one surface of the synthetic resin substrate to ensure the gas barrier property is also a preferable method.

### (Anode)

The anode 2 is an electrode that plays a role of injecting holes into a layer on an emission layer 5 side.

The anode 2 is generally formed of a metal such as aluminum, gold, silver, nickel, palladium, and platinum, a metal oxide such as an oxide of indium and/or tin, a metal halide such as copper iodide, a conductive polymer such as carbon black, poly(3-methylthiophene), polypyrrole, and polyaniline, and the like.

The anode 2 is frequently formed generally by a method such as a sputtering method, a vacuum deposition method, and the like.

In a case where fine particles of a metal such as silver, fine particles of copper iodide and the like, carbon black, fine particles of a conductive metal oxide, fine powder of a conductive polymer, and the like are used to form the anode 2, the anode 2 can also be formed by dispersing such particulate materials in an appropriate binder resin solution and applying the dispersion on the substrate 1.

In a case of a conductive polymer, a thin film can be formed directly on the substrate 1 by electrolytic polymerization.

The anode 2 can also be formed by applying the conductive polymer on the substrate 1 (Appl. Phys. Lett., volume 60, p. 2711, 1992).

The anode 2 generally has a single-layer structure, but may have a multilayer structure made of a plurality of materials if desired.

A thickness of the anode 2 may be appropriately selected according to required transparency and the like. In a case where the transparency is required, visible light transmittance is generally 60% or more, preferably 80% or more. In this case, the thickness of the anode 2 is generally 5 nm or more, preferably 10 nm or more, and is generally 1,000 nm or less, preferably 500 nm or less. In a case where the anode 2 may be non-transparent, the thickness of the anode 2 is any thickness. The substrate 1 which combines a function of the anode 2 may be used. A different conductive material may be superposed on the above anode 2.

For the purpose of removing impurities adhering to the anode 2 and adjusting an ionization potential to improve a hole injection property, it is preferable to subject a surface of the anode 2 to an ultraviolet (UV)/ozone treatment, or an oxygen plasma treatment or an argon plasma treatment.

### (Hole Injection Layer)

The hole injection layer 3 is a layer that transports holes from the anode 2 to the emission layer 5. In a case where the hole injection layer 3 is provided, the hole injection layer 3 is generally formed on the anode 2.

A method for forming the hole injection layer 3 may be a vacuum deposition method or a wet-process film formation method, and is not particularly limited. The hole injection layer 3 is preferably formed by a wet-process film formation method from the viewpoint of reducing dark spots.

A film thickness of the hole injection layer 3 is in a range of generally 5 nm or more, preferably 10 nm or more, and is generally 1,000 nm or less, preferably 500 nm or less.

### <Hole-transporting Material>

A composition for forming a hole injection layer generally contains a hole-transporting material and a solvent as constituent materials of the hole injection layer 3.

The hole-transporting material may be a polymer compound such as a polymer and a low molecular weight compound such as a monomer as long as the hole-transporting material is a compound having hole transportability which is generally used for the hole injection layer 3 of the organic electroluminescent element, but is preferably a polymer compound.

The hole-transporting material is preferably a compound having an ionization potential of 4.5 eV to 6.0 eV from the viewpoint of a charge injection barrier from the anode 2 to the hole injection layer 3. Examples of the hole-transporting material include an aromatic amine derivative, a phthalocyanine derivative, a porphyrin derivative, an oligothiophene derivative, a polythiophene derivative, a benzylphenyl derivative, a compound in which a tertiary amine is linked with a fluorene group, a hydrazone derivative, a silazane derivative, a silanamine derivative, a phosphamine derivative, a quinacridone derivative, a polyaniline derivative, a polypyrrole derivative, a polyphenylene vinylene derivative, a polythienylene vinylene derivative, a polyquinoline derivative, a polyquinoxaline derivative, and carbon.

In the present invention, when an aromatic amine derivative is taken as an example, the derivative is a derivative containing an aromatic amine and a compound having an aromatic amine as a main framework, and may be a polymer or a monomer.

The hole-transporting material used as a material of the hole injection layer 3 may contain one kind of such compounds alone, or may contain two or more kinds thereof. In a case where two or more kinds of hole-transporting materials are contained, a combination thereof is optional, and it is preferable to use one kind or two or more kinds of aromatic tertiary amine polymer compounds in combination with one kind or two or more kinds of other hole-transporting materials.

Among the exemplified examples described above, an aromatic amine compound is preferable and an aromatic tertiary amine compound is particularly preferable as the hole-transporting material, in terms of amorphous property and visible light transmittance. The aromatic tertiary amine compound is a compound having an aromatic tertiary amine structure, and also includes a compound having a group derived from an aromatic tertiary amine.

A type of the aromatic tertiary amine compound is not particularly limited, but a polymer compound having a weight average molecular weight of 1,000 or more and 1,000,000 or less (polymerization-type compound in which repeating units are continuous) is still more preferable in terms of uniform luminescence obtained by a surface smoothing effect. Preferred examples of the aromatic tertiary amine polymer compound include a polymer compound having a repeating unit represented by the following formula (51) or the following formula (61).

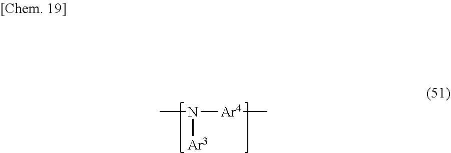

(In the formula (51), Ar³ represents an aromatic hydrocarbon group or an aromatic heterocyclic group which may have a substituent, and Ar⁴ represents a divalent aromatic hydrocarbon group or a divalent aromatic heterocyclic group which may have a substituent, or a divalent group in which a plurality of aromatic hydrocarbon groups and aromatic heterocyclic groups are linked directly or via a linking group.)

In the formula (51), a linking group in a case where a plurality of aromatic hydrocarbon groups and aromatic heterocyclic groups are linked via the linking group is a divalent linking group, and examples thereof include a group in which 1 to 30, preferably 1 to 5, and more preferably 1 to 3 groups selected from a —O—group, a —C(═O)— group, and a —CH₂—group (which may have a substituent) are linked in any order.

Among the linking groups, Ar⁴ in the formula (51) preferably represents a plurality of aromatic hydrocarbon groups or aromatic heterocyclic groups linked via a linking group represented by the following formula (52) in terms of excellent hole injection into the emission layer.

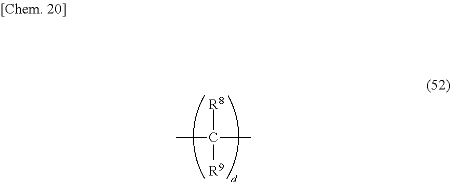

(In the formula (52), d represents an integer of 1 to 10, R⁸ and R⁹ each independently represent a hydrogen atom, or an alkyl group, an aromatic hydrocarbon group, or an aromatic heterocyclic group which may have a substituent.

In a case where there are a plurality of R⁸ and R⁹, they may be the same as or different from each other.)

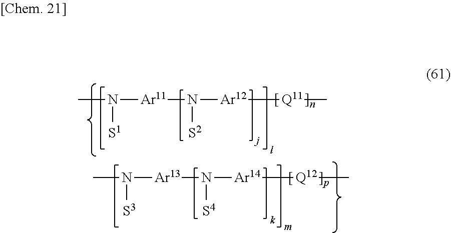

In the formula (61), j, k, l, m, n, and p each independently represent an integer of 0 or more. Here, l+m≥1. Ar¹¹, Ar¹², and Ar¹⁴ each independently represent a divalent aromatic ring group having 30 or less carbon atoms which may have a substituent. Ar¹³ represents a divalent aromatic ring group having 30 or less carbon atoms which may have a substituent or a divalent group represented by the following formula (62), Q¹¹ and Q¹² each independently represent an oxygen atom, a sulfur atom, or a hydrocarbon chain having 6 or less carbon atoms which may have a substituent, and S¹ to S⁴ each independently represent a group represented by the following formula (63).

Here, the aromatic ring group refers to an aromatic hydrocarbon group and an aromatic heterocyclic group.

Examples of the aromatic ring groups represented by Ar¹¹, Ar¹², and Ar¹⁴ include monocyclic rings, 2- to 6-condensed rings, or groups in which two or more of these aromatic rings are linked. Specific examples of the aromatic ring group of a monocyclic ring or a 2- to 6-condensed ring include a divalent group derived from a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, a fluorene ring, a biphenyl group, a terphenyl group, a quaterphenyl group, a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzoisoxazole ring, a benzoisothiazole ring, a benzoimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a perimidine ring, a quinazoline ring, a quinazolinone ring, or an azulene ring. Among those, a divalent group derived from a benzene ring, a naphthalene ring, a fluorene ring, a pyridine ring, or a carbazole ring, or a biphenyl group is preferable because negative charges are efficiently delocalized, and stability and heat resistance are excellent.

Examples of the aromatic ring group of Ar¹³ are the same as those of Ar¹¹, Ar¹², and Ar¹⁴.

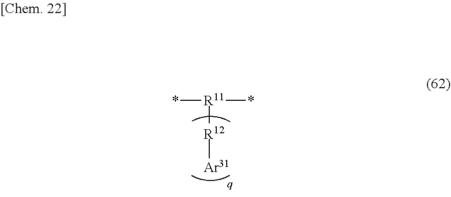

In the above formula (62), R¹¹ represents an alkyl group, an aromatic ring group, or a trivalent group composed of an alkyl group and an aromatic ring group having 40 or less carbon atoms, and those groups may have a substituent. R¹² represents an alkyl group, an aromatic ring group, or a divalent group composed of an alkyl group having 40 or less carbon atoms and an aromatic ring group, and those groups may have a substituent. Ar³¹ represents a monovalent aromatic ring group or a monovalent crosslinking group, and the groups may have a substituent. q represents 1 to 4. In a case where q is 2 or more, a plurality of R¹² may be the same as or different from each other, and a plurality of Ar³¹ may be the same as or different from each other. The asterisk (*) represents a bond to the nitrogen atom of the formula (61).

The aromatic ring group represented by R¹¹ is preferably one aromatic ring group which is a monocyclic or a condensed ring having 3 to 30 carbon atoms or a group in which 2 to 6 monocyclic or condensed ring groups are linked. Specific examples thereof include a benzene ring, a fluorene ring, a naphthalene ring, a carbazole ring, a dibenzofuran ring, a dibenzothiophene ring, and a trivalent group derived from a group in which 2 to 6 of those rings are linked.

The alkyl group represented by R¹¹ is preferably an alkyl group having 1 to 12 carbon atoms and containing a straight chain, a branched chain, or a ring, and specific examples thereof include a group derived from methane, ethane, propane, isopropane, butane, isobutane, pentane, hexane, and octane.

The group composed of an alkyl group having 40 or less carbon atoms and an aromatic ring group represented by R¹¹ is preferably a group in which an alkyl group having 1 or more and 12 or less carbon atoms and containing a straight chain, a branched chain, or a ring is linked to one or 2 to 6 aromatic ring groups each being a monocyclic ring or a condensed ring having 3 or more and 30 or less carbon atoms.

Specific examples of the aromatic ring group represented by R¹² include a benzene ring, a fluorene ring, a naphthalene ring, a carbazole ring, a dibenzofuran ring, a dibenzothiophene ring, and a divalent group derived from a linking ring having 30 or less carbon atoms to which these rings are linked.

Specific examples of the alkyl group represented by R¹² include a divalent group derived from methane, ethane, propane, isopropane, butane, isobutane, pentane, hexane, and octane.

Specific examples of the aromatic ring group represented by Ar³¹ include a benzene ring, a fluorene ring, a naphthalene ring, a carbazole ring, a dibenzofuran ring, a dibenzothiophene ring, and a monovalent group derived from a linking ring having 30 or less carbon atoms to which these rings are linked.

Preferred examples of a structure of the formula (62) include the following structures, and a benzene ring or a fluorene ring of a main chain in the following structure which is a substructure represented by R¹¹ may further have a substituent.

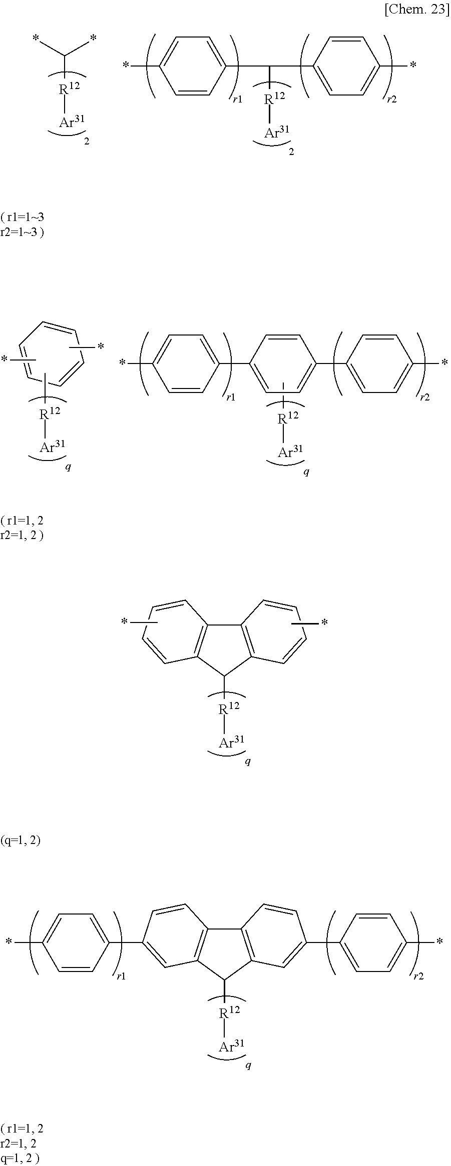

Examples of the crosslinking group of Ar³¹ include a vinyl group, an acrylic group, and a group derived from a benzocyclobutene ring, a naphthocyclobutene ring, or an oxetane ring. In terms of stability of the compound, a group derived from a benzocyclobutene ring or a naphthocyclobutene ring is preferable.

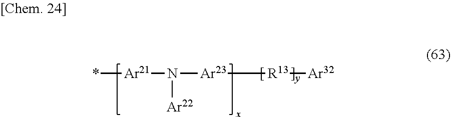

In the above formula (63), x and y each represent an integer of 0 or more. Ar²¹ and Ar²³ each independently represent a divalent aromatic ring group, and these groups may have a substituent. Ar²² represents a monovalent aromatic ring group which may have a substituent, and R¹³ represents an alkyl group, an aromatic ring group, or a divalent group composed of an alkyl group and an aromatic ring group, and those groups may have a substituent. Ar³² represents a monovalent aromatic ring group or a monovalent crosslinking group, and these groups may have a substituent. The asterisk (*) represents a bond to the nitrogen atom of the formula (61).

Examples of the aromatic ring groups represented by Ar²¹ and Ar²³ are the same as those of Ar¹¹, Ar¹², and Ar¹⁴.

Examples of the aromatic ring groups represented by Ar²² and Ar³² include groups in which two or more monocyclic rings, 2- to 6-condensed rings, or aromatic rings thereof are linked. Specific examples thereof include a monovalent group derived from a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, a fluorene ring, a biphenyl group, a terphenyl group, a quaterphenyl group, a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzoisoxazole ring, a benzoisothiazole ring, a benzoimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a perimidine ring, a quinazoline ring, a quinazolinone ring, or an azulene ring. Among those, a monovalent group derived from a benzene ring, a naphthalene ring, a fluorene ring, a pyridine ring, or a carbazole ring, or a biphenyl group is preferable because negative charges are efficiently delocalized, and stability and heat resistance are excellent.

Examples of the alkyl group or aromatic ring group represented by R¹³ are the same as those represented by R¹².

The crosslinking group represented by Ar³² is not particularly limited, and preferred examples thereof include a vinyl group, an acrylic group, and a group derived from a benzocyclobutene ring, a naphthocyclobutene ring, or an oxetane ring.

Each of the above Ar¹¹ to Ar¹⁴, R¹¹ to R¹³, Ar²¹ to Ar²³, Ar³¹, Ar³², Q¹¹, and Q¹² may further have a substituent without departing from the spirit of the present invention. A molecular weight of the substituent is preferably 400 or less, and more preferably 250 or less. A type of the substituent is not particularly limited, and examples thereof include one kind or two or more kinds selected from the following substituent group W.

Substituent Group W:

an alkyl group having 1 or more, preferably 10 or less, and more preferably 8 or less carbon atoms, such as a methyl group and an ethyl group; an alkenyl group having 2 or more, preferably 11 or less, and more preferably 5 or less carbon atoms, such as a vinyl group; an alkynyl group having 2 or more, preferably 11 or less, and more preferably 5 or less carbon atoms, such as an ethynyl group; an alkoxy group having 1 or more, preferably 10 or less, and more preferably 6 or less carbon atoms, such as a methoxy group and an ethoxy group; an aryloxy group having 4 or more, preferably 5 or more, and preferably 25 or less, more preferably 14 or less carbon atoms, such as a phenoxy group, a naphthoxy group, and a pyridyloxy group; an alkoxycarbonyl group having 2 or more, preferably 11 or less, and more preferably 7 or less carbon atoms, such as a methoxycarbonyl group and an ethoxycarbonyl group; a dialkylamino group having 2 or more, preferably 20 or less, and more preferably 12 or less carbon atoms, such as a dimethylamino group and a diethylamino group; a diarylamino group having 10 or more, preferably 12 or more, and preferably 30 or less, more preferably 22 or less carbon atoms, such as a diphenylamino group, a ditolylamino group, and an N-carbazolyl group; an arylalkylamino group having 6 or more, more preferably 7 or more, and preferably 25 or less, more preferably 17 or less carbon atoms, such as a phenylmethylamino group; an acyl group having 2 or more, preferably 10 or less, and more preferably 7 or less carbon atoms, such as an acetyl group and a benzoyl group; a halogen atom such as a fluorine atom and a chlorine atom; a haloalkyl group having 1 or more, preferably 8 or less, and more preferably 4 or less carbon atoms, such as a trifluoromethyl group; an alkylthio group having 1 or more, preferably 10 or less, and more preferably 6 or less carbon atoms, such as a methylthio group and an ethylthio group; an arylthio group having 4 or more, preferably 5 or more, and preferably 25 or less, more preferably 14 or less carbon atoms, such as a phenylthio group, a naphthylthio group, and a pyridylthio group; a silyl group having 2 or more, preferably 3 or more, and preferably 33 or less, more preferably 26 or less carbon atoms, such as a trimethylsilyl group and a triphenylsilyl group; a siloxy group having 2 or more, preferably 3 or more, and preferably 33 or less, more preferably 26 or less carbon atoms, such as a trimethylsiloxy group and a triphenylsiloxy group; a cyano group; an aromatic hydrocarbon group having 6 or more, preferably 30 or less, and more preferably 18 or less carbon atoms, such as a phenyl group and a naphthyl group; and an aromatic heterocyclic group having 3 or more, preferably 4 or more, and preferably 28 or less, more preferably 17 or less carbon atoms, such as a thienyl group and a pyridyl group.

In the above substituent group W, an alkyl group or an alkoxy group is preferable from the viewpoint of improving solubility, and an aromatic hydrocarbon group or an aromatic heterocyclic group is preferable from the viewpoint of charge transportability and stability.

In particular, among polymer compounds having a repeating unit represented by the formula (61), a polymer compound having a repeating unit represented by the following formula (64) is preferable because hole injection and transport properties are very high.

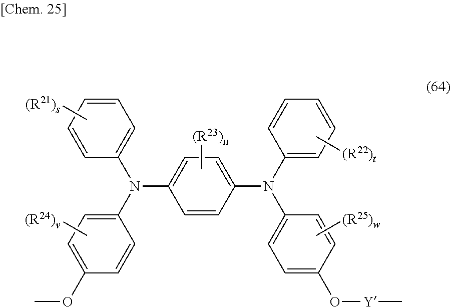

In the formula (64), R²¹ to R²⁵ each independently represent any substituent. Specific examples of the substituents represented by R²¹ to R²⁵ are the same as the substituents described in the above-described [Substituent Group W].

s and t each independently represent an integer of 0 or more and 5 or less.

u, v, and w each independently represent an integer of 0 or more and 4 or less.

Preferred examples of the aromatic tertiary amine polymer compound include a polymer compound having a repeating unit represented by the following formula (65) and/or formula (66).

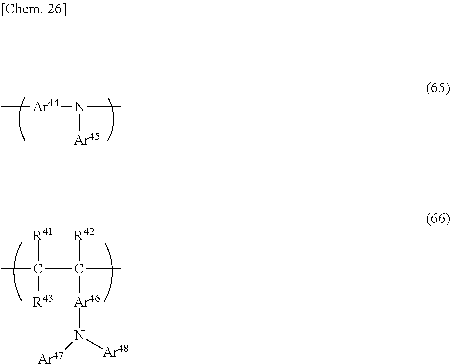

In the above formulae (65) and (66), Ar⁴⁵, Ar⁴⁷, and Ar⁴⁸ each independently represent a monovalent aromatic hydrocarbon group which may have a substituent or a monovalent aromatic heterocyclic group which may have a substituent. Ar⁴⁴ and Ar⁴⁶ each independently represent a divalent aromatic hydrocarbon group which may have a substituent or a divalent aromatic heterocyclic group which may have a substituent.

R⁴¹ to R⁴³ each independently represent a hydrogen atom or any substituent.

Specific examples and preferred examples of Ar⁴⁵, Ar⁴⁷, and Ar⁴⁸, and examples and preferred examples of substituents which may be provided are the same as those of Ar²², and specific examples and preferred examples of Ar⁴⁴ and Ar⁴⁶, and examples and preferred examples of substituents which may be provided are the same as those of Ar¹¹, Ar¹², and Ar¹⁴. Each of R⁴¹ to R⁴³ is preferably a hydrogen atom or a substituent described in the above-described [Substituent Group W], and more preferably a hydrogen atom, an alkyl group, an alkoxy group, an amino group, an aromatic hydrocarbon group, or an aromatic heterocyclic group.

Preferred specific examples of the repeating units represented by the formulae (65) and (66) applicable in the present invention are shown below, but the present invention is not limited thereto.

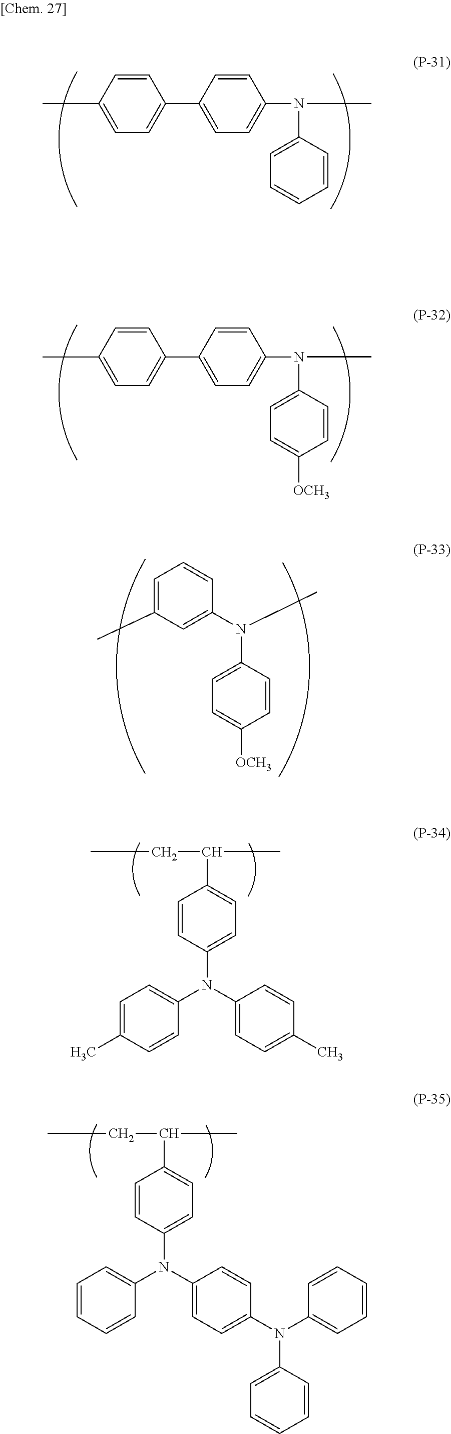

### <Electron-accepting Compound>

The composition for forming a hole injection layer preferably contains an electron-accepting compound as a constituent material of the hole injection layer 3.

The electron-accepting compound is preferably a compound having oxidizing power and the ability to accept one electron from the above-described hole-transporting material. Specifically, as the electron-accepting compound, a compound having an electron affinity of 4.0 eV or more is preferable, and a compound having an electron affinity of 5.0 eV or more is more preferable.

Examples of such an electron-accepting compound include one kind or two or more kinds of compounds selected from the group consisting of a triaryl boron compound, a metal halide, a Lewis acid, an organic acid, an onium salt, a salt of an arylamine and a metal halide, and a salt of an arylamine and a Lewis acid. More specifically, examples of the electron-accepting compound include: onium salts substituted with an organic group, such as 4-isopropyl-4′-methyldiphenyliodonium tetrakis(pentafluorophenyl)borate and triphenylsulfonium tetrafluoroborate (International Publication WO 2005/089024, International Publication WO 2017/164268); high-valence inorganic compounds, such as iron (III) chloride (JP-A-11-251067) and ammonium peroxodisulfate; cyano compounds, such as tetracyanoethylene; aromatic boron compounds, such as tris(pentafluorophenyl)borane (JP-A-2003-31365); fullerene derivatives; iodine; sulfonic acid ions, such as polystyrene sulfonic acid ions, alkylbenzene sulfonic acid ions, and camphorsulfonic acid ions.

The electron-accepting compound can further improve conductivity of the hole injection layer 3 by oxidizing the hole-transporting material.

### <Other Constituent Materials>

The material of the hole injection layer 3 may further contain other components in addition to the above-described hole-transporting material and electron-accepting compound as long as the effect of the present invention is not significantly impaired.

### (Hole Transport Layer)

The hole transport layer 4 is a layer that executes transportation of hole from the anode 2 to the emission layer 5. The hole transport layer 4 is not an essential layer for the organic electroluminescent element according to the present invention, but in a case where the hole transport layer 4 is provided, the hole transport layer 4 is generally formed on the hole injection layer 3 when the hole injection layer 3 is present, and on the anode 2 when the hole injection layer 3 is absent.

A method for forming the hole transport layer 4 may be a vacuum deposition method or a wet-process film formation method, and is not particularly limited. The hole transport layer 4 is preferably formed by a wet-process film formation method from the viewpoint of reducing dark spots.

A material for forming the hole transport layer 4 is preferably a material having high hole transportability and capable of efficiently transporting injected holes. Therefore, it is preferable that the material for forming the hole transport layer 4 has a small ionization potential, high transparency to visible light, high hole mobility, excellent stability, and is less likely to generate impurities serving as a trap during production or use. In many cases, since the hole transport layer 4 is in contact with the emission layer 5, it is preferable that the hole transport layer 4 does not quench luminescence from the emission layer 5 or form an exciplex with the emission layer 5 so as to reduce the efficiency.

The material of the hole transport layer 4 may be any material used as a constituent material of the hole transport layer 4 in the related art. Examples of the material of the hole transport layer 4 include an arylamine derivative, a fluorene derivative, a spiro derivative, a carbazole derivative, a pyridine derivative, a pyrazine derivative, a pyrimidine derivative, a triazine derivative, a quinoline derivative, a phenanthroline derivative, a phthalocyanine derivative, a porphyrin derivative, a silole derivative, an oligothiophene derivative, a condensed polycyclic aromatic derivative, and a metal complex.

Examples of the material of the hole transport layer 4 include a polyvinyl carbazole derivative, a polyaryl amine derivative, a polyvinyl triphenylamine derivative, a polyfluorene derivative, a polyarylene derivative, a polyarylene ether sulfone derivative containing tetraphenylbenzidine, a polyarylene vinylene derivative, a polysiloxane derivative, a polythiophene derivative, and a poly(p-phenylene vinylene) derivative. The derivative may be any of an alternating copolymer, a random polymer, a block polymer, and a graft copolymer. In addition, the derivative may be a polymer having branches in a main chain and having three or more terminal portions, or a so-called dendrimer.

Among those, as the material of the hole transport layer 4, a polyaryl amine derivative or a polyarylene derivative is preferable.

Specific examples of the polyaryl amine derivative and the polyarylene derivative include those described in JP-A-2008-98619.

As the polyaryl amine derivative, the aromatic tertiary amine polymer compound is preferably used.

In a case where the hole transport layer 4 is formed by a wet-process film formation method, a composition for forming a hole transport layer is prepared in the same manner as in the formation of the hole injection layer 3, and then subjected to wet-process film formation and dried.

The composition for forming a hole transport layer contains a solvent in addition to the above-described hole-transporting material. The solvent used is the same as that used in the above composition for forming a hole injection layer. In addition, film formation conditions, drying conditions, and the like are the same as those in the case of formation of the hole injection layer 3.

In a case where the hole transport layer 4 is formed by a vacuum deposition method, film formation conditions and the like thereof are also the same as those in the case of formation of the hole injection layer 3.

A film thickness of the hole transport layer 4 is generally 5 nm or more, preferably 10 nm or more, and is generally 300 nm or less, preferably 200 nm or less, in consideration of factors such as immersion of a low molecular weight material in the emission layer and swelling of the hole-transporting material.

### (Emission Layer)

The emission layer 5 is a layer which is excited by recombination of holes injected from the anode 2 and electrons injected from the cathode 9 between electrodes to which an electric field is applied, and becomes a main emission source. The emission layer 5 is generally formed on the hole transport layer 4 when the hole transport layer 4 is present, on the hole injection layer 3 when the hole transport layer 4 is absent and the hole injection layer 3 is present, and on the anode 2 when neither the hole transport layer 4 nor the hole injection layer 3 is present.

### (Material for Emission Layer)

The material for an emission layer according to the present invention includes at least a luminescent material and at least two kinds of compounds respectively selected from at least any two groups among three groups represented by the following (group A), (group B), and (group C).
(Group A): a group consisting of a compound represented by the later-described formula (1-A) and a compound represented by the later-described formula (1-B)
(Group B): a compound represented by the later-described formula (2)
(Group C): a group consisting of a compound represented by the later-described formula (3), a compound represented by the later-described formula (1-1), and a compound represented by the later-described formula (1-2)

In the present invention, the emission layer generally contains a luminescent material and a matrix compound as the material for an emission layer, and preferably contains a phosphorescent compound and a matrix compound from the viewpoint of internal quantum efficiency. The matrix compound includes compounds respectively selected from at least any two groups among the three groups represented by the (group A), the (group B), and the (group C). The matrix compound will be described later.

A method for forming the emission layer 5 is not limited. The emission layer 5 can be formed by a wet-process film formation method, a vapor deposition method, or other methods. In a case where molecular weights of the matrix compound and the luminescent material to be described later are large, a wet-process film formation method is preferable, and an inkjet method is more preferable.

The material for an emission layer generally contains a matrix compound and a luminescent material, and preferably contains a matrix compound and a phosphorescent compound from the viewpoint of internal quantum efficiency. The matrix compound referred to in the present description is also referred to as a charge-transporting material.

### <Luminescent Material>

As the luminescent material, any known material generally used as a luminescent material of an organic electroluminescent element can be applied, and there is no particular limitation, and a substance which emits light at a desired emission wavelength and has good luminescent efficiency may be used. The luminescent material may be a fluorescent compound or a phosphorescent compound, but is preferably a phosphorescent compound from the viewpoint of internal quantum efficiency. Still more preferably, a red luminescent material and a green luminescent material are phosphorescent compounds, and a blue luminescent material is a fluorescent compound.

### <Phosphorescent Compound>

The phosphorescent compound refers to a compound that emits light from an excited triplet state. For example, a metal complex compound containing Ir, Pt, Eu, and the like is a representative example thereof, and a metal complex is preferably contained as a material structure.

Among metal complexes, examples of a phosphorescent organometallic complex that emits light via a triplet state include a Werner complex or an organometallic complex compound containing a metal selected from Group 7 to Group 11 of a long-period periodic table (hereinafter, the term “periodic table” referred to a long-period periodic table unless otherwise specified) as a central metal. Examples of such a phosphorescent compound include phosphorescent compounds described in International Publication WO 2014/024889, International Publication WO 2015/087961, International Publication WO 2016/194784, and JP-A-2014-074000. A compound represented by the following formula (201) or a compound represented by the following formula (205) is preferable, and a compound represented by the following formula (201) is more preferable.

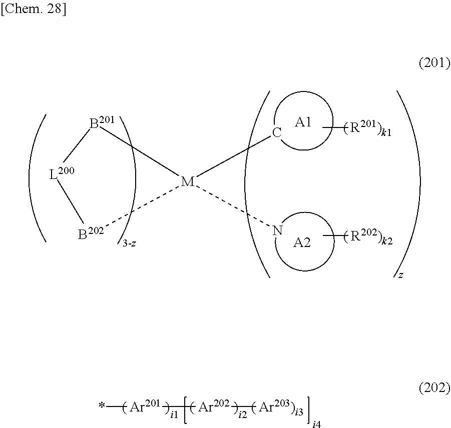

In the formula (201), a ring A1 represents an aromatic hydrocarbon ring structure which may have a substituent or an aromatic heterocyclic ring structure which may have a substituent.

A ring A2 represents an aromatic heterocyclic ring structure which may have a substituent.

R²⁰¹ and R²⁰² each independently represent a structure represented by the formula (202), and “*” represents a bonding site with the ring A1 or the ring A2. R²⁰¹ and R²⁰² may be the same as or different from each other, and in a case where there are a plurality of each of R²⁰¹ and a plurality of R²⁰², they may be the same as or different from each other.

Ar²⁰¹ and Ar²⁰³ each independently represent an aromatic hydrocarbon ring structure which may have a substituent or an aromatic heterocyclic ring structure which may have a substituent.

Ar²⁰² represents an aromatic hydrocarbon ring structure which may have a substituent, an aromatic heterocyclic ring structure which may have a substituent, or an aliphatic hydrocarbon structure which may have a substituent. The substituents bonded to the ring A1, the substituents bonded to the ring A2, or the substituents bonded to the ring A1 and the substituents bonded to the ring A2 may be bonded to each other to form a ring.

B²⁰¹-L²⁰⁰-B²⁰² represents an anionic bidentate ligand. B²⁰¹ and B²⁰² each independently represent a carbon atom, an oxygen atom, or a nitrogen atom, and these atoms may be atoms constituting a ring. L²⁰⁰ represents a single bond or an atomic group constituting a bidentate ligand together with B²⁰¹ and B²⁰². In a case where there are a plurality of B²⁰¹-L²⁰⁰-B²⁰², they may be the same as or different from each other.

In the formulae (201) and (202),
i1 and i2 each independently represent an integer of 0 or more and 12 or less,
i3 represents an integer of 0 or more whose upper limit is the number that can be substituted with Ar²⁰²,
i4 represents an integer of 0 or more whose upper limit is the number that can be substituted with Ar²⁰¹,
k1 and k2 each independently represent an integer of 0 or more whose upper limit is the number that can be substituted with the ring A1 and the ring A2, and
z represents an integer of 1 to 3.

Unless otherwise specified, the substituent is preferably a group selected from the following substituent group S.

### Substituent Group S:

An alkyl group, preferably an alkyl group having 1 to 20 carbon atoms, more preferably an alkyl group having 1 to 12 carbon atoms, still more preferably an alkyl group having 1 to 8 carbon atoms, particularly preferably an alkyl group having 1 to 6 carbon atoms.
An alkoxy group, preferably an alkoxy group having 1 to 20 carbon atoms, more preferably an alkoxy group having 1 to 12 carbon atoms, and still more preferably an alkoxy group having 1 to 6 carbon atoms.
An aryloxy group, preferably an aryloxy group having 6 to 20 carbon atoms, more preferably an aryloxy group having 6 to 14 carbon atoms, still more preferably an aryloxy group having 6 to 12 carbon atoms, and particularly preferably an aryloxy group having 6 carbon atoms.
A heteroaryloxy group, preferably a heteroaryloxy group having 3 to 20 carbon atoms, and more preferably a heteroaryloxy group having 3 to 12 carbon atoms.
An alkylamino group, preferably an alkylamino group having 1 to 20 carbon atoms, and more preferably an alkylamino group having 1 to 12 carbon atoms.
An arylamino group, preferably an arylamino group having 6 to 36 carbon atoms, more preferably an arylamino group having 6 to 24 carbon atoms.
An aralkyl group, preferably an aralkyl group having 7 to 40 carbon atoms, more preferably an aralkyl group having 7 to 18 carbon atoms, and still more preferably an aralkyl group having 7 to 12 carbon atoms.
A heteroaralkyl group, preferably a heteroaralkyl group having 7 to 40 carbon atoms, and more preferably a heteroaralkyl group having 7 to 18 carbon atoms.
An alkenyl group, preferably an alkenyl group having 2 to 20 carbon atoms, more preferably an alkenyl group having 2 to 12 carbon atoms, still more preferably an alkenyl group having 2 to 8 carbon atoms, and particularly preferably an alkenyl group having 2 to 6 carbon atoms.
An alkynyl group, preferably an alkynyl group having 2 to 20 carbon atoms, and more preferably an alkynyl group having 2 to 12 carbon atoms.
An aryl group, preferably an aryl group having 6 to 30 carbon atoms, more preferably an aryl group having 6 to 24 carbon atoms, still more preferably an aryl group having 6 to 18 carbon atoms, and particularly preferably an aryl group having 6 to 14 carbon atoms.
A heteroaryl group, preferably a heteroaryl group having 3 to 30 carbon atoms, more preferably a heteroaryl group having 3 to 24 carbon atoms, still more preferably a heteroaryl group having 3 to 18 carbon atoms, and particularly preferably a heteroaryl group having 3 to 14 carbon atoms.
An alkylsilyl group, preferably an alkylsilyl group having an alkyl group with 1 to 20 carbon atoms, and more preferably an alkylsilyl group having an alkyl group with 1 to 12 carbon atoms.
An arylsilyl group, preferably an arylsilyl group having an aryl group with 6 to 20 carbon atoms, and more preferably an arylsilyl group having an aryl group with 6 to 14 carbon atoms.
An alkylcarbonyl group, preferably an alkylcarbonyl group having 2 to 20 carbon atoms.
An arylcarbonyl group, preferably an arylcarbonyl group having 7 to 20 carbon atoms.

In the above groups, one or more hydrogen atoms may be substituted with fluorine atoms, or one or more hydrogen atoms may be substituted with deuterium atoms. Unless otherwise specified, aryl is an aromatic hydrocarbon ring, and heteroaryl is an aromatic heterocyclic ring.
A hydrogen atom, a deuterium atom, a fluorine atom, a cyano group, or —SF₅.

In the above substituent group S, an alkyl group, an alkoxy group, an aryloxy group, an arylamino group, an aralkyl group, an alkenyl group, an aryl group, a heteroaryl group, an alkylsilyl group, an arylsilyl group, a group in which one or more hydrogen atoms of these groups are substituted with fluorine atoms, a fluorine atom, a cyano group, or —SF₅ is preferable,

an alkyl group, an arylamino group, an aralkyl group, an alkenyl group, an aryl group, a heteroaryl group, a group in which one or more hydrogen atoms of these groups are substituted with fluorine atoms, a fluorine atom, a cyano group, or —SF₅ is more preferable,

an alkyl group, an alkoxy group, an aryloxy group, an arylamino group, an aralkyl group, an alkenyl group, an aryl group, a heteroaryl group, an alkylsilyl group, and an arylsilyl group are still more preferable,

an alkyl group, an arylamino group, an aralkyl group, an alkenyl group, an aryl group, and a heteroaryl group are particularly preferable, and

an alkyl group, an arylamino group, an aralkyl group, an aryl group, and a heteroaryl group are most preferable.

In the substituent group S, a substituent selected from the substituent group S may be further provided as a substituent. Preferred groups, more preferred groups, still more preferred groups, particularly preferred groups, and most preferred groups of the substituent which may be provided are the same as the preferred groups in the substituent group S.

The ring A1 represents an aromatic hydrocarbon ring structure which may have a substituent or an aromatic heterocyclic ring structure which may have a substituent.

The aromatic hydrocarbon ring is preferably an aromatic hydrocarbon ring having 6 to 30 carbon atoms. Specifically, a benzene ring, a naphthalene ring, an anthracene ring, a triphenylyl ring, an acenaphthene ring, a fluoranthene ring, and a fluorene ring are preferable.

The aromatic heterocyclic ring is preferably an aromatic heterocyclic ring having 3 to 30 carbon atoms containing any of a nitrogen atom, an oxygen atom, and a sulfur atom as a heteroatom. A furan ring, a benzofuran ring, a thiophene ring, and a benzothiophene ring are more preferable.

The ring A1 is more preferably a benzene ring, a naphthalene ring, or a fluorene ring, particularly preferably a benzene ring or a fluorene ring, and most preferably a benzene ring.

The ring A2 represents an aromatic heterocyclic ring structure which may have a substituent.

The aromatic heterocyclic ring is preferably an aromatic heterocyclic ring having 3 to 30 carbon atoms containing any of a nitrogen atom, an oxygen atom, and a sulfur atom as a heteroatom. Specific examples thereof include a pyridine ring, a pyrimidine ring, a pyrazine ring, a triazine ring, an imidazole ring, an oxazole ring, a thiazole ring, a benzothiazole ring, a benzoxazole ring, a benzoimidazole ring, a quinoline ring, an isoquinoline ring, a quinoxaline ring, a quinazoline ring, a naphthyridine ring, and a phenanthridine ring, preferably a pyridine ring, a pyrazine ring, a pyrimidine ring, an imidazole ring, a benzothiazole ring, a benzoxazole ring, a quinoline ring, an isoquinoline ring, a quinoxaline ring, and a quinazoline ring, more preferably a pyridine ring, an imidazole ring, a benzothiazole ring, a quinoline ring, an isoquinoline ring, a quinoxaline ring, and a quinazoline ring, and most preferably a pyridine ring, an imidazole ring, a benzothiazole ring, a quinoline ring, a quinoxaline ring, and a quinazoline ring.

Preferred combinations of the ring A1 and the ring A2 include, when represented as (ring A1-ring A2), (benzene ring-pyridine ring), (benzene ring-quinoline ring), (benzene ring-quinoxaline ring), (benzene ring-quinazoline ring), (benzene ring-benzothiazole ring), (benzene ring-imidazole ring), (benzene ring-pyrrole ring), (benzene ring-diazole ring), and (benzene ring-thiophene ring).

The substituent, which the ring A1 and the ring A2 may have, may be optionally selected, and is preferably one or more substituents selected from the substituent group S.

Ar²⁰¹ and Ar²⁰³ each independently represent an aromatic hydrocarbon ring structure which may have a substituent or an aromatic heterocyclic ring structure which may have a substituent.

Ar²⁰² represents an aromatic hydrocarbon ring structure which may have a substituent, an aromatic heterocyclic ring structure which may have a substituent, or an aliphatic hydrocarbon structure which may have a substituent.

In a case where any of Ar²⁰¹, Ar²⁰², and Ar²⁰³ is an aromatic hydrocarbon ring structure which may have a substituent, the aromatic hydrocarbon ring structure is preferably an aromatic hydrocarbon ring having 6 to 30 carbon atoms. Specifically, a benzene ring, a naphthalene ring, an anthracene ring, a triphenylyl ring, an acenaphthene ring, a fluoranthene ring, and a fluorene ring are preferable, a benzene ring, a naphthalene ring, and a fluorene ring are more preferable, and a benzene ring is most preferable.

In a case where any of Ar²⁰¹ and Ar²⁰² is a benzene ring which may have a substituent, it is preferable that at least one benzene ring is bonded to an adjacent structure at an ortho position or a meta position, and it is more preferable that at least one benzene ring is bonded to an adjacent structure at a meta position.

In a case where any of Ar²⁰¹, Ar²⁰², and Ar²⁰³ is a fluorene ring which may have a substituent, it is preferable that a 9-position and a 9′-position of the fluorene ring have a substituent or are bonded to adjacent structures.

In a case where any of Ar²⁰¹, Ar²⁰², and Ar²⁰³ is an aromatic heterocyclic ring structure which may have a substituent, the aromatic heterocyclic ring structure is preferably an aromatic heterocyclic ring having 3 to 30 carbon atoms containing any of a nitrogen atom, an oxygen atom, and a sulfur atom as a heteroatom, and specific examples thereof include a pyridine ring, a pyrimidine ring, a pyrazine ring, a triazine ring, an imidazole ring, an oxazole ring, a thiazole ring, a benzothiazole ring, a benzoxazole ring, a benzoimidazole ring, a quinoline ring, an isoquinoline ring, a quinoxaline ring, a quinazoline ring, a naphthyridine ring, a phenanthridine ring, a carbazole ring, a dibenzofuran ring, and a dibenzothiophene ring, and preferably a pyridine ring, a pyrimidine ring, a triazine ring, a carbazole ring, a dibenzofuran ring, and a dibenzothiophene ring.

In a case where any of Ar²⁰¹, Ar²⁰² and Ar²⁰³ is a carbazole ring which may have a substituent, it is preferable that an N-position of the carbazole ring has a substituent or is bonded to an adjacent structure.

In a case where Ar²⁰² is an aliphatic hydrocarbon structure which may have a substituent, the aliphatic hydrocarbon structure has a straight chain, a branched chain, or a cyclic structure, and preferably has 1 or more and 24 or less carbon atoms, more preferably 1 or more and 12 or less carbon atoms, and still more preferably 1 or more and 8 or less carbon atoms.

i1 and i2 each independently represent an integer of 0 to 12, preferably 1 to 12, more preferably 1 to 8, and still more preferably 1 to 6. Within this range, improvement in solubility and improvement in charge transportability are expected.

i3 represents an integer of preferably 0 to 5, more preferably 0 to 2, and still more preferably 0 or 1.

i4 represents an integer of preferably 0 to 2, and more preferably 0 or 1.

k1 and k2 each independently represent an integer of preferably 0 to 3, more preferably 1 to 3, still more preferably 1 or 2, and particularly preferably 1.

The substituent, which Ar²⁰¹, Ar²⁰², and Ar²⁰³ may have, can be optionally selected, but is preferably one or more substituents selected from the substituent group S and has preferred groups also as those described in the substituent group S, more preferably an unsubstituted (hydrogen atom), an alkyl group, or an aryl group, particularly preferably an unsubstituted (hydrogen atom), or an alkyl group, and most preferably an unsubstituted (hydrogen atom) or a tertiary butyl group, the tertiary butyl group being preferably substituted with Ar²⁰³ in a case where Ar²⁰³ is present, Ar²⁰² in a case where Ar²⁰³ is absent, and Ar²⁰¹ in a case where Ar²⁰² and Ar²⁰³ are absent.

The compound represented by the formula (201) is preferably a compound satisfying any one or more of the following (I) to (IV).

### (I) Phenylene Linkage Type

The structure represented by the formula (202) is preferably a structure having a group to which benzene rings are linked, that is, a benzene ring structure, in which i1 is 1 to 6, and at least one of the benzene rings is preferably bonded to an adjacent structure at an ortho position or a meta position.

With such a structure, it is expected to improve the solubility and improve the charge transportability.

(II) (Phenylene)-aralkyl(alkyl)

A structure having an aromatic hydrocarbon group or an aromatic heterocyclic group in which an alkyl group or an aralkyl group is bonded to the ring A1 or the ring A2, that is, a structure in which Ar²⁰¹ is an aromatic hydrocarbon structure or an aromatic heterocyclic ring structure, i1 is 1 to 6, Ar²⁰² is an aliphatic hydrocarbon structure, i2 is 1 to 12 and preferably 3 to 8, Ar²⁰³ is a benzene ring structure, and i3 is 0 or 1, preferably a structure in which Ar²⁰¹ is the aromatic hydrocarbon structure, more preferably a structure in which 1 to 5 benzene rings are linked, and still more preferably one benzene ring.

With such a structure, it is expected to improve the solubility and improve the charge transportability.

### (III) Dendron

A structure in which dendron is bonded to the ring A1 or the ring A2, for example, Ar²⁰¹ and Ar²⁰² are benzene ring structures, Ar²⁰³ is a biphenyl or terphenyl structure, i1 and i2 are 1 to 6, i3 is 2, and j is 2.

With such a structure, it is expected to improve the solubility and improve the charge transportability.

(IV) B²⁰¹-L²⁰⁰-B²⁰²

A structure represented by B²⁰¹-L²⁰⁰-B²⁰² is preferably a structure represented by the following formula (203) or the following formula (204).

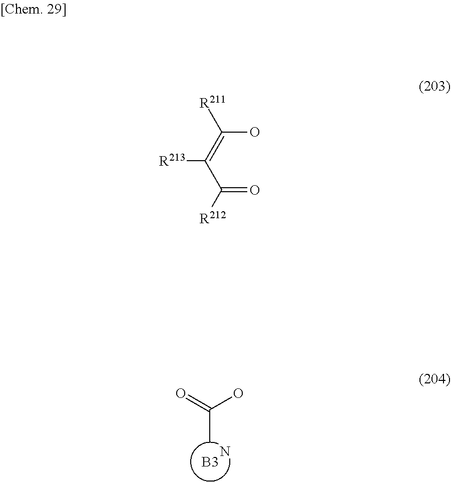

In the formula (203), R²¹¹, R²¹², and R²¹³ each independently represent a substituent.

In the formula (204), a ring B3 represents an aromatic heterocyclic ring structure containing a nitrogen atom which may have a substituent. The ring B3 is preferably a pyridine ring.

The phosphorescent compound represented by the formula (201) is not particularly limited, and preferable examples thereof include the following compounds.

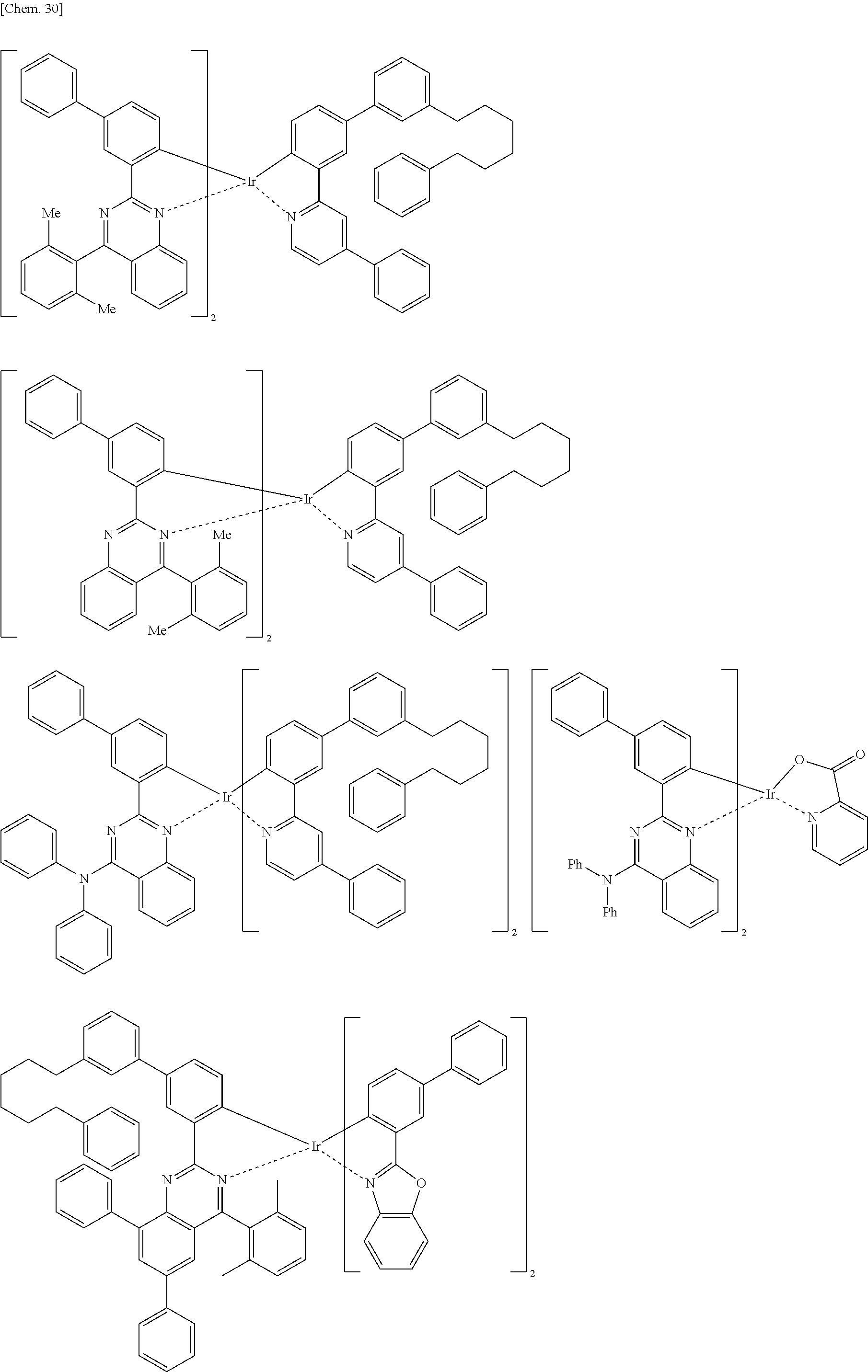

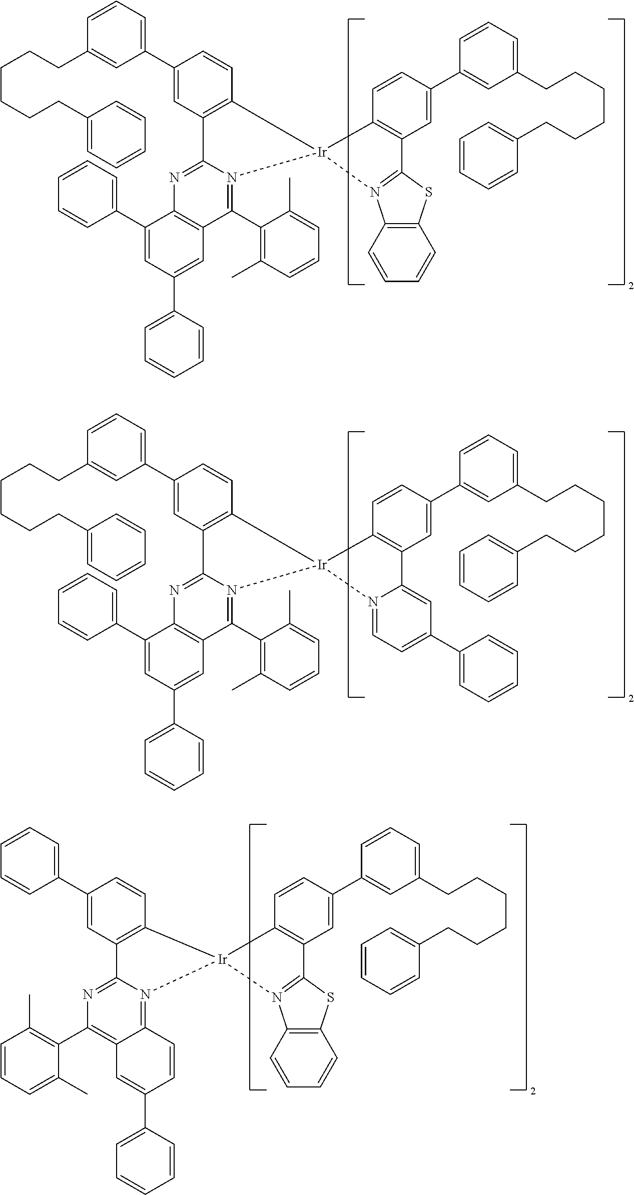

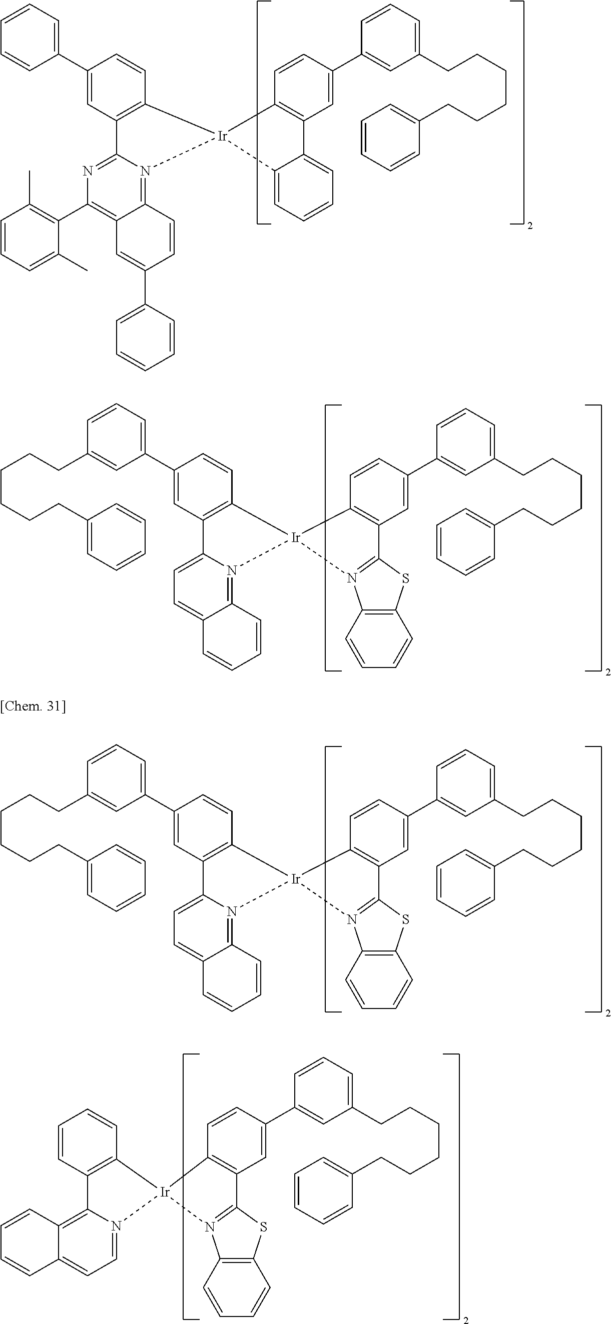

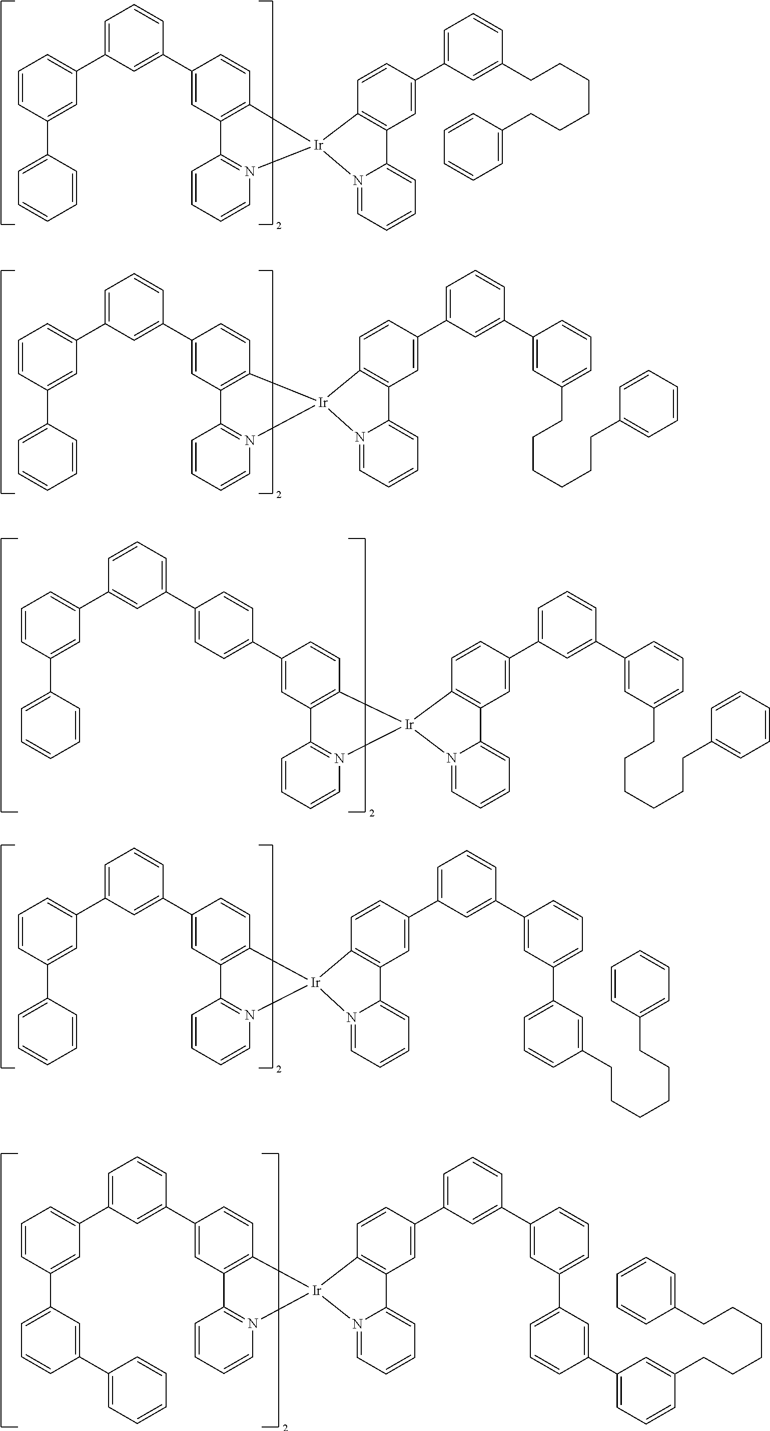

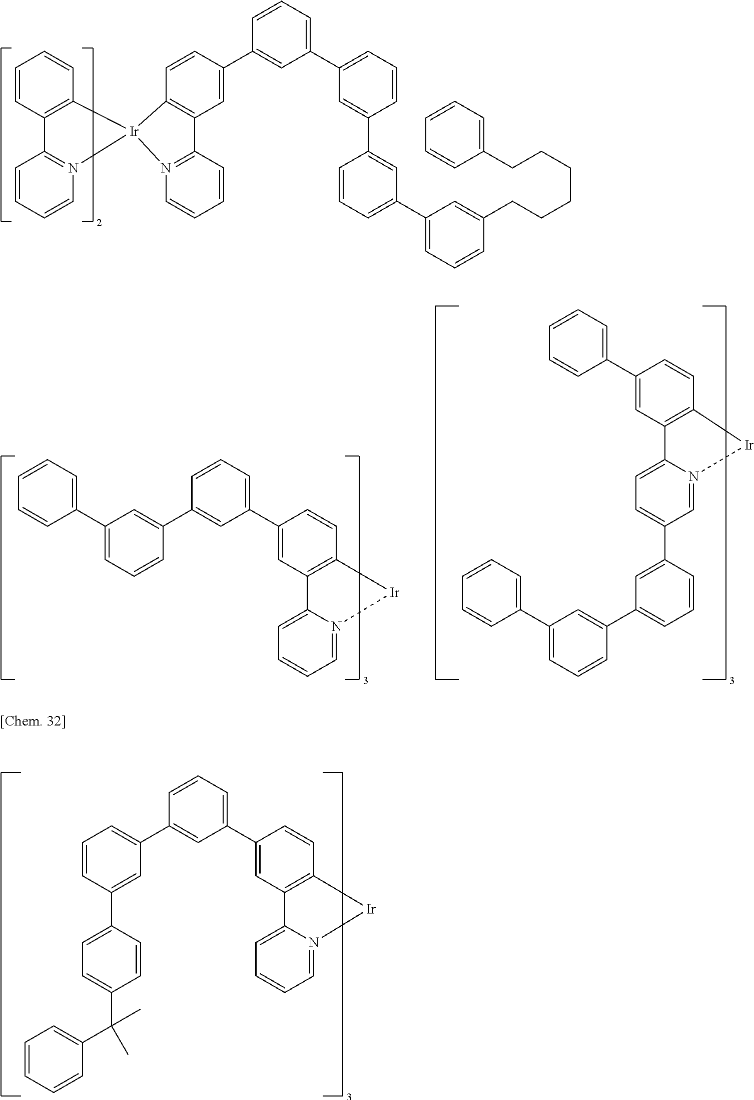

A phosphorescent compound represented by the following formula (205) is also preferable.

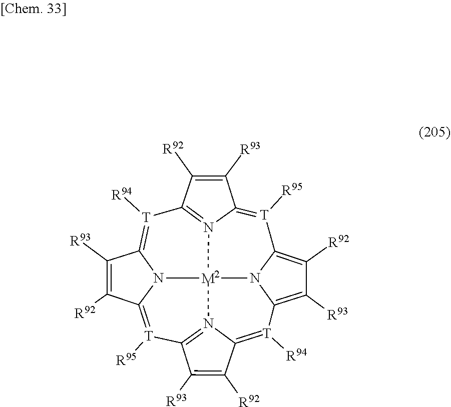

In the formula (205), M² represents a metal, and T represents a carbon atom or a nitrogen atom. R⁹² to R⁹⁵ each independently represent a substituent. However, in a case where T is a nitrogen atom, R⁹⁴ and R⁹⁵ do not exist.]

In the formula (205), specific examples of M² include metals selected from Group 7 to Group 11 of the periodic table. Among those, ruthenium, rhodium, palladium, silver, rhenium, osmium, iridium, platinum, and gold are preferable, and divalent metals such as platinum and palladium are particularly preferable.

In the formula (205), R⁹² and R⁹³ each independently represent a hydrogen atom, a halogen atom, an alkyl group, an aralkyl group, an alkenyl group, a cyano group, an amino group, an acyl group, an alkoxycarbonyl group, a carboxyl group, an alkoxy group, an alkylamino group, an aralkylamino group, a haloalkyl group, a hydroxyl group, an aryloxy group, an aromatic hydrocarbon group, or an aromatic heterocyclic group.

Further, in a case where T is a carbon atom, R⁹⁴ and R⁹⁵ each independently represent a substituent represented by the same example as that of R⁹² and R⁹³. In addition, in a case where T is a nitrogen atom, R⁹⁴ or R⁹⁵ directly bonded to T does not exist. R⁹² to R⁹⁵ may further have a substituent. The substituent may be the above-described substituent. Further, any two or more groups among R⁹² to R⁹⁵ may be linked to each other to form a ring.

A molecular weight of the phosphorescent compound is preferably 5,000 or less, more preferably 4,000 or less, and particularly preferably 3,000 or less. In addition, the molecular weight of the phosphorescent compound is preferably 1,200 or more, more preferably 1,400 or more, and still more preferably 1,600 or more. It is considered that with this range of molecular weight, phosphorescent compounds do not aggregate with each other and are uniformly mixed with the charge-transporting material, whereby an emission layer having high luminescent efficiency can be obtained.

The molecular weight of the phosphorescent compound is preferably large because Tg, a melting point, a decomposition temperature, and the like thereof are high, the phosphorescent compound and the formed emission layer are excellent in heat resistance, and deterioration in film quality due to gas generation, recrystallization, migration of molecules, and the like, an increase in impurity concentration due to thermal decomposition of the material, and the like hardly occur. On the other hand, the molecular weight of the phosphorescent compound is preferably small because purification of an organic compound is easy.

### <Matrix Compound>

The matrix compound used in the emission layer is a compound having a framework excellent in charge transportability, and is preferably selected from an electron-transporting compound, a hole transporting compound, and a bipolar compound capable of transporting both electrons and holes, or a compound that adjusts the charge transportability.

Specific examples of the framework excellent in charge transportability include an aromatic structure, an aromatic amine structure, a triarylamine structure, a dibenzofuran structure, a naphthalene structure, a phenanthrene structure, a phthalocyanine structure, a porphyrin structure, a thiophene structure, a benzylphenyl structure, a fluorene structure, a quinacridone structure, a triphenylene structure, a carbazole structure, a pyrene structure, an anthracene structure, a phenanthroline structure, a quinoline structure, a pyridine structure, a pyrimidine structure, a triazine structure, an oxadiazole structure, and an imidazole structure.

From the viewpoint of a compound having excellent electron transportability and a relatively stable structure, the electron-transporting compound is more preferably a compound having a pyridine structure, a pyrimidine structure, or a triazine structure, and still more preferably a compound having a pyrimidine structure or a triazine structure.

The hole transporting compound is a compound having a structure excellent in hole transportability, and among central frameworks excellent in charge transportability, a carbazole structure, a dibenzofuran structure, a triarylamine structure, a naphthalene structure, a phenanthrene structure, or a pyrene structure is preferable as the structure excellent in hole transportability, and a carbazole structure, a dibenzofuran structure, or a triarylamine structure is more preferable.

As the compound that adjusts the charge transportability, a compound having a structure in which many benzene rings are linked is preferable. When the compound is contained as a matrix compound, it is considered that excitons generated in the emission layer are efficiently recombined to increase the luminescent efficiency, and it is also considered that the charge transportability in the emission layer is appropriately adjusted to prevent deterioration of the luminescent material and the driving lifetime is extended.

The matrix compound of the emission layer preferably has a low molecular weight from the viewpoint of ease of synthesis and purification, ease of design of electron transport performance and hole transport performance, and ease of viscosity adjustment when dissolved in an organic solvent. In a case where the matrix compound contained in the emission layer is a low molecular weight compound, the molecular weight thereof is preferably 5,000 or less, still more preferably 4,000 or less, particularly preferably 3,000 or less, most preferably 2,000 or less, and is preferably 1,200 or more, more preferably 1,400 or more, and still more preferably 1,600 or more.

Here, in the present description, the matrix compound contained in the emission layer is referred to as (group A), (group B), and (group C) as follows for convenience.
(group A): a group consisting of a compound represented by the following formula (1-A) and a compound represented by the following formula (1-B);
(group B): a compound represented by the following formula (2); and
(group C): a group consisting of a compound represented by the following formula (3), a compound represented by the following formula (1-1), and a compound represented by the following formula (1-2).

In the present invention, the matrix compound contained in the emission layer includes at least compounds respectively selected from any two groups among the three groups represented by the (group A), the (group B), and the (group C). The compounds respectively selected from the three groups may be one kind or two or more kinds.

In the present invention, the matrix compound contained in the emission layer preferably includes at least compounds respectively selected from the three groups represented by the (group A), the (group B), and the (group C). The compounds respectively selected from the three groups may be one kind or two or more kinds.

Further, in the present invention, the matrix compound contained in the emission layer more preferably includes at least compounds respectively selected from the two groups represented by the (group A) and the (group C). The compounds respectively selected from the two groups may be one kind or two or more kinds.

### Reason for Achieving Effect]

The reason why the organic electroluminescent element according to the present invention exhibits high luminescent efficiency when the matrix compound in the present invention contains the material for an emission layer according to the present invention having at least two kinds of compounds respectively selected from at least any two groups among the three groups represented by the (group A), the (group B), and the (group C) is considered as follows.

The compound represented by the (group A) has a carbazole framework as represented by the following formula (1-A) or the following formula (1-B) in a molecule, and has a wide energy gap and high hole transportability in the emission layer.

The compound represented by the (group B) has a molecular structure represented by the following formula (2), and has a function of adjusting a wide energy gap and charge transportability in the emission layer.

The compound represented by the (group C) has a heterocyclic framework as represented by the following formula (3), the following formula (1-1), or the following formula (1-2) in a molecule, and has a wide energy gap and high electron transportability in the emission layer.

In the present invention, it is considered that when the matrix compound contained in the emission layer is selected from any two groups among the three groups represented by the (group A), the (group B), and the (group C) having these features, the emission layer formed using the composition of the present invention has a wide energy gap and appropriate charge transportability, and thus an organic electroluminescent element exhibiting high luminescent efficiency can be obtained.

Among those, containing at least two kinds of compounds respectively selected from two groups of the (group A) and the (group C) is preferable from the viewpoint of having high hole transportability in the emission layer, easily adjusting the hole transportation, and easily adjusting a charge balance, and further containing a compound selected from the (group B) is preferable because the transportability of holes and electrons in the emission layer can be adjusted.

In addition, containing at least two kinds of compounds respectively selected from two groups of the (group B) and the (group C) is preferable from the viewpoint of having high electron transportability in the emission layer, easily adjusting the electron transportability, and easily adjusting a charge balance, and further containing a compound selected from the (group A) is preferable because the transportability of holes and electrons in the emission layer can be adjusted.

The compounds of the three groups represented by the (group A), the (group B), and the (group C) of the present invention each have a group in which a plurality of aromatic hydrocarbon rings are linked. Among those, the compound represented by the (group A) and the compound represented by the (group B) each have a group in which a plurality of aromatic hydrocarbon rings are linked. Still more preferably, the compounds each have a group in which a plurality of benzene rings are linked, and particularly preferably, the compounds each have a plurality of groups in which a plurality of benzene rings are linked. Such a site in which a plurality of aromatic hydrocarbon rings, particularly benzene rings are linked is preferable also from the viewpoint of charge transportability. On the other hand, it is considered that formation of an excited dimer between the same compound and an exciplex between different compounds is prevented by a steric effect caused by a site where a plurality of aromatic hydrocarbon rings are linked. Since the excited dimer and the exciplex have lower excitation energy than excitation energy of an original compound alone, they cause a decrease in luminescent efficiency, but by using the compounds of the three groups represented by the (group A), the (group B), and the (group C) of the present invention as the material for an emission layer, an organic electroluminescent element having high luminescent efficiency can be obtained.

Further, it is considered that sites, where a plurality of aromatic hydrocarbon rings of respective molecules are linked, are appropriately entangled with each other between molecules in the film, resulting in a film stronger than a film formed simply by a van der Waals force, which is difficult to dissolve in the first organic solvent, and wet-film formation can be further performed on the film.

### [Composition for Forming Emission Layer]

The composition for forming an emission layer according to the present invention contains the material for an emission layer and a second organic solvent. In the present description, the organic solvent contained in the composition for forming an emission layer is referred to as the second organic solvent.

In a case where the emission layer is formed by a wet-process film formation method, the material for an emission layer is dissolved or dispersed in the second organic solvent to prepare a composition for forming an emission layer, and the composition for forming an emission layer is subjected to wet-film formation to form an emission layer. In the composition for forming an emission layer according to the present invention, from the viewpoint of forming a uniform film, a material for forming an emission layer according to the present invention is preferably dissolved in the second organic solvent. The method for producing an organic electroluminescent element according to the present invention is a method for producing an organic electroluminescent element including at least an anode, a cathode, and an emission layer located between the anode and the cathode, preferably including a step of forming the emission layer by a wet-process film formation method using the composition for forming an emission layer.

In one aspect, the composition for forming an emission layer according to the present invention includes at least two kinds of compounds respectively selected from at least any two groups among the three groups represented by the (group A), the (group B), and the (group C), and the second organic solvent. The second organic solvent preferably contains at least two different kinds of organic solvents. A boiling point of at least one kind of the second organic solvents is preferably 200° C. or higher. A preferred organic solvent as the second organic solvent will be described later. In the present invention, the compounds represented by the (group A), the (group B), and the (group C) may be collectively referred to as the compound according to the present invention.

### [(Group A), (Group B), and (Group C)]

The (group A): a group consisting of a compound represented by the following formula (1-A) and a compound represented by the following formula (1-B),

the (group B): a compound represented by the following formula (2), and

the (group C): a group consisting of a compound represented by the following formula (3), a compound represented by the following formula (1-1), and a compound represented by the following formula (1-2)

will be described below.

### (Compound Represented by Formula (1-A) or Formula (1-B))

Preferred embodiments of the compound represented by the formula (1-A) or the formula (1-B) are shown below.

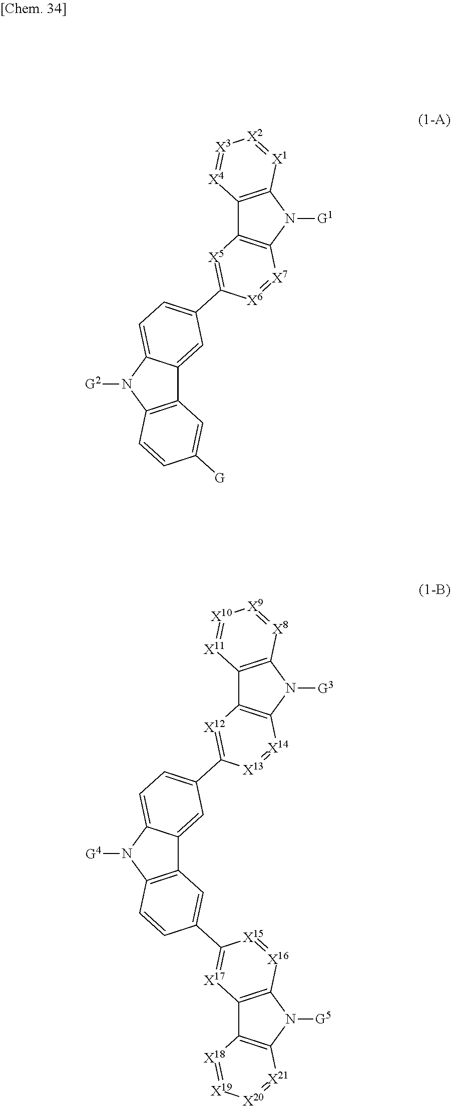

(In the formula (1-A), G¹ and G² each independently represent an aromatic hydrocarbon group, and the total carbon atom number of the number of carbon atoms of G¹ and the number of carbon atoms of G² is 42 or more and 240 or less, or at least one of the number of carbon atoms of G¹ and G² is 54 or more and 240 or less. X¹ to X⁷ each independently represent CR^{1A} or a nitrogen atom, and R^{1A} each independently represent, for each occurrence, a hydrogen atom, a deuterium atom, CN, or an aromatic hydrocarbon group having 6 to 30 carbon atoms which may have a substituent. G represents a hydrogen atom, a deuterium atom, CN, or an aromatic hydrocarbon group having 6 to 30 carbon atoms which may have a substituent.

In the formula (1-B), G, G⁴, and G⁵ each independently represent an aromatic hydrocarbon group, and the total carbon atom number of the number of carbon atoms of G³, the number of carbon atoms of G⁴, and the number of carbon atoms of G⁵ is 42 or more and 240 or less, or at least one of the number of carbon atoms of G³, G⁴, and G⁵ is 28 or more and 240 or less; and X⁸ to X²¹ each independently represent a CR^{1B} or a nitrogen atom, and R^{1B} each independently represent, for each occurrence, a hydrogen atom, a deuterium atom, a CN, or an aromatic hydrocarbon group having 6 to 30 carbon atoms which may have a substituent).

(X¹ to X⁷ and X⁸ to X²¹)

In the formula (1-A), X¹ to X⁷ each independently represent CR^{1A} or a nitrogen atom, preferably CR^{1A}

In the formula (1-B), X⁸ to X²¹ each independently represent CR^{1B} or a nitrogen atom, preferably CR^{1B}

It is preferable that all of X¹ to X⁷ are CR^{1A}, that is, a ring containing X¹ to X⁷ is a carbazole ring.

It is preferable that all of X⁸ to X¹⁴ are CR^{1A}, that is, a ring containing X⁸ to X¹⁴ is a carbazole ring.

It is preferable that all of X¹⁵ to X²¹ are CR¹B, that is, a ring containing X¹⁵ to X²¹ is a carbazole ring.

(R^{1A} and R^{1B})

In the formulae (1-A) and (1-B), R^{1A} and R^{1B} each independently represent, for each occurrence, a hydrogen atom, a deuterium atom, CN, or an aromatic hydrocarbon group having 6 to 30 carbon atoms which may have a substituent.

In the formulae (1-A) and (1-B), R^{1A} and R^{1B} are preferably a hydrogen atom or an aromatic hydrocarbon group having 6 to 30 carbon atoms.

### (G)

In the formula (1-A), G represents a hydrogen atom, a deuterium atom, CN, or an aromatic hydrocarbon group having 6 to 30 carbon atoms which may have a substituent. From the viewpoint of a level of difficulty in solubility of an aromatic compound in a solvent, G is preferably a hydrogen atom, a deuterium atom, or an aromatic hydrocarbon group having 6 to 30 carbon atoms which may have a substituent, and more preferably a hydrogen atom.

The number of carbon atoms of the aromatic hydrocarbon group having 6 to 30 carbon atoms of R^{1A} and R^{1B} in the formulae (1-A) and (1-B) and G in the formula (1-A) is preferably 24 or less, more preferably 18 or less, and still more preferably 10 or less. The aromatic hydrocarbon group is preferably a phenyl group, a naphthyl group, an anthracenyl group, a benzoanthracenyl group, a tetraphenylenyl group, a phenanthrenyl group, a benzophenanthrenyl group, a pyrenyl group, a chrysenyl group, a fluoranthenyl group, a perylenyl group, a benzopyrenyl group, a benzofluoranthenyl group, a naphthacenyl group, a pentacenyl group, a biphenyl group, a terphenyl group, a fluorenyl group, a spirobifluorenyl group, a dihydrophenanthrenyl group, a dihydropyrenyl group, or a tetrahydropyrenyl group, more preferably a monovalent group such as a phenyl group, a naphthyl group, an anthracenyl group, a tetraphenylenyl group, a phenanthrenyl group, a chrysenyl group, a pyrenyl group, a benzoanthracenyl group, and a perylenyl group.

The substituent, which the aromatic hydrocarbon group having 6 to 30 carbon atoms of R^{1A} and R^{1B} in the formulae (1-A) and (1-B) and G in the formula (1-A) may have, is preferably an aromatic hydrocarbon group. The aromatic hydrocarbon group as the substituent is preferably an aromatic hydrocarbon group having 6 to 30 carbon atoms, more preferably an aromatic hydrocarbon group having 24 or less carbon atoms, and still more preferably an aromatic hydrocarbon group having 18 or less carbon atoms. Examples of the aromatic hydrocarbon group as the substituent include a phenyl group, a naphthyl group, an anthracenyl group, a benzoanthracenyl group, a phenanthrenyl group, a benzophenanthrenyl group, a pyrenyl group, a chrysenyl group, a fluoranthenyl group, a perylenyl group, a benzopyrenyl group, a benzofluoranthenyl group, a naphthacenyl group, a pentacenyl group, a biphenyl group, a terphenyl group, a fluorenyl group, a spirobifluorenyl group, a tetrahydropyrenyl group, and a group in which two or more of these groups are linked, such as a naphthyl group substituted with a phenyl group and a phenanthrenyl group substituted with a phenyl group.

From the viewpoint of ease of synthesis and charge transportability, it is also preferable that the aromatic hydrocarbon groups having 6 to 30 carbon atoms of R^{1A} and R^{1B} in the formulae (1-A) and (1-B) and G in the formula (1-A) have no substituent.

(G¹ to G⁵)

In the formula (1-A), G¹ and G² each independently represent an aromatic hydrocarbon group. The number of carbon atoms of the aromatic hydrocarbon group is preferably 6 or more, more preferably 24 or more, still more preferably 28 or more, particularly preferably 30 or more, particularly more preferably 54 or more, and most preferably 60 or more. In addition, the number of carbon atoms is preferably 240 or less, more preferably 180 or less, and still more preferably 120 or less. The total carbon atom number of the number of carbon atoms of G¹ and the number of carbon atoms of G² is preferably 42 or more and is preferably 240 or less.

Further, at least one of the number of carbon atoms of G¹ and the number of carbon atoms of G² is preferably 54 or more, more preferably 60 or more, and at least one of the number of carbon atoms of G¹ and the number of carbon atoms of G² is preferably 240 or less, more preferably 180 or less, and particularly preferably 120 or less.

In the formula (1-B), G, G⁴, and G⁵ each independently represent an aromatic hydrocarbon group. The number of carbon atoms of the aromatic hydrocarbon group is preferably 6 or more, more preferably 24 or more, still more preferably 28 or more, particularly preferably 30 or more, particularly more preferably 54 or more, and most preferably 60 or more. In addition, the number of carbon atoms is preferably 240 or less, more preferably 180 or less, and still more preferably 120 or less. The total carbon atom number of the number of carbon atoms of G, the number of carbon atoms of G⁴, and the number of carbon atoms of G⁵ is preferably 42 or more, and preferably 240 or less.

In addition, at least one of the number of carbon atoms of G³, the number of carbon atoms of G⁴, and the number of carbon atoms of G⁵ is preferably 28 or more, more preferably 30 or more, and at least one of the number of carbon atoms of G³, the number of carbon atoms of G⁴, and the number of carbon atoms of G⁵ is preferably 240 or less, more preferably 180 or less, and particularly preferably 120 or less.

In a case where at least one of the number of carbon atoms of G¹ and the number of carbon atoms of G² is 54 or more and 240 or less in the formula (1-A), and in a case where at least one of the number of carbon atoms of G³, the number of carbon atoms of G⁴, and the number of carbon atoms of G⁵ is 28 or more and 240 or less in the formula (1-B), it is considered that in both a case of the compound represented by the formula (1-A) and a case of the compound represented by the formula (1-B), the electron transportability is improved, a driving voltage of an element is low, and the luminescent efficiency is high. It is considered that the effect is higher in a case where the number of carbon atoms of both G¹ and G² is 54 or more and 240 or less in the formula (1-A), and in a case where the number of carbon atoms of all of G, G⁴, and G⁵ is 28 to 240 in the formula (1-B). When at least one of the number of carbon atoms of G¹ and the number of carbon atoms of G² is less than 54 in the formula (1-A), or when at least one of the number of carbon atoms of G³, the number of carbon atoms of G⁴, and the number of carbon atoms of G⁵ is less than 28 in the formula (1-B), crystallinity of the compound may be improved and aggregation may occur. On the other hand, when the number of carbon atoms of G¹, G², G, G⁴, and G⁵ exceeds 240, it is considered that the driving voltage of the element increases and the luminescent efficiency may be reduced.

In a case where G¹ to G⁵ are aromatic hydrocarbon groups, examples of the aromatic hydrocarbon groups each independently include a monovalent group of an aromatic hydrocarbon structure having generally 6 or more, and generally 30 or less, preferably 18 or less, more preferably 10 or less carbon numbers, such as a benzene ring, a naphthalene ring, an anthracene ring, a tetraphenylene ring, a phenanthrene ring, a chrysene ring, a pyrene ring, a benzanthracene ring, or a perylene ring, and a monovalent group of a structure in which a plurality of structures selected from these structures are bonded to each other in a chain form or a branched manner. Preferably, the aromatic hydrocarbon group is a monovalent group in which a plurality of benzene rings are bonded in a plurality of chain forms or a branched manner, or a monovalent group in which a plurality of benzene rings and, at least one naphthalene ring, at least one phenanthrene ring, or at least one tetraphenylene ring are bonded in a chain form or a branched manner, and most preferably a monovalent group in which a plurality of benzene rings are bonded in a plurality of chain forms or a branched manner.

In a case where the aromatic hydrocarbon groups in G¹ to G⁵ each contain a benzene ring as a phenylene group, it is preferable that at least one of the phenylenes has a bonding site at a meta position or an ortho position.

### (Formulae (11) to (16))

In the formulae (1-A) and (1-B), it is preferable that at least one of G¹ to G⁵ includes at least one substructure selected from the following formulae (11) to (16) from the viewpoint of solubility and durability of the compound, and it is more preferable that G¹ to G⁵ each independently include at least one substructure represented by the following formulae (11) to (16).

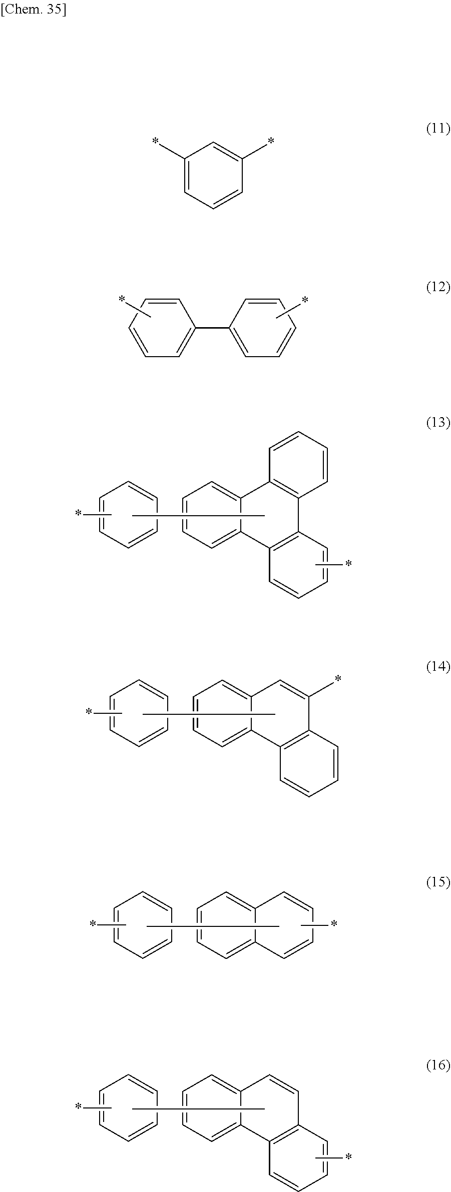

In each of the above formulae (11) to (16), * represents a bond to an adjacent structure or a hydrogen atom, and at least one of two present *s represents a bonding site to the adjacent structure. In the following description, the definition of * is the same unless otherwise specified.

More preferably, at least one of G¹ and G² in the formula (1-A) or at least one of G to G⁵ in the formula (1-B) has at least one substructure selected from the formulae (11) to (14). More preferably, both G¹ and G² in the formula (1-A) or all of G³ to G⁵ in the formula (1-B) have at least one substructure selected from the formulae (11) to (14).

Still more preferably, at least one of G¹ and G² in the formula (1-A) or at least one of G³ to G⁵ in the formula (1-B) has at least one substructure selected from the formulae (11) to (13). Further preferably, both G¹ and G² in the formula (1-A) or all of G³ to G⁵ in the formula (1-B) have at least one substructure selected from the formulae (11) to (13).

Particularly preferably, at least one of G¹ and G² in the formula (1-A) or at least one of G³ to G⁵ in the formula (1-B) has at least one substructure selected from the formulae (11) and (12). Still more preferably, both G¹ and G² in the formula (1-A) or all of G³ to G⁵ in the formula (1-B) have at least one substructure selected from the formulae (11) and (12).

In the formulae (1-A) and (1-B), the formula (12) is preferably the following formula (12-2).

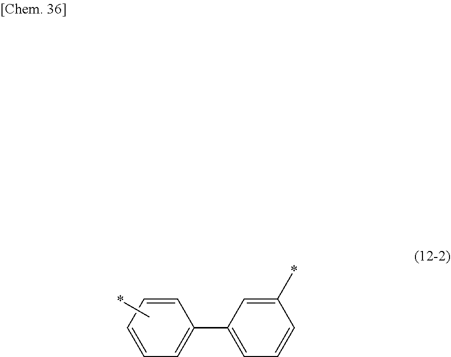

In the formulae (1-A) and (1-B), the formula (12) is more preferably the following formula (12-3).

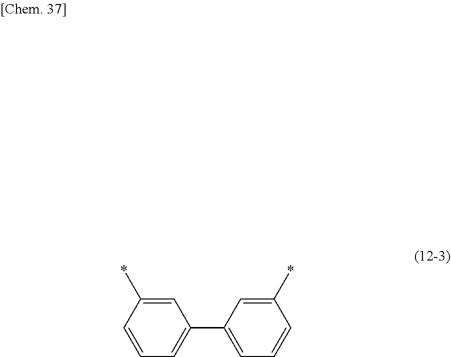 [SMILES: *c1cccc(-c2cccc(*)c2)c1]

From the viewpoint of solubility and durability of the compound, preferred examples of the substructure, which at least one of G¹ and G² in the formula (1-A) or at least one of G³ to G⁵ in the formula (1-B) has, include a substructure having the substructure represented by the formula (11) and the substructure represented by the formula (12).

In the formulae (1-A) and (1-B), as the substructure having the substructure represented by the formula (11) and the substructure represented by the formula (12), a substructure represented by at least one selected from the following formulae (17) to (22), which is a structure including a plurality of structures selected from the substructure represented by the formula (11) and the substructure represented by the formula (12), is more preferable.

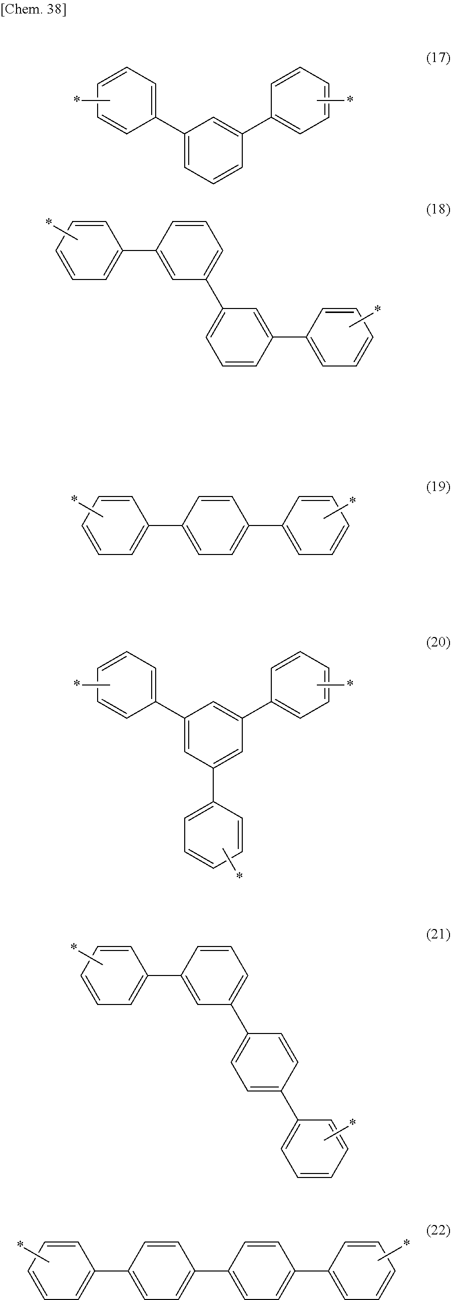

In the formulae (1-A) and (1-B), the structure including a plurality of structures selected from the substructure represented by the formula (11) and the substructure represented by the formula (12) is, for example, a substructure in which the formula (17) can be regarded as having one substructure represented by the formula (11) and two substructures represented by the formula (12) as in the following formula (17a).

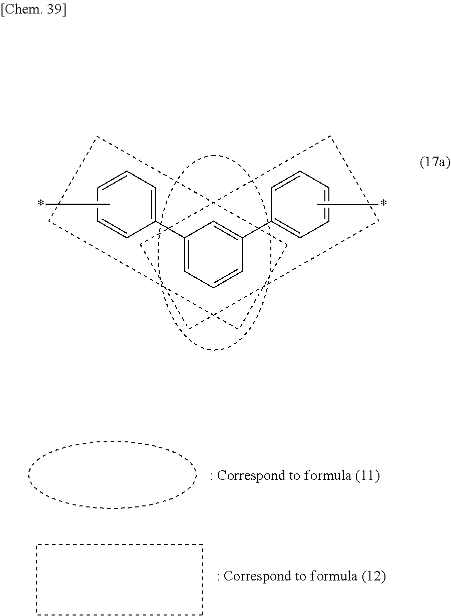

Still more preferably, at least one of G¹ and G² in the formula (1-A) or at least one of G³ to G⁵ in the formula (1-B) at least has the substructure represented by the formula (17) or the substructure represented by the formula (18).

In the formulae (1-A) and (1-B), the formula (17) is preferably the following formula (17-2).

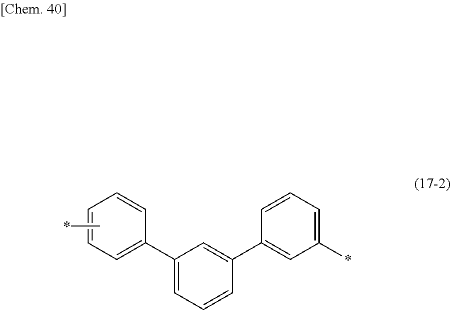

In the formulae (1-A) and (1-B), the formula (17) is more preferably the following formula (17-3).

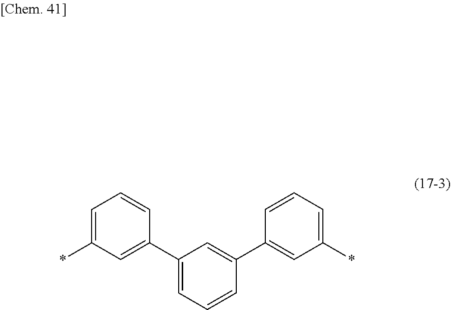 [SMILES: *c1cccc(-c2cccc(-c3cccc(*)c3)c2)c1]

In the formulae (1-A) and (1-B), the formula (18) is preferably the following formula (18-2).

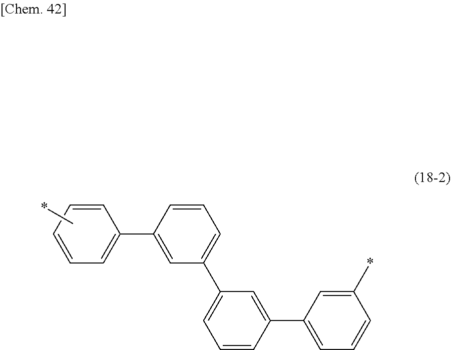

In the formulae (1-A) and (1-B), the formula (18) is more preferably the following formula (18-3).

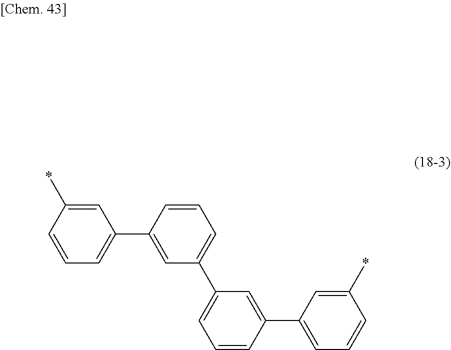 [SMILES: *c1cccc(-c2cccc(-c3cccc(-c4cccc(*)c4)c3)c2)c1]

In the formulae (1-A) and (1-B), the formula (20) is preferably the following formula (20-2).

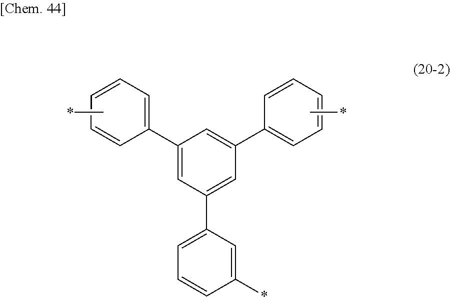

In the formulae (1-A) and (1-B), the formula (21) is preferably the following formula (21-2).

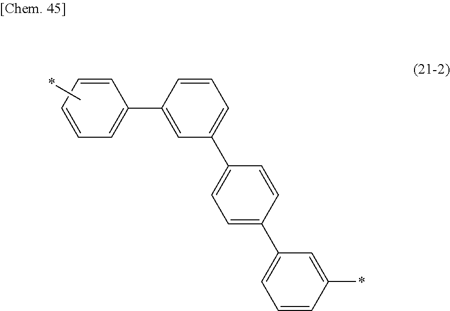

In the formulae (1-A) and (1-B), the formula (22) is preferably the following formula (22-2).

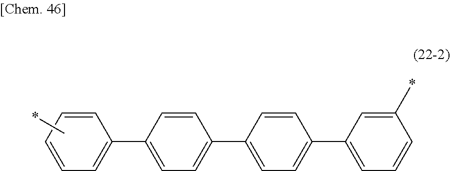

In at least one of G¹, G², and G in the formulae (1-A) and (1-B), a substructure including the substructure represented by the formula (13) more preferably has at least one substructure selected from the following formulae (13-2) to (13-4).

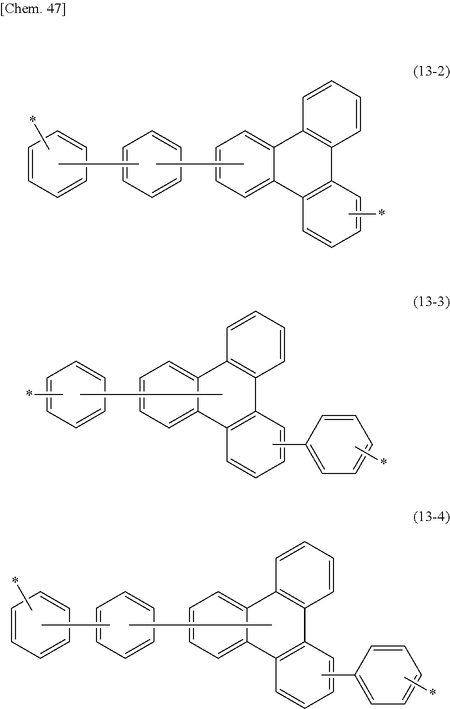

In at least one of G¹, G², and G in the formulae (1-A) and (1-B), a substructure including the substructure represented by the formula (14) more preferably has at least one substructure selected from the following formulae (14-2) and (14-3).

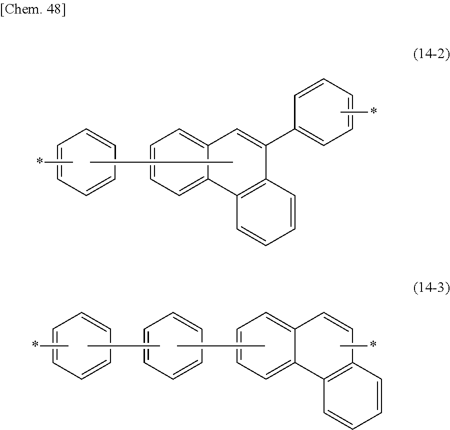

In at least one of G¹, G², and G³ in the formulae (1-A) and (1-B), a substructure including the substructure represented by the formula (15) more preferably has at least one substructure selected from the following formulae (15-2) and (15-3).

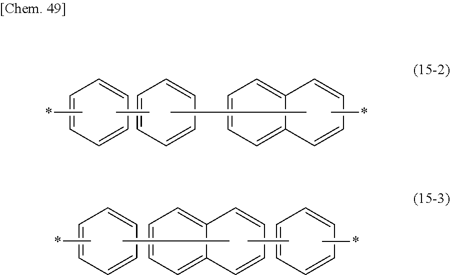

In at least one of G¹, G², and G³ in the formulae (1-A) and (1-B), a substructure including the substructure represented by the formula (16) more preferably has at least one substructure selected from the following formulae (16-2) and (16-3).

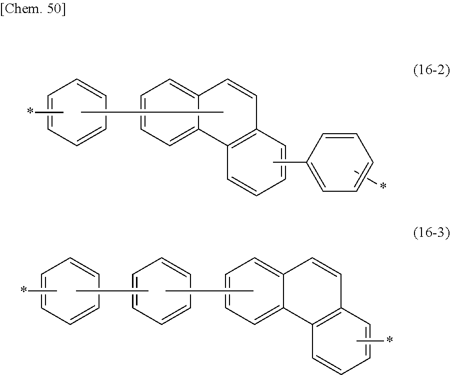

In each of the formulae (13-2) to (16-3), * represents a bond to an adjacent structure or a hydrogen atom, and at least one of two present *s represents a bonding site to the adjacent structure.

In the formulae (1-A) and (1-B), among the formulae (13-2) to (16-3), the formulae (13-2) to (14-3) are preferable, and the formulae (13-2) to (13-4) are more preferable.

From the viewpoint of electron durability, in the formula (1-A), at least one or both of G¹ and G² preferably include a substructure represented by the formula (17-2), the formula (20-2), the formula (13), the formula (14), the formula (15), or the formula (16).

Similarly, from the viewpoint of electronic durability, in the formula (1-B), at least one of G to G⁵, or all of G to G⁵ preferably include a substructure represented by the formula (17-2), the formula (20-2), the formula (13), the formula (14), the formula (15), or the formula (16).

### (Total Carbon Atom Number)

The total carbon atom number of the number of carbon atoms of G¹ and the number of carbon atoms of G² in the formula (1-A) (hereinafter, may be referred to as “total carbon atom number a”) is preferably 42 or more and 240 or less. The total carbon atom number of the number of carbon atoms of G³, the number of carbon atoms of G⁴, and the number of carbon atoms of G⁵ in the formula (1-B) (hereinafter, may be referred to as “total carbon atom number”) is preferably 42 or more and 240 or less. In addition, at least one of G¹ to G⁵ in the formulae (1-A) and (1-B) more preferably has six or more aromatic hydrocarbon groups.

From the viewpoint of charge transportability, it is considered that when the total carbon atom number a and the total carbon atom number R in each of the compound represented by the formula (1-A) and the compound represented by the formula (1-B) are in the range of 42 or more and 240 or less, the driving voltage of the element is low and the luminescent efficiency is high. When the total carbon atom number a and the total carbon atom number R are both less than 42, the crystallinity of the compound may be improved and aggregation may occur, and when the total carbon atom number a and the total carbon atom number R are both more than 240, the driving voltage of the element may increase and the luminescent efficiency may be reduced.

The total carbon atom number a and the total carbon atom number R are both preferably 54 or more, particularly preferably 72 or more, and are preferably 180 or less, particularly preferably 168 or less.

### (Substituent)

The substituent used in the compound represented by the formula (1-A) or the formula (1-B) is preferably a substituent selected from the following substituent group Z.

### <Substituent Group Z>

The substituent group Z is a substituent group consisting of an alkyl group, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, a cyano group, an aralkyl group, and an aromatic hydrocarbon group.

Examples of the alkyl group include a straight, branched, or cyclic alkyl group having generally 1 or more, preferably 4 or more, and generally 24 or less, preferably 10 or less carbon atoms, such as a methyl group, an ethyl group, a branched, straight, or cyclic propyl group, a branched, straight, or cyclic butyl group, a branched, straight, or cyclic pentyl group, a branched, straight, or cyclic hexyl group, a branched, straight, or cyclic octyl group, a branched, straight, or cyclic nonyl group, and a branched, straight, or cyclic dodecyl group. From the viewpoint of stability of the compound, a methyl group, an ethyl group, a branched, straight, or cyclic propyl group, a branched, straight, or cyclic butyl group is preferable, and a branched propyl group is particularly preferable.

Examples of the alkenyl group include an alkenyl group having generally 2 or more, and generally 24 or less, preferably 12 or less carbon atoms, such as a vinyl group.

Examples of the alkynyl group include an alkynyl group having generally 2 or more, and generally 24 or less, preferably 12 or less carbon atoms, such as an ethynyl group.

Examples of the alkoxy group include an alkoxy group having generally 1 or more, and generally 24 or less, preferably 12 or less carbon atoms, such as a methoxy group and an ethoxy group.

Examples of the aryloxy group include an aryloxy group or a heteroaryloxy group having generally 4 or more, preferably 5 or more, and generally 36 or less, preferably 24 or less carbon atoms, such as a phenoxy group, a naphthoxy group, and a pyridyloxy group.

Examples of the alkoxycarbonyl group include an alkoxycarbonyl group having generally 2 or more, and generally 24 or less, preferably 12 or less carbon atoms, such as a methoxycarbonyl group and an ethoxycarbonyl group.

Examples of the acyl group include an acyl group having generally 2 or more, and generally 24 or less, preferably 12 or less carbon atoms, such as an acetyl group and a benzoyl group.

Examples of the halogen atom include a halogen atom such as a fluorine atom and a chlorine atom.

Examples of the haloalkyl group include a haloalkyl group having generally 1 or more, and generally 12 or less, preferably 6 or less carbon atoms, such as trifluoromethyl groups.

Examples of the alkylthio group include an alkylthio group having generally 1 or more, and generally 24 or less, preferably 12 or less carbon atoms, such as a methylthio group and an ethylthio group.

Examples of the arylthio group include an arylthio group having generally 4 or more, preferably 5 or more, and generally 36 or less, preferably 24 or less carbon atoms, such as a phenylthio group, a naphthylthio group, and a pyridylthio group.

Examples of the silyl group include a silyl group having generally 2 or more, preferably 3 or more, and generally 36 or less, preferably 24 or less carbon atoms, such as a trimethylsilyl group and a triphenylsilyl group.

Examples of the siloxy group include a siloxy group having generally 2 or more, preferably 3 or more, and generally 36 or less, preferably 24 or less carbon atoms, such as a trimethylsiloxy group and a triphenylsiloxy group.

Examples of the aralkyl group include an aralkyl group having generally 7 or more, preferably 9 or more, and generally 30 or less, preferably 18 or less, more preferably 10 or less carbon atoms, such as benzyl group, 2-phenylethyl group, 2-phenylpropyl-2-yl group, 2-phenylbutyl-2-yl group, 3-phenylpentyl-3-yl group, 3-phenyl-1-propyl group, 4-phenyl-1-butyl group, 5-phenyl-1-pentyl group, 6-phenyl-1-hexyl group, 7-phenyl-1-heptyl group, and 8-phenyl-1-octyl group.

Examples of the aromatic hydrocarbon group include an aromatic hydrocarbon group having generally 6 or more, and generally 30 or less, preferably 18 or less, and more preferably 10 or less carbon atoms, such as a benzene ring, a naphthalene ring, an anthracene ring, a tetraphenylene ring, a phenanthrene ring, a chrysene ring, a pyrene ring, a benzanthracene ring, or a perylene ring.

Among the above substituents, an alkyl group, an alkoxy group, an aralkyl group, and an aromatic hydrocarbon group are preferable, an alkyl group having 10 or less carbon atoms, an aralkyl group having 30 or less carbon atoms, and an aromatic hydrocarbon group having 30 or less carbon atoms are more preferable, an aromatic hydrocarbon group having 30 or less carbon atoms is still more preferable, and it is particularly preferably that the compound has no substituent.

The above substituent may further have a substituent. As the substituent which may be further provided, the same substituents as those described above (substituent group Z) can be used. The substituent of the above substituent group Z preferably has no further substituent.

(Molecular Weight) A molecular weight of the compound represented by the formula (1-A) or the formula (1-B) is preferably 800 or more, more preferably 1,200 or more, particularly preferably 1,300 or more, most preferably 1,400 or more, and is preferably 5,000 or less, more preferably 4,000 or less, particularly preferably 3,000 or less, most preferably 2,500 or less.

### Specific Example

Specific examples of the compound represented by the formula (1-A) or the formula (1-B) are shown below, but the present invention is not limited thereto.

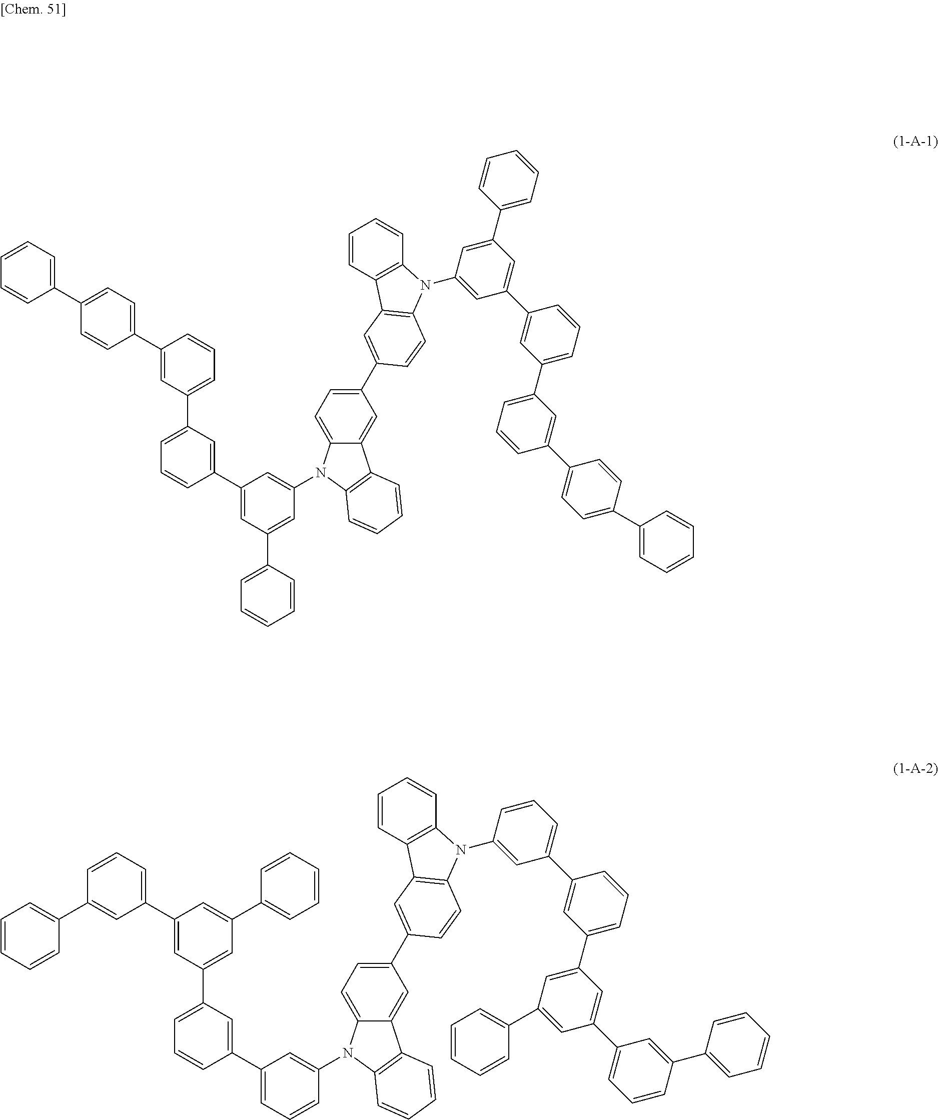 [SMILES: c1ccc(-c2ccc(-c3cccc(-c4cccc(-c5cc(-c6ccccc6)cc(-n6c7ccccc7c7cc(-c8ccc9c(c8)c8ccccc8n9-c8cc(-c9ccccc9)cc(-c9cccc(-c%10cccc(-c%11ccc(-c%12ccccc%12)cc%11)c%10)c9)c8)ccc76)c5)c4)c3)cc2)cc1 ; c1ccc(-c2cccc(-c3cc(-c4ccccc4)cc(-c4cccc(-c5cccc(-n6c7ccccc7c7cc(-c8ccc9c(c8)c8ccccc8n9-c8cccc(-c9cccc(-c%10cc(-c%11ccccc%11)cc(-c%11cccc(-c%12ccccc%12)c%11)c%10)c9)c8)ccc76)c5)c4)c3)c2)cc1]

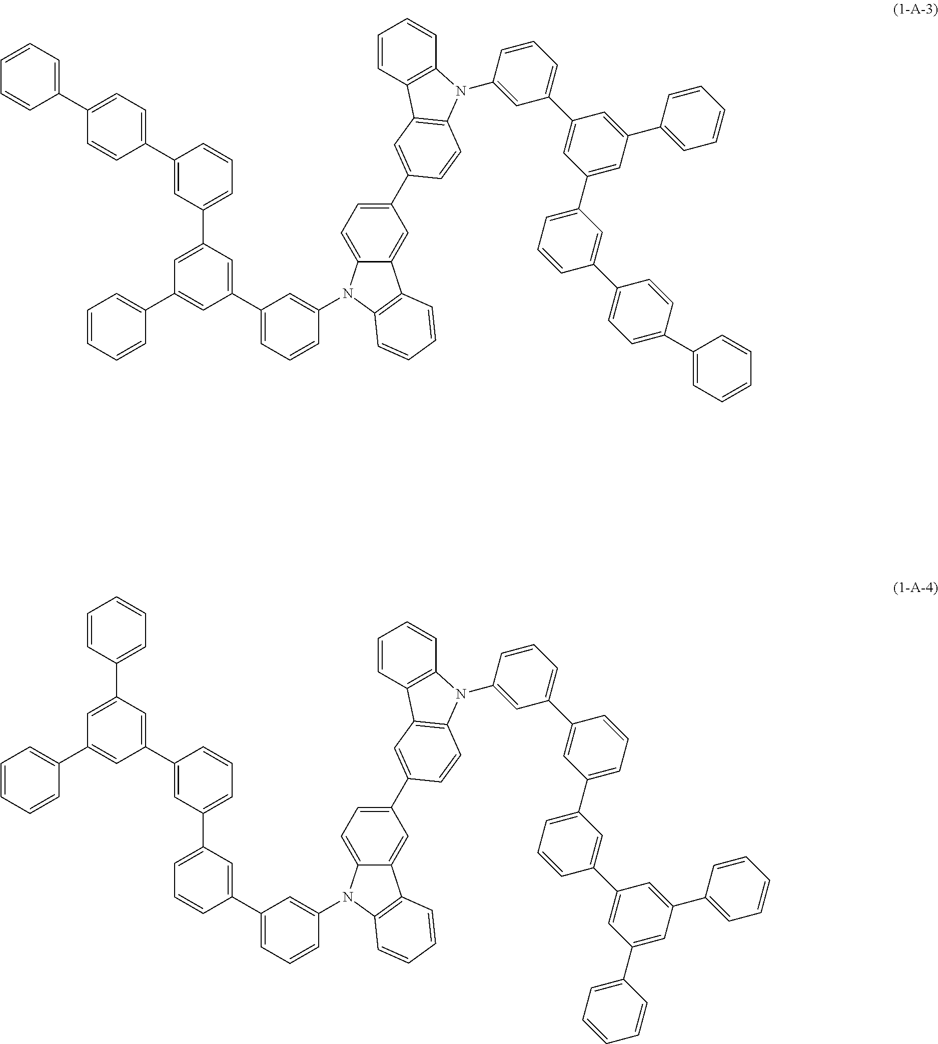 [SMILES: c1ccc(-c2ccc(-c3cccc(-c4cc(-c5ccccc5)cc(-c5cccc(-n6c7ccccc7c7cc(-c8ccc9c(c8)c8ccccc8n9-c8cccc(-c9cc(-c%10ccccc%10)cc(-c%10cccc(-c%11ccc(-c%12ccccc%12)cc%11)c%10)c9)c8)ccc76)c5)c4)c3)cc2)cc1 ; c1ccc(-c2cc(-c3ccccc3)cc(-c3cccc(-c4cccc(-c5cccc(-n6c7ccccc7c7cc(-c8ccc9c(c8)c8ccccc8n9-c8cccc(-c9cccc(-c%10cccc(-c%11cc(-c%12ccccc%12)cc(-c%12ccccc%12)c%11)c%10)c9)c8)ccc76)c5)c4)c3)c2)cc1]

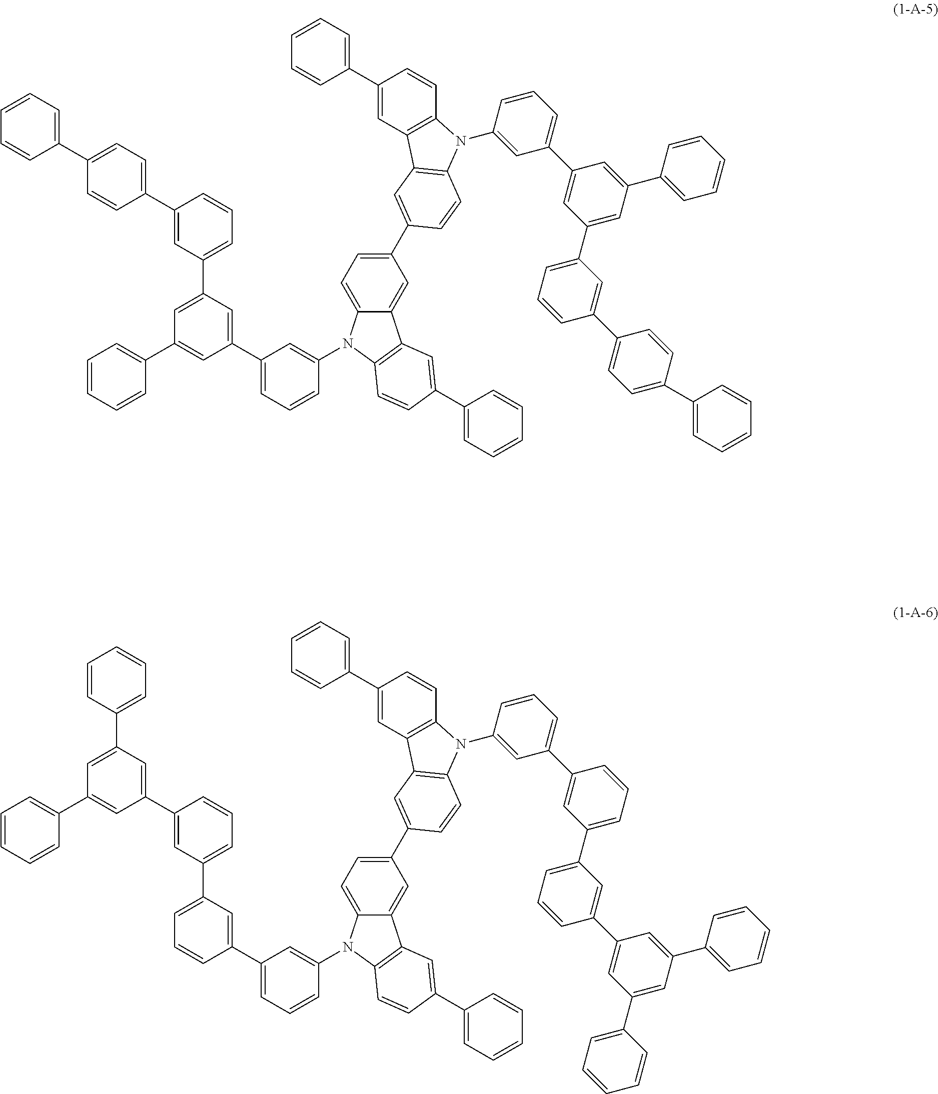 [SMILES: c1ccc(-c2ccc(-c3cccc(-c4cc(-c5ccccc5)cc(-c5cccc(-n6c7ccc(-c8ccccc8)cc7c7cc(-c8ccc9c(c8)c8cc(-c%10ccccc%10)ccc8n9-c8cccc(-c9cc(-c%10ccccc%10)cc(-c%10cccc(-c%11ccc(-c%12ccccc%12)cc%11)c%10)c9)c8)ccc76)c5)c4)c3)cc2)cc1 ; c1ccc(-c2cc(-c3ccccc3)cc(-c3cccc(-c4cccc(-c5cccc(-n6c7ccc(-c8ccccc8)cc7c7cc(-c8ccc9c(c8)c8cc(-c%10ccccc%10)ccc8n9-c8cccc(-c9cccc(-c%10cccc(-c%11cc(-c%12ccccc%12)cc(-c%12ccccc%12)c%11)c%10)c9)c8)ccc76)c5)c4)c3)c2)cc1]

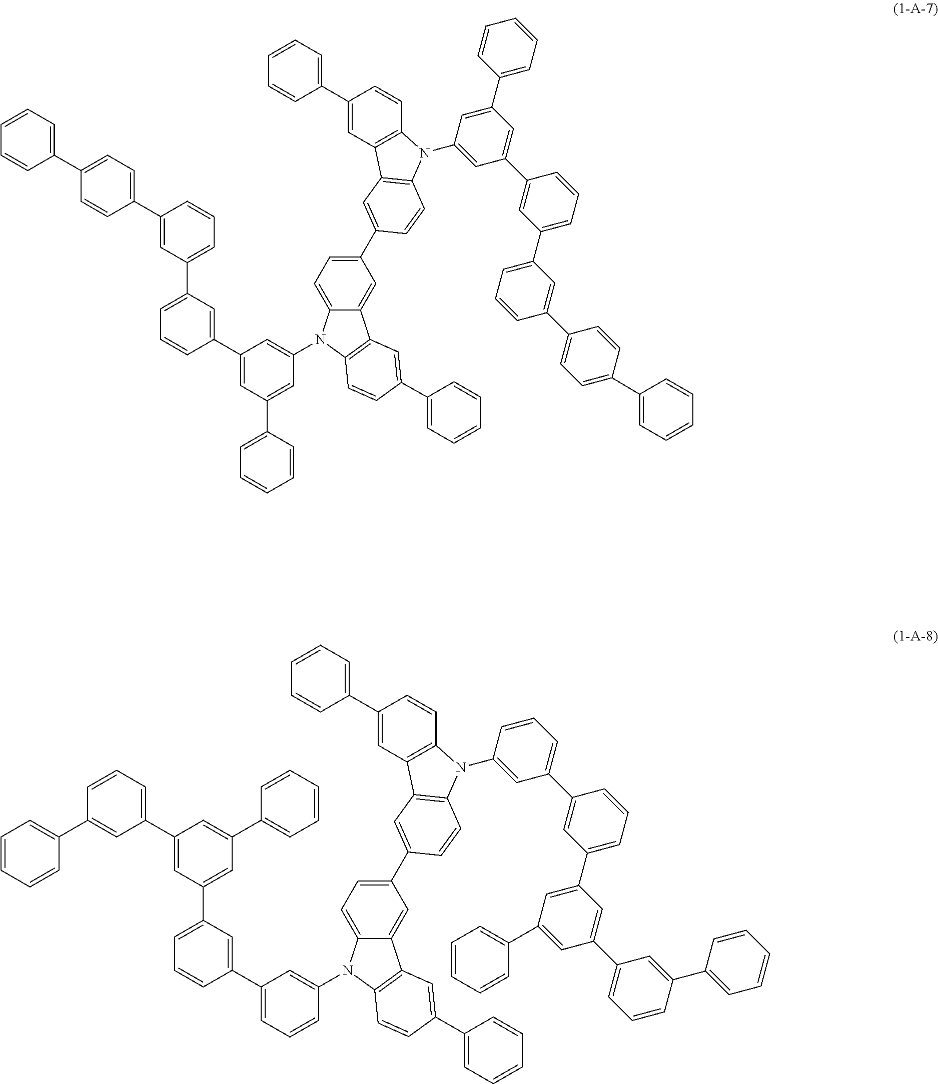 [SMILES: c1ccc(-c2ccc(-c3cccc(-c4cccc(-c5cc(-c6ccccc6)cc(-n6c7ccc(-c8ccccc8)cc7c7cc(-c8ccc9c(c8)c8cc(-c%10ccccc%10)ccc8n9-c8cc(-c9ccccc9)cc(-c9cccc(-c%10cccc(-c%11ccc(-c%12ccccc%12)cc%11)c%10)c9)c8)ccc76)c5)c4)c3)cc2)cc1 ; c1ccc(-c2cccc(-c3cc(-c4ccccc4)cc(-c4cccc(-c5cccc(-n6c7ccc(-c8ccccc8)cc7c7cc(-c8ccc9c(c8)c8cc(-c%10ccccc%10)ccc8n9-c8cccc(-c9cccc(-c%10cc(-c%11ccccc%11)cc(-c%11cccc(-c%12ccccc%12)c%11)c%10)c9)c8)ccc76)c5)c4)c3)c2)cc1]

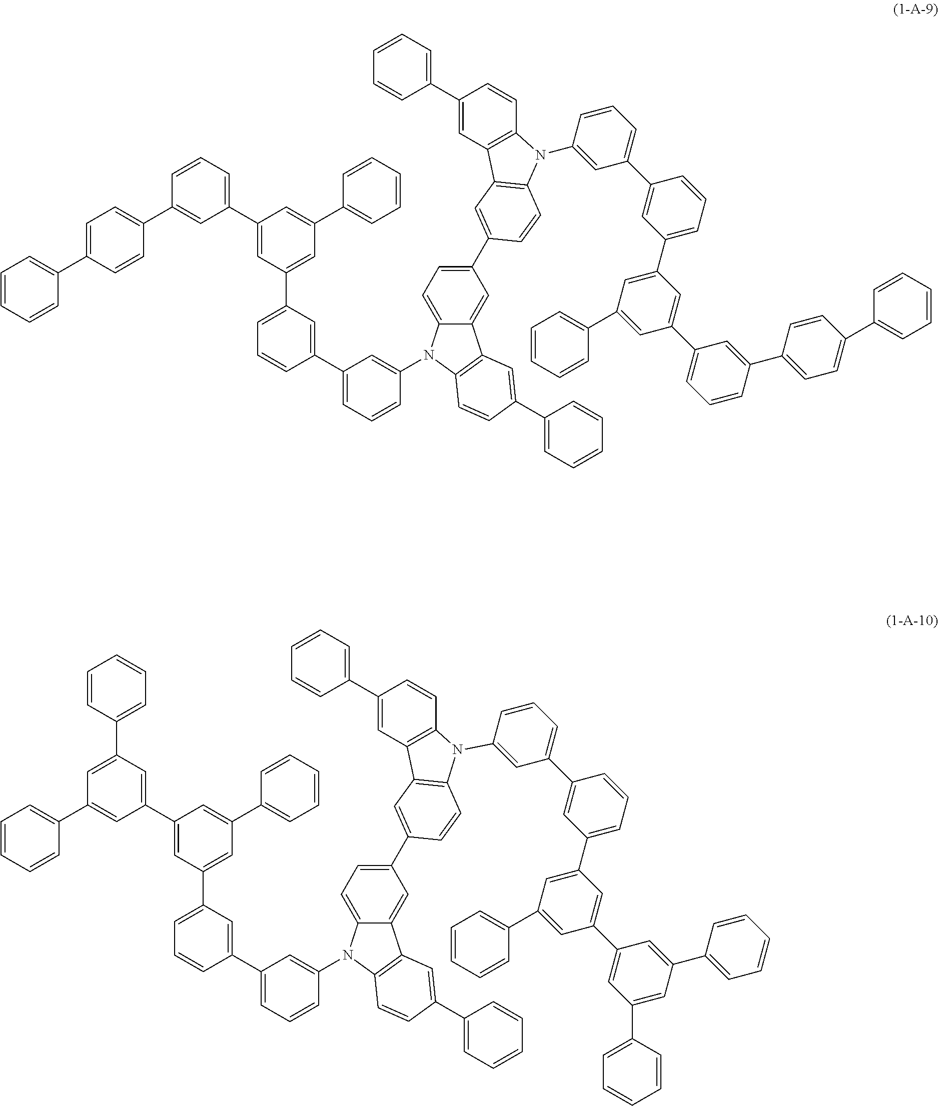 [SMILES: c1ccc(-c2ccc(-c3cccc(-c4cc(-c5ccccc5)cc(-c5cccc(-c6cccc(-n7c8ccc(-c9ccccc9)cc8c8cc(-c9ccc%10c(c9)c9cc(-c%11ccccc%11)ccc9n%10-c9cccc(-c%10cccc(-c%11cc(-c%12ccccc%12)cc(-c%12cccc(-c%13ccc(-c%14ccccc%14)cc%13)c%12)c%11)c%10)c9)ccc87)c6)c5)c4)c3)cc2)cc1 ; c1ccc(-c2cc(-c3ccccc3)cc(-c3cc(-c4ccccc4)cc(-c4cccc(-c5cccc(-n6c7ccc(-c8ccccc8)cc7c7cc(-c8ccc9c(c8)c8cc(-c%10ccccc%10)ccc8n9-c8cccc(-c9cccc(-c%10cc(-c%11ccccc%11)cc(-c%11cc(-c%12ccccc%12)cc(-c%12ccccc%12)c%11)c%10)c9)c8)ccc76)c5)c4)c3)c2)cc1]

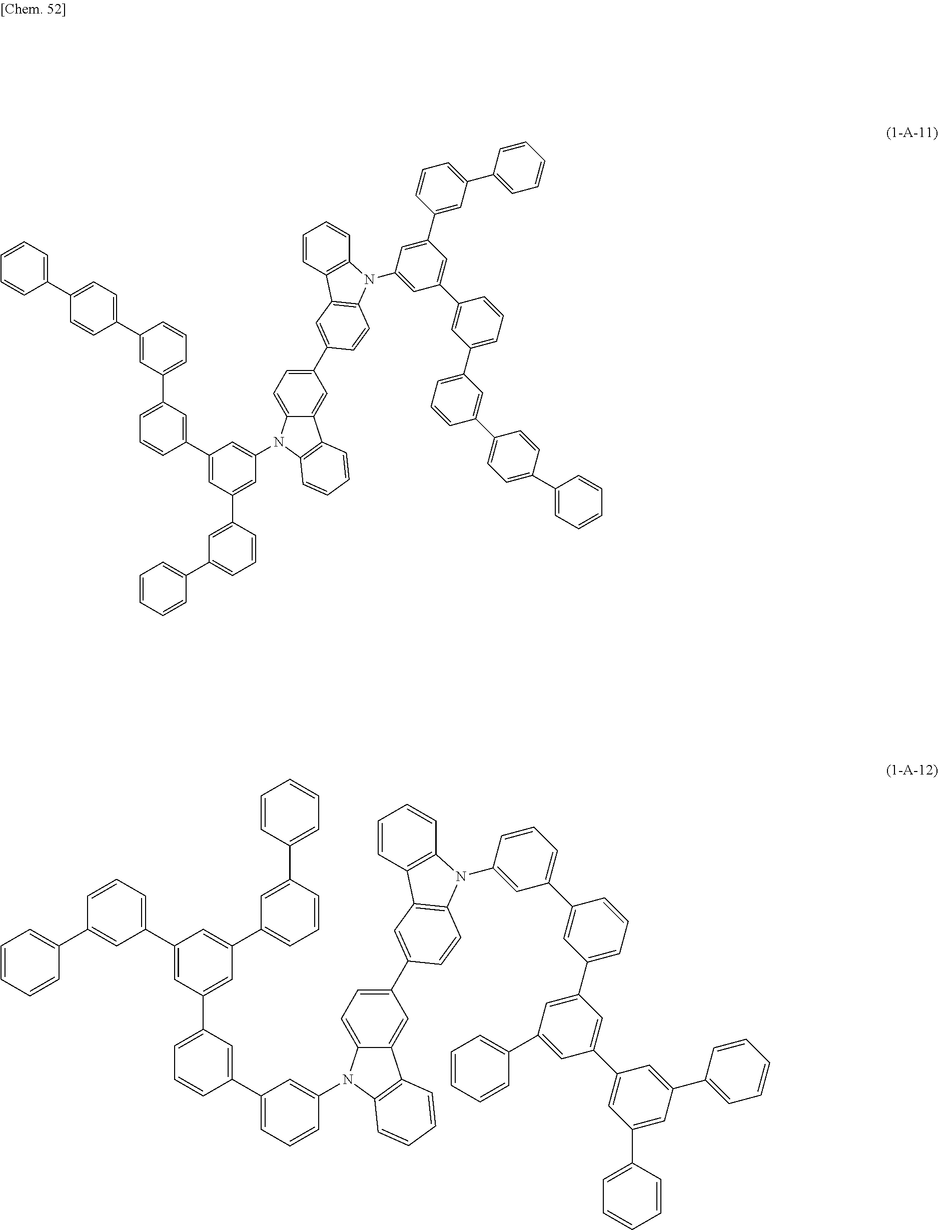 [SMILES: c1ccc(-c2ccc(-c3cccc(-c4cccc(-c5cc(-c6cccc(-c7ccccc7)c6)cc(-n6c7ccccc7c7cc(-c8ccc9c(c8)c8ccccc8n9-c8cc(-c9cccc(-c%10ccccc%10)c9)cc(-c9cccc(-c%10cccc(-c%11ccc(-c%12ccccc%12)cc%11)c%10)c9)c8)ccc76)c5)c4)c3)cc2)cc1 ; c1ccc(-c2cccc(-c3cc(-c4cccc(-c5ccccc5)c4)cc(-c4cccc(-c5cccc(-n6c7ccccc7c7cc(-c8ccc9c(c8)c8ccccc8n9-c8cccc(-c9cccc(-c%10cc(-c%11ccccc%11)cc(-c%11cc(-c%12ccccc%12)cc(-c%12ccccc%12)c%11)c%10)c9)c8)ccc76)c5)c4)c3)c2)cc1]

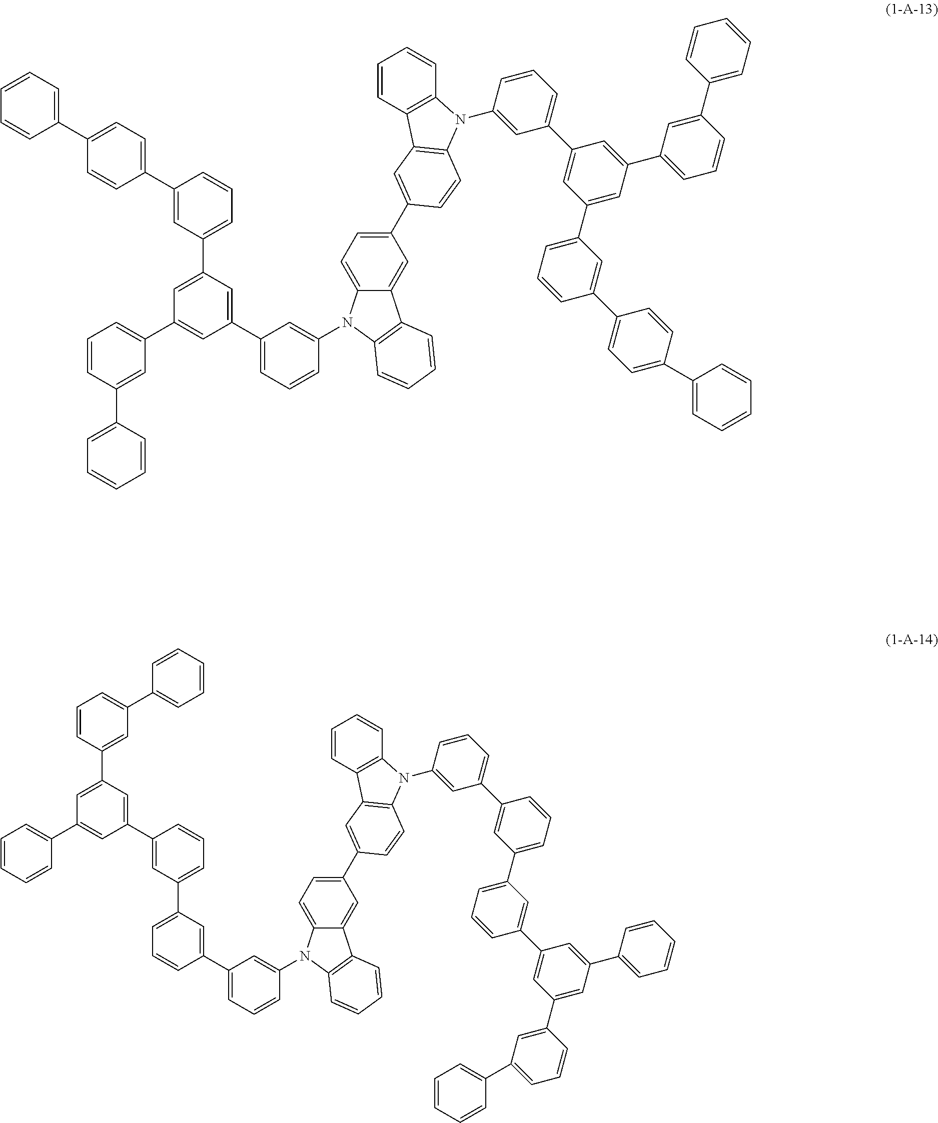 [SMILES: c1ccc(-c2ccc(-c3cccc(-c4cc(-c5cccc(-c6ccccc6)c5)cc(-c5cccc(-n6c7ccccc7c7cc(-c8ccc9c(c8)c8ccccc8n9-c8cccc(-c9cc(-c%10cccc(-c%11ccccc%11)c%10)cc(-c%10cccc(-c%11ccc(-c%12ccccc%12)cc%11)c%10)c9)c8)ccc76)c5)c4)c3)cc2)cc1 ; c1ccc(-c2cccc(-c3cc(-c4ccccc4)cc(-c4cccc(-c5cccc(-c6cccc(-n7c8ccccc8c8cc(-c9ccc%10c(c9)c9ccccc9n%10-c9cccc(-c%10cccc(-c%11cccc(-c%12cc(-c%13ccccc%13)cc(-c%13cccc(-c%14ccccc%14)c%13)c%12)c%11)c%10)c9)ccc87)c6)c5)c4)c3)c2)cc1]

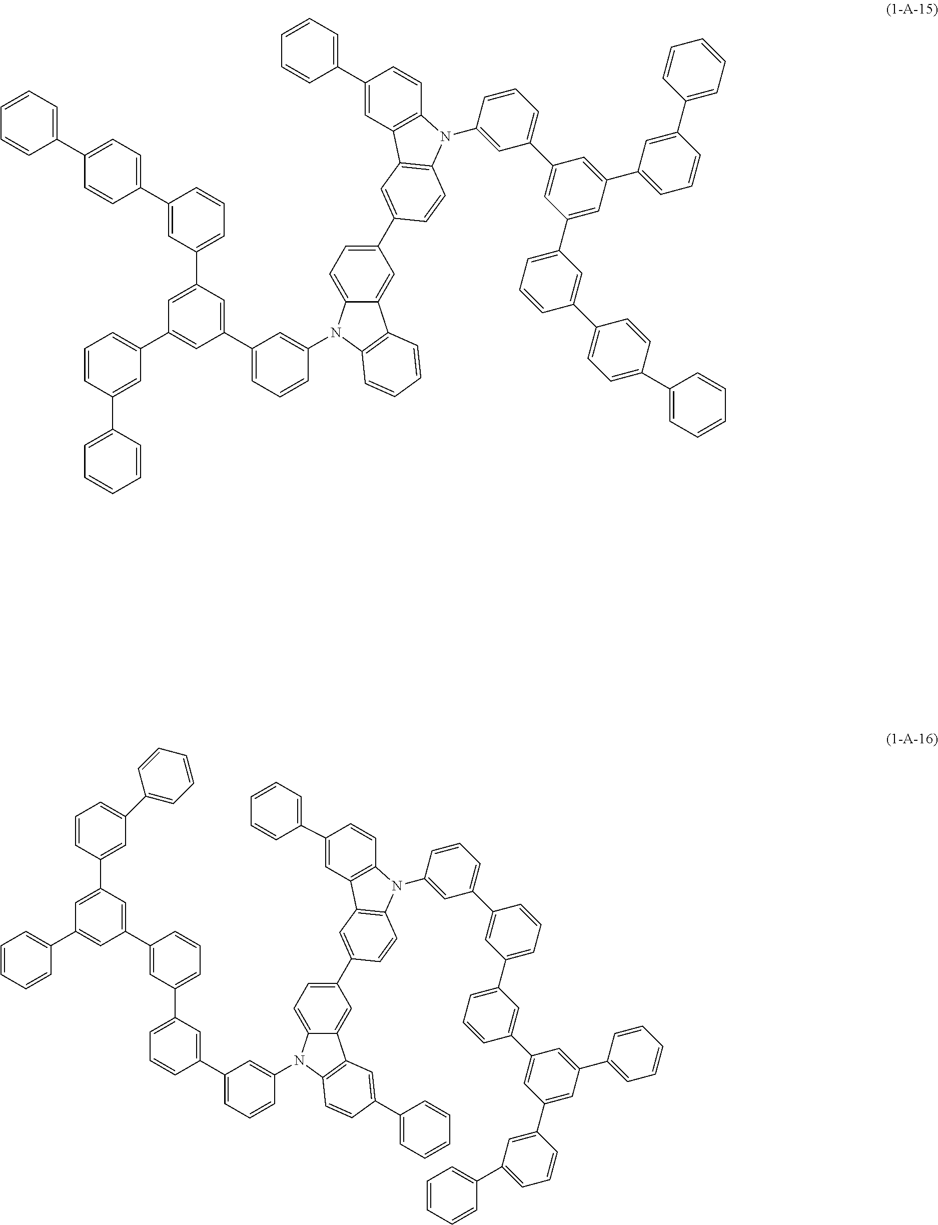 [SMILES: c1ccc(-c2ccc(-c3cccc(-c4cc(-c5cccc(-c6ccccc6)c5)cc(-c5cccc(-n6c7ccccc7c7cc(-c8ccc9c(c8)c8cc(-c%10ccccc%10)ccc8n9-c8cccc(-c9cc(-c%10cccc(-c%11ccccc%11)c%10)cc(-c%10cccc(-c%11ccc(-c%12ccccc%12)cc%11)c%10)c9)c8)ccc76)c5)c4)c3)cc2)cc1 ; c1ccc(-c2cccc(-c3cc(-c4ccccc4)cc(-c4cccc(-c5cccc(-c6cccc(-n7c8ccc(-c9ccccc9)cc8c8cc(-c9ccc%10c(c9)c9cc(-c%11ccccc%11)ccc9n%10-c9cccc(-c%10cccc(-c%11cccc(-c%12cc(-c%13ccccc%13)cc(-c%13cccc(-c%14ccccc%14)c%13)c%12)c%11)c%10)c9)ccc87)c6)c5)c4)c3)c2)cc1]

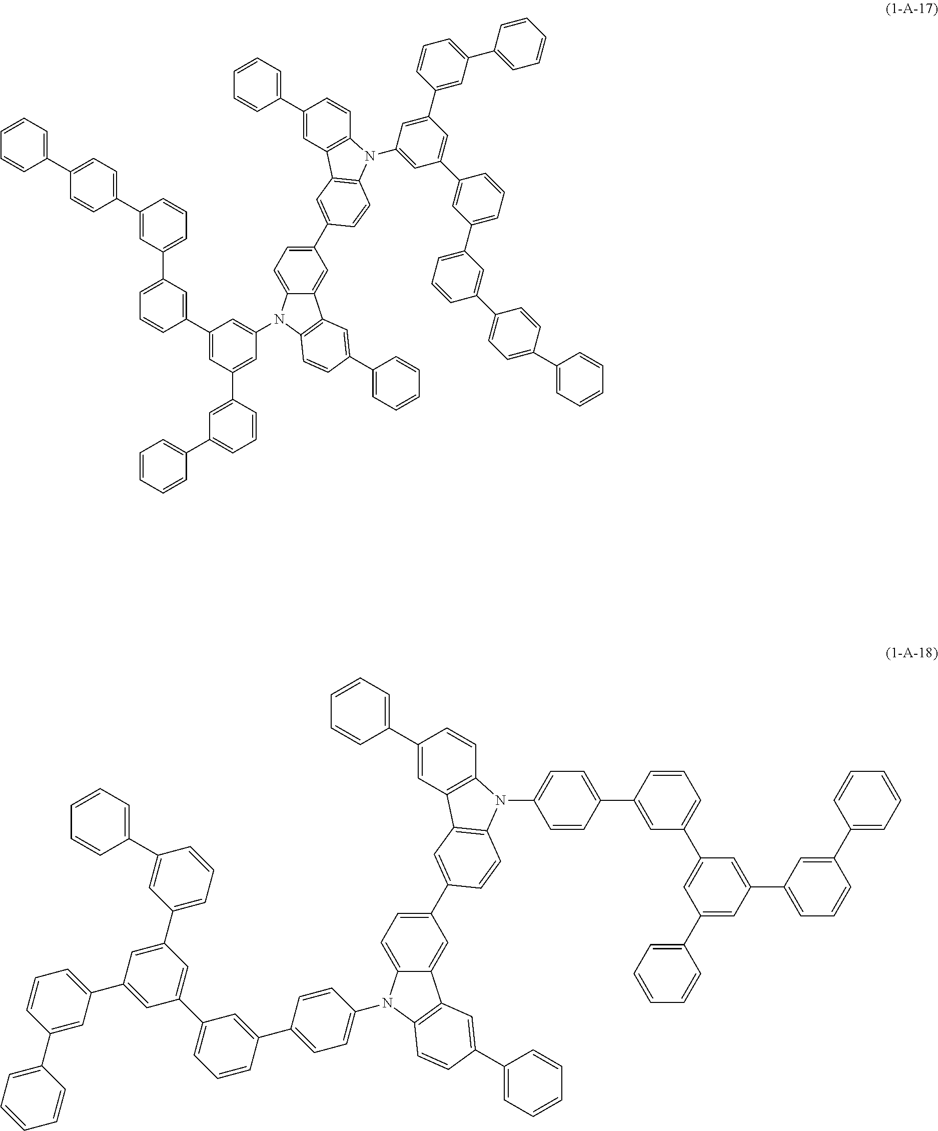 [SMILES: c1ccc(-c2ccc(-c3cccc(-c4cccc(-c5cc(-c6cccc(-c7ccccc7)c6)cc(-n6c7ccc(-c8ccccc8)cc7c7cc(-c8ccc9c(c8)c8cc(-c%10ccccc%10)ccc8n9-c8cc(-c9cccc(-c%10ccccc%10)c9)cc(-c9cccc(-c%10cccc(-c%11ccc(-c%12ccccc%12)cc%11)c%10)c9)c8)ccc76)c5)c4)c3)cc2)cc1 ; c1ccc(-c2cccc(-c3cc(-c4ccccc4)cc(-c4cccc(-c5ccc(-n6c7ccc(-c8ccccc8)cc7c7cc(-c8ccc9c(c8)c8cc(-c%10ccccc%10)ccc8n9-c8ccc(-c9cccc(-c%10cc(-c%11cccc(-c%12ccccc%12)c%11)cc(-c%11cccc(-c%12ccccc%12)c%11)c%10)c9)cc8)ccc76)cc5)c4)c3)c2)cc1]

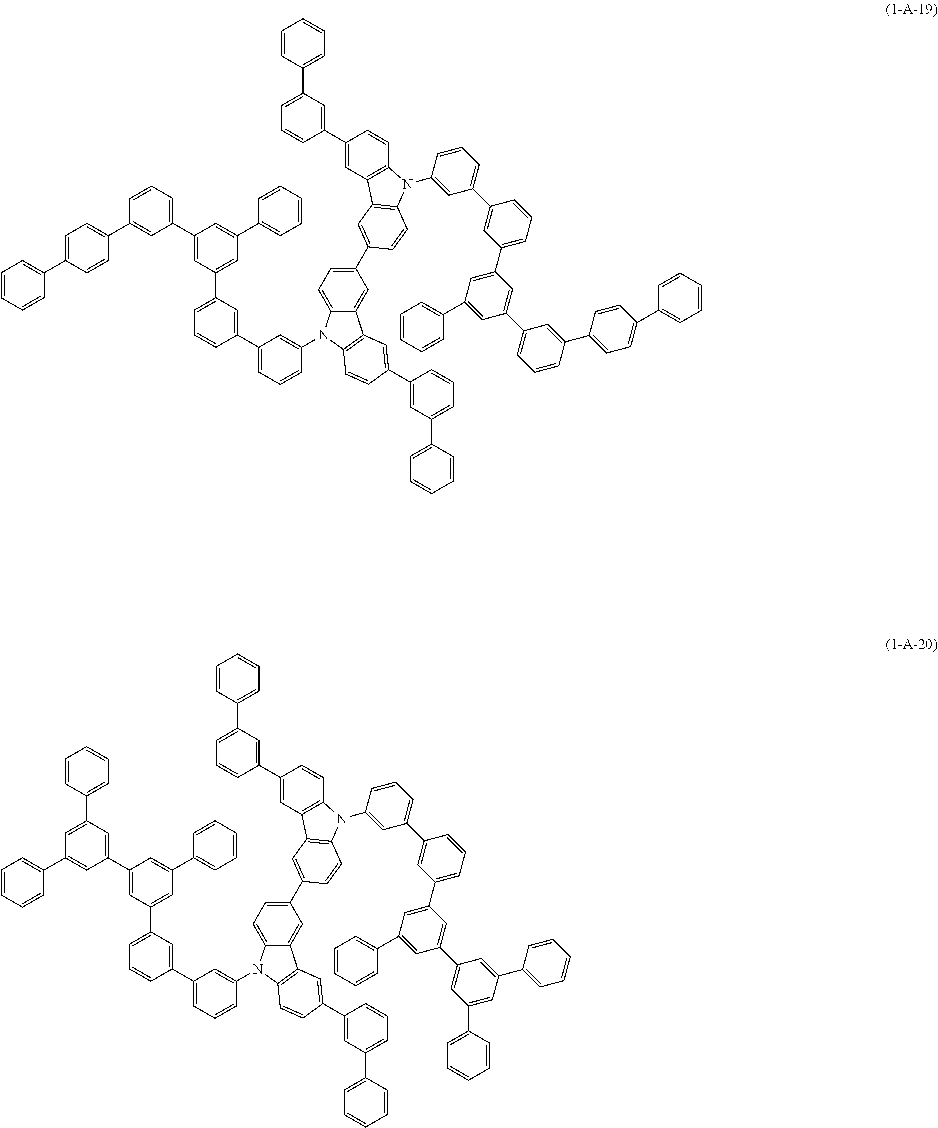

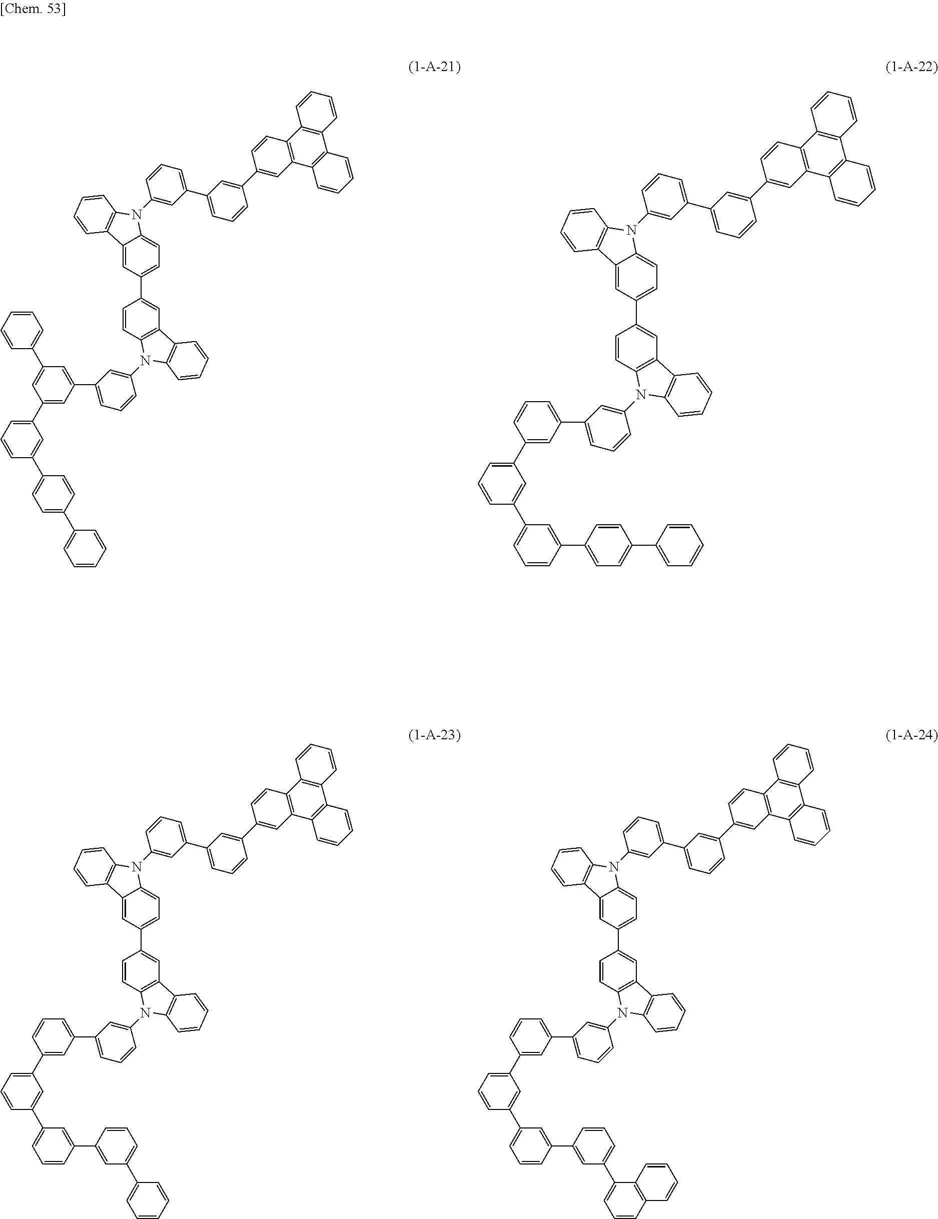

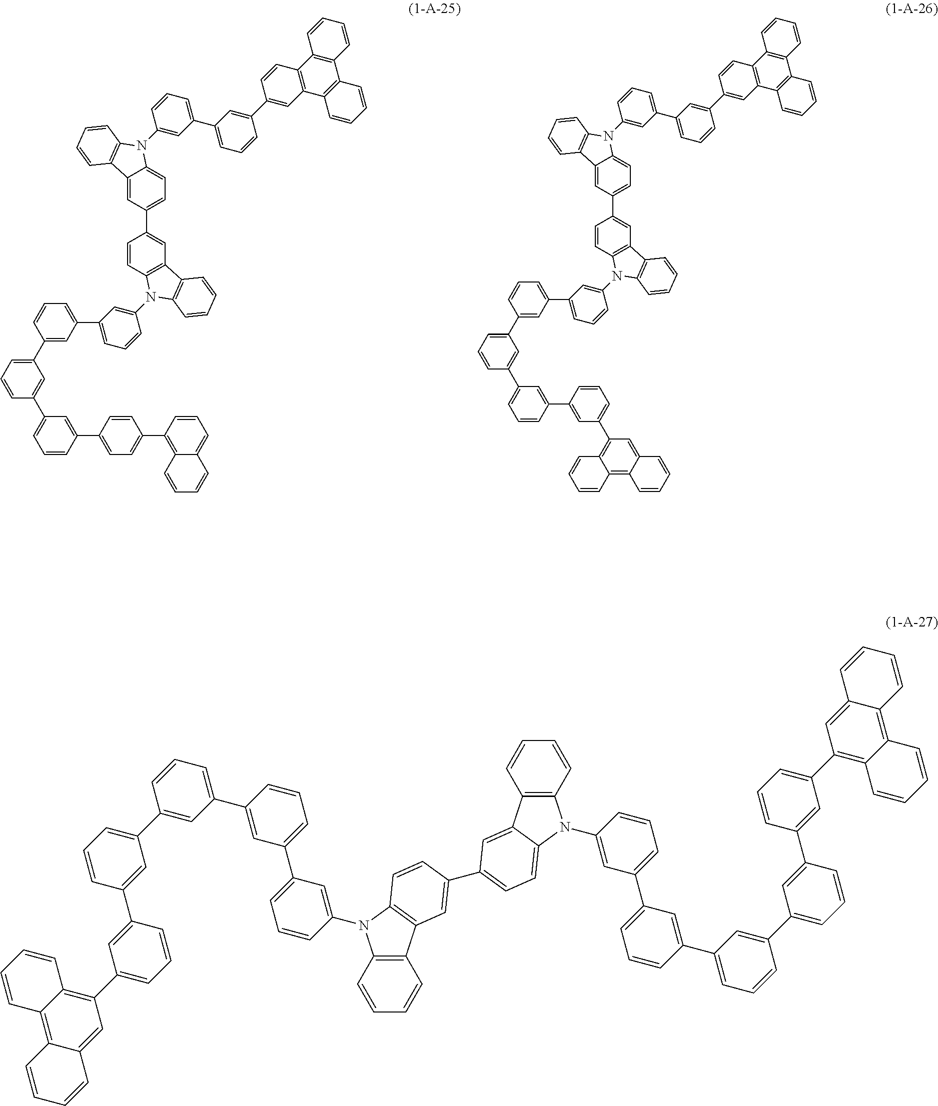

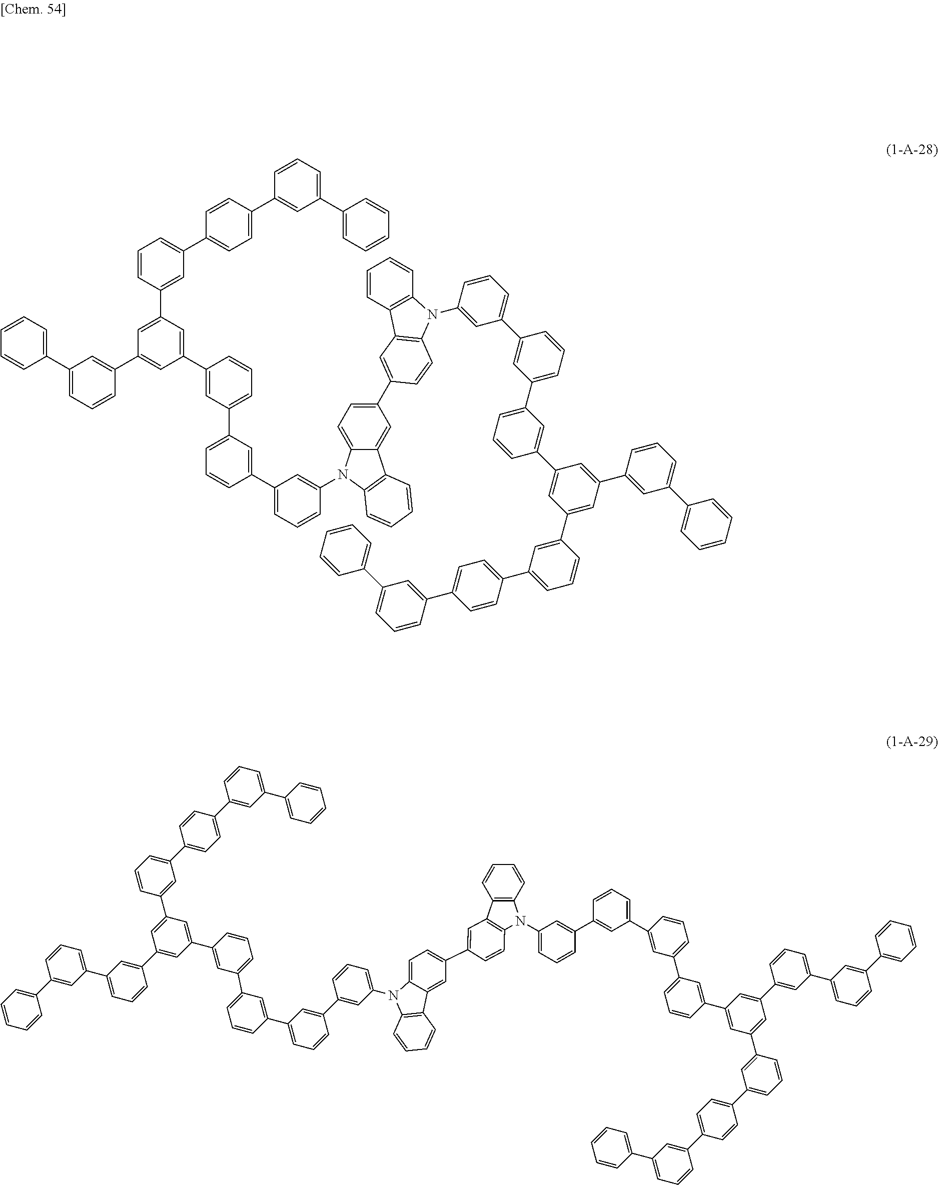

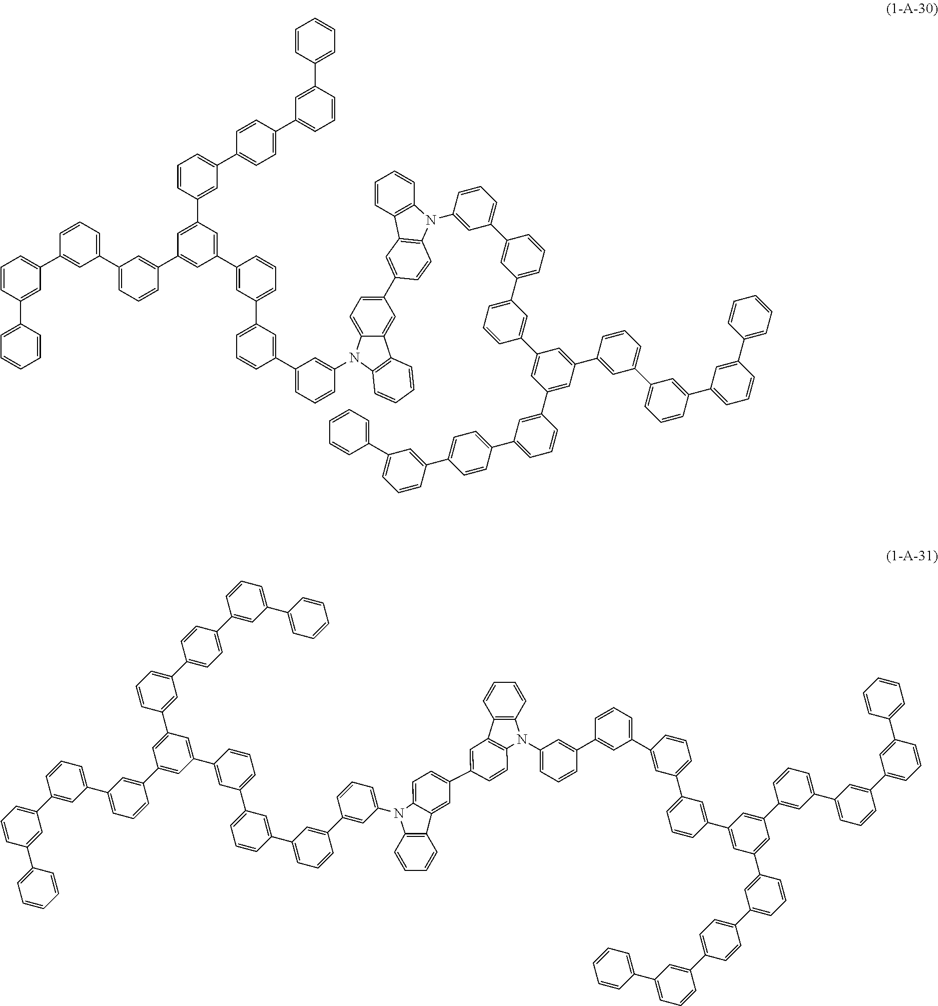

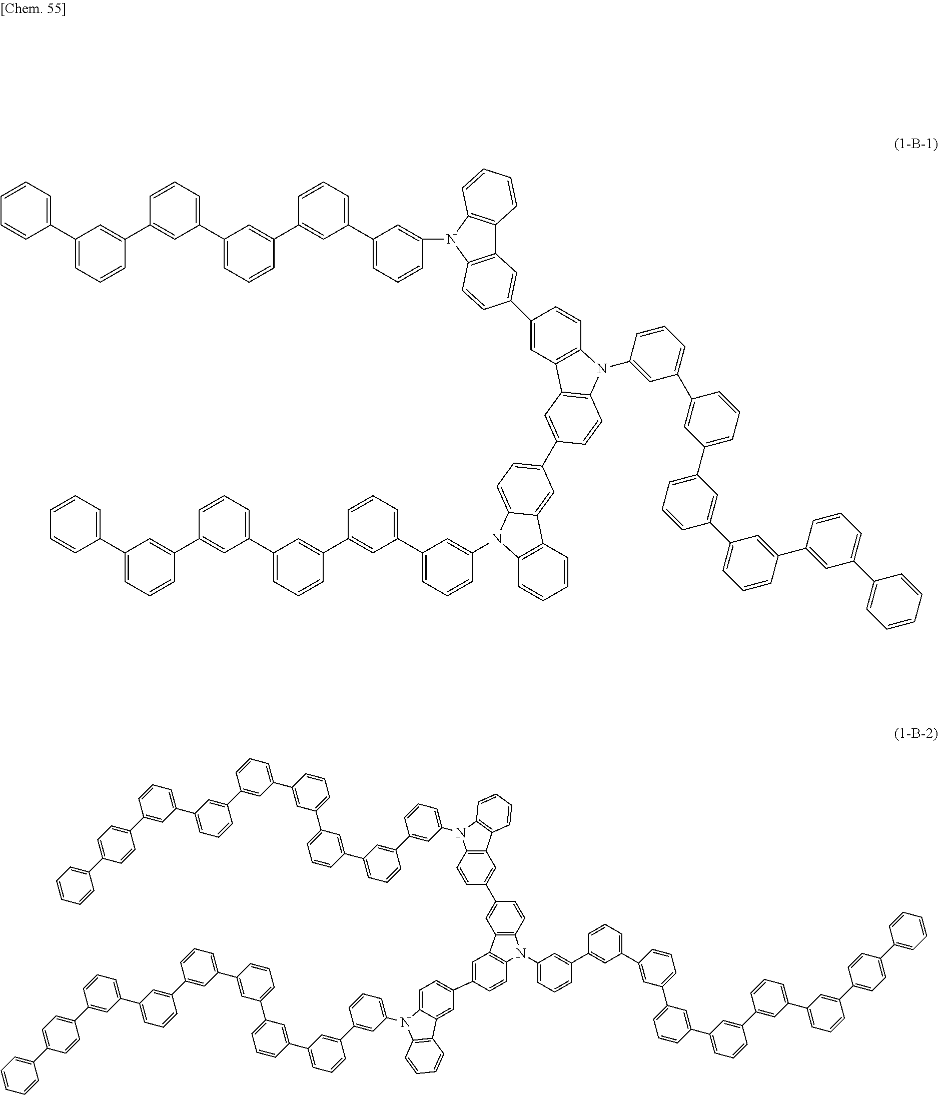

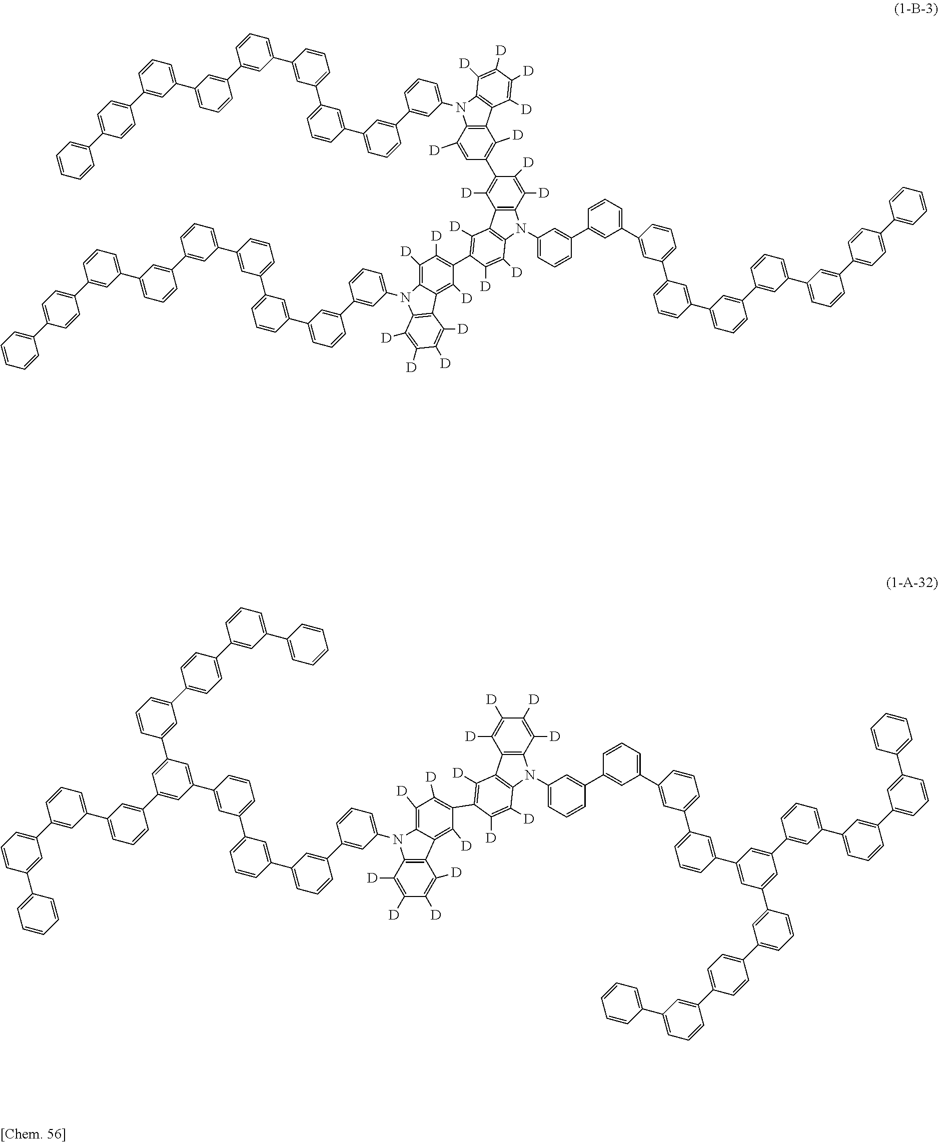

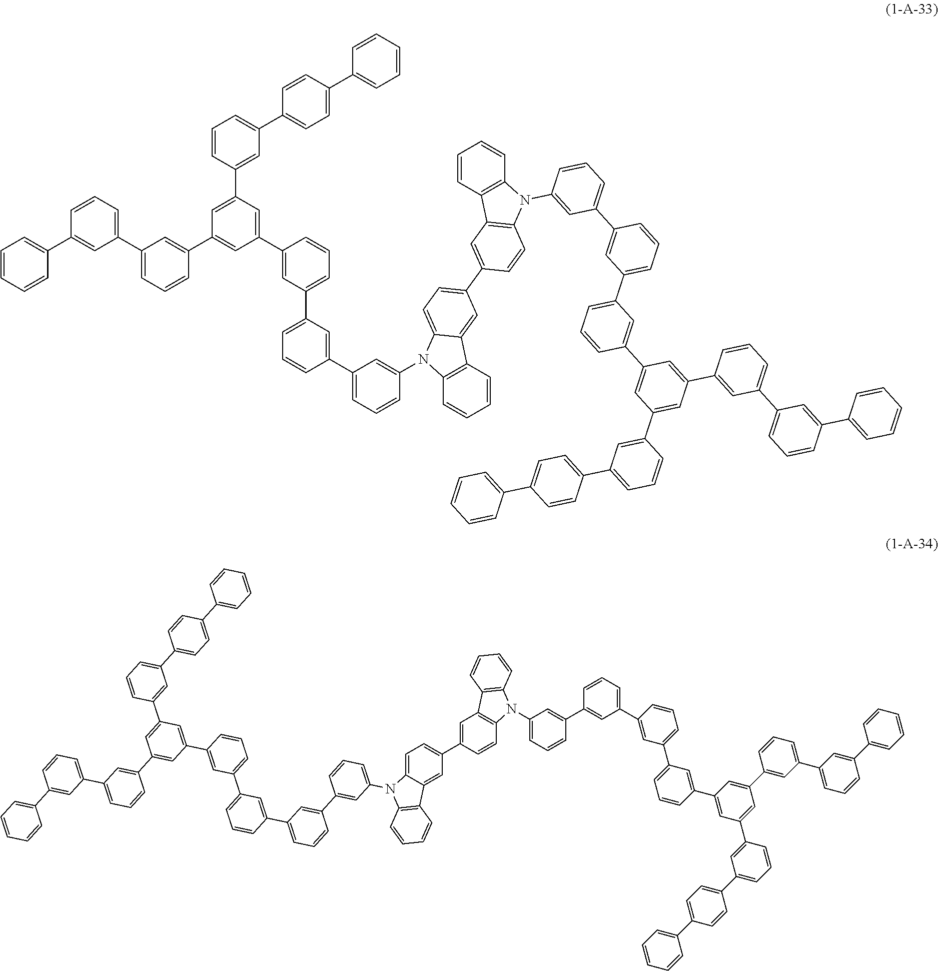

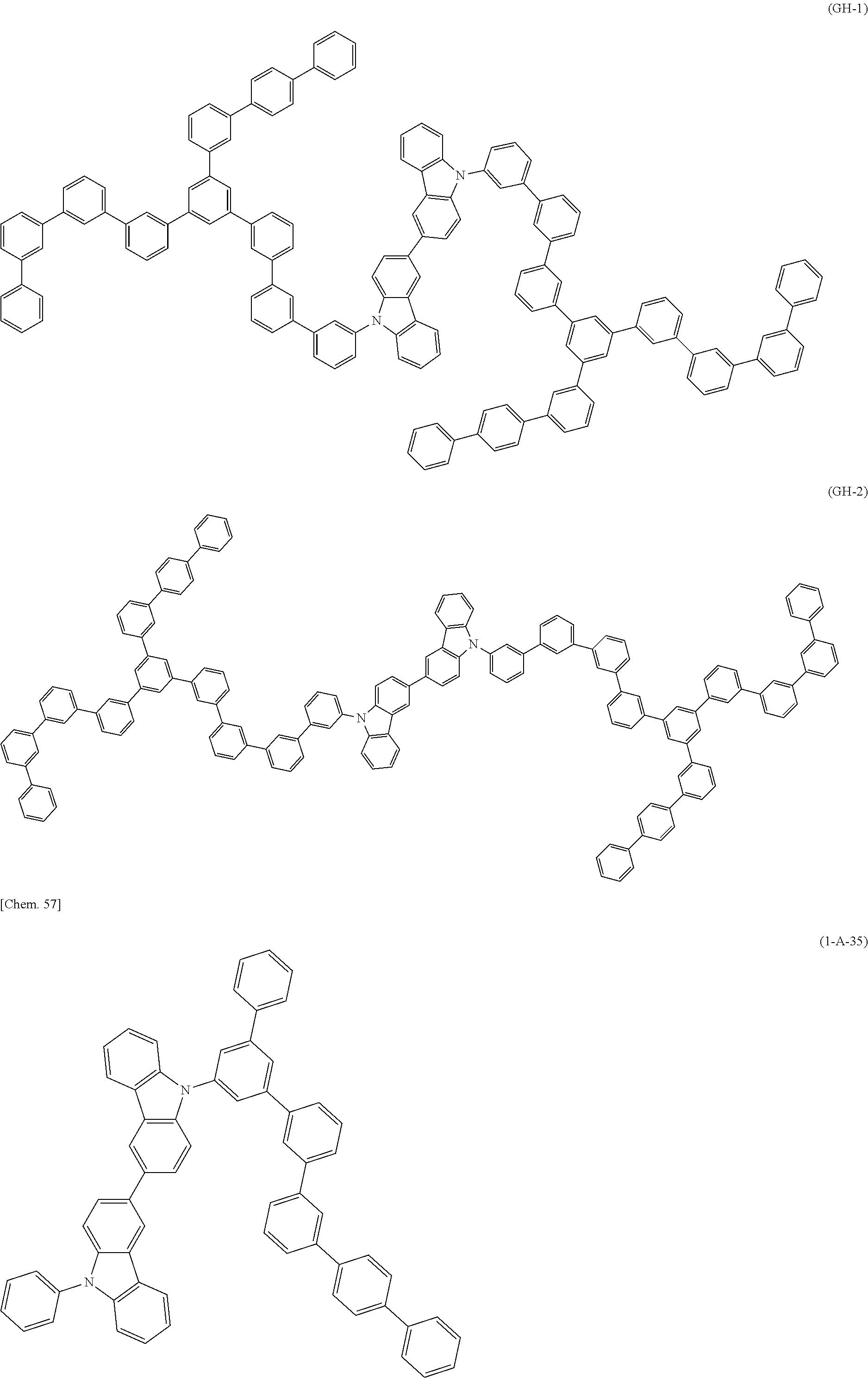

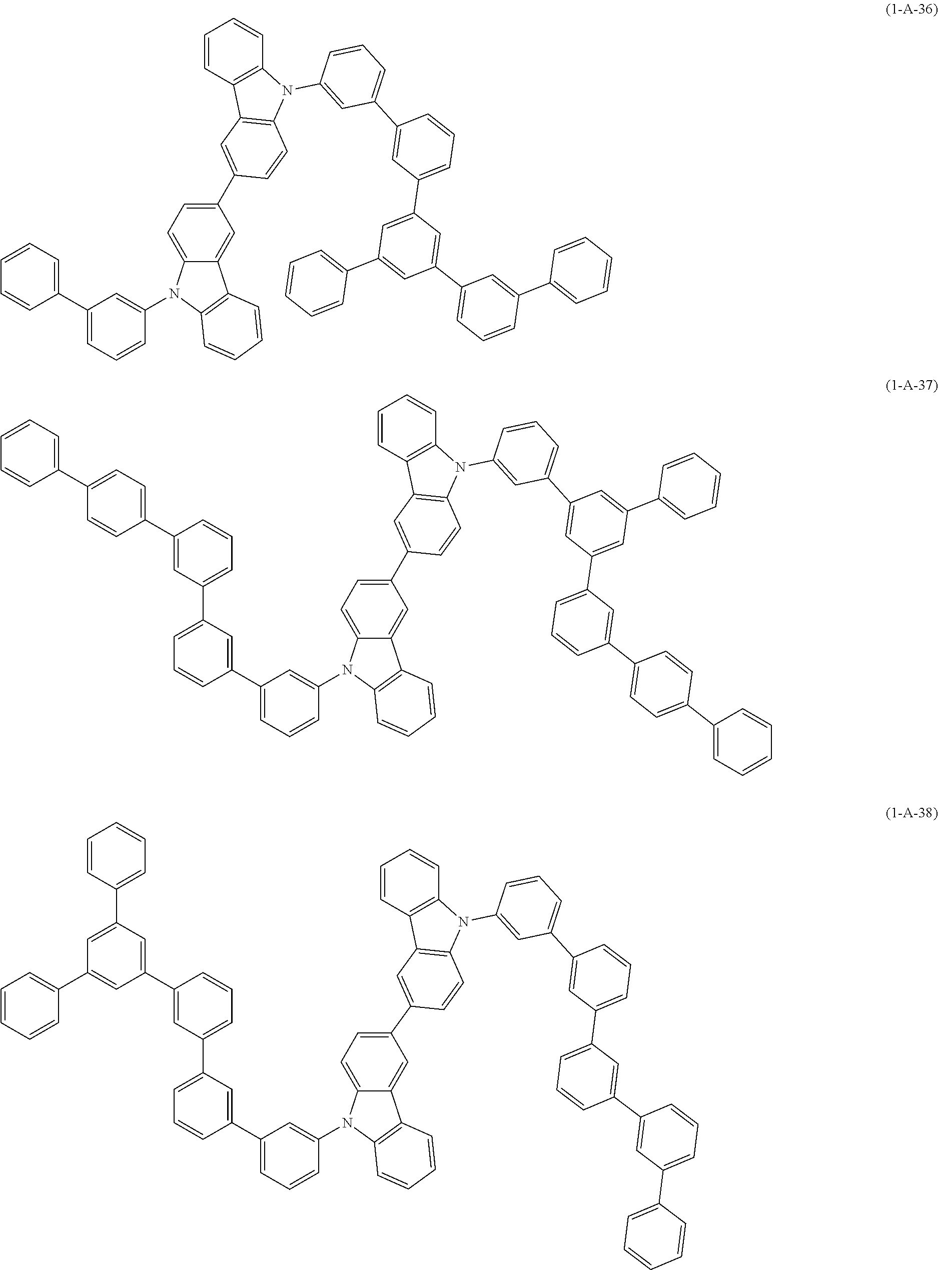 [SMILES: c1ccc(-c2cccc(-c3cc(-c4ccccc4)cc(-c4cccc(-c5cccc(-n6c7ccccc7c7cc(-c8ccc9c(c8)c8ccccc8n9-c8cccc(-c9ccccc9)c8)ccc76)c5)c4)c3)c2)cc1 ; c1ccc(-c2ccc(-c3cccc(-c4cccc(-c5cccc(-n6c7ccccc7c7cc(-c8ccc9c(c8)c8ccccc8n9-c8cccc(-c9cc(-c%10ccccc%10)cc(-c%10cccc(-c%11ccc(-c%12ccccc%12)cc%11)c%10)c9)c8)ccc76)c5)c4)c3)cc2)cc1 ; c1ccc(-c2cccc(-c3cccc(-c4cccc(-c5cccc(-n6c7ccccc7c7cc(-c8ccc9c(c8)c8ccccc8n9-c8cccc(-c9cccc(-c%10cccc(-c%11cc(-c%12ccccc%12)cc(-c%12ccccc%12)c%11)c%10)c9)c8)ccc76)c5)c4)c3)c2)cc1]

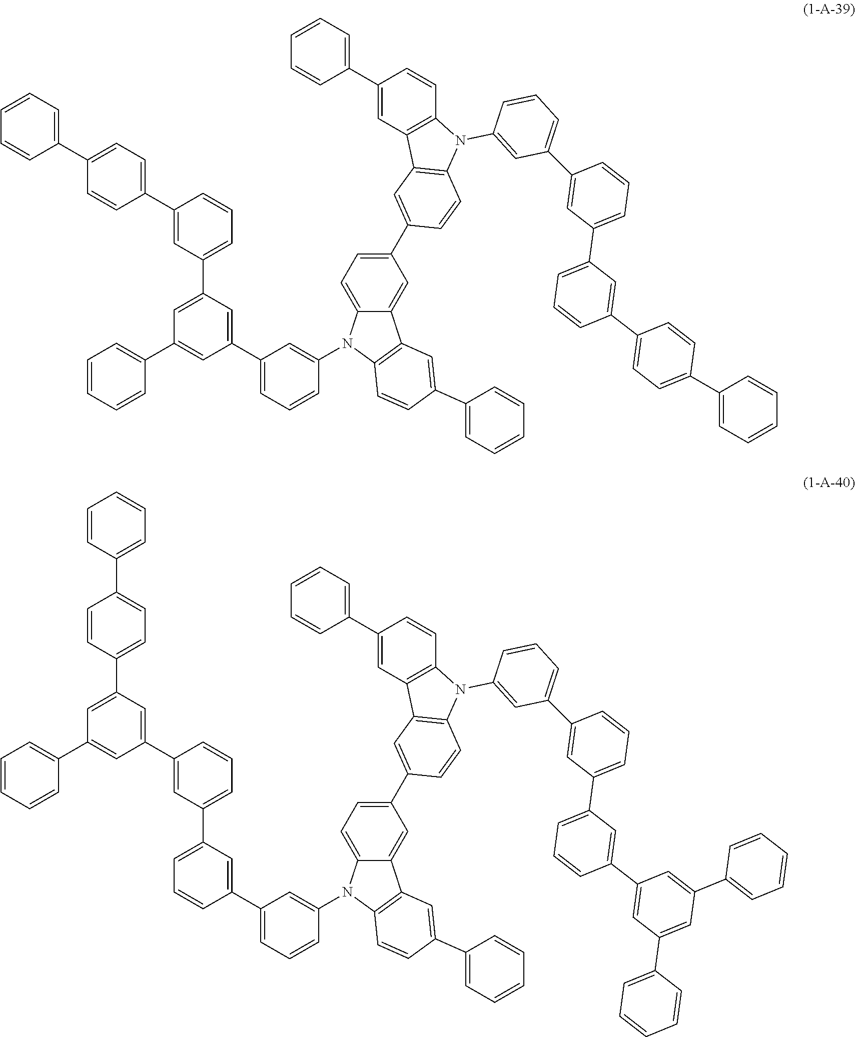 [SMILES: c1ccc(-c2ccc(-c3cccc(-c4cccc(-c5cccc(-n6c7ccc(-c8ccccc8)cc7c7cc(-c8ccc9c(c8)c8cc(-c%10ccccc%10)ccc8n9-c8cccc(-c9cc(-c%10ccccc%10)cc(-c%10cccc(-c%11ccc(-c%12ccccc%12)cc%11)c%10)c9)c8)ccc76)c5)c4)c3)cc2)cc1 ; c1ccc(-c2ccc(-c3cc(-c4ccccc4)cc(-c4cccc(-c5cccc(-c6cccc(-n7c8ccc(-c9ccccc9)cc8c8cc(-c9ccc%10c(c9)c9cc(-c%11ccccc%11)ccc9n%10-c9cccc(-c%10cccc(-c%11cccc(-c%12cc(-c%13ccccc%13)cc(-c%13ccccc%13)c%12)c%11)c%10)c9)ccc87)c6)c5)c4)c3)cc2)cc1]

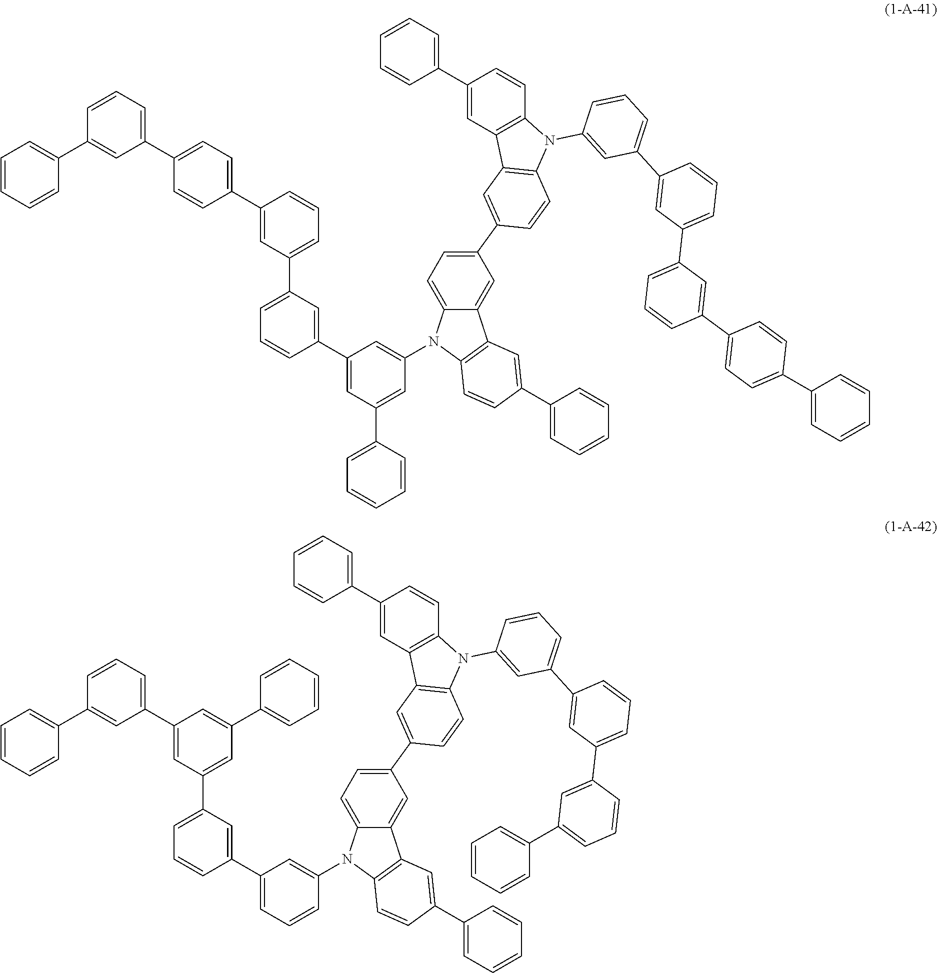 [SMILES: c1ccc(-c2ccc(-c3cccc(-c4cccc(-c5cccc(-n6c7ccc(-c8ccccc8)cc7c7cc(-c8ccc9c(c8)c8cc(-c%10ccccc%10)ccc8n9-c8cc(-c9ccccc9)cc(-c9cccc(-c%10cccc(-c%11ccc(-c%12cccc(-c%13ccccc%13)c%12)cc%11)c%10)c9)c8)ccc76)c5)c4)c3)cc2)cc1 ; c1ccc(-c2cccc(-c3cccc(-c4cccc(-n5c6ccc(-c7ccccc7)cc6c6cc(-c7ccc8c(c7)c7cc(-c9ccccc9)ccc7n8-c7cccc(-c8cccc(-c9cc(-c%10ccccc%10)cc(-c%10cccc(-c%11ccccc%11)c%10)c9)c8)c7)ccc65)c4)c3)c2)cc1]

### (Compound Represented by Formula (2)]

Preferred embodiments of the compound represented by the formula (2) are shown below.

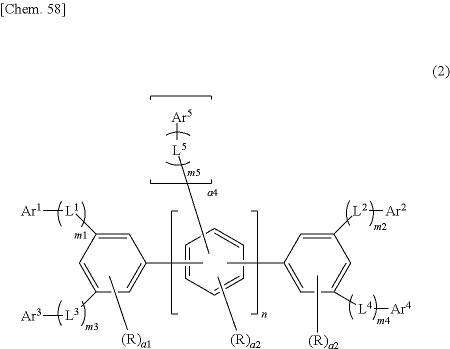

(In the formula (2),
Ar¹ to Ar⁵ each independently represent a hydrogen atom or a monovalent aromatic hydrocarbon group having 6 or more and 60 or less carbon atoms which may have a substituent,
at least one of Ar¹, Ar², and Ar⁵ is represented by the following formula (4) or the following formula (5),
Ar³ and Ar⁴ each independently represent a hydrogen atom or a monovalent aromatic hydrocarbon group having 6 or more and 60 or less carbon atoms which may have a substituent,
L¹ to L⁵ each independently represent a divalent aromatic hydrocarbon group having 6 or more and 60 or less carbon atoms which may have a substituent,
R each independently represents a substituent,
m1, m2, and m5 each independently represent an integer of 0 to 5,
m3 and m4 each independently represent an integer of 1 to 5,
n represents an integer of 0 to 10,
a1 and a2 each independently represent an integer of 0 to 3,
a3 represents an integer of 0 to 4, and
a4 represents an integer of 0 or 1.
Here, when a3 is 4, a4 is 0.

In the formula (2), Ar¹—(L¹)ₘ₁—, Ar²—(L²)ₘ₂—, Ar³—(L³)ₘ₃—, and Ar⁴—(L⁴)ₘ₄— do not become hydrogen atoms).

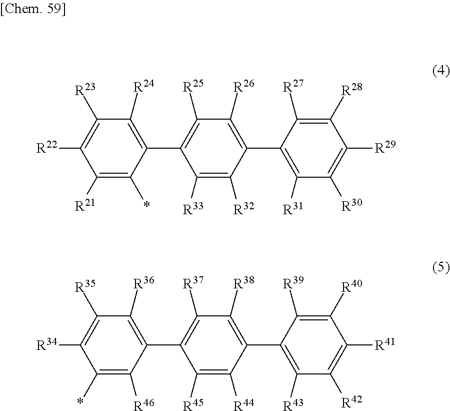

(In the formula (4) or the formula (5)
an asterisk (*) represents a bond to the formula (2), and
R²¹ to R⁴⁶ each independently represent a hydrogen atom or a substituent).
(Ar¹, Ar², and Ar⁵) (Formula (4) and Formula (5))
Ar¹, Ar², and Ar⁵ in the formula (2) each independently represent a hydrogen atom, or a monovalent aromatic hydrocarbon group having 6 or more and 60 or less carbon atoms which may have a substituent. At least one of Ar¹, Ar², and Ar⁵ is represented by the following formula (4) or the following formula (5). From the viewpoint of stability, Ar¹, Ar², and Ar⁵ each independently preferably represented by the formula (5).

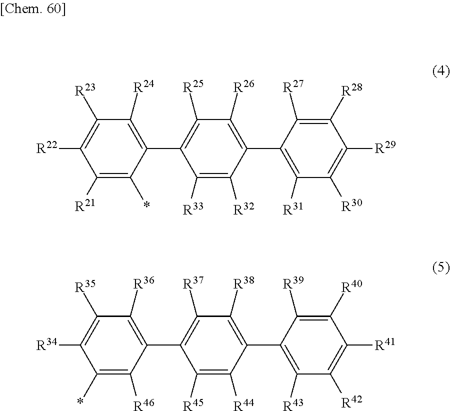

(In the formula (4) or the formula (5),
an asterisk (*) represents a bond to the formula (2), and
R²¹ to R⁴⁶ each independently represent a hydrogen atom or a substituent).

From the viewpoint of solubility and durability of the compound, Ar¹, Ar², and Ar⁵ in the formula (2) are preferably a hydrogen atom, a monovalent group of a benzene ring, a monovalent group of a naphthalene ring, or a structure represented by the formula (4) or the formula (5), more preferably a hydrogen atom, a monovalent group of a benzene ring, or a structure represented by the formula (4) or the formula (5), still more preferably a hydrogen atom, a monovalent group of a benzene ring, or a structure represented by the formula (5), and particularly preferably a structure represented by the formula (5).

From the viewpoint of durability, Ar¹ and Ar², as well as Ar⁵ in a case where n is 1 or more or at least one Ar⁵ in a case where n is 2 or more are preferably the structure represented by the formula (4) or the formula (5), and particularly preferably the structure represented by the formula (5).

(Ar³ and Ar⁴)

Ar³ and Ar⁴ in the formula (2) each independently represent a hydrogen atom, or a monovalent aromatic hydrocarbon group having 6 or more and 60 or less carbon atoms which may have a substituent.

Examples of the monovalent aromatic hydrocarbon group having 6 or more and 60 or less carbon atoms include a monovalent group of a benzene ring, a naphthalene ring, an anthracene ring, a phenanthrene ring, a tetraphenylene ring, a chrysene ring, a pyrene ring, a benzanthracene ring, a perylene ring, a biphenyl ring, or a terphenyl ring.

From the viewpoint of solubility and durability of the compound, Ar³ and Ar⁴ in the formula (2) each independently preferably represent a hydrogen atom, a monovalent group of a benzene ring, or a monovalent group of a naphthalene ring, and more preferably a hydrogen atom or a monovalent group of a benzene ring.

(L¹ to L⁵)

L¹ to L⁵ in the formula (2) each independently represent a divalent aromatic hydrocarbon group having 6 or more and 60 or less carbon atoms which may have a substituent.

Examples of the divalent aromatic hydrocarbon group having 6 or more and 60 or less carbon atoms include a divalent group of a benzene ring, a naphthalene ring, an anthracene ring, a tetraphenylene ring, a phenanthrene ring, a chrysene ring, a pyrene ring, a benzanthracene ring, or a perylene ring.

L¹ to L⁵ each independently preferably represent a phenylene group, or a divalent group in which two or more, for example, 2 to 5 phenylene groups are directly bonded to each other which may have a substituent, and more preferably a 1,3-phenylene group which may have a substituent, from the viewpoint of solubility.

### (R)

R in the formula (2) each independently represents a substituent. As the substituent, those selected from the substituent group Z may be used. Among those, an alkyl group, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, an aralkyl group, or an aromatic hydrocarbon group is preferable. From the viewpoint of heat resistance and durability, an alkyl group, an alkenyl group, an alkoxy group, an aryloxy group, an alkoxycarbonyl group, an acyl group, a halogen atom, a haloalkyl group, a silyl group, a siloxy group, an aralkyl group, or an aromatic hydrocarbon group is preferable, an alkyl group, an alkoxy group, an aralkyl group, or an aromatic hydrocarbon group is more preferable, an alkyl group having 10 or less carbon atoms, an aralkyl group having 30 or less carbon atoms, or an aromatic hydrocarbon group having 30 or less carbon atoms is still more preferable, and a benzene ring or a group in which 2 to 5 benzene rings are linked to each other is particularly preferable.

(m1 to m5)

In the formula (2), m1, m2, and m5 each independently represent an integer of 0 to 5, and

m3 and m4 each independently represent an integer of 1 to 5.

From the viewpoint of solubility and durability of the compound, m1, m2, and m5 in the formula (2) are preferably 4 or less, more preferably 3 or less, still more preferably 2 or less, particularly preferably 1 or less, and most preferably 0.

From the viewpoint of solubility and durability of the compound, m3 and m4 in the formula (2) are preferably 1 or more, and preferably 4 or less, more preferably 3 or less, particularly preferably 2 or less.

In a case where m1 in the formula (2) is 2 or more, a plurality of L¹ may be the same as or different from each other. In a case where m2 in the formula (2) is 2 or more, a plurality of L² may be the same as or different from each other. In a case where m3 in the formula (2) is 2 or more, a plurality of L³ may be the same as or different from each other. In a case where m4 in the formula (2) is 2 or more, a plurality of L⁴ may be the same as or different from each other. In a case where m5 in the formula (2) is 2 or more, a plurality of L⁵ may be the same as or different from each other.

(Ar¹—(L¹)ₘ₁—,Ar²—(L²)ₘ₂—, and Ar⁵—(L⁵)ₘ₅—)

From the viewpoint of durability of the compound, among Ar¹—(L¹)ₘ₁—, Ar²—(L²)ₘ₂—, and Ar⁵—(L⁵)ₘ₅-in the formula (2), it is preferable that at least one thereof is a structure represented by the formula (4) or the formula (5), more preferable that at least one thereof is a structure represented by the formula (5), still more preferable that at least two thereof are structures represented by the formula (5), and most preferable all three thereof are structures represented by the formula (5).

Here, Ar¹—(L¹)ₘ₁—, Ar²—(L²)ₘ₂—, Ar³—(L³)ₘ₃—, and Ar⁴—(L⁴)ₘ₄— do not become hydrogen atoms.

((L³)ₘ₃ and (L⁴)ₘ₄)

From the viewpoint of solubility and durability of the compound, at least one of (L³)ₘ₃ and (L⁴)ₘ₄ in the formula (2) preferably has at least one substructure selected from a substructure represented by the following formula (11), a substructure represented by the following formula (12), and a substructure represented by the following formula (15).

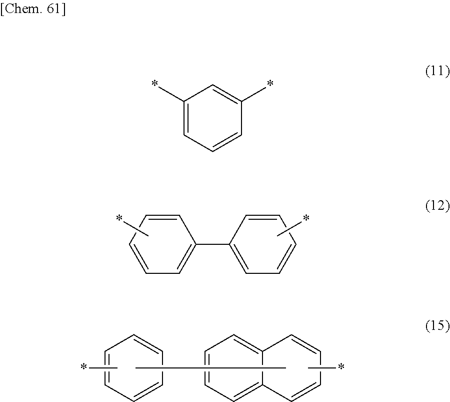

In each of the formulae (11), (12), and (15), * represents a bond to an adjacent structure or a hydrogen atom, and at least one of two present *s represents a bonding site to the adjacent structure. In the following description, the definition of * is the same unless otherwise specified.

More preferably, at least one of (L³)ₘ₃ and (L⁴)ₘ₄ in the formula (2) has at least the substructure represented by the formula (11) or the substructure represented by the formula (12).

Still more preferably, each of (L³)ₘ₃ and (L⁴)ₘ₄ in the formula (2) has at least the substructure represented by the formula (11) or the substructure represented by the formula (12).

Particularly preferably, each of (L³)ₘ₃ and (L⁴)ₘ₄ in the formula (2) has the substructure represented by the formula (11) and the substructure represented by the formula (12).

In the formula (2), the formula (12) is preferably the following formula (12-2).

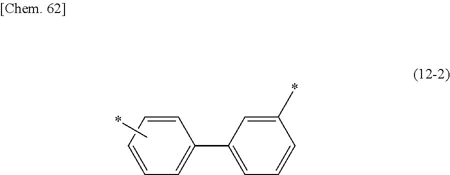

In the formula (2), the formula (12) is still more preferably the following formula (12-3).

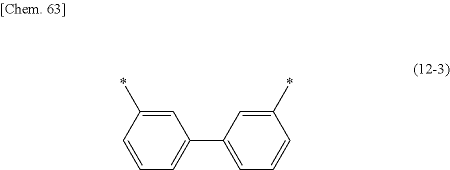 [SMILES: *c1cccc(-c2cccc(*)c2)c1]

From the viewpoint of solubility and durability of the compound, preferred examples of a substructure, which at least one of (L³)ₘ₃ and (L⁴)ₘ₄ in the formula (2) has, include a substructure having the substructure represented by the formula (11) and the substructure represented by the formula (12).

In the formula (2), the substructure having the substructure represented by the formula (11) and the substructure represented by the formula (12) is more preferably a substructure represented by at least one selected from the following formulae (17) to (19), (21), and (22), which is a structure including a plurality of structures selected from the substructure represented by the formula (11) and the substructure represented by the formula (12).

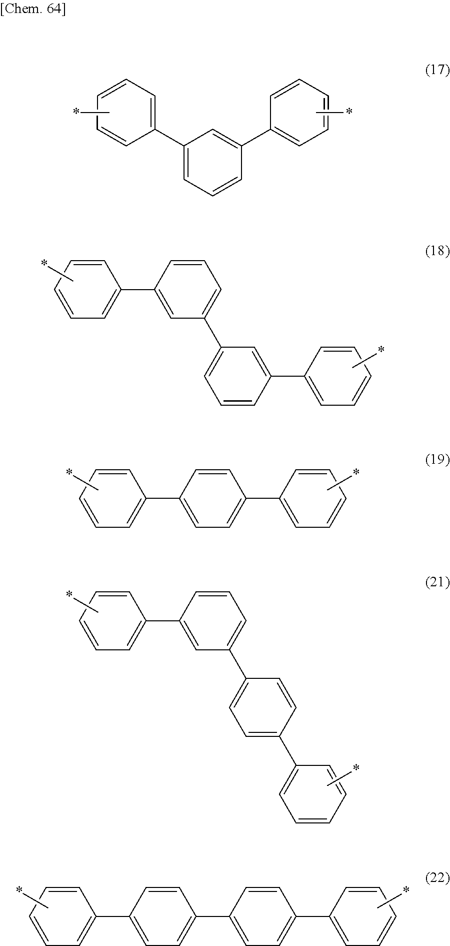

In the formula (2), the structure including a plurality of structures selected from the substructure represented by the formula (11) and the substructure represented by the formula (12) is, for example, a substructure in which the formula (17) can be regarded as having one substructure represented by the formula (11) and two substructures represented by the formula (12) as in the following formula (17a).

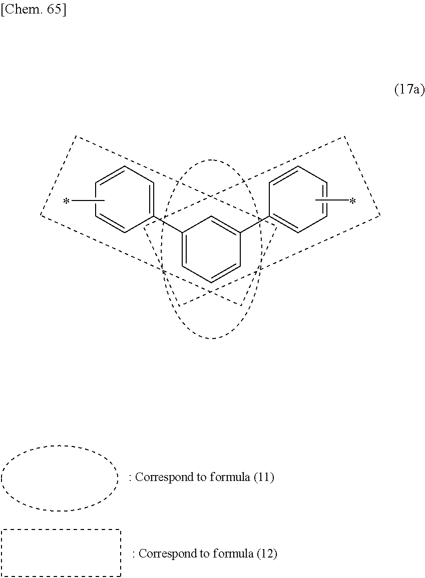

Still more preferably, at least one of (L³)ₘ₃ and (L⁴)ₘ₄ in the formula (2) has the substructure represented by the formula (17) or the substructure represented by the formula (18).

In the formula (2), the formula (17) is preferably the following formula (17-2).

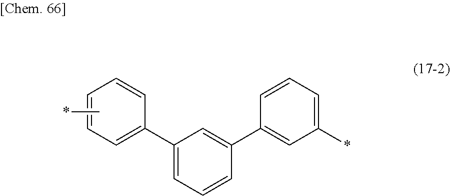

In the formula (2), the formula (17) is still more preferably the following formula (17-3).

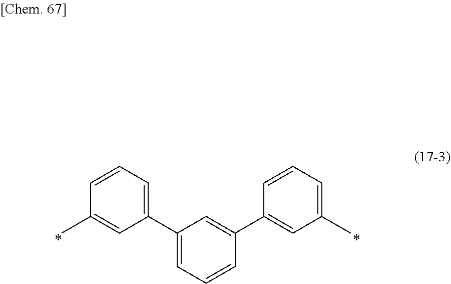

In the formula (2), the formula (18) is preferably the following formula (18-2).

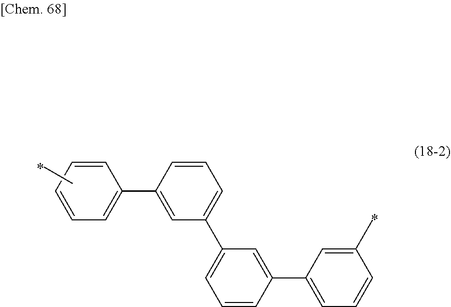

In the formula (2), the formula (18) is still more preferably the following formula (18-3).

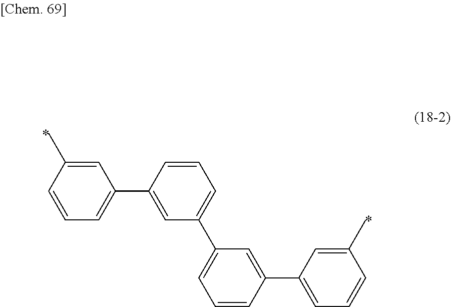 [SMILES: Cc1cccc(-c2cccc(-c3cccc(-c4cccc(C)c4)c3)c2)c1]

In the formula (2), the formula (21) is preferably the following formula (21-2).

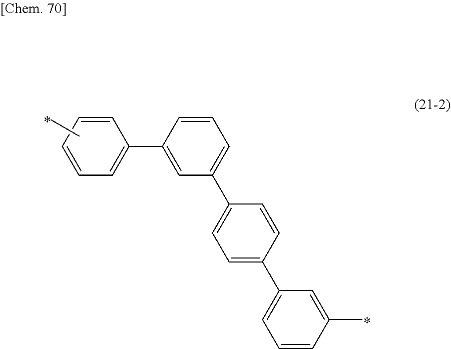

In the formula (2), the formula (22) is preferably the following formula (22-2).

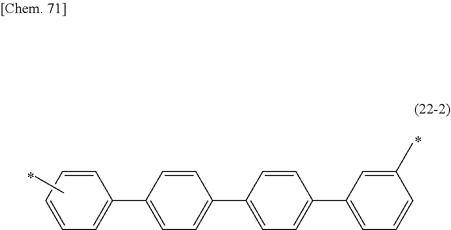

At least one of (L³)ₘ₃ and (L⁴)ₘ₄ in the formula (2) more preferably has a substructure represented by the following formula (15-2) or a substructure represented by the following formula (15-3) as a substructure having the substructure represented by the formula (15).

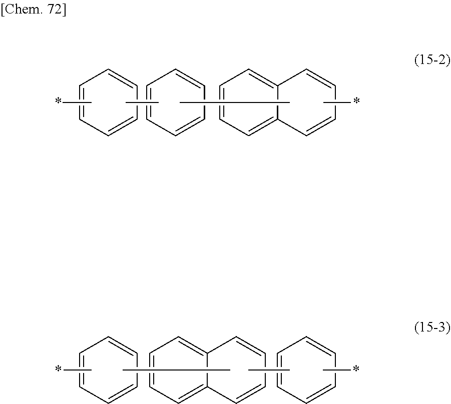

In each of the formulae (14) to (20), * represents a bond to an adjacent structure or a hydrogen atom, and at least one of two present *s represents a bonding site to the adjacent structure.

In the formula (2), among the formulae (14) to (20), the formula (14-3) and the formula (15-3) are preferable, and the formula (14-3) is more preferable.

(Preferred Substructure of L¹ to L⁵)

In the formula (2), L¹ to L⁵ preferably have the substructure represented by the formula (12-3), the substructure represented by the formula (14-3), or the substructure represented by the formula (15-3).

(n)

In the formula (2), n represents an integer of 0 to 10.

From the viewpoint of solubility and durability of the compound, n in the formula (2) is preferably 1 or more, more preferably 2 or more, and is preferably 6 or less, more preferably 5 or less, particularly preferably 4 or less.

(a1 to a4)
a1 and a2 each independently represent an integer of 0 to 3,
a3 represents an integer of 0 to 4, and
a4 represents an integer of 0 or 1.

Here, when a3 is 4, a4 is 0.

From the viewpoint of solubility and durability of the compound, a1 to a4 in the formula (2)
preferably satisfy a1=a2=a4=0 and a3=an integer of 0 to 4,
a4=1 and a1 to a3 each independently an integer of 0 to 3, or
a1 to a4 each independently 0 or 1,
further preferably satisfy a1=a2=a3=a4=0,
a1=a2=a4=0 and a3=1,
a1 to a3 each independently 0 or 1 and a4=1, or
a1=a2=a3=0 and a4=1, and
most preferably satisfy a1=a2=a3=a4=0, or
a1=a2=a3=0 and a4=1,
that is, a1=a2=a3=0.
   (R²¹ to R⁴⁶)

In the formula (2), R²¹ to R⁴⁶ each independently represent a hydrogen atom or a substituent. As the substituent, those selected from the substituent group Z may be used. Among those, an alkyl group, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, an aralkyl group, or an aromatic hydrocarbon group is preferable. From the viewpoint of durability, an alkyl group, an alkenyl group, an alkoxy group, an aryloxy group, an alkoxycarbonyl group, an acyl group, a halogen atom, a haloalkyl group, a silyl group, a siloxy group, an aralkyl group, or an aromatic hydrocarbon group is preferable, a hydrogen atom or an aromatic hydrocarbon group is more preferable, and a hydrogen atom is particularly preferable.

### (Substituent)

In the formula (2), the substituents which a monovalent aromatic hydrocarbon group having 6 or more and 60 or less carbon atoms in Ar¹ to Ar⁵ and a divalent aromatic hydrocarbon group having 6 or more and 60 or less carbon atoms in L¹ to L⁵ may have may each independently be selected from the substituent group Z. Among those, an alkyl group, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, an aralkyl group, or an aromatic hydrocarbon group is preferable, an alkyl group, an alkenyl group, an alkoxy group, an aryloxy group, an alkoxycarbonyl group, an acyl group, a halogen atom, a haloalkyl group, a silyl group, a siloxy group, an aralkyl group, or an aromatic hydrocarbon group is more preferable.

### (Molecular Weight)

A molecular weight of the compound represented by the formula (2) is preferably 1,000 or more, more preferably 1,100 or more, particularly preferably 1,200 or more, most preferably 1,300 or more, and is preferably 5,000 or less, more preferably 4,000 or less, particularly preferably 3,000 or less, most preferably 2,000 or less.

### Specific Example

Specific examples of the compound represented by the formula (2) are shown below, but the present invention is not limited thereto.

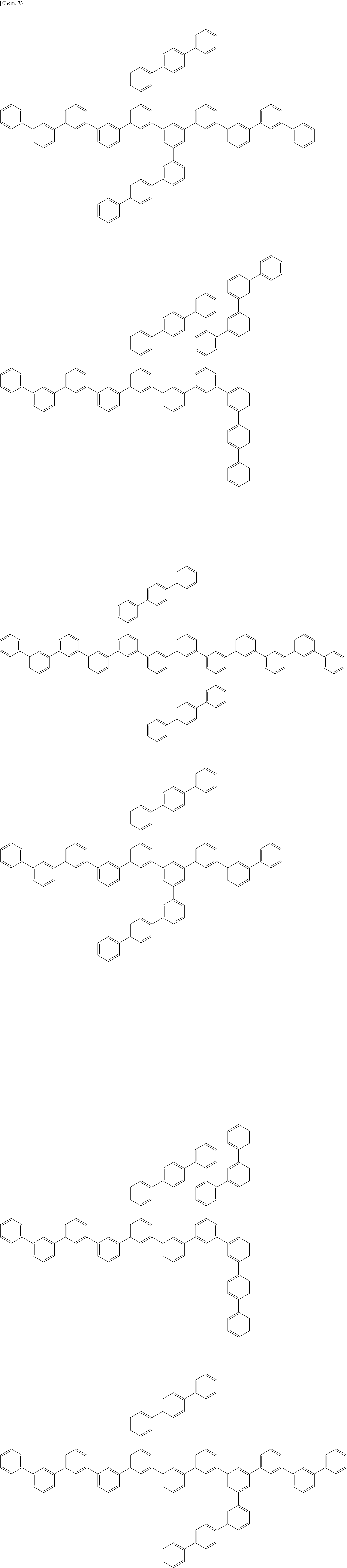

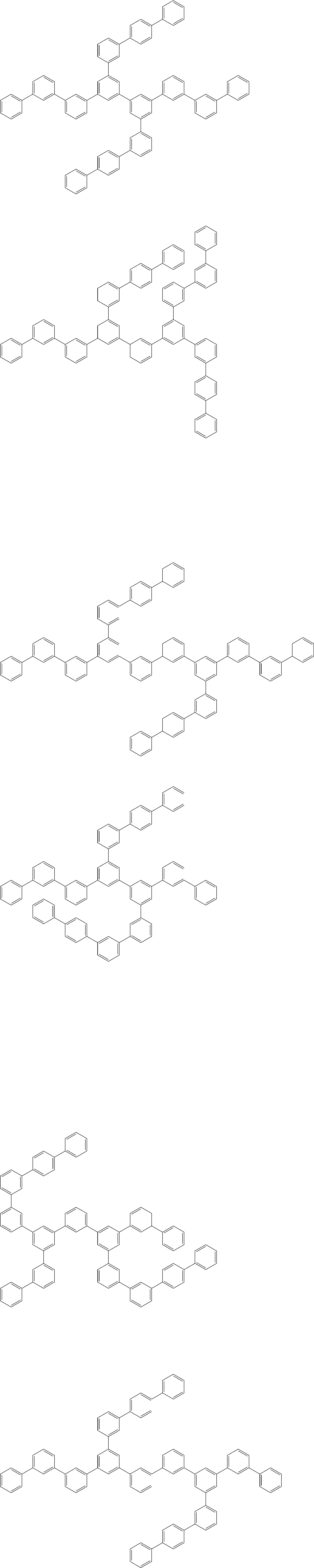

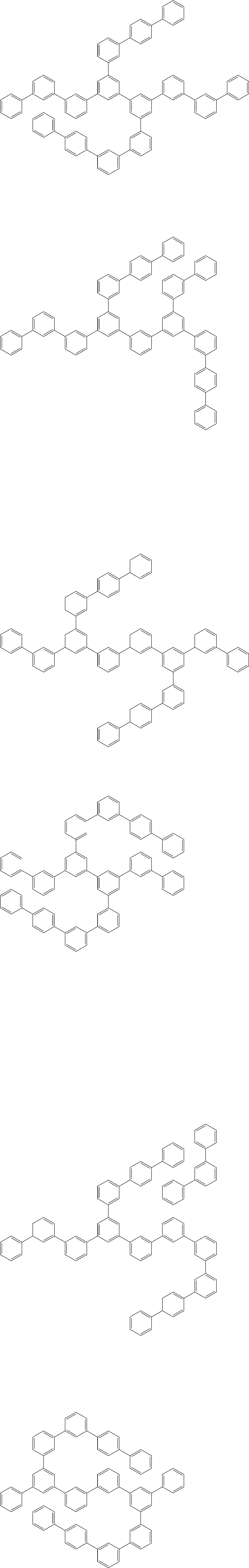

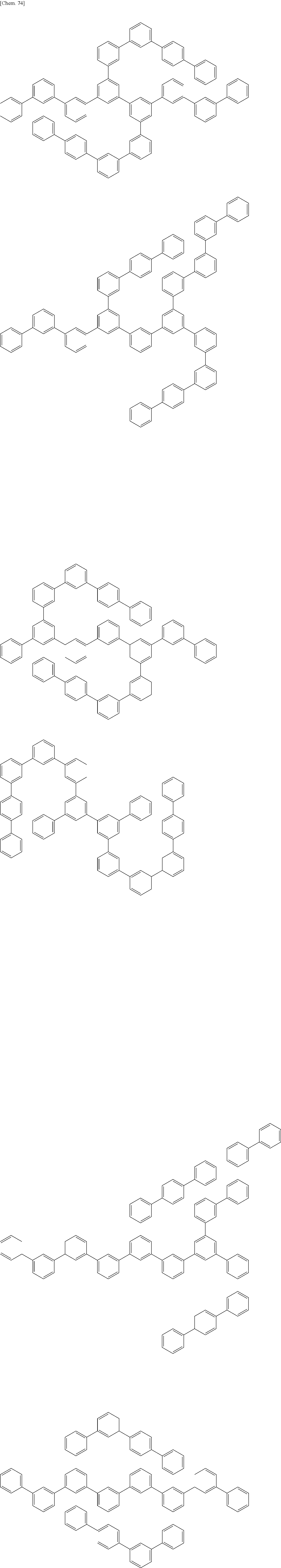

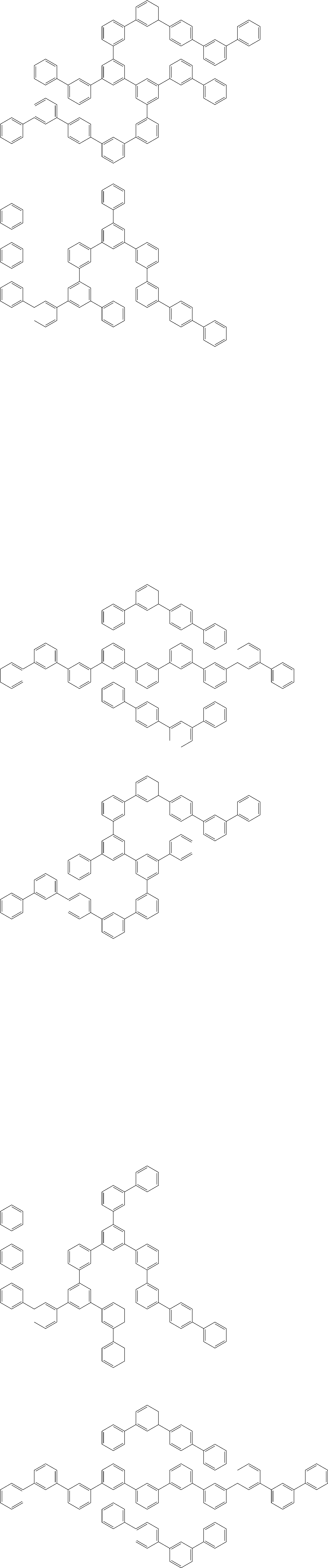

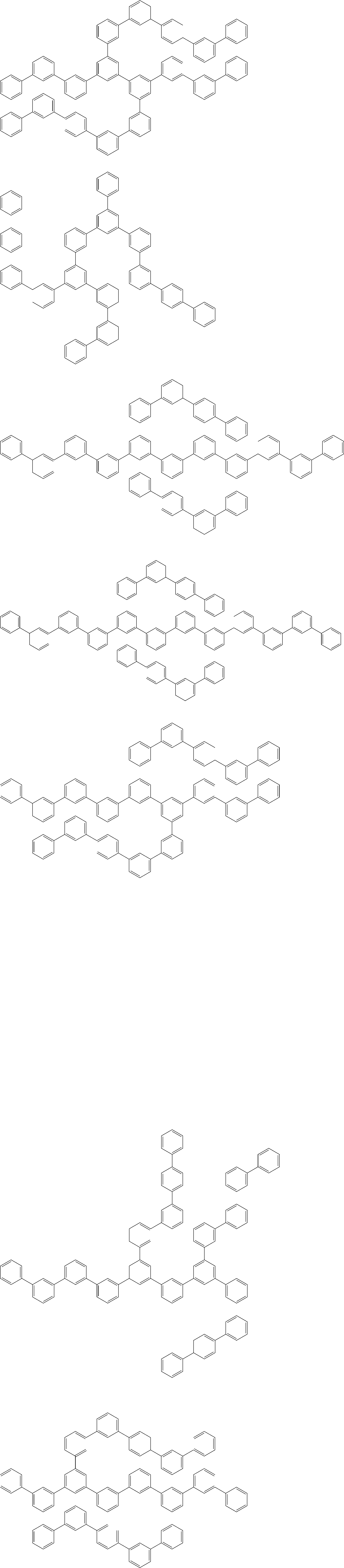

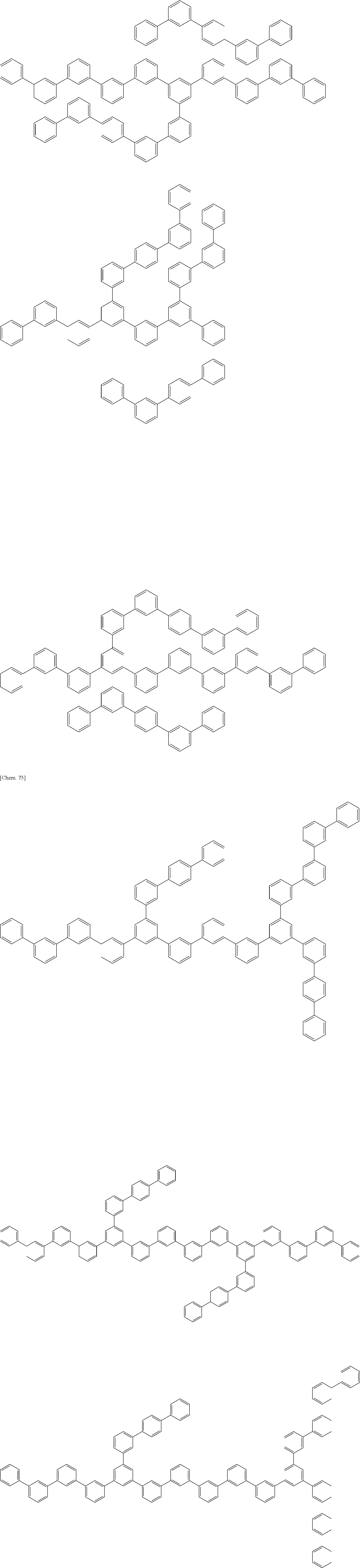

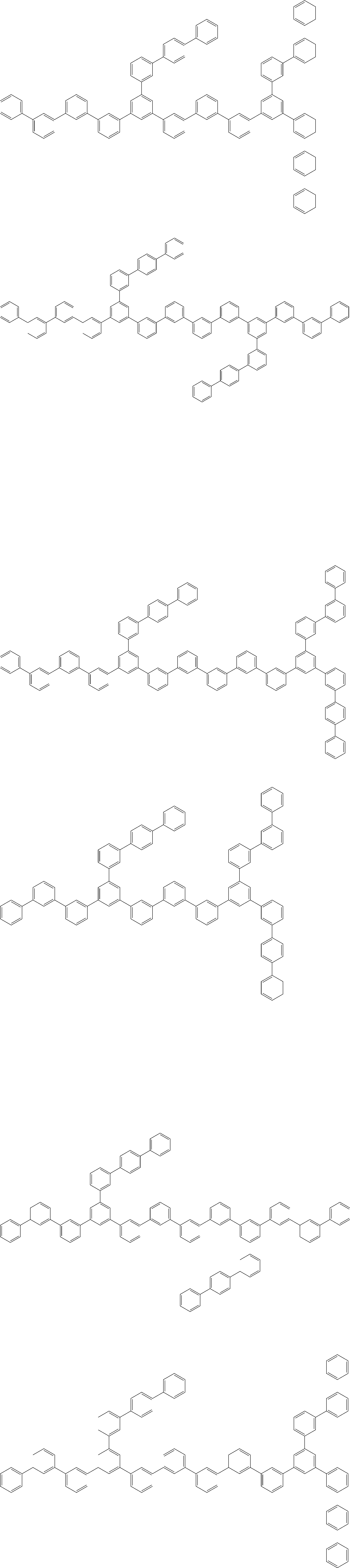

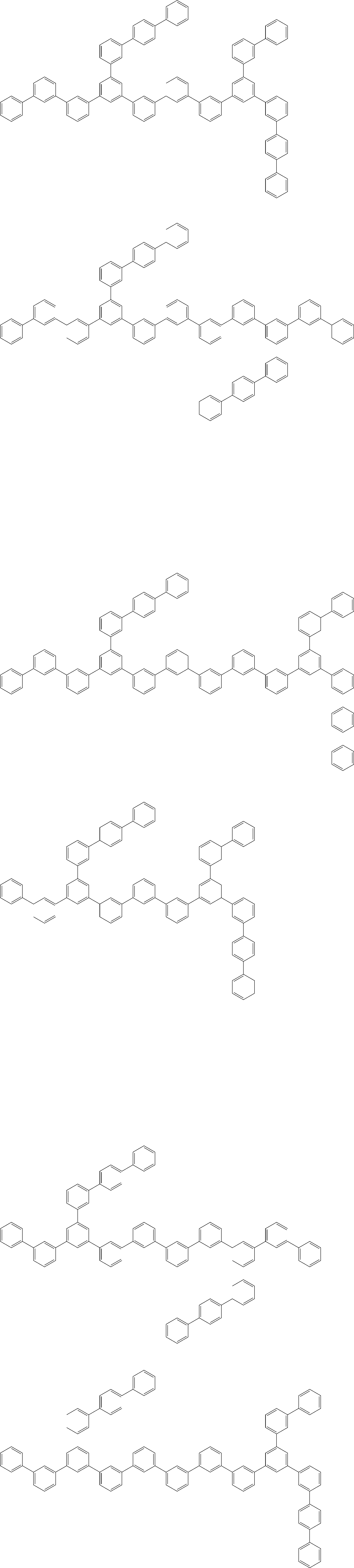

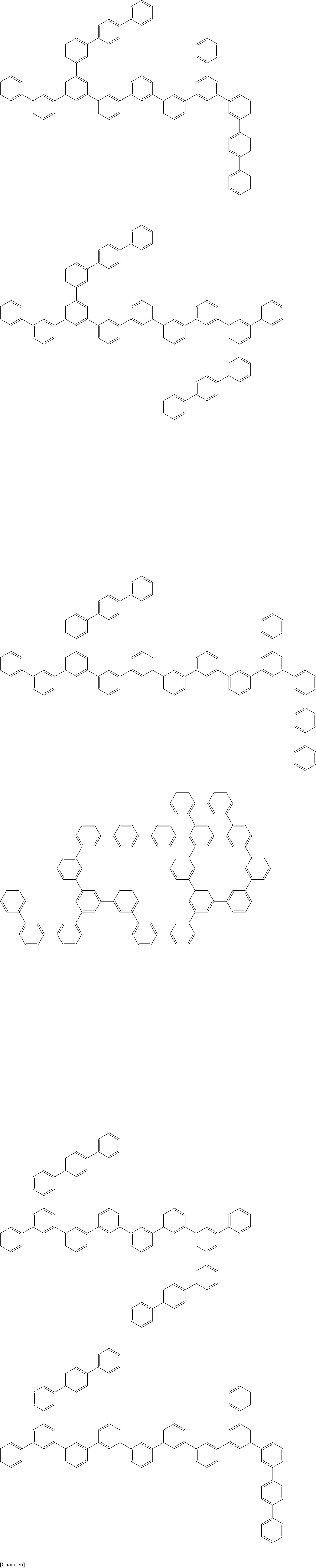

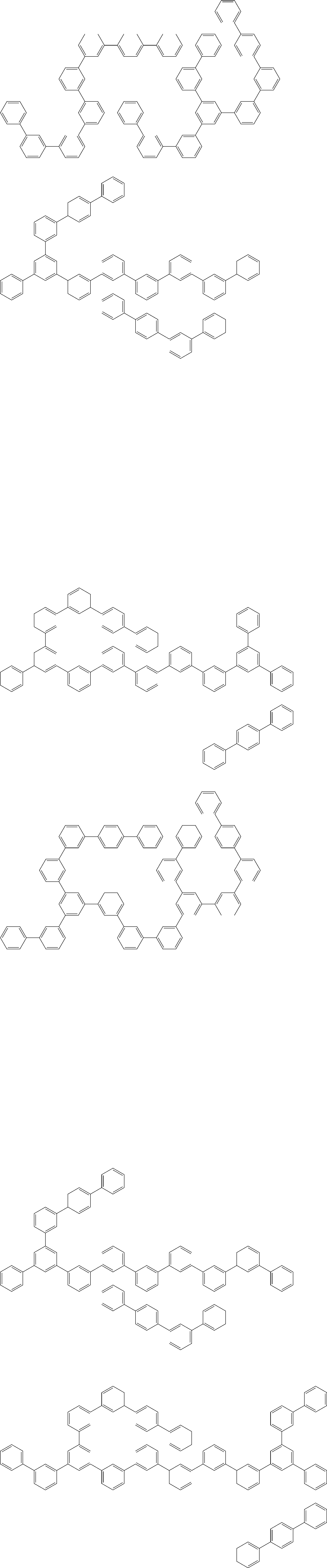

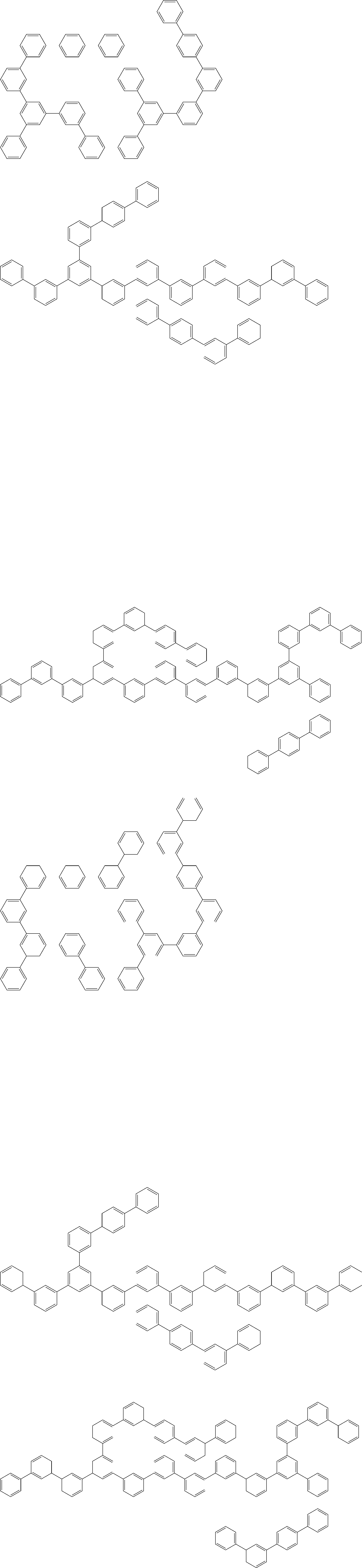

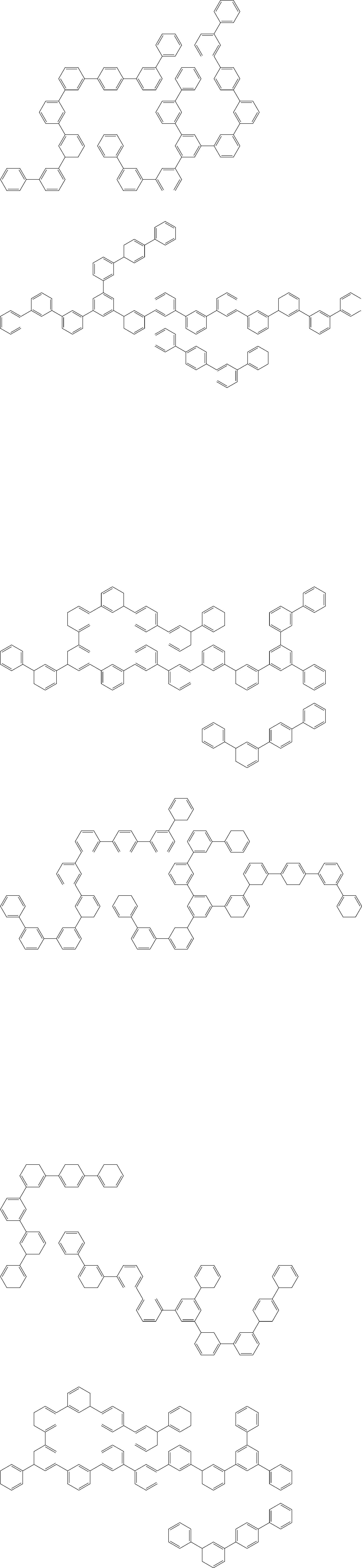

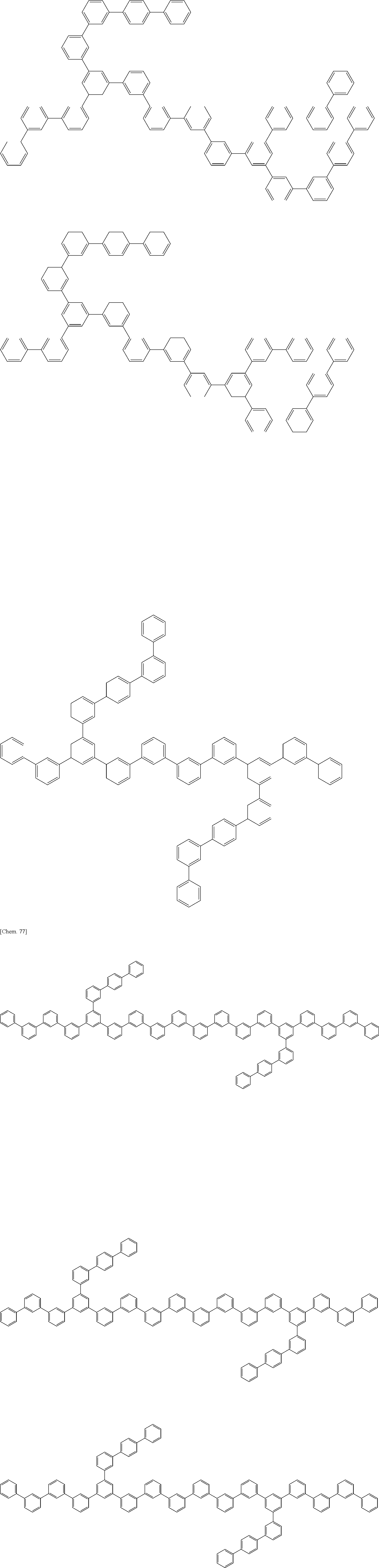

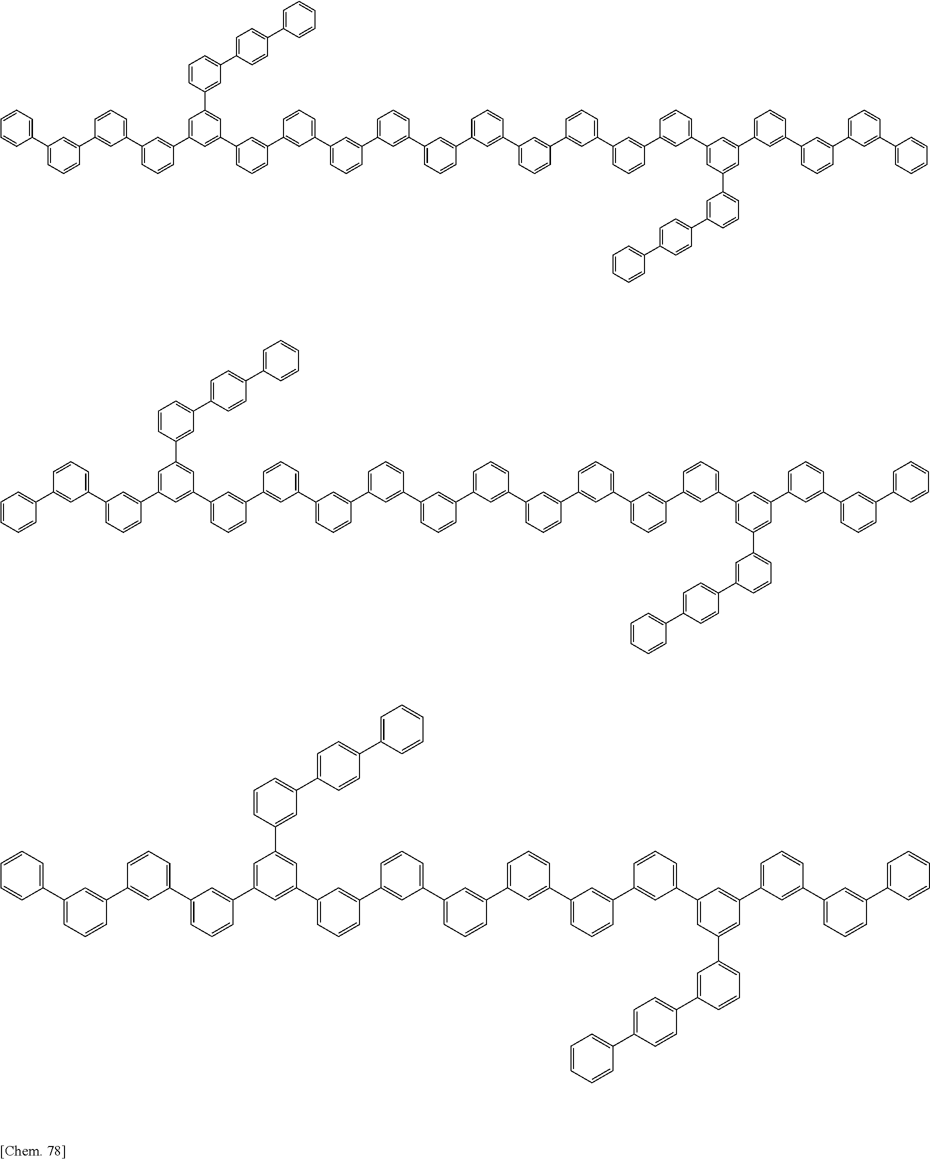

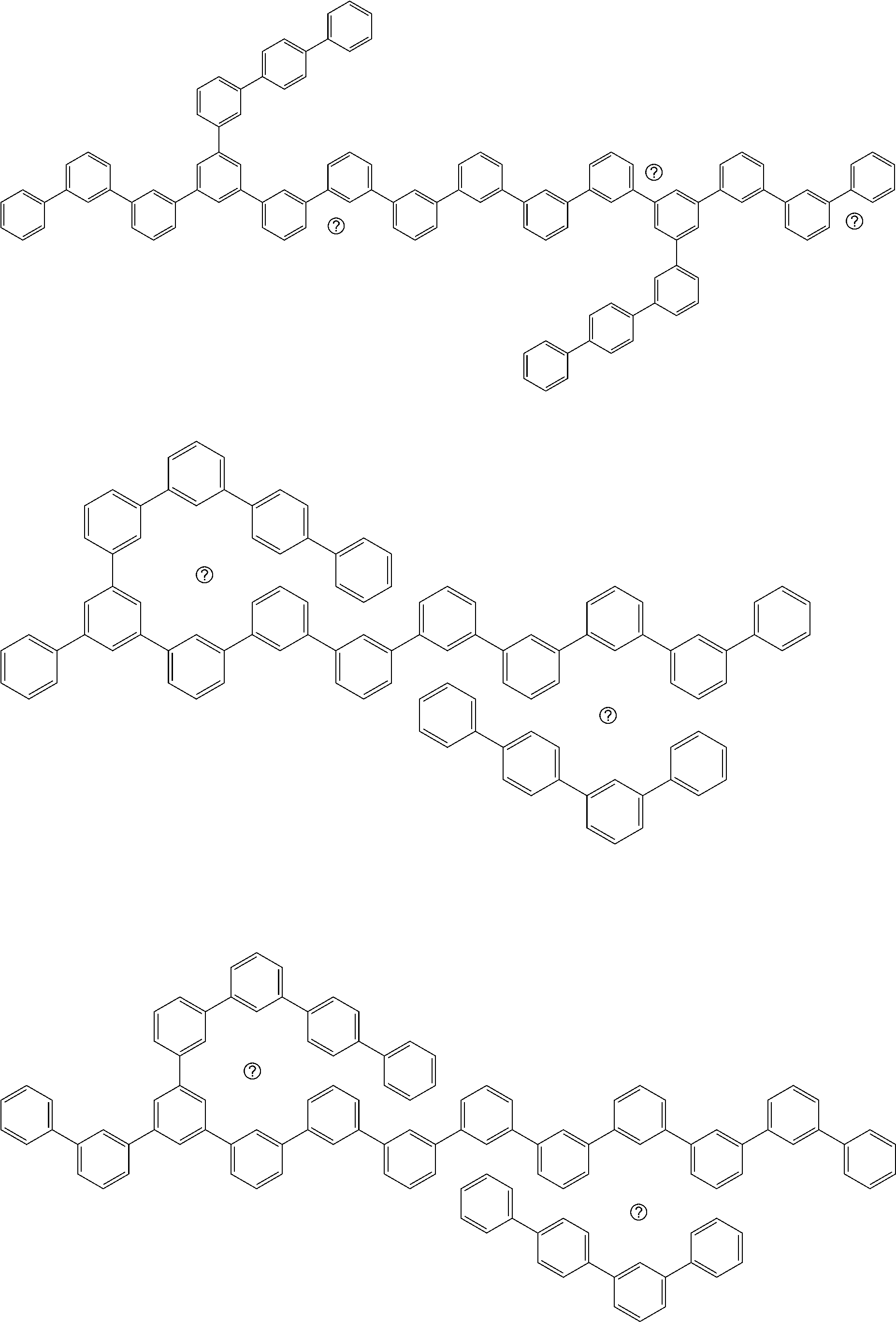

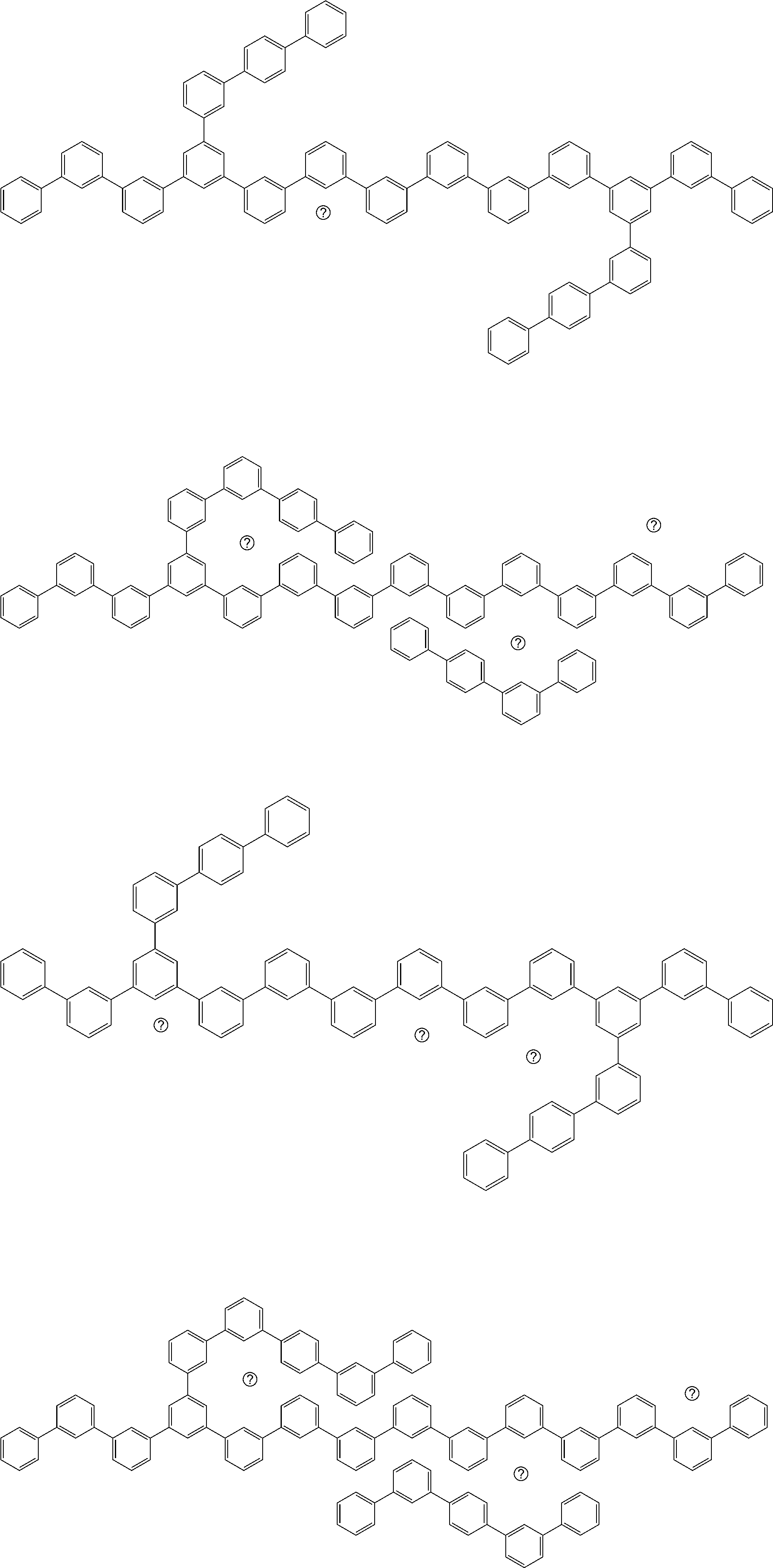

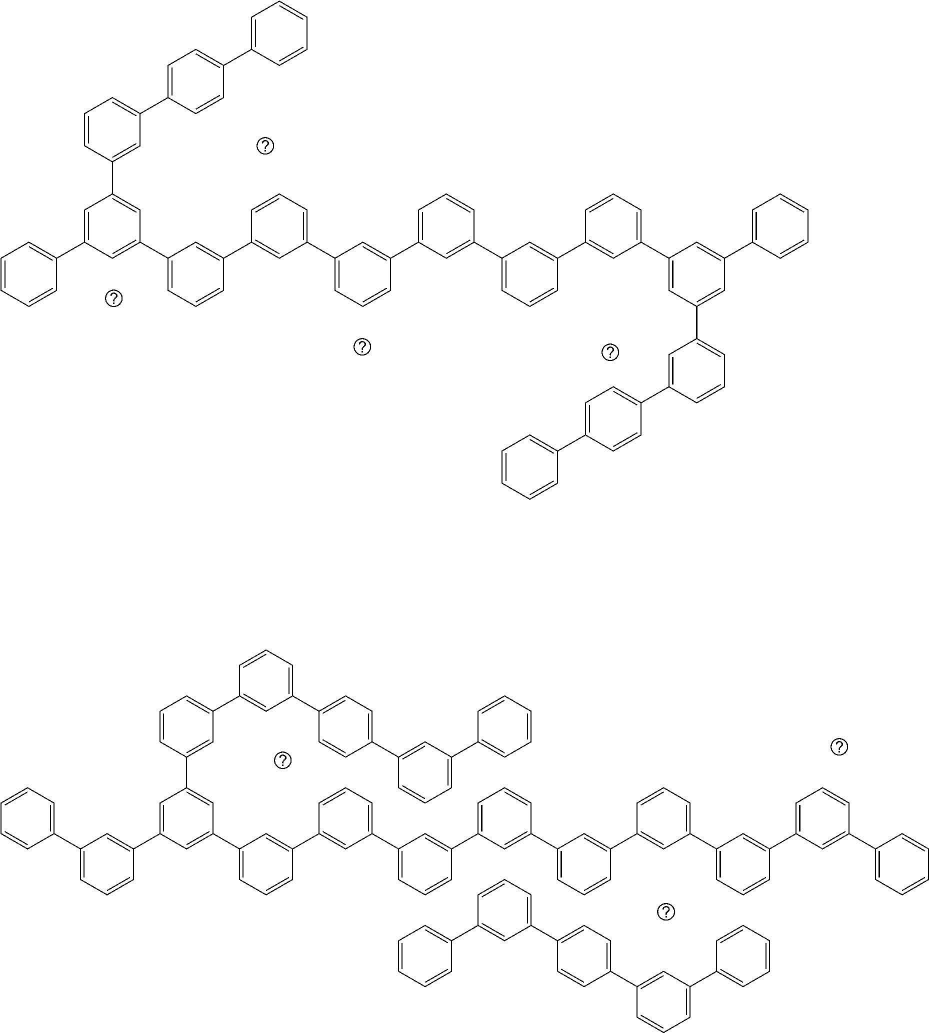

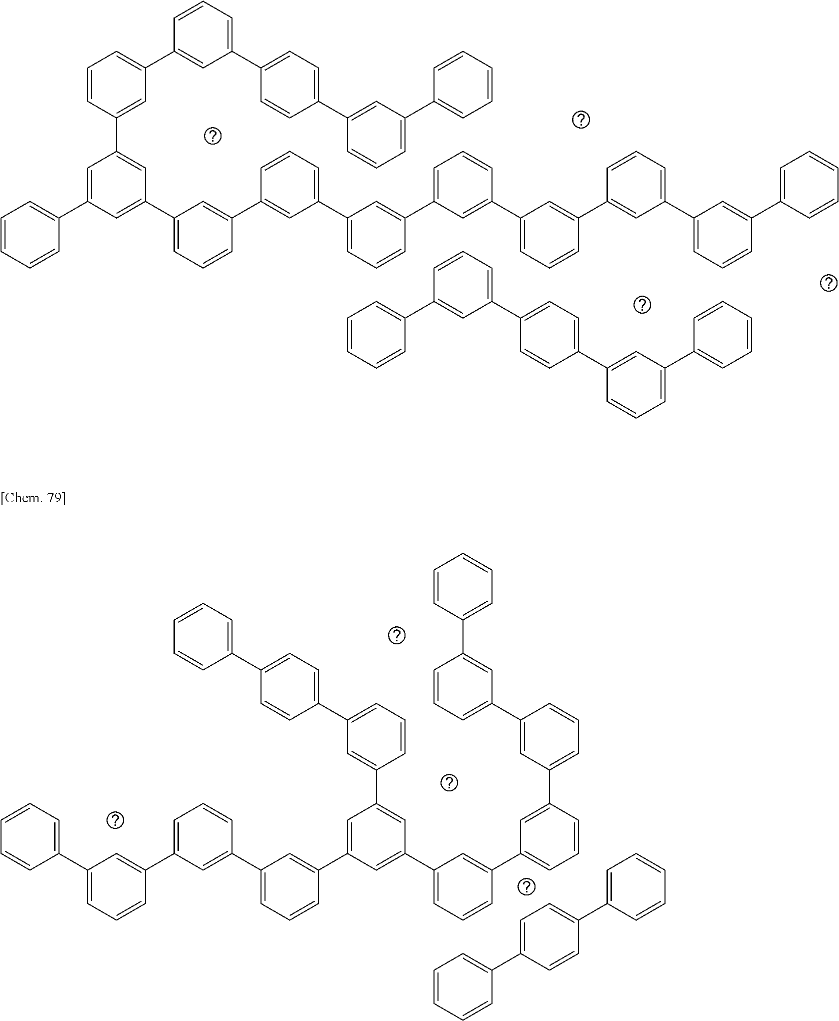

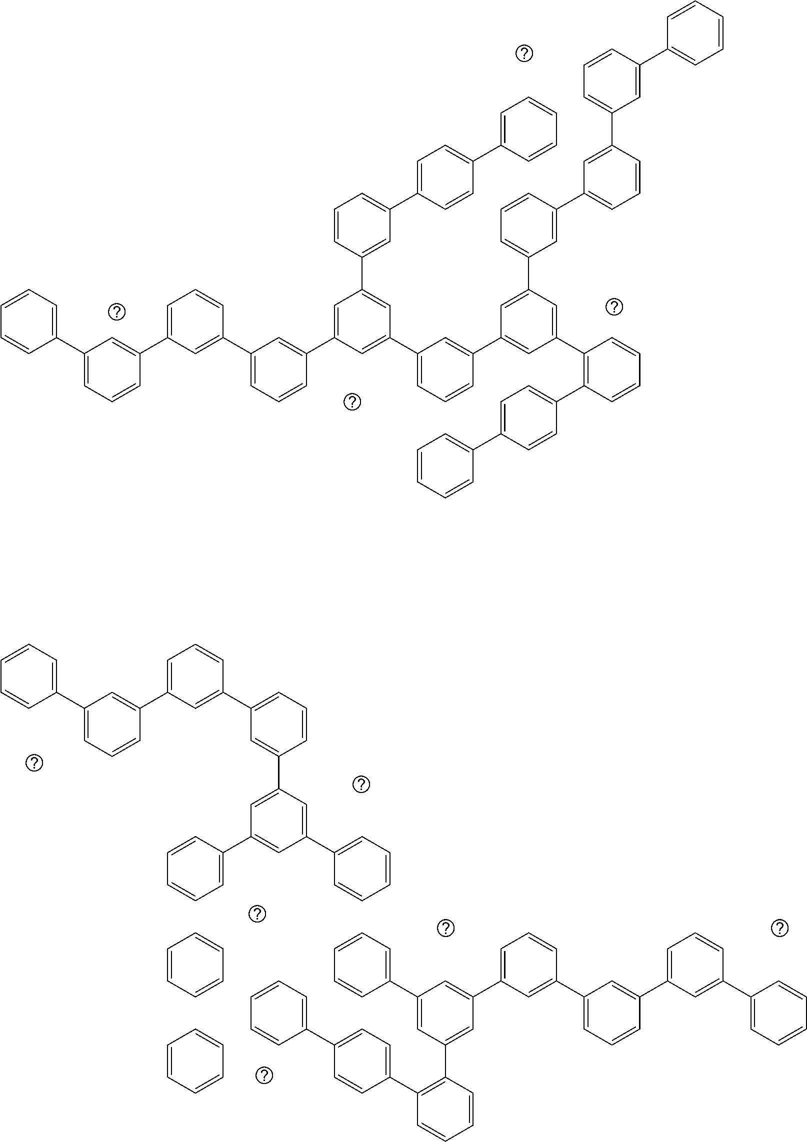

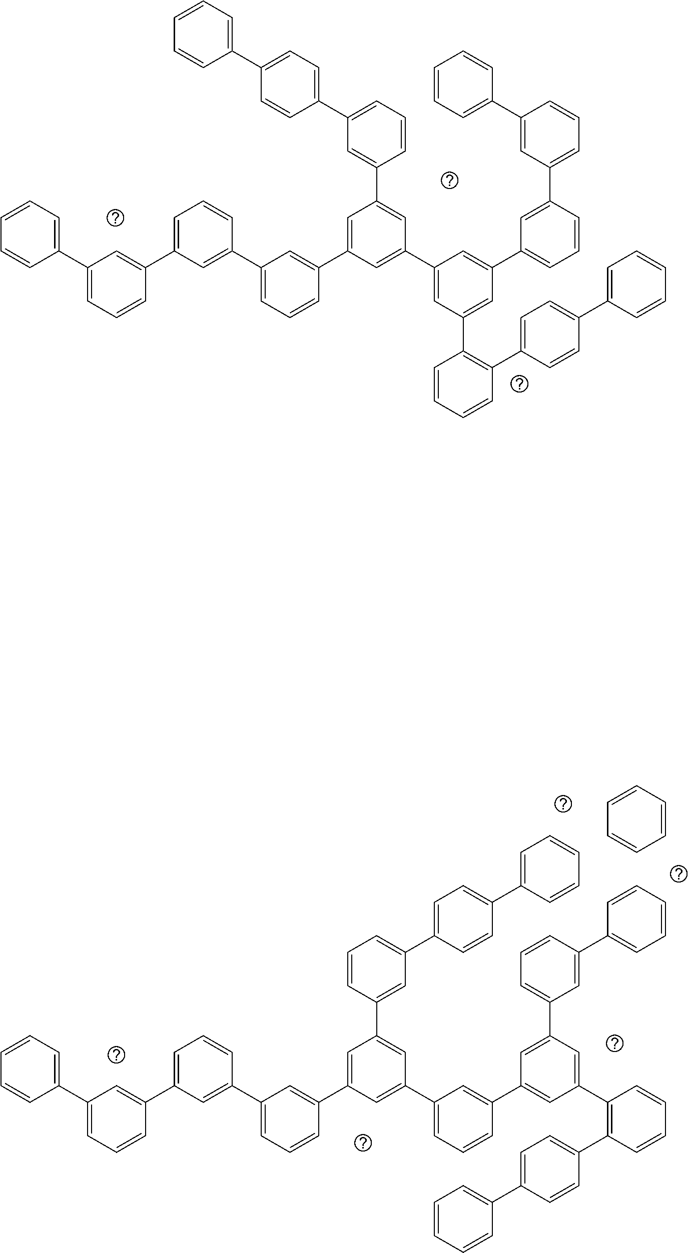

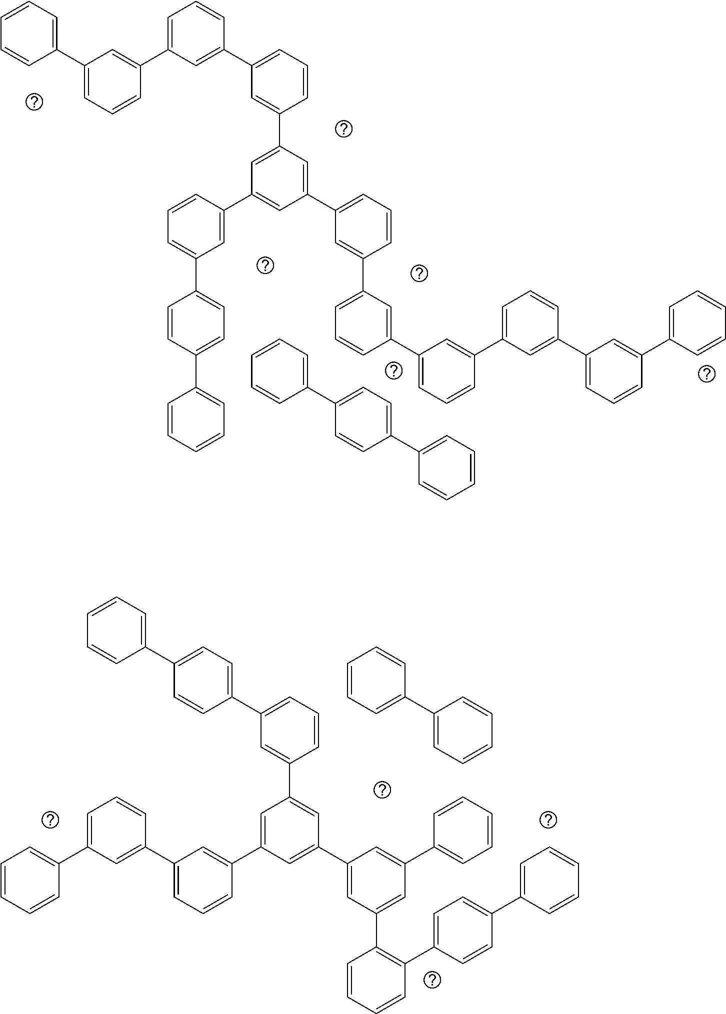

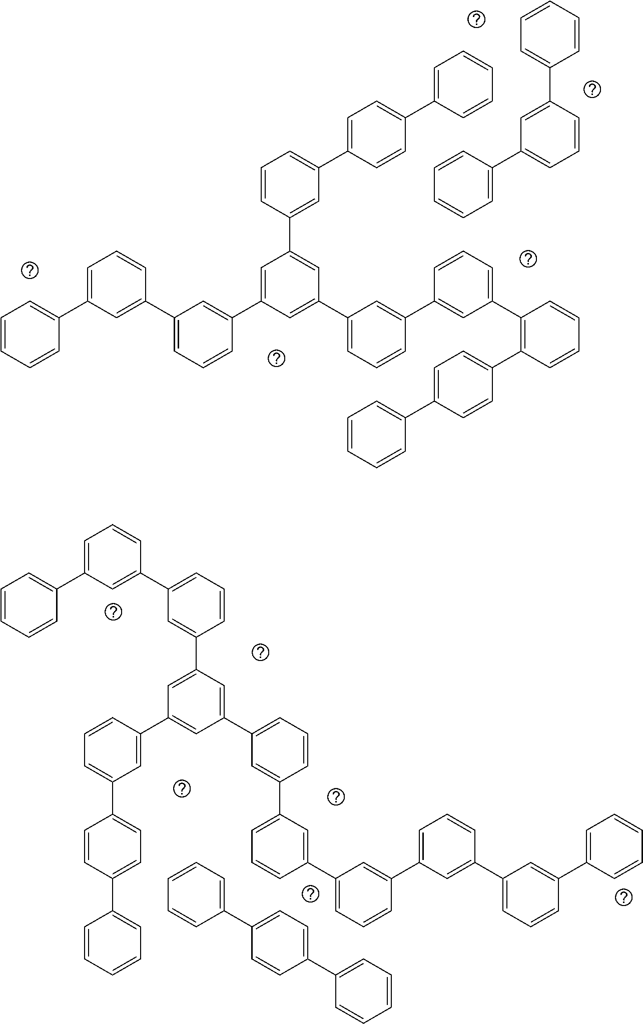

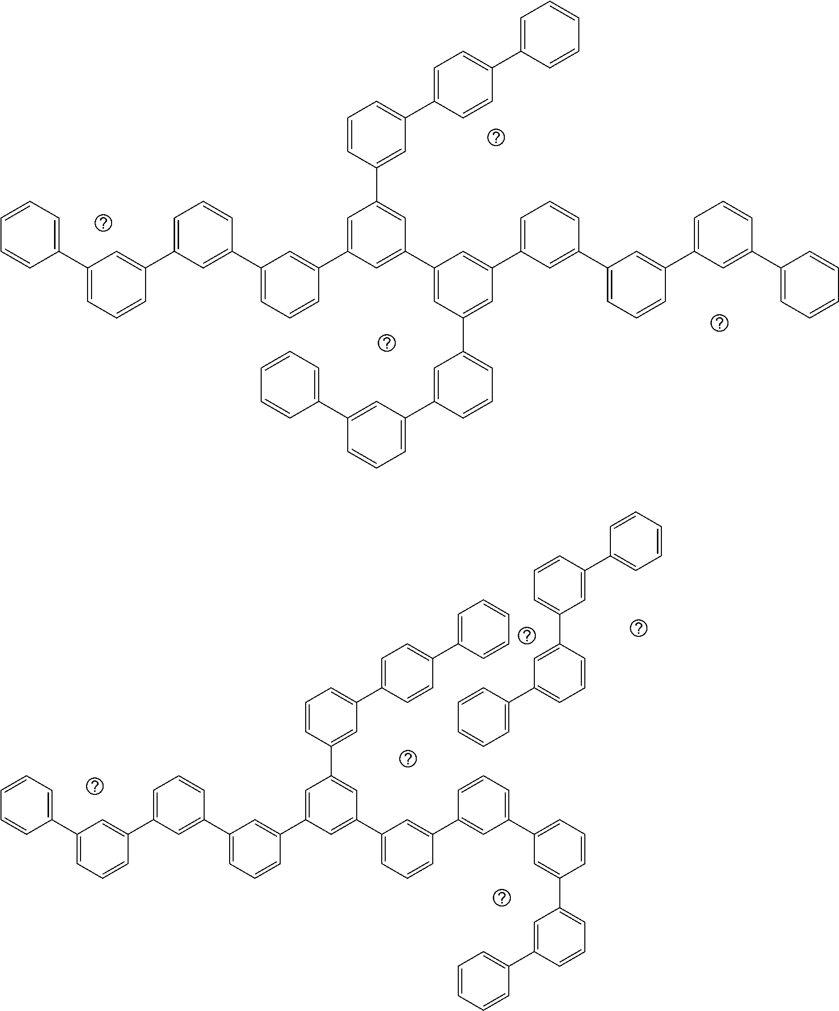

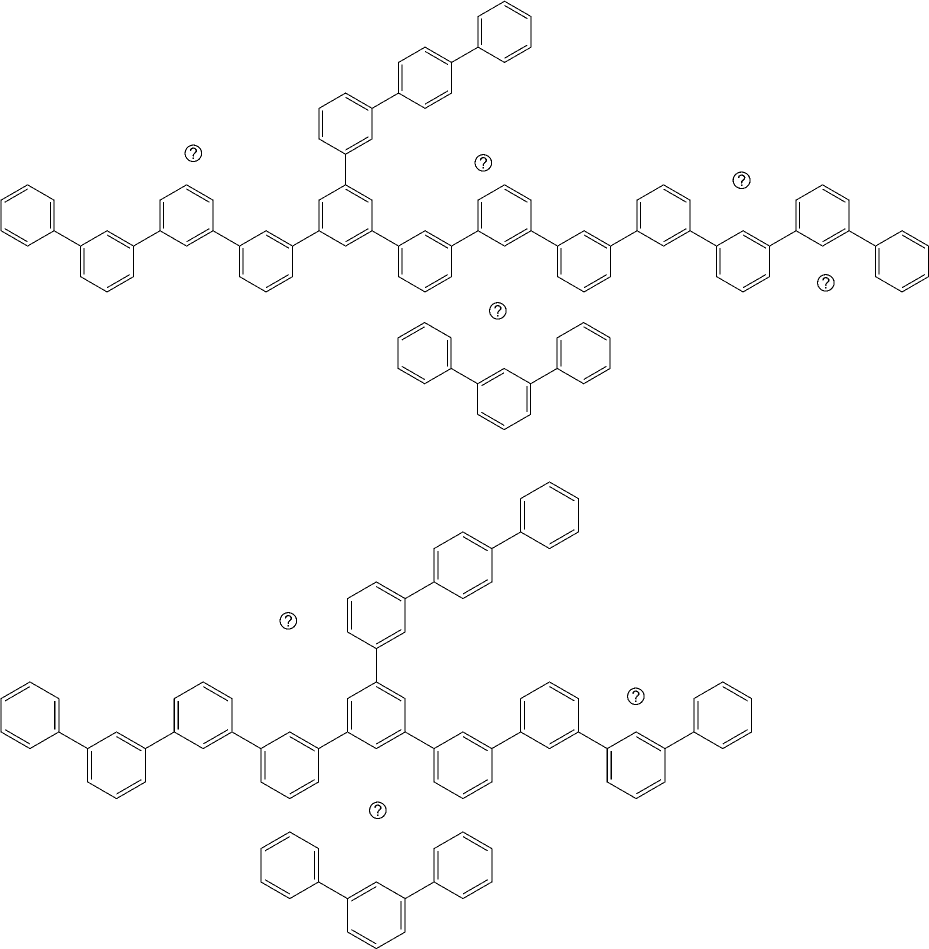

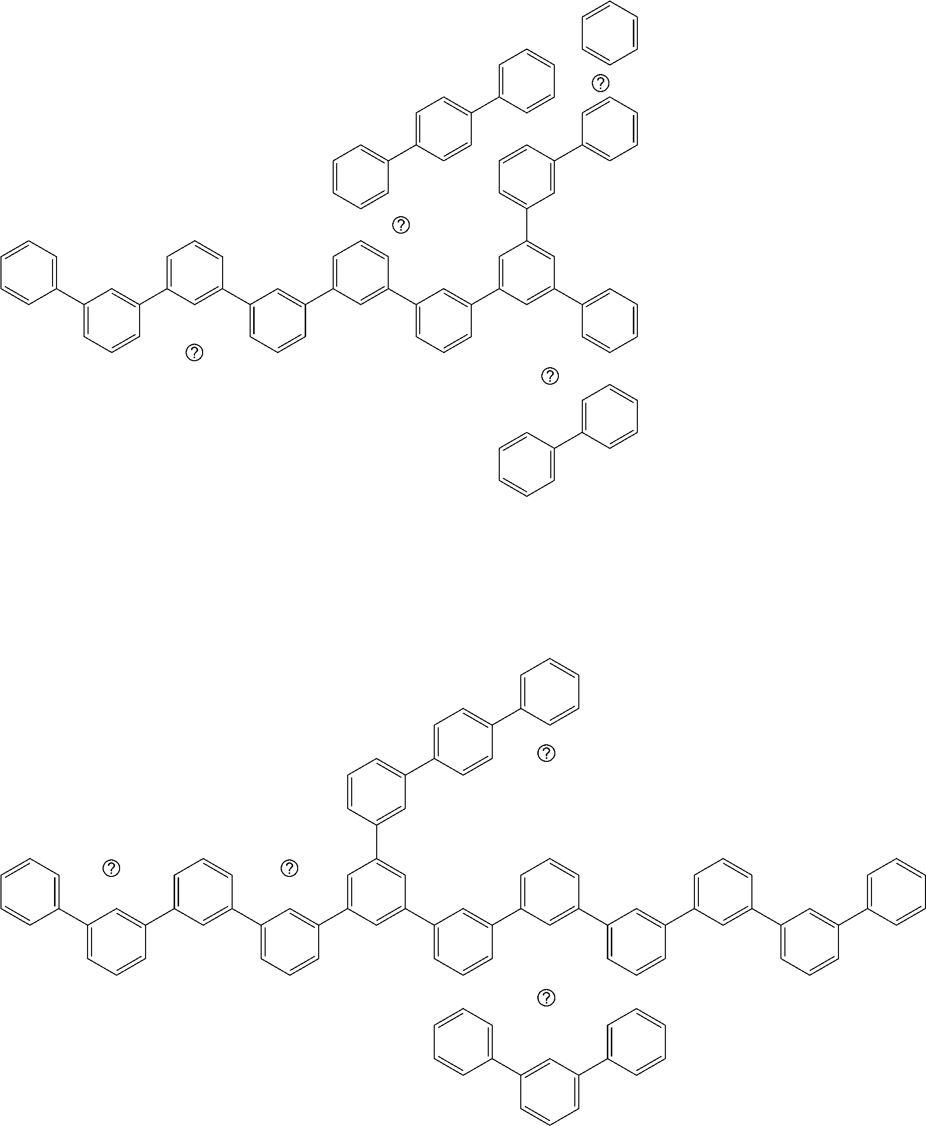

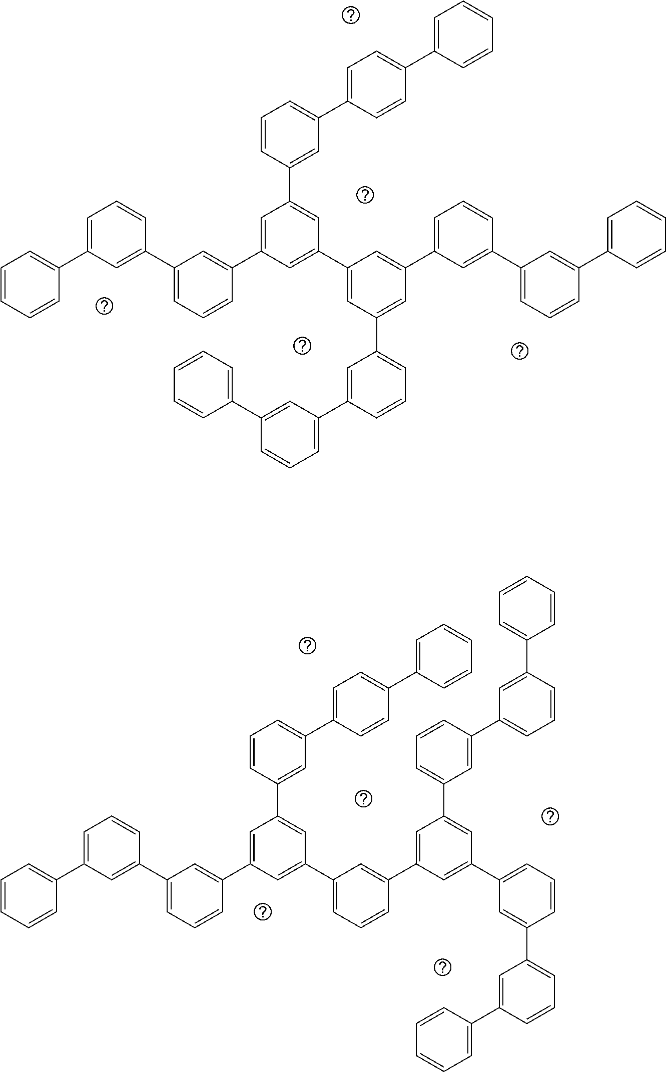

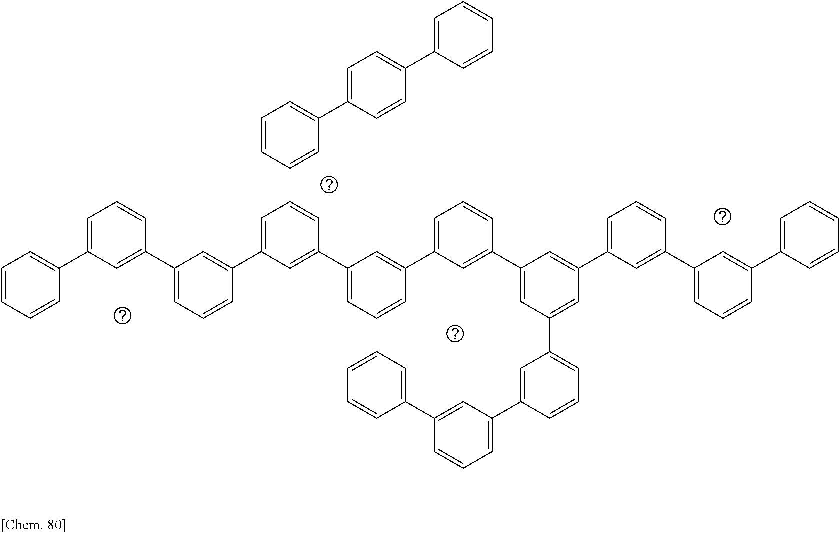

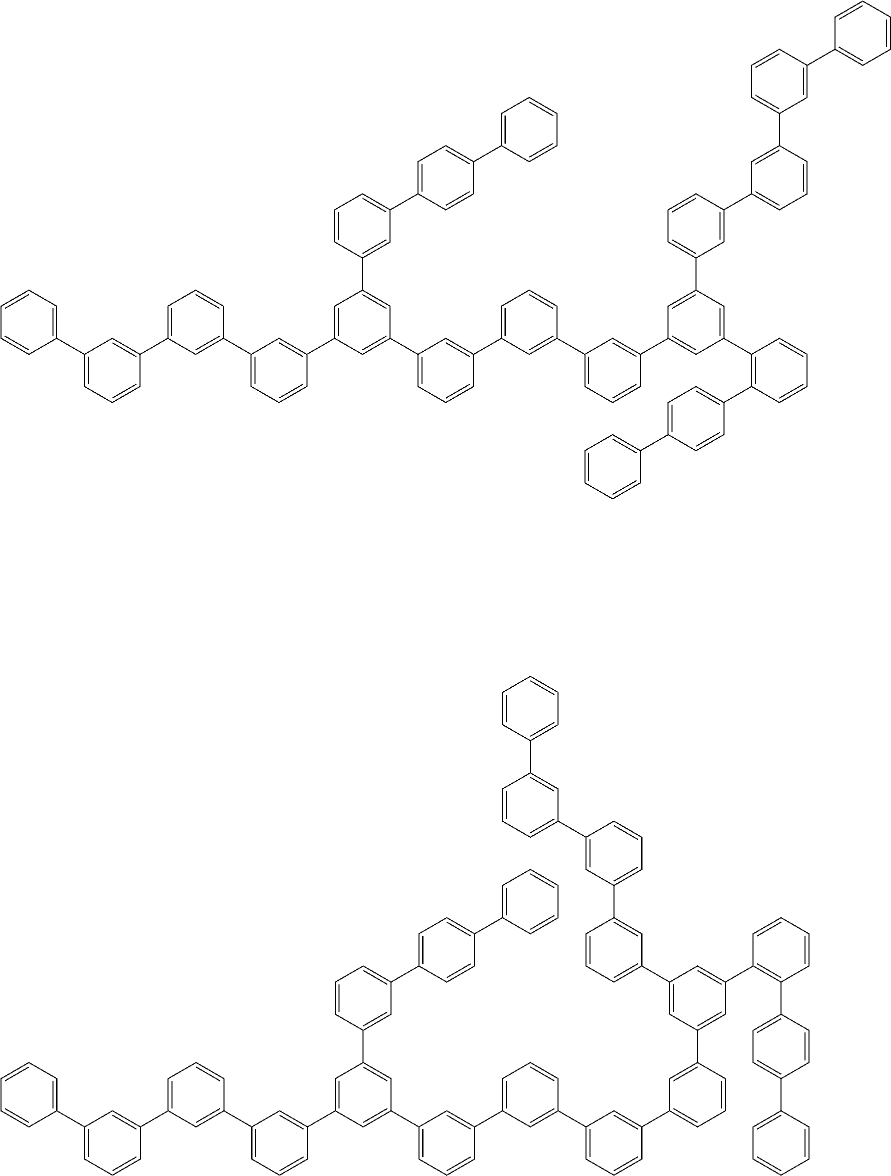

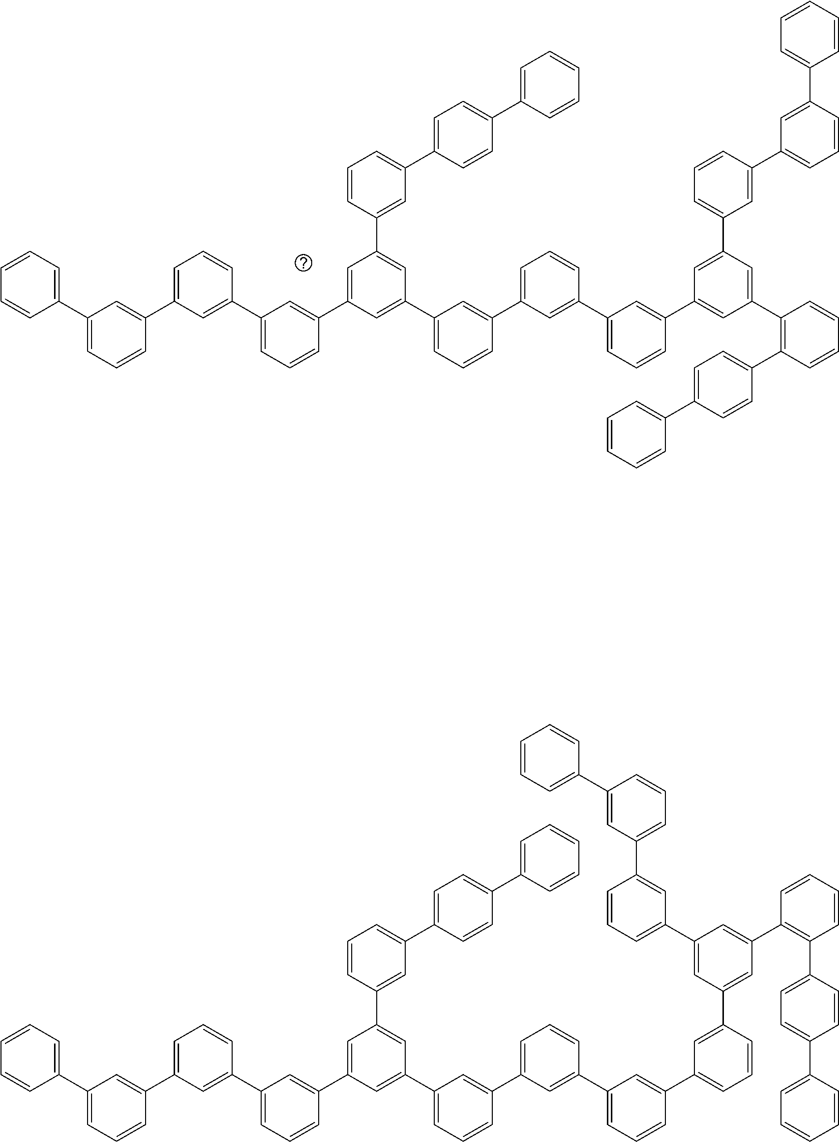

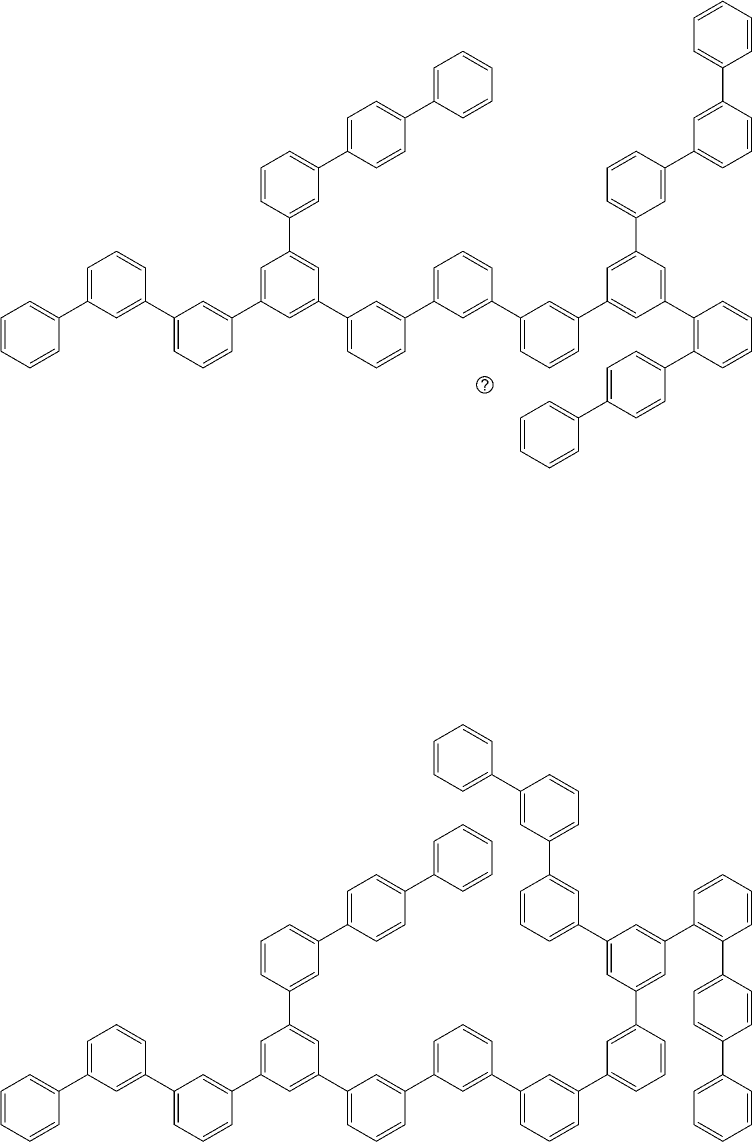

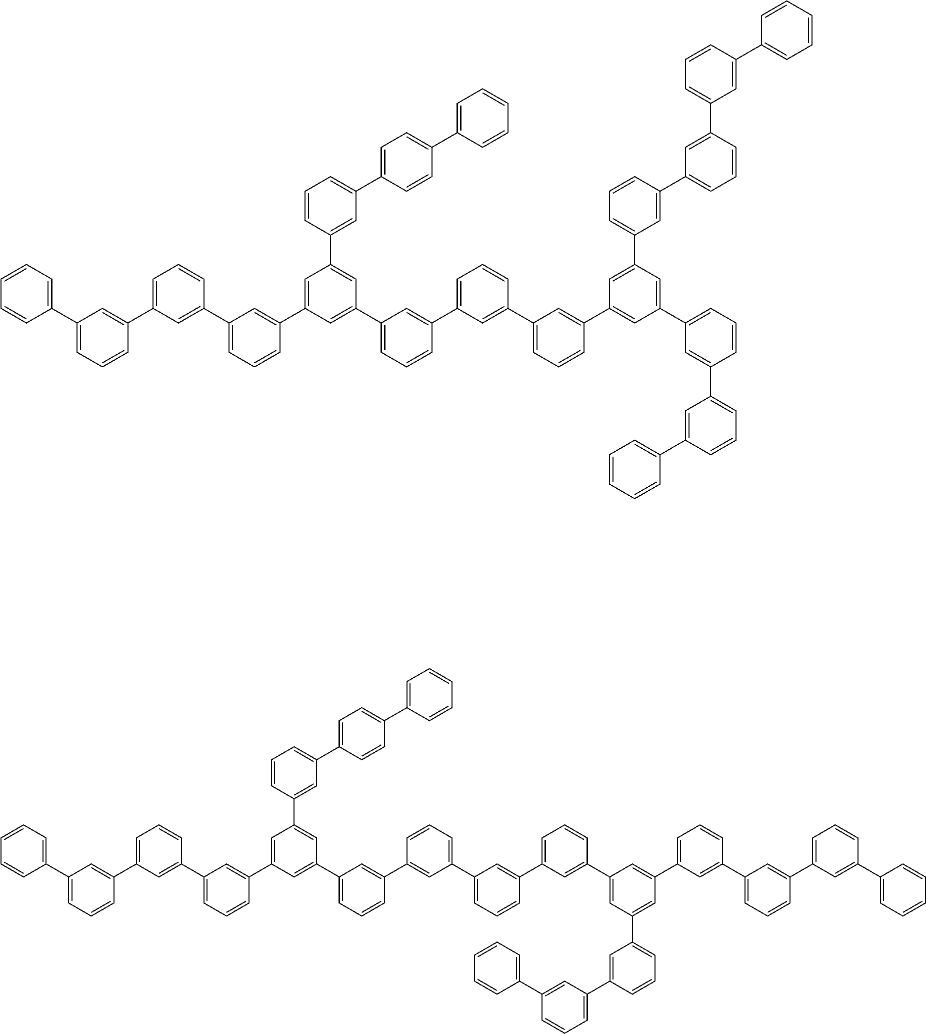

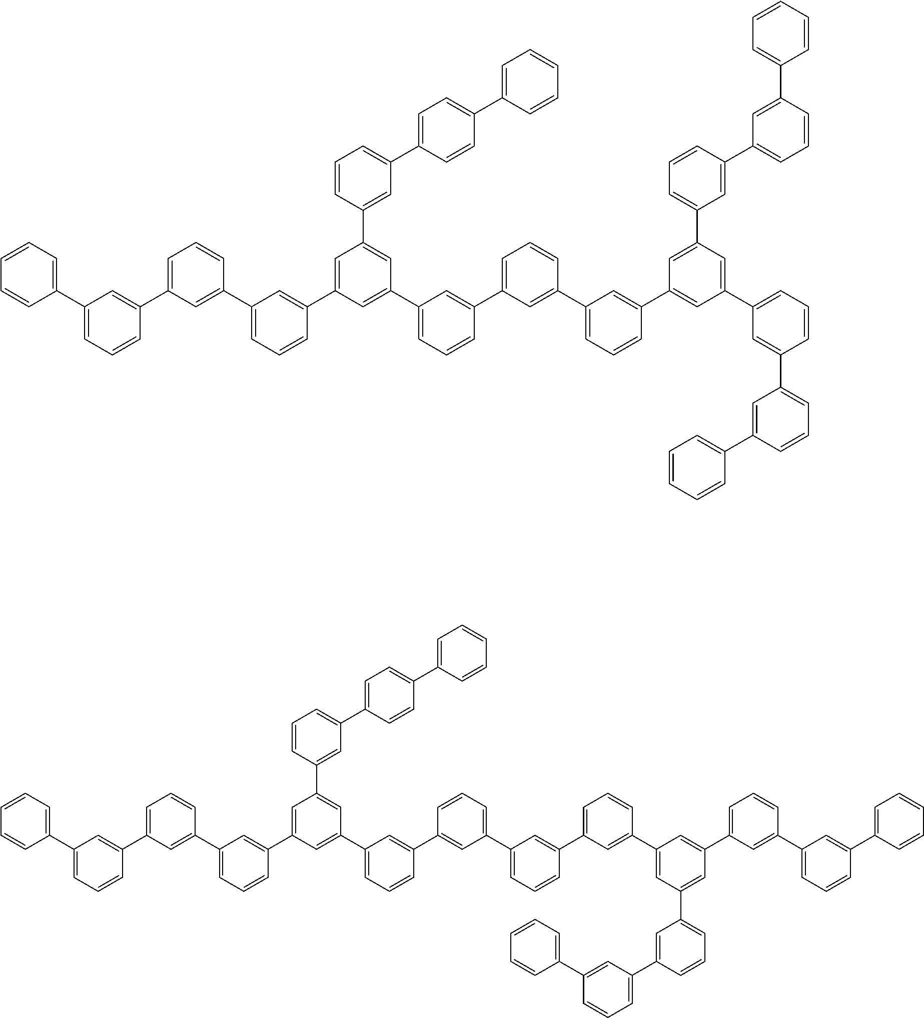

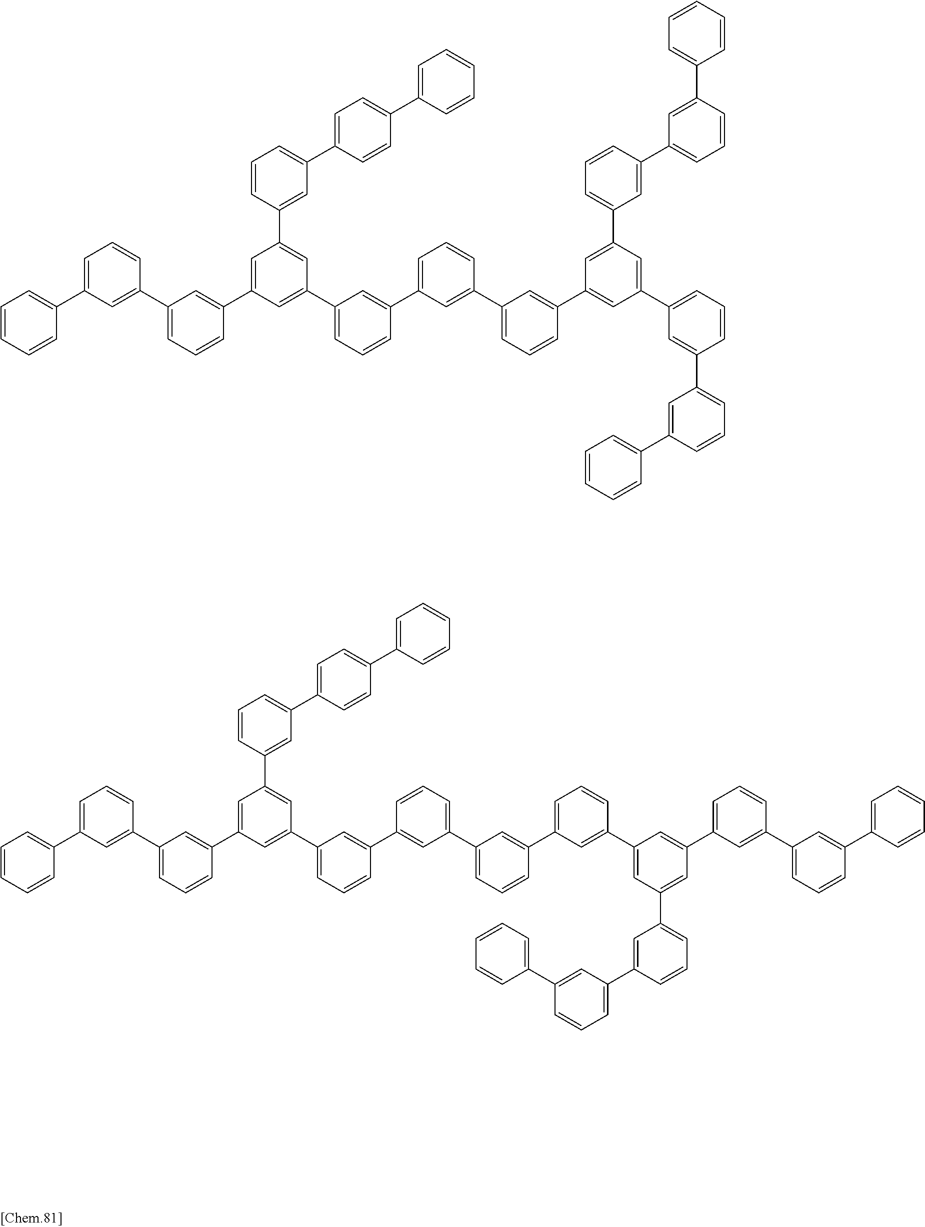

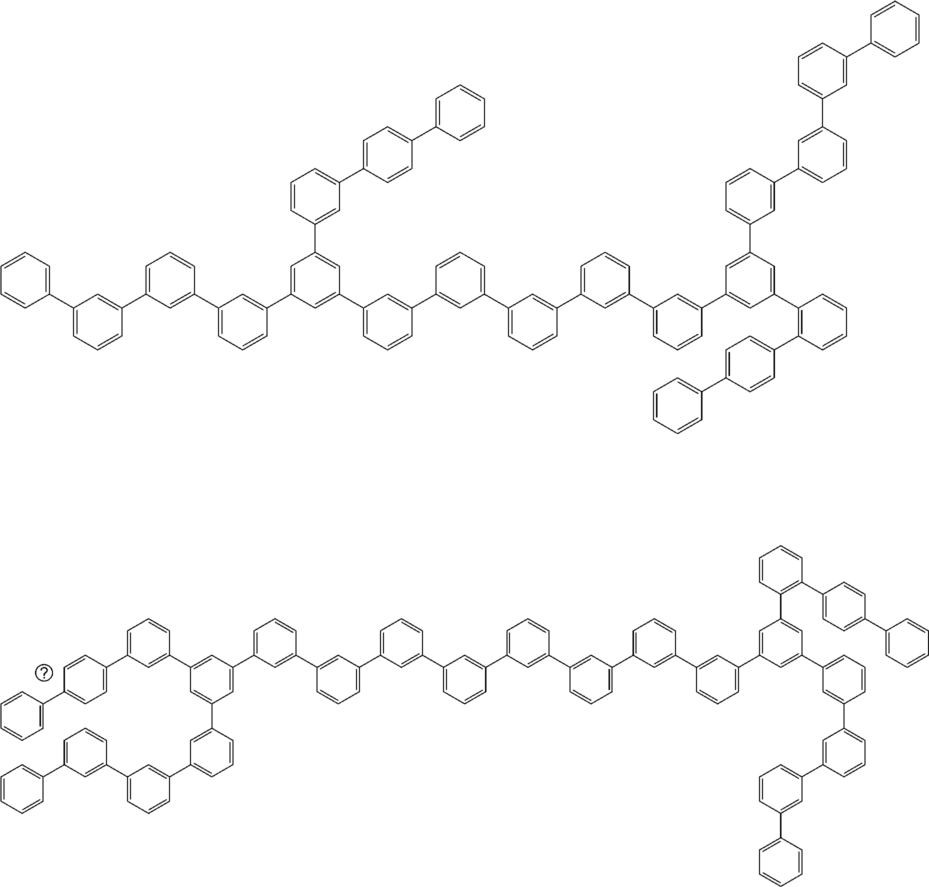

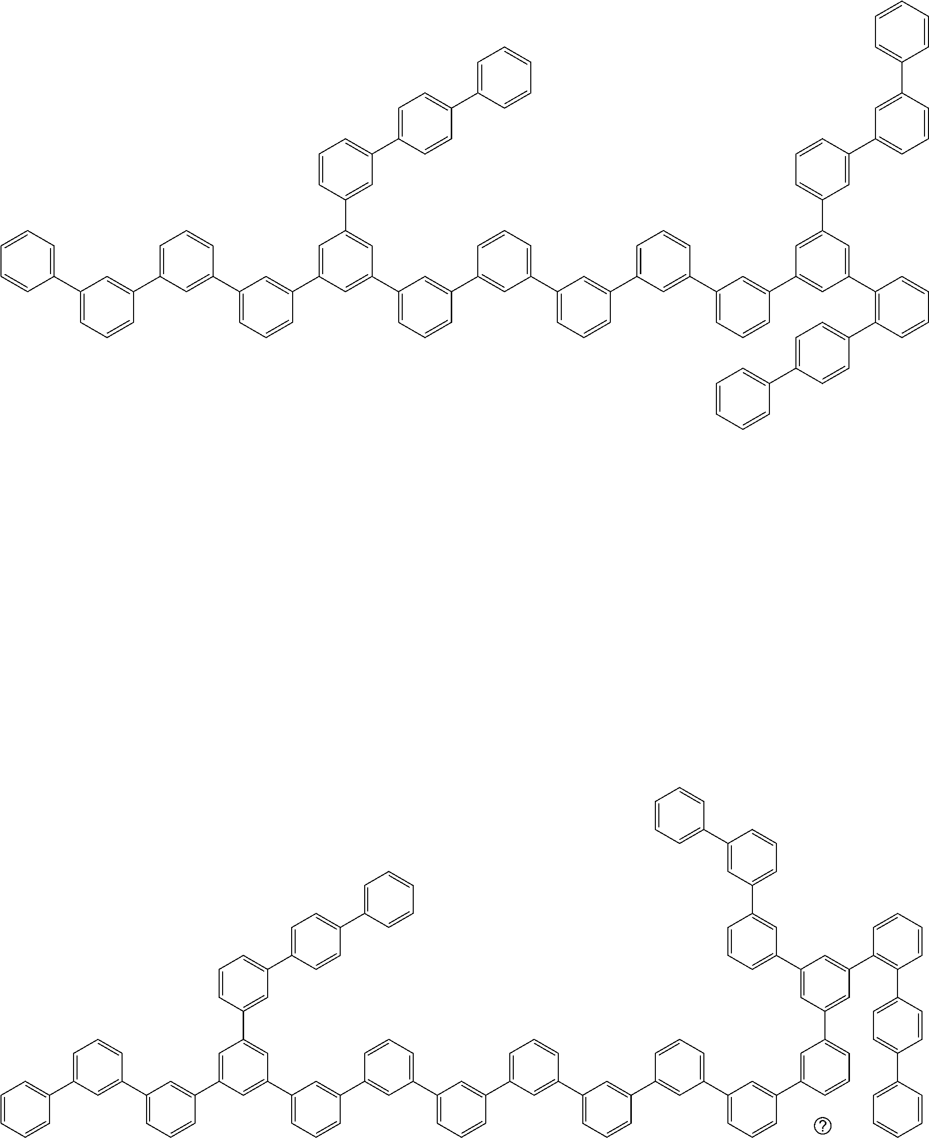

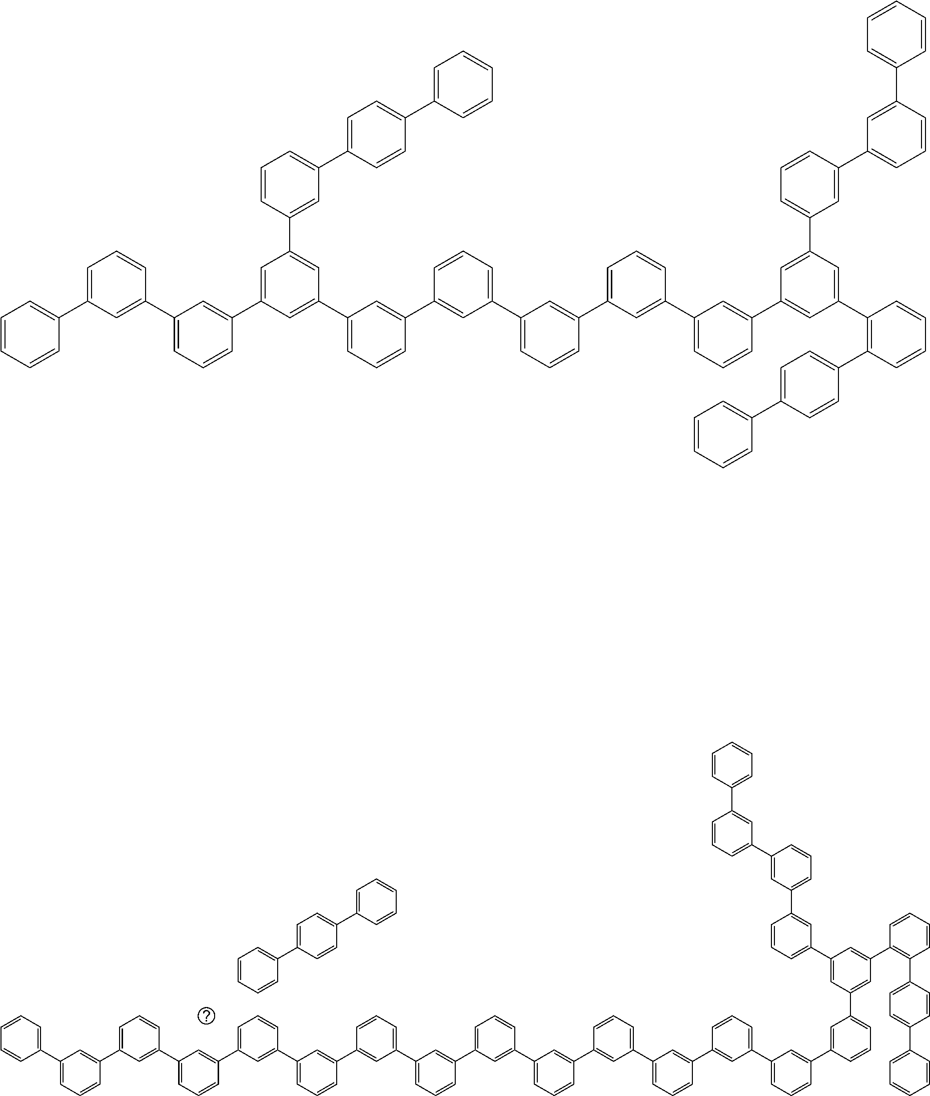

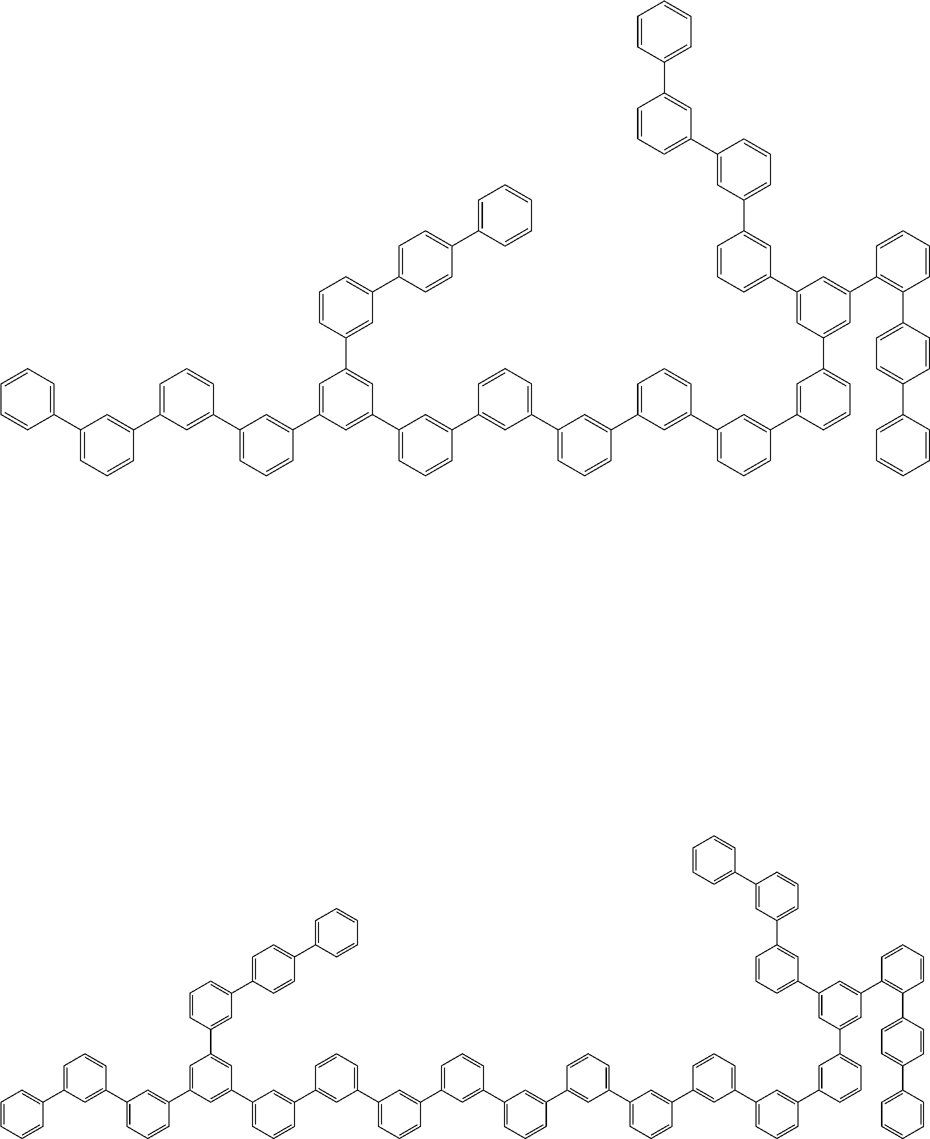

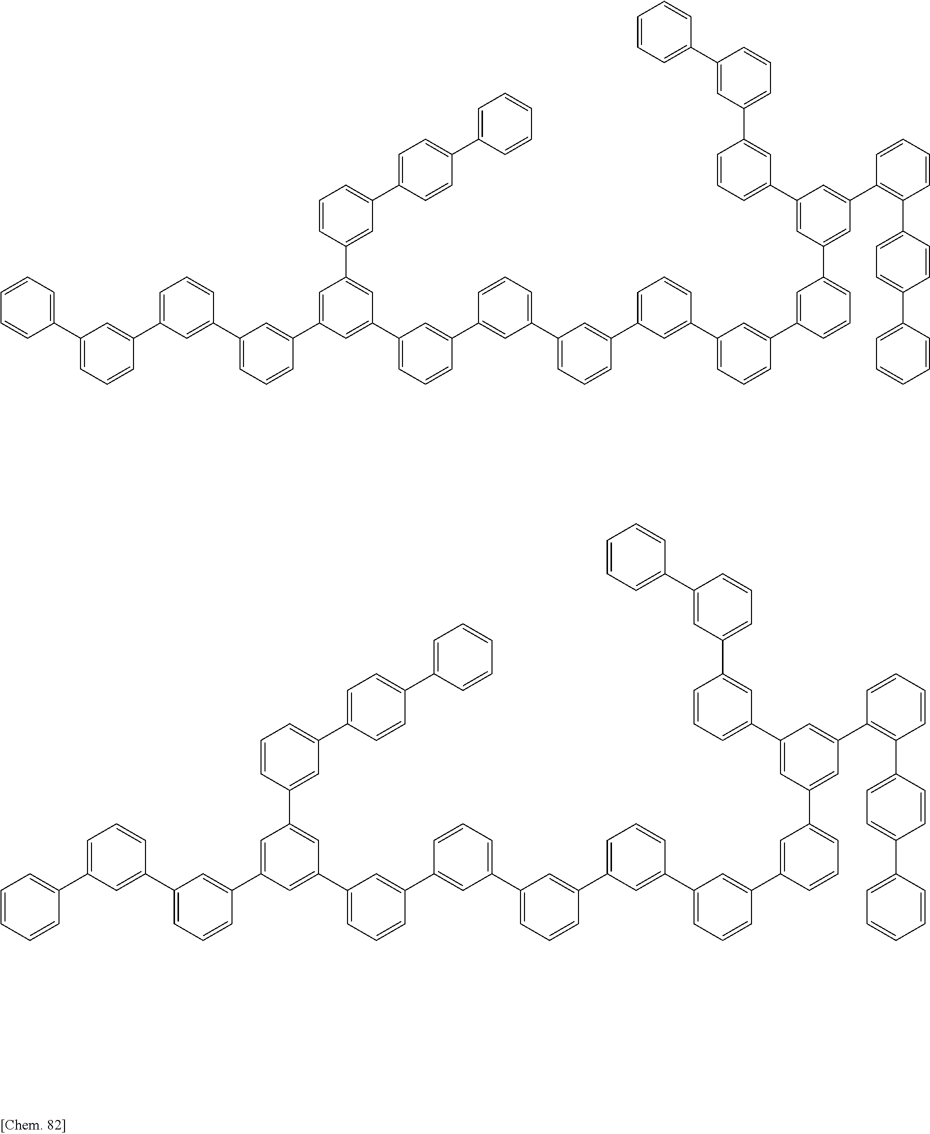

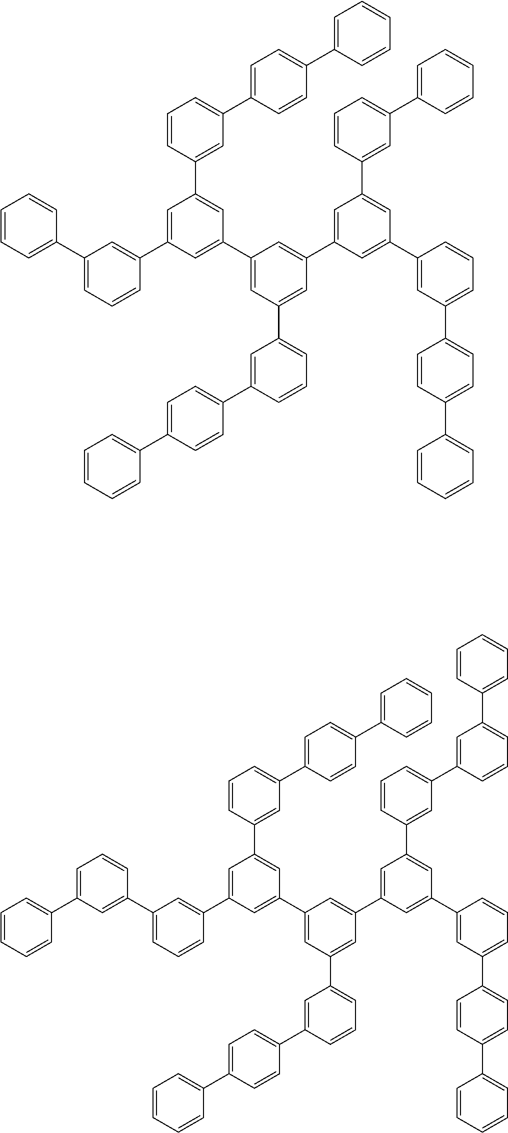

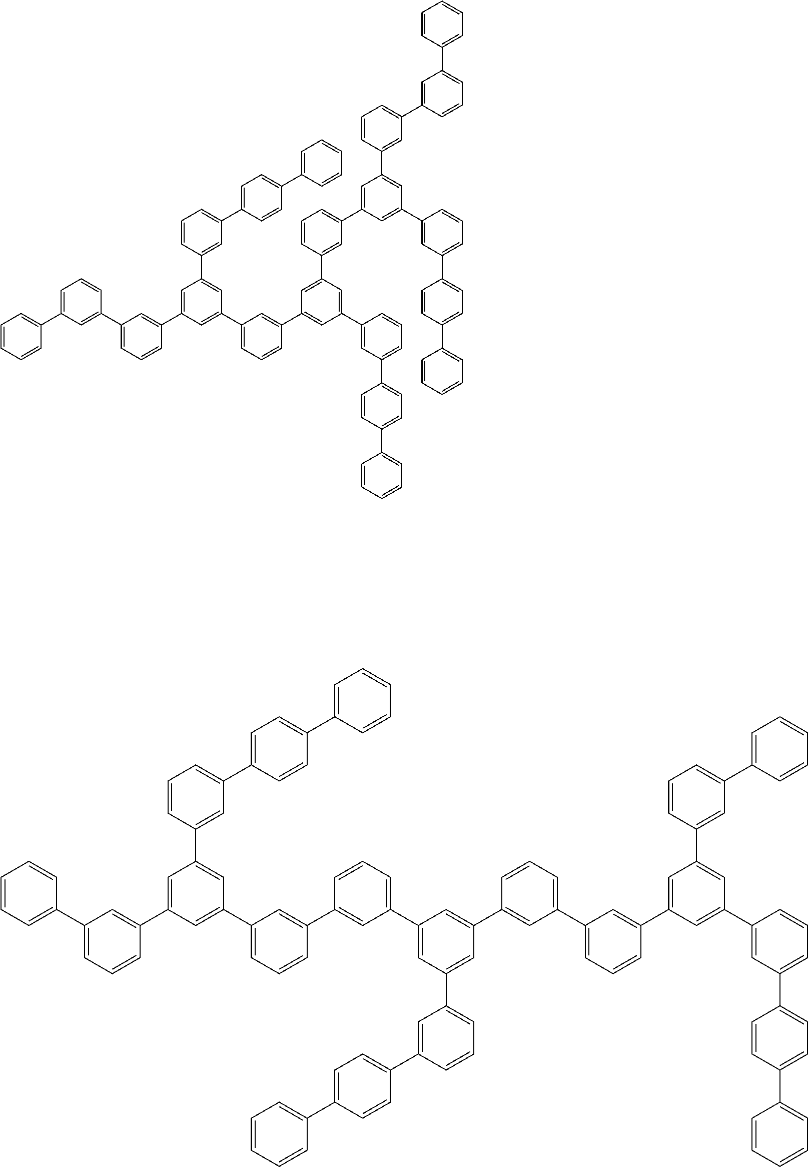

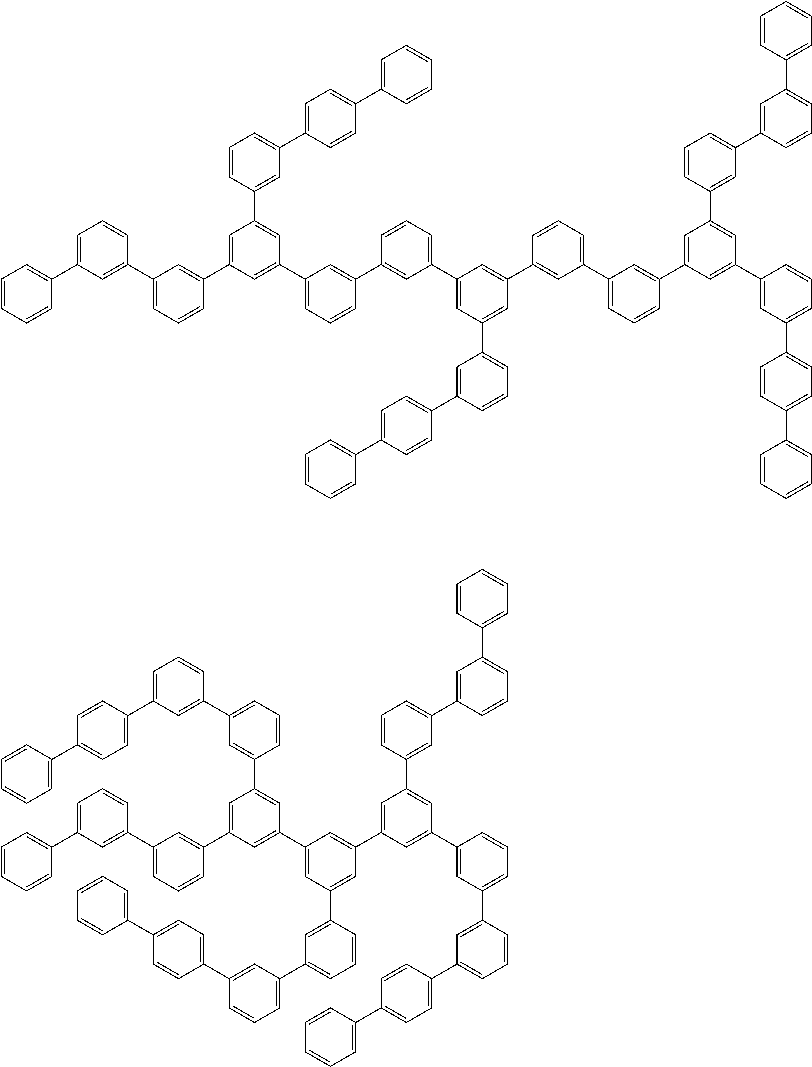

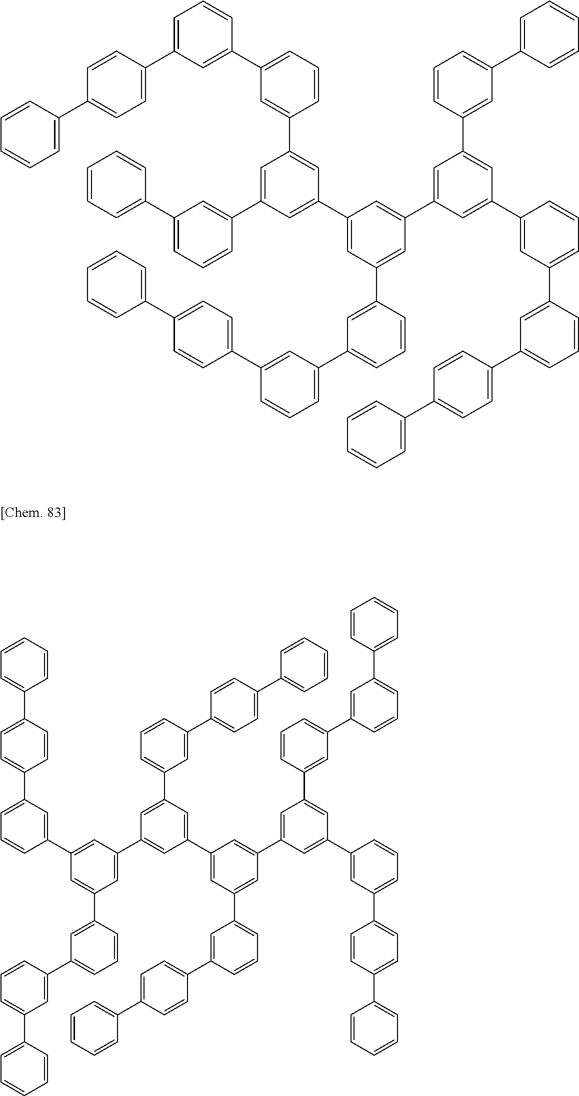

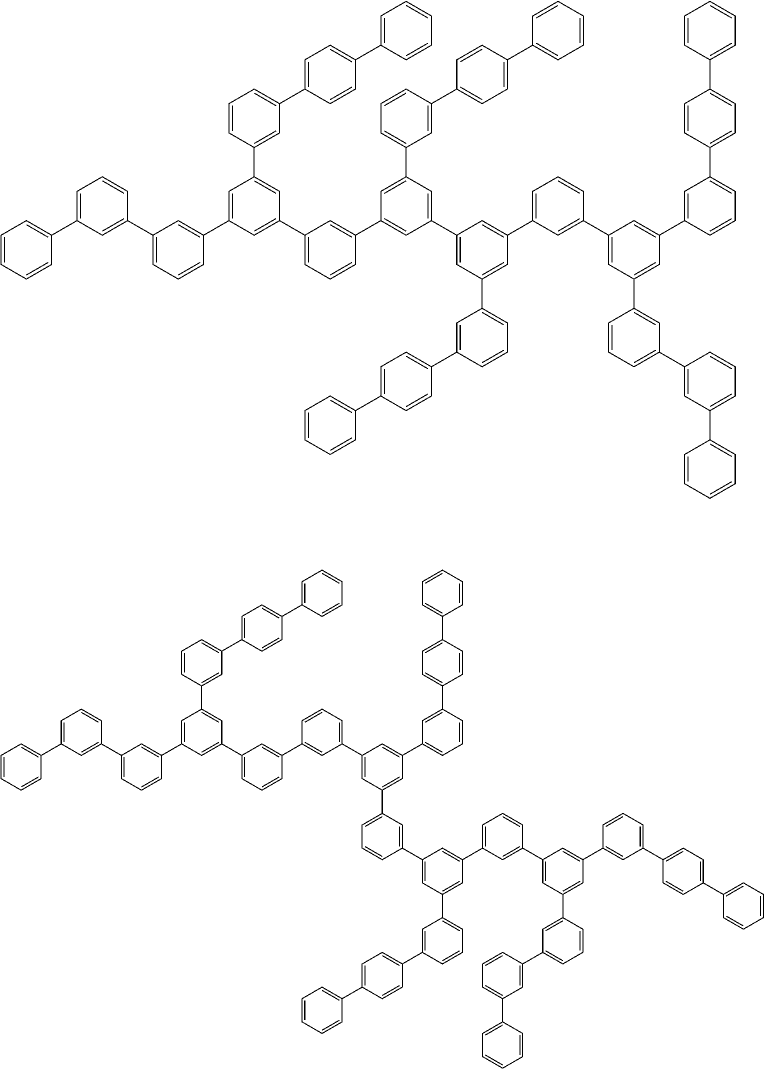

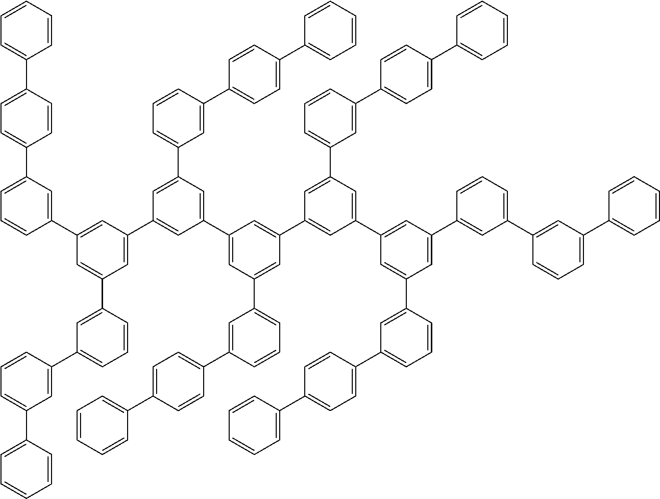 [SMILES: c1ccc(-c2ccc(-c3cccc(-c4cc(-c5cccc(-c6cccc(-c7ccccc7)c6)c5)cc(-c5cc(-c6cccc(-c7ccc(-c8ccccc8)cc7)c6)cc(-c6cc(-c7cccc(-c8ccc(-c9ccccc9)cc8)c7)cc(-c7cc(-c8cccc(-c9ccc(-c%10ccccc%10)cc9)c8)cc(-c8cc(-c9cccc(-c%10ccc(-c%11ccccc%11)cc%10)c9)cc(-c9cccc(-c%10cccc(-c%11ccccc%11)c%10)c9)c8)c7)c6)c5)c4)c3)cc2)cc1]

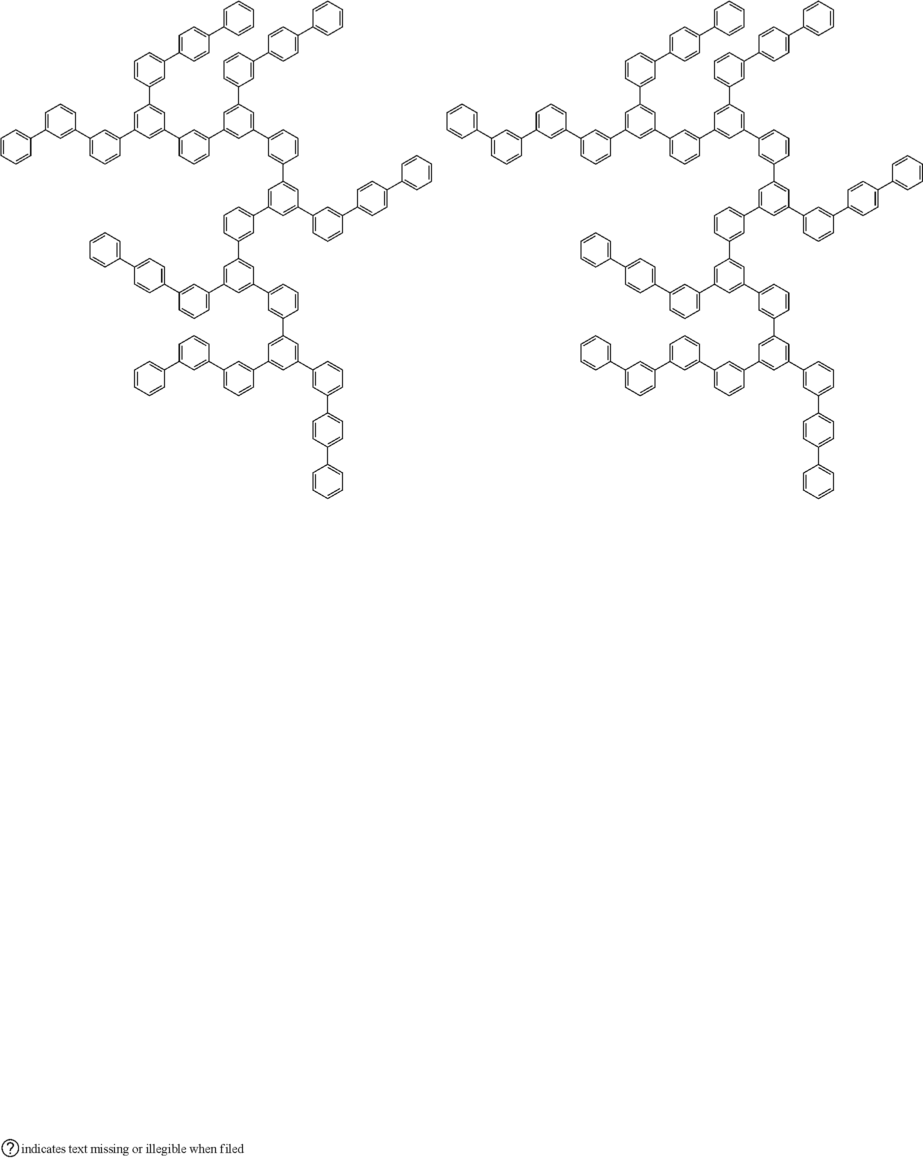

### (Compound Represented by Formula (3))

Preferred embodiments of the compound represented by the formula (3) are shown below.

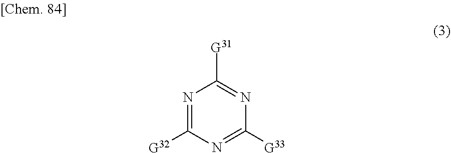

(In the formula (3), G³¹ and G³² each independently represent the following formula (7), and G³³ represents the following formula (8)).

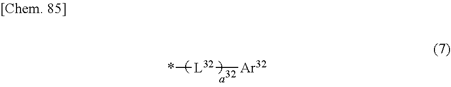

(In the formula (7), an asterisk (*) represents a bond to the formula (3),
L³² represents a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked,
Ar³² represents a monovalent aromatic hydrocarbon group having 60 or less carbon atoms which may have a substituent, a monovalent heteroaromatic group having 60 or less carbon atoms which may have a substituent, or a group in which a plurality of groups selected from the monovalent aromatic hydrocarbon group having 60 or less carbon atoms which may have a substituent and the monovalent heteroaromatic group having 60 or less carbon atoms which may have a substituent are linked, and
a³² represents an integer of 0 to 5).

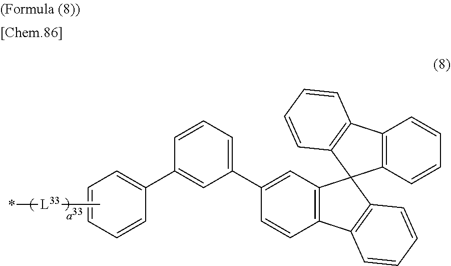

(In the formula (8), an asterisk (*) represents a bond to the formula (3),
L³³ represents a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked, and
a³³ represents an integer of 0 to 5).

From the viewpoint of electron transportability, G³¹ is preferably represented by the following formula (6).

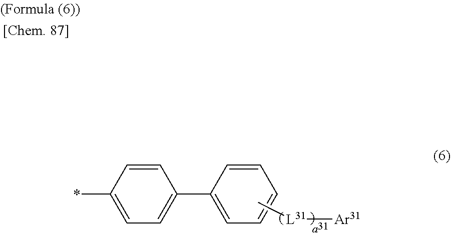

(In the formula (6), an asterisk (*) represents a bond to the formula (3),
L³¹ represents a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked,
Ar³¹ represents a monovalent aromatic hydrocarbon group having 60 or less carbon atoms which may have a substituent, a monovalent heteroaromatic group having 60 or less carbon atoms which may have a substituent, or a group in which a plurality of groups selected from the monovalent aromatic hydrocarbon group having 60 or less carbon atoms which may have a substituent and the monovalent heteroaromatic group having 60 or less carbon atoms which may have a substituent are linked, and
a³¹ represents an integer of 0 to 5).
   (Ar³¹ and Ar³²)

In the formulae (6) and (7), Ar³¹ and Ar³² each independently represent a monovalent aromatic hydrocarbon group having 60 or less carbon atoms which may have a substituent, a monovalent heteroaromatic group having 60 or less carbon atoms which may have a substituent, or a group in which a plurality of groups selected from the monovalent aromatic hydrocarbon group having 60 or less carbon atoms which may have a substituent and the monovalent heteroaromatic group having 60 or less carbon atoms which may have a substituent are linked.

Examples of the monovalent aromatic hydrocarbon group having 60 or less carbon atoms include a monovalent group of a benzene ring, a naphthalene ring, an anthracene ring, a phenanthrene ring, a tetraphenylene ring, a chrysene ring, a pyrene ring, a benzanthracene ring, a perylene ring, a biphenyl ring, or a terphenyl ring.

Examples of the monovalent heteroaromatic group having 60 or less carbon atoms include a monovalent group of a furan ring, a benzofuran ring, a dibenzofuran ring, a thiophene ring, a benzothiophene ring, a dibenzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzoisoxazole ring, a benzoisothiazole ring, a benzoimidazole ring, a pyridine ring, a pyrazine ring, a pyridazine ring, a pyrimidine ring, a triazine ring, a quinoline ring, an isoquinoline ring, a cinnoline ring, a quinoxaline ring, a perimidine ring, a quinazoline ring, a quinazolinone ring, or an azulene ring.

From the viewpoint of solubility and durability of the compound, a phenyl group, a group in which a plurality of phenyl groups are linked, or a naphthyl group is preferable, and a phenyl group or a group in which a plurality of phenyl groups are linked is more preferable.

(L³¹, L³², and L³³)

In the formulae (6) to (8), L³¹, L³², and L³³ each independently represent a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked.

Examples of the divalent aromatic hydrocarbon group having 60 or less carbon atoms include a divalent group of a benzene ring, a naphthalene ring, an anthracene ring, a tetraphenylene ring, a phenanthrene ring, a chrysene ring, a pyrene ring, a benzanthracene ring, or a perylene ring.

Examples of the divalent heteroaromatic group having 60 or less carbon atoms include a divalent group of a furan ring, a benzofuran ring, a dibenzofuran ring, a thiophene ring, a benzothiophene ring, a dibenzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzoisoxazole ring, a benzoisothiazole ring, a benzoimidazole ring, a pyridine ring, a pyrazine ring, a pyridazine ring, a pyrimidine ring, a triazine ring, a quinoline ring, an isoquinoline ring, a cinnoline ring, a quinoxaline ring, a perimidine ring, a quinazoline ring, a quinazolinone ring, or an azulene ring.

From the viewpoint of solubility and durability of the compound, a phenylene group, a group in which a plurality of phenylene groups are linked, or a naphthylene group is preferable, and a phenylene group or a group in which a plurality of phenylene groups are linked is more preferable. Among those, a 1,3-phenylene group or a 1,4-phenylene group is still more preferable.

Among those, L³² and L³³ in the formulae (7) and (8) each independently preferably represent a phenylene group or a group in which a plurality of phenylene groups are linked in a directly bonded manner, and more preferably a 1,3-phenylene group or a 1,4-phenylene group. In a case where G³¹ is represented by the formula (6), L³¹ to L³³ each independently preferably represent a phenylene group or a group in which a plurality of phenylene groups are linked in a directly bonded manner, and more preferably a 1,3-phenylene group or a 1,4-phenylene group.

L³² and L³³ in the formulae (7) and (8), as well as L³¹ in the formula (6) each independently represent a phenylene group or a group in which a plurality of phenylene groups are linked in a directly bonded manner.

(a³¹ to a³³)

In the formulae (6) to (8), a³¹ to a³³ each independently represent an integer of 0 to 5. From the viewpoint of solubility and durability of the compound, a³¹ and a³³ are each independently preferably 1 or more, and preferably 3 or less, more preferably 2 or less, particularly preferably 1, and a³² is preferably 1 or more, and preferably 4 or less, more preferably 3 or less.

In a case where a³¹ to a33 in the formulae (6) to (8) each represent 2 or more, a plurality of L³¹ to L³³ may be the same as or different from each other.

From the viewpoint of solubility and durability of the compound, at least one of (L³¹)ₐ₃₁, (L³²)ₐ₃₂, and (L³³)ₐ₃₃ in the formulae (6) to (8) preferably has at least one substructure selected from a substructure represented by the following formula (11), a substructure represented by the following formula (12), and a substructure represented by the following formula (15).

### (Formula (11), Formula (12), and Formula (15))

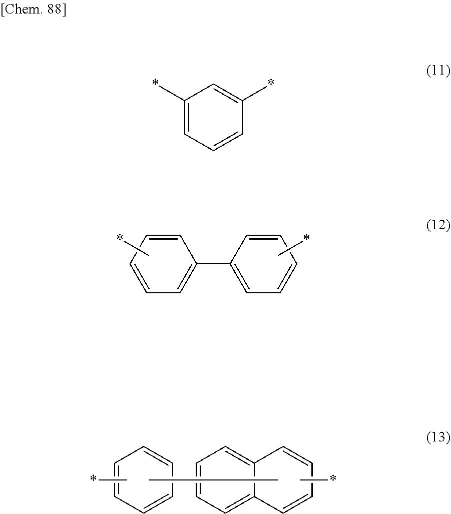

In each of the formulae (11), (12), and (15), * represents a bond to an adjacent structure or a hydrogen atom, and at least one of two present *s represents a bonding site to the adjacent structure. In the following description, the definition of * is the same unless otherwise specified.

More preferably, at least one of (L³¹)a31, (L³²)ₐ₃₂, and (L³³)ₐ₃₃ in the formulae (6) to (8) has at least the substructure represented by the formula (11) or the substructure represented by the formula (12).

Still more preferably, each of (L³¹)a31, (L³²)ₐ₃₂, and (L³³)ₐ₃₃ in the formulae (6) to (8) has at least the substructure represented by the formula (11) or the substructure represented by the formula (12).

Particularly preferably, (L³²)ₐ₃₂ in the formula (7) has the substructure represented by the formula (11) and the substructure represented by the formula (12).

In the formula (3),_the formula (12) is preferably the following formula (12-2).

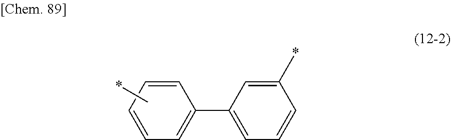

In the formula (3), the formula (12) is still more preferably the following formula (12-3).

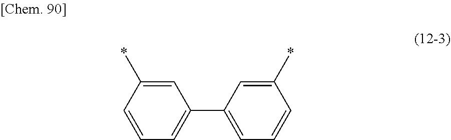 [SMILES: *c1cccc(-c2cccc(*)c2)c1]

In the formula (3), in a case where the substructure represented by the formula (11) and the substructure represented by the formula (12) are provided, it is more preferable that a substructure represented by at least one selected from the following formulae (17) to (19), (21), and (22), which is a structure including a plurality of structures selected from the substructure represented by the formula (11) and the substructure represented by the formula (12), is provided.

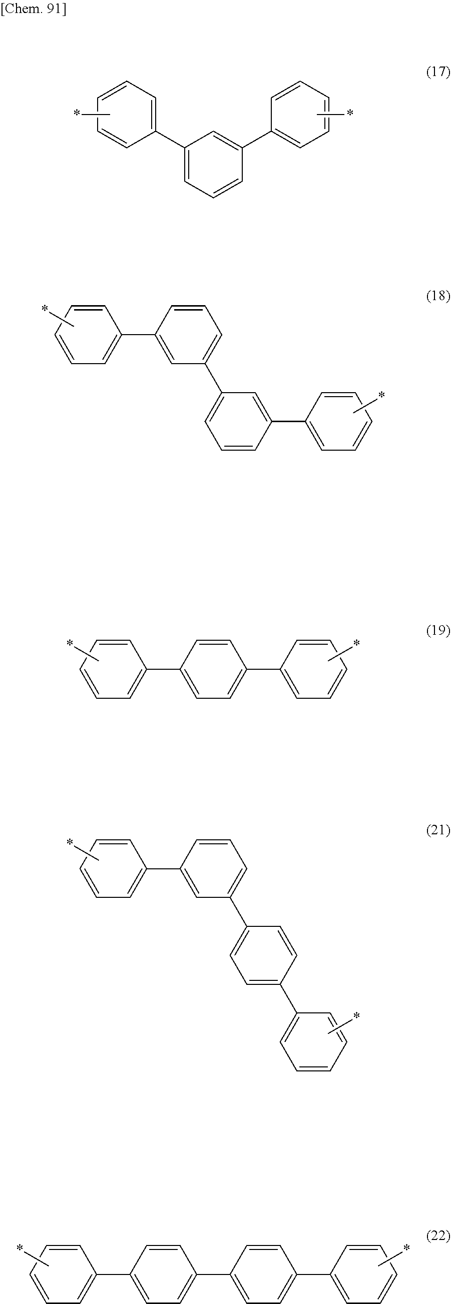

In the formula (3), the structure including a plurality of structures selected from the substructure represented by the formula (11) and the substructure represented by the formula (12) is, for example, a substructure in which the formula (17) has one substructure represented by the formula (11) and two substructures represented by the formula (12) as in the following formula (17a).

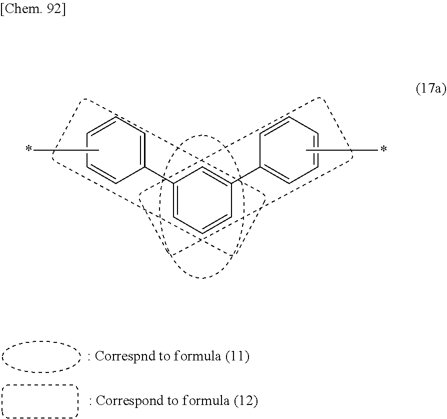

Still more preferably, at least one of (L³¹)ₐ₃₁, (L³²)ₐ₃₂, and (L³³)ₐ₃₃ in the formulae (6) to (8) has at least the substructure represented by the formula (17) or the substructure represented by the formula (18).

In the formula (3), the formula (17) is preferably the following formula (17-2).

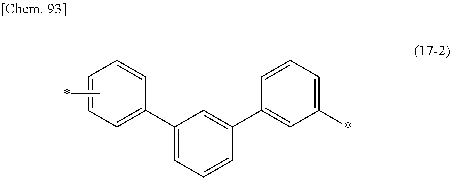

In the formula (3), the formula (17) is still more preferably the following formula (17-3).

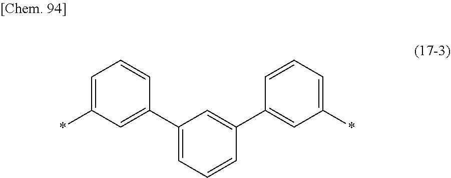 [SMILES: *c1cccc(-c2cccc(-c3cccc(*)c3)c2)c1]

In the formula (3), the formula (18) is preferably the following formula (18-2).

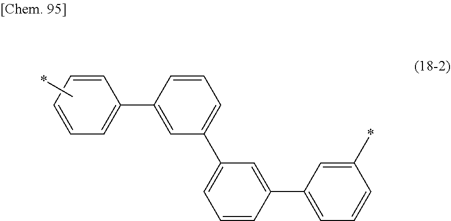

In the formula (3), the formula (18) is still more preferably the following formula (18-3).

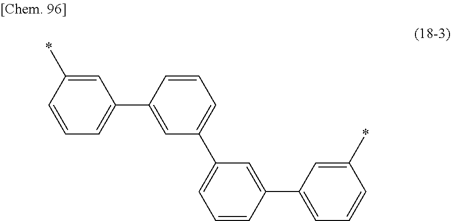 [SMILES: *c1cccc(-c2cccc(-c3cccc(-c4cccc(*)c4)c3)c2)c1]

In the formula (3), the formula (21) is preferably the following formula (21-2).

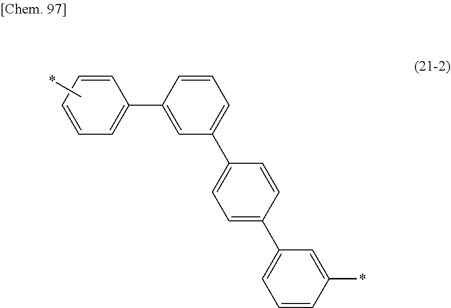

In the formula (3), the formula (22) is preferably the following formula (22-2).

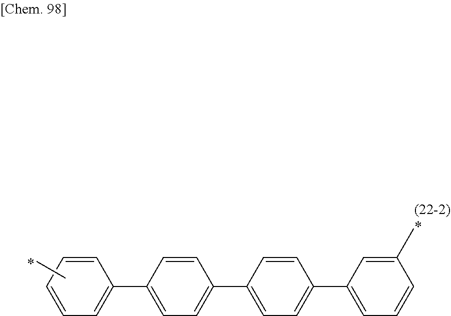

In the formula (3), as a structure having the substructure represented by the formula (15), a substructure represented by the following formula (15-2) or a substructure represented by the following formula (15-3) is more preferable.

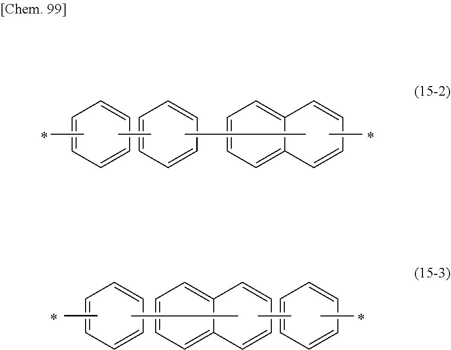

In each of the formulae (14) to (20), * represents a bond to an adjacent structure or a hydrogen atom, and at least one of two present *s represents a bonding site to the adjacent structure.

In the formula (3), among the formulae (14) to (20), the formula (14-3) and the formula (15-3) are preferable, and the formula (14-3) is more preferable.

### (Substituent)

In the formulae (6) to (8), substituents which Ar³¹ and Ar³², and L³¹ to L³³ may have can be selected from the following substituent group Z2.

(Substituent Group Z2) The substituent group Z2 is a substituent group consisting of an alkyl group, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, a cyano group, an aralkyl group, an aromatic hydrocarbon group, and a heteroaromatic group.

The alkyl group, the alkenyl group, the alkynyl group, the alkoxy group, the aryloxy group, the alkoxycarbonyl group, the acyl group, the halogen atom, the haloalkyl group, the alkylthio group, the arylthio group, the silyl group, the siloxy group, the cyano group, the aralkyl group, and the aromatic hydrocarbon group in the substituent group Z2 are the same as those in the substituent group Z.

Examples of the heteroaromatic group include a heteroaromatic group having generally 4 or more, and generally 30 or less, preferably 18 or less, more preferably 12 or less carbon atoms, such as a furan ring, a benzofuran ring, a dibenzofuran ring, a thiophene ring, a benzothiophene ring, a dibenzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzoisoxazole ring, a benzoisothiazole ring, a benzoimidazole ring, a pyridine ring, a pyrazine ring, a pyridazine ring, a pyrimidine ring, a triazine ring, a quinoline ring, an isoquinoline ring, a cinnoline ring, a quinoxaline ring, a perimidine ring, a quinazoline ring, a quinazolinone ring, or an azulene ring.

Among those in the substituent group Z2, an alkyl group, an alkoxy group, an aralkyl group, and an aromatic hydrocarbon group are preferable, an alkyl group having 10 or less carbon atoms, an aralkyl group having 30 or less carbon atoms, and an aromatic hydrocarbon group having 30 or less carbon atoms are more preferable, an aromatic hydrocarbon group having 30 or less carbon atoms is still more preferable, and providing no substituent is particularly preferable.

Each substituent of the above substituent group Z2 may further have a substituent. As those substituents which may be further provided, the same substituents as those described above (substituent group Z2) can be used. The substituent of the above substituent group Z2 preferably has no further substituent.

### (Molecular Weight)

A molecular weight of the compound represented by the formula (3) is preferably 1,000 or more, more preferably 1,100 or more, most preferably 1,200 or more, and is preferably 5,000 or less, more preferably 4,000 or less, particularly preferably 3,000 or less, most preferably 2,000 or less.

### Specific Example

Specific examples of the compound represented by the formula (3) are shown below, but the present invention is not limited thereto.

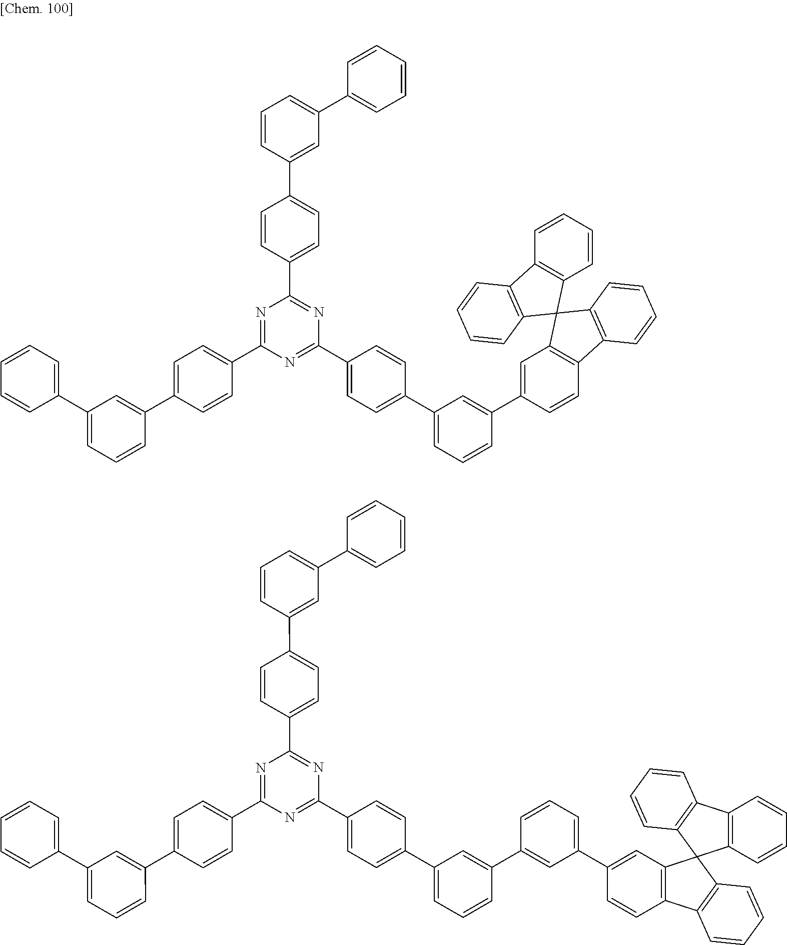 [SMILES: c1ccc(-c2cccc(-c3ccc(-c4nc(-c5ccc(-c6cccc(-c7ccccc7)c6)cc5)nc(-c5ccc(-c6cccc(-c7ccc8c(c7)C7(c9ccccc9-c9ccccc97)c7ccccc7-8)c6)cc5)n4)cc3)c2)cc1 ; c1ccc(-c2cccc(-c3ccc(-c4nc(-c5ccc(-c6cccc(-c7ccccc7)c6)cc5)nc(-c5ccc(-c6cccc(-c7cccc(-c8ccc9c(c8)C8(c%10ccccc%10-c%10ccccc%108)c8ccccc8-9)c7)c6)cc5)n4)cc3)c2)cc1]

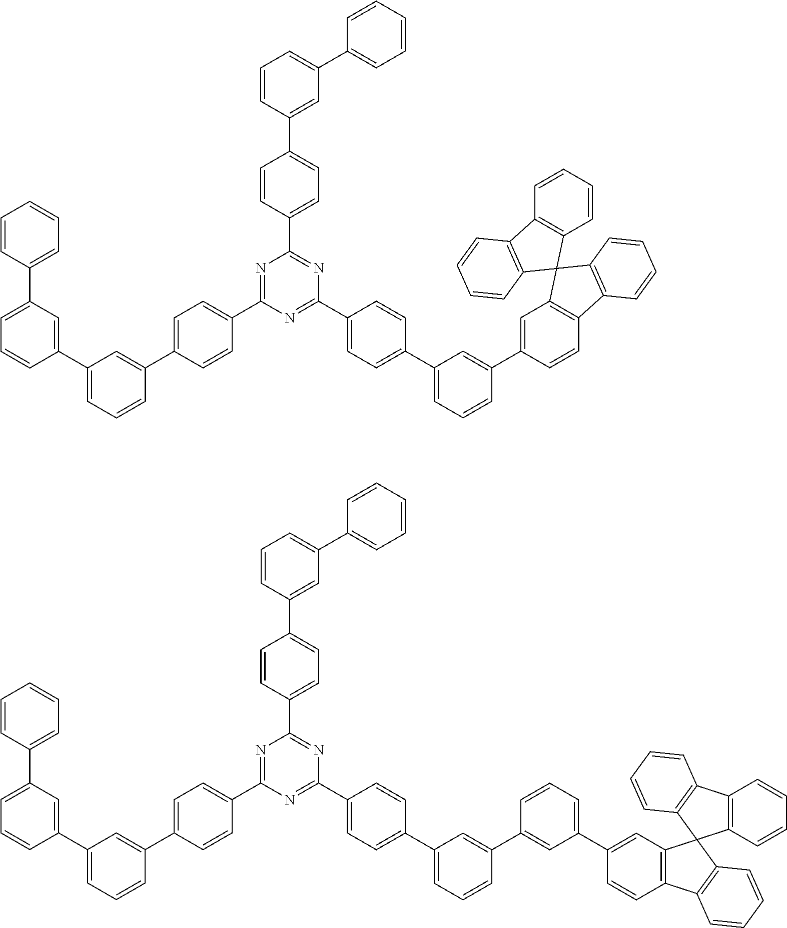 [SMILES: c1ccc(-c2cccc(-c3ccc(-c4nc(-c5ccc(-c6cccc(-c7cccc(-c8ccccc8)c7)c6)cc5)nc(-c5ccc(-c6cccc(-c7ccc8c(c7)C7(c9ccccc9-c9ccccc97)c7ccccc7-8)c6)cc5)n4)cc3)c2)cc1 ; c1ccc(-c2cccc(-c3ccc(-c4nc(-c5ccc(-c6cccc(-c7cccc(-c8ccccc8)c7)c6)cc5)nc(-c5ccc(-c6cccc(-c7cccc(-c8ccc9c(c8)C8(c%10ccccc%10-c%10ccccc%108)c8ccccc8-9)c7)c6)cc5)n4)cc3)c2)cc1]

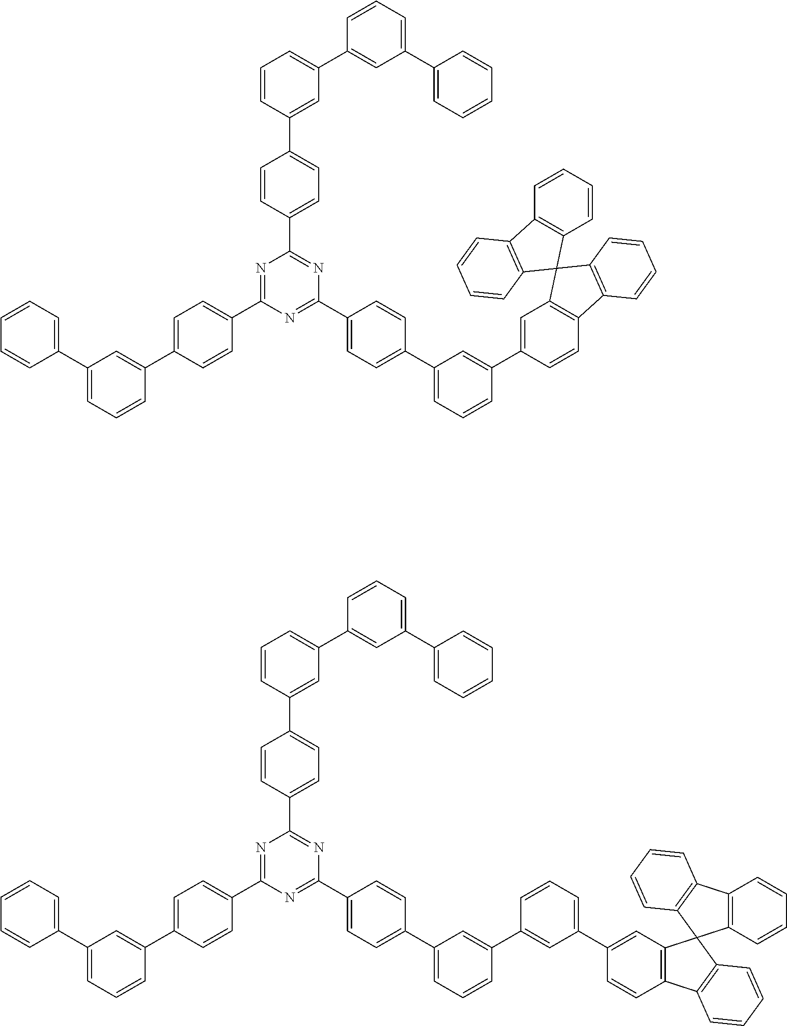 [SMILES: c1ccc(-c2cccc(-c3ccc(-c4nc(-c5ccc(-c6cccc(-c7cccc(-c8ccccc8)c7)c6)cc5)nc(-c5ccc(-c6cccc(-c7ccc8c(c7)C7(c9ccccc9-c9ccccc97)c7ccccc7-8)c6)cc5)n4)cc3)c2)cc1 ; c1ccc(-c2cccc(-c3ccc(-c4nc(-c5ccc(-c6cccc(-c7cccc(-c8ccccc8)c7)c6)cc5)nc(-c5ccc(-c6cccc(-c7cccc(-c8ccc9c(c8)C8(c%10ccccc%10-c%10ccccc%108)c8ccccc8-9)c7)c6)cc5)n4)cc3)c2)cc1]

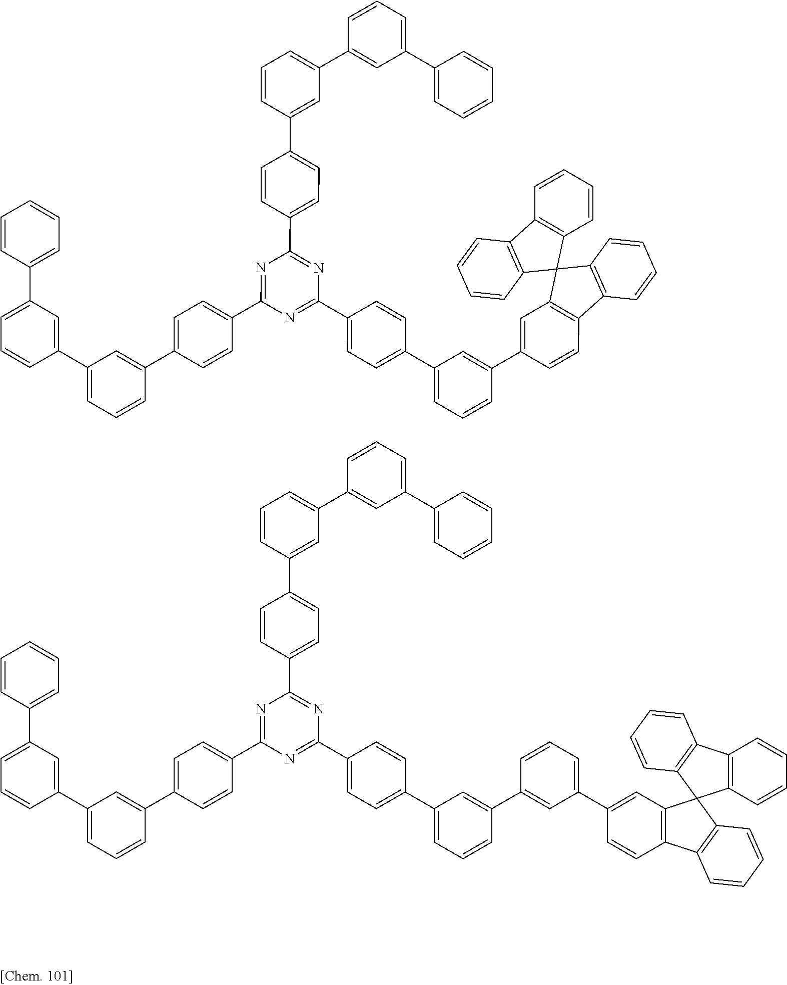 [SMILES: c1ccc(-c2cccc(-c3cccc(-c4ccc(-c5nc(-c6ccc(-c7cccc(-c8cccc(-c9ccccc9)c8)c7)cc6)nc(-c6ccc(-c7cccc(-c8ccc9c(c8)C8(c%10ccccc%10-c%10ccccc%108)c8ccccc8-9)c7)cc6)n5)cc4)c3)c2)cc1 ; c1ccc(-c2cccc(-c3cccc(-c4ccc(-c5nc(-c6ccc(-c7cccc(-c8cccc(-c9ccccc9)c8)c7)cc6)nc(-c6ccc(-c7cccc(-c8cccc(-c9ccc%10c(c9)C9(c%11ccccc%11-c%11ccccc%119)c9ccccc9-%10)c8)c7)cc6)n5)cc4)c3)c2)cc1]

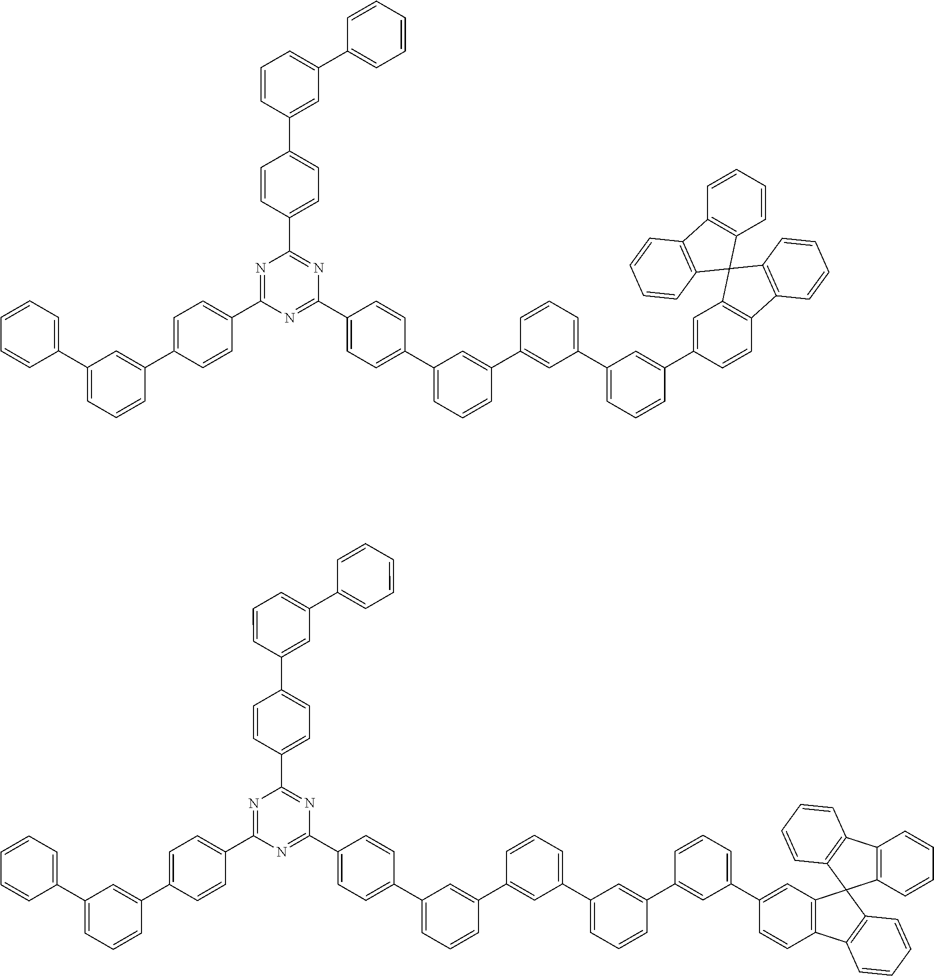 [SMILES: c1ccc(-c2cccc(-c3ccc(-c4nc(-c5ccc(-c6cccc(-c7ccccc7)c6)cc5)nc(-c5ccc(-c6cccc(-c7cccc(-c8cccc(-c9ccc%10c(c9)C9(c%11ccccc%11-c%11ccccc%119)c9ccccc9-%10)c8)c7)c6)cc5)n4)cc3)c2)cc1 ; c1ccc(-c2cccc(-c3ccc(-c4nc(-c5ccc(-c6cccc(-c7ccccc7)c6)cc5)nc(-c5ccc(-c6cccc(-c7cccc(-c8cccc(-c9cccc(-c%10ccc%11c(c%10)C%10(c%12ccccc%12-c%12ccccc%12%10)c%10ccccc%10-%11)c9)c8)c7)c6)cc5)n4)cc3)c2)cc1]

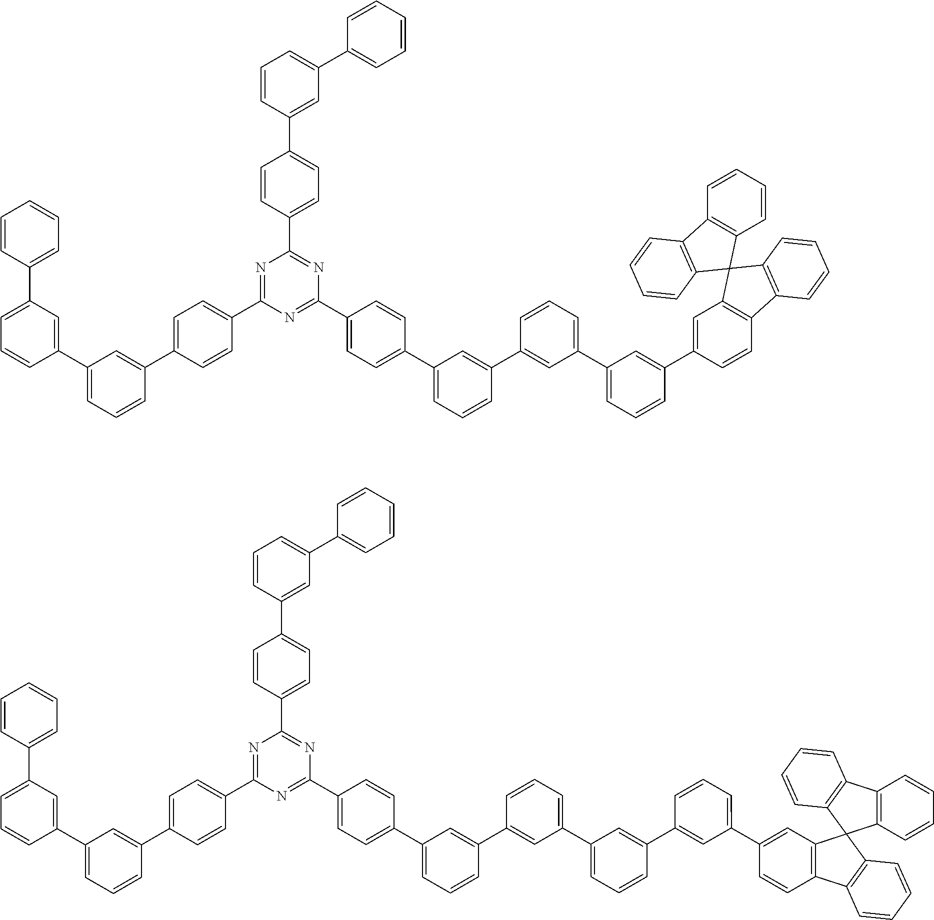 [SMILES: c1ccc(-c2cccc(-c3ccc(-c4nc(-c5ccc(-c6cccc(-c7cccc(-c8ccccc8)c7)c6)cc5)nc(-c5ccc(-c6cccc(-c7cccc(-c8cccc(-c9ccc%10c(c9)C9(c%11ccccc%11-c%11ccccc%119)c9ccccc9-%10)c8)c7)c6)cc5)n4)cc3)c2)cc1 ; c1ccc(-c2cccc(-c3ccc(-c4nc(-c5ccc(-c6cccc(-c7cccc(-c8ccccc8)c7)c6)cc5)nc(-c5ccc(-c6cccc(-c7cccc(-c8cccc(-c9cccc(-c%10ccc%11c(c%10)C%10(c%12ccccc%12-c%12ccccc%12%10)c%10ccccc%10-%11)c9)c8)c7)c6)cc5)n4)cc3)c2)cc1]

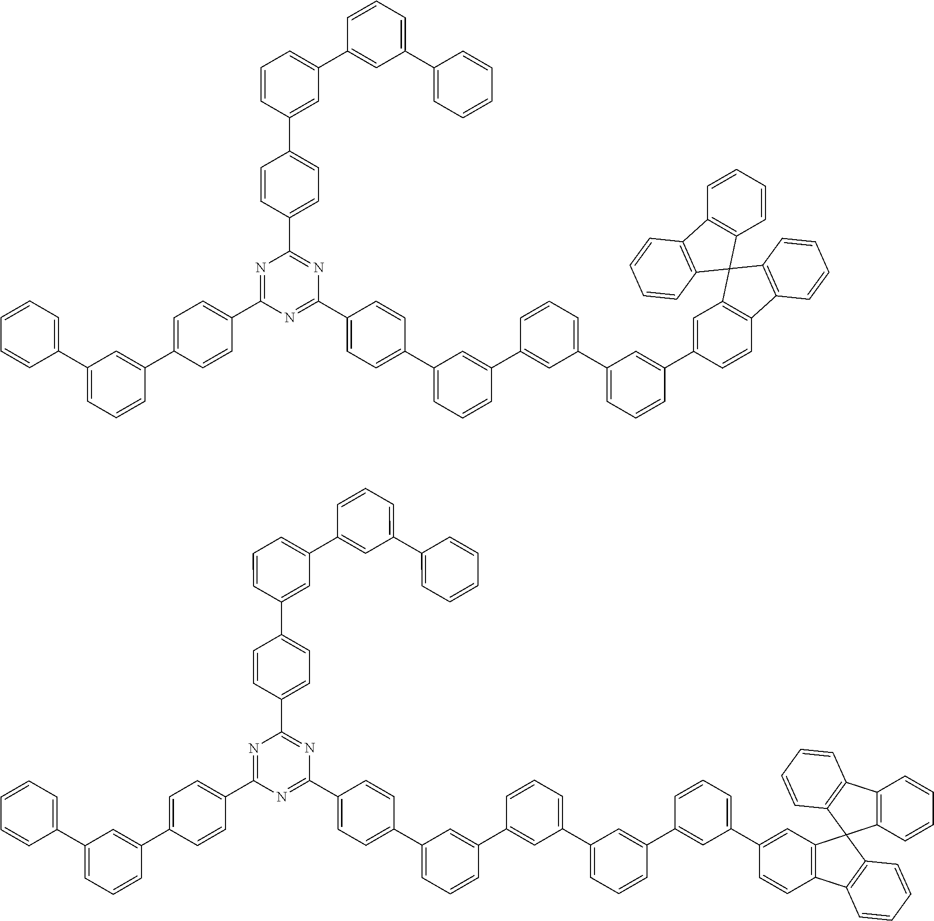 [SMILES: c1ccc(-c2cccc(-c3ccc(-c4nc(-c5ccc(-c6cccc(-c7cccc(-c8ccccc8)c7)c6)cc5)nc(-c5ccc(-c6cccc(-c7cccc(-c8cccc(-c9ccc%10c(c9)C9(c%11ccccc%11-c%11ccccc%119)c9ccccc9-%10)c8)c7)c6)cc5)n4)cc3)c2)cc1 ; c1ccc(-c2cccc(-c3ccc(-c4nc(-c5ccc(-c6cccc(-c7cccc(-c8ccccc8)c7)c6)cc5)nc(-c5ccc(-c6cccc(-c7cccc(-c8cccc(-c9cccc(-c%10ccc%11c(c%10)C%10(c%12ccccc%12-c%12ccccc%12%10)c%10ccccc%10-%11)c9)c8)c7)c6)cc5)n4)cc3)c2)cc1]

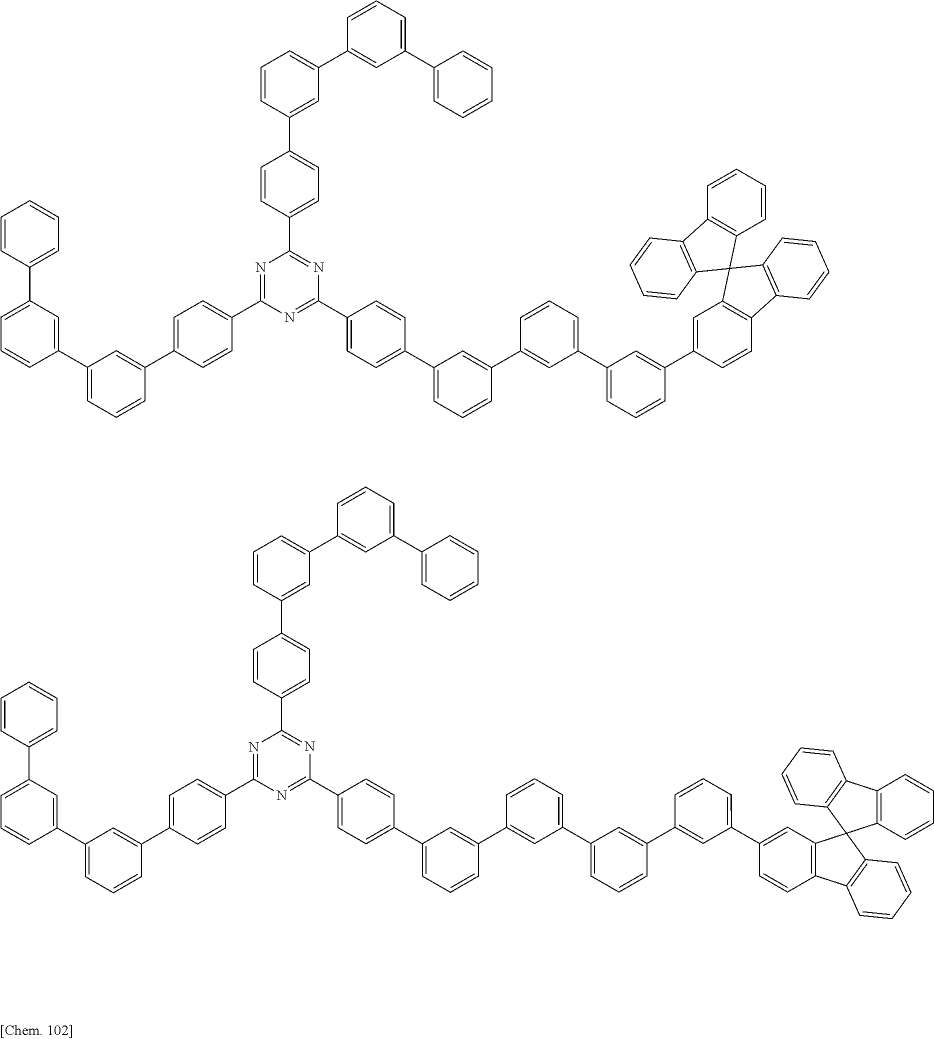 [SMILES: c1ccc(-c2cccc(-c3cccc(-c4ccc(-c5nc(-c6ccc(-c7cccc(-c8cccc(-c9ccccc9)c8)c7)cc6)nc(-c6ccc(-c7cccc(-c8cccc(-c9cccc(-c%10ccc%11c(c%10)C%10(c%12ccccc%12-c%12ccccc%12%10)c%10ccccc%10-%11)c9)c8)c7)cc6)n5)cc4)c3)c2)cc1 ; c1ccc(-c2cccc(-c3cccc(-c4ccc(-c5nc(-c6ccc(-c7cccc(-c8cccc(-c9ccccc9)c8)c7)cc6)nc(-c6ccc(-c7cccc(-c8cccc(-c9cccc(-c%10cccc(-c%11ccc%12c(c%11)C%11(c%13ccccc%13-c%13ccccc%13%11)c%11ccccc%11-%12)c%10)c9)c8)c7)cc6)n5)cc4)c3)c2)cc1]

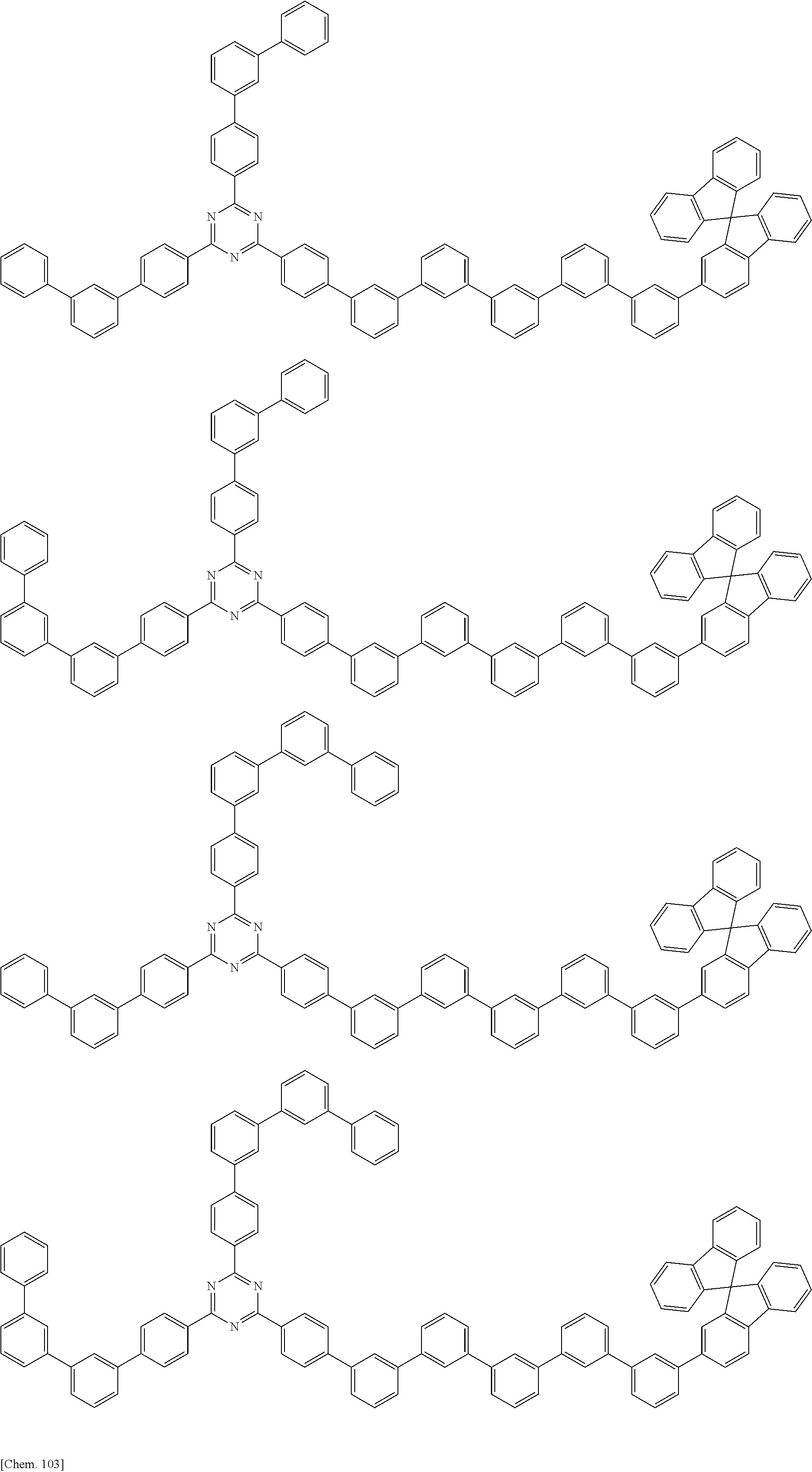

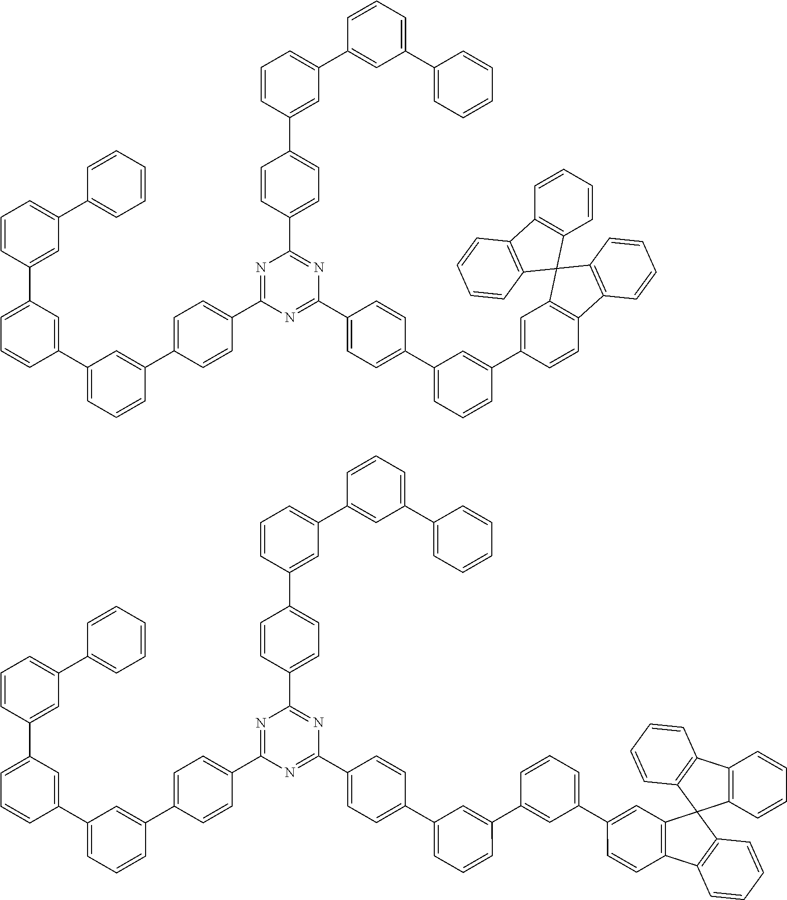 [SMILES: c1ccc(-c2cccc(-c3cccc(-c4ccc(-c5nc(-c6ccc(-c7cccc(-c8cccc(-c9cccc(-c%10ccccc%10)c9)c8)c7)cc6)nc(-c6ccc(-c7cccc(-c8ccc9c(c8)C8(c%10ccccc%10-c%10ccccc%108)c8ccccc8-9)c7)cc6)n5)cc4)c3)c2)cc1 ; c1ccc(-c2cccc(-c3cccc(-c4ccc(-c5nc(-c6ccc(-c7cccc(-c8cccc(-c9cccc(-c%10ccccc%10)c9)c8)c7)cc6)nc(-c6ccc(-c7cccc(-c8cccc(-c9ccc%10c(c9)C9(c%11ccccc%11-c%11ccccc%119)c9ccccc9-%10)c8)c7)cc6)n5)cc4)c3)c2)cc1]

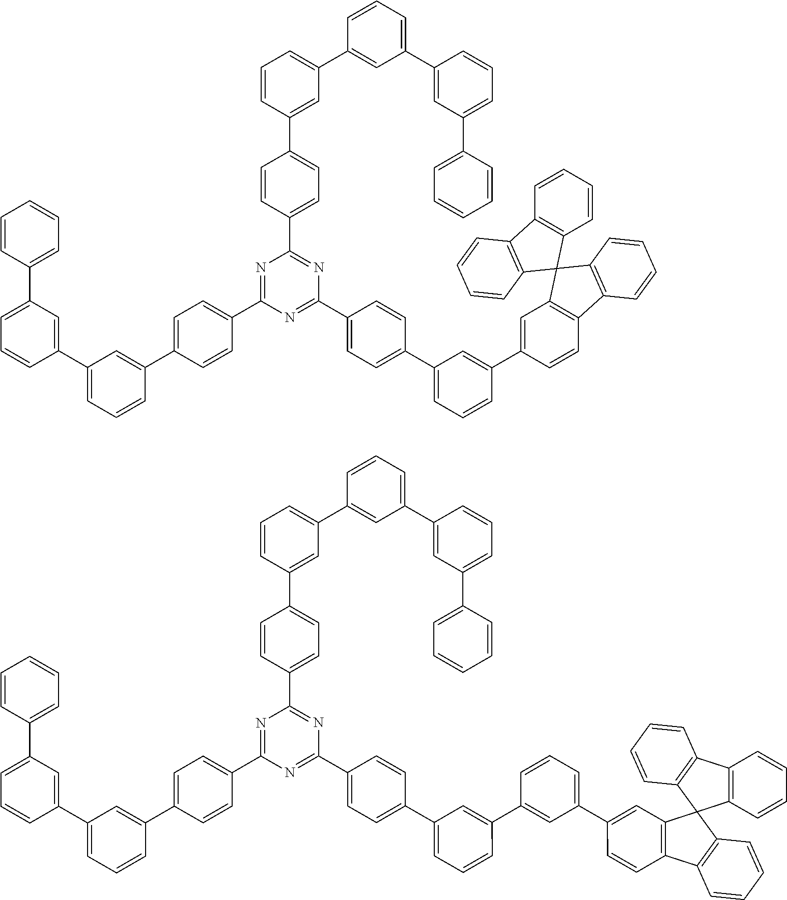 [SMILES: c1ccc(-c2cccc(-c3cccc(-c4ccc(-c5nc(-c6ccc(-c7cccc(-c8cccc(-c9cccc(-c%10ccccc%10)c9)c8)c7)cc6)nc(-c6ccc(-c7cccc(-c8ccc9c(c8)C8(c%10ccccc%10-c%10ccccc%108)c8ccccc8-9)c7)cc6)n5)cc4)c3)c2)cc1 ; c1ccc(-c2cccc(-c3cccc(-c4ccc(-c5nc(-c6ccc(-c7cccc(-c8cccc(-c9cccc(-c%10ccccc%10)c9)c8)c7)cc6)nc(-c6ccc(-c7cccc(-c8cccc(-c9ccc%10c(c9)C9(c%11ccccc%11-c%11ccccc%119)c9ccccc9-%10)c8)c7)cc6)n5)cc4)c3)c2)cc1]

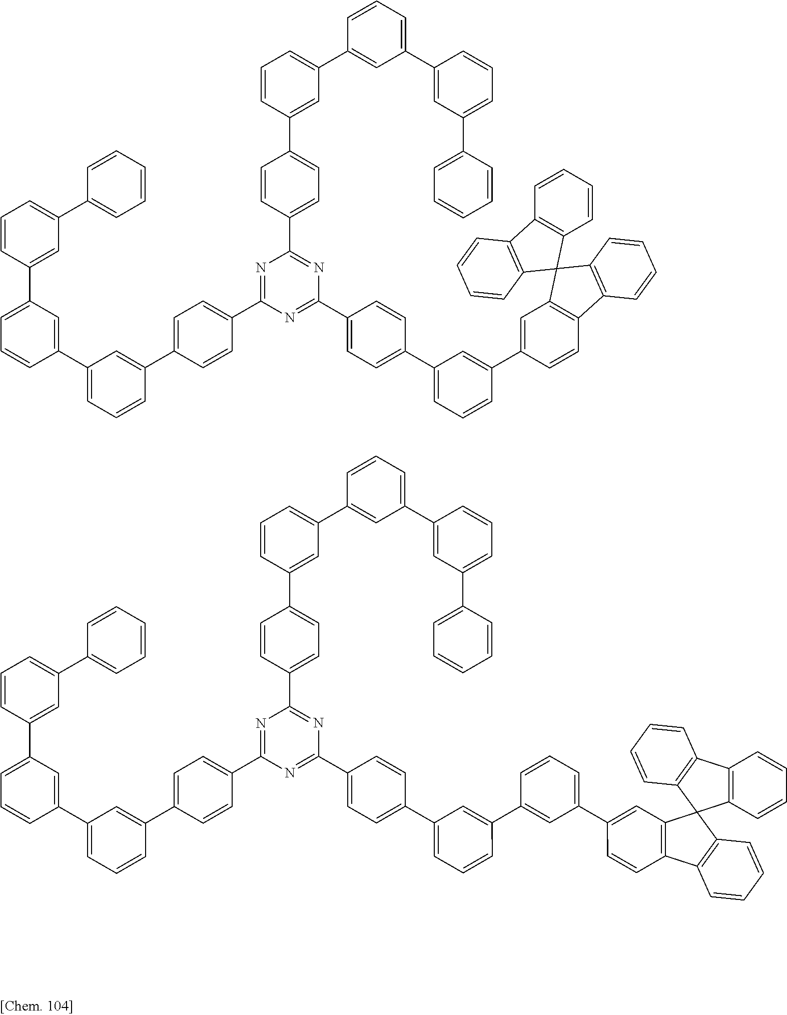 [SMILES: c1ccc(-c2cccc(-c3cccc(-c4cccc(-c5ccc(-c6nc(-c7ccc(-c8cccc(-c9cccc(-c%10cccc(-c%11ccccc%11)c%10)c9)c8)cc7)nc(-c7ccc(-c8cccc(-c9ccc%10c(c9)C9(c%11ccccc%11-c%11ccccc%119)c9ccccc9-%10)c8)cc7)n6)cc5)c4)c3)c2)cc1 ; c1ccc(-c2cccc(-c3cccc(-c4cccc(-c5ccc(-c6nc(-c7ccc(-c8cccc(-c9cccc(-c%10cccc(-c%11ccccc%11)c%10)c9)c8)cc7)nc(-c7ccc(-c8cccc(-c9cccc(-c%10ccc%11c(c%10)C%10(c%12ccccc%12-c%12ccccc%12%10)c%10ccccc%10-%11)c9)c8)cc7)n6)cc5)c4)c3)c2)cc1]

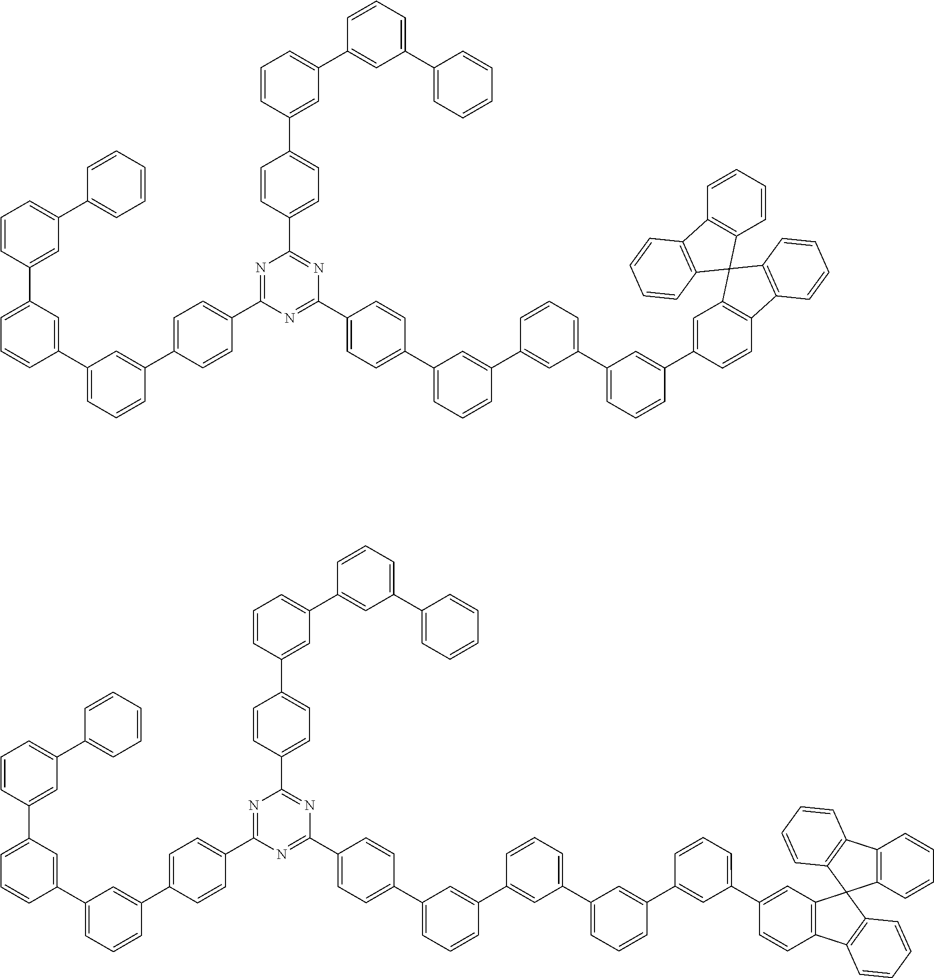 [SMILES: c1ccc(-c2cccc(-c3cccc(-c4ccc(-c5nc(-c6ccc(-c7cccc(-c8cccc(-c9cccc(-c%10ccccc%10)c9)c8)c7)cc6)nc(-c6ccc(-c7cccc(-c8cccc(-c9cccc(-c%10ccc%11c(c%10)C%10(c%12ccccc%12-c%12ccccc%12%10)c%10ccccc%10-%11)c9)c8)c7)cc6)n5)cc4)c3)c2)cc1 ; c1ccc(-c2cccc(-c3cccc(-c4ccc(-c5nc(-c6ccc(-c7cccc(-c8cccc(-c9cccc(-c%10ccccc%10)c9)c8)c7)cc6)nc(-c6ccc(-c7cccc(-c8cccc(-c9cccc(-c%10cccc(-c%11ccc%12c(c%11)C%11(c%13ccccc%13-c%13ccccc%13%11)c%11ccccc%11-%12)c%10)c9)c8)c7)cc6)n5)cc4)c3)c2)cc1]

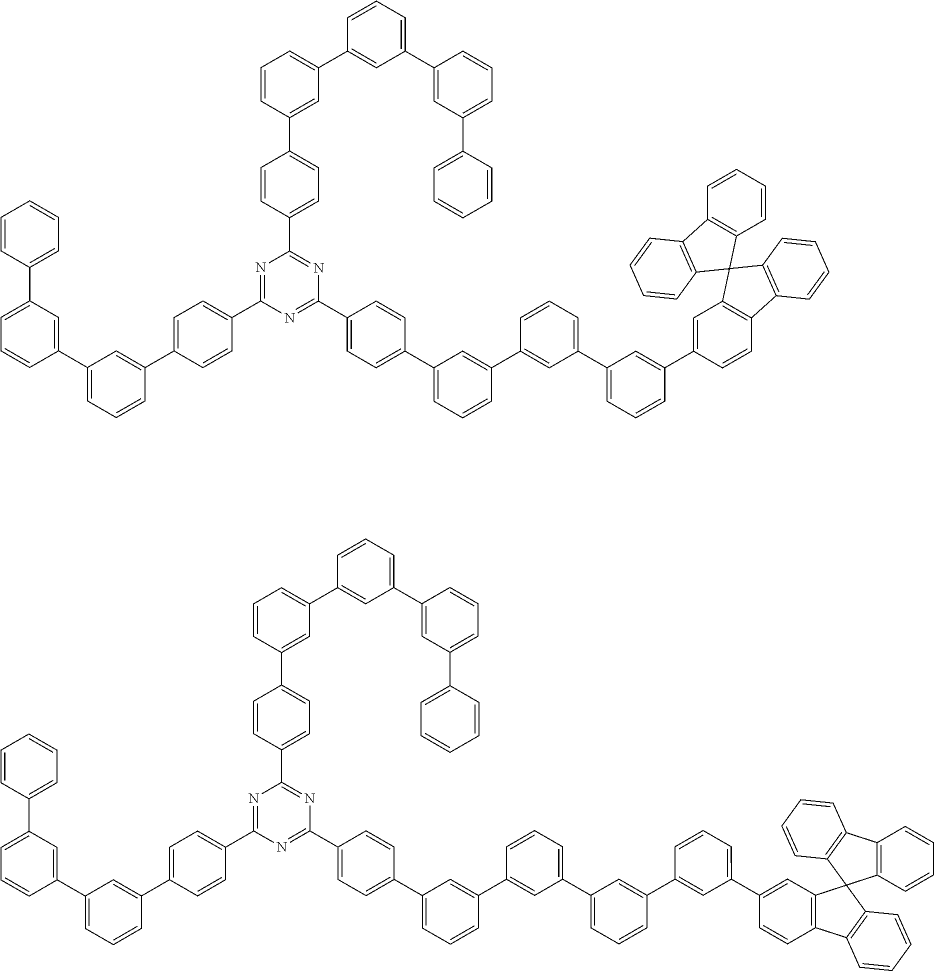 [SMILES: c1ccc(-c2cccc(-c3cccc(-c4ccc(-c5nc(-c6ccc(-c7cccc(-c8cccc(-c9cccc(-c%10ccccc%10)c9)c8)c7)cc6)nc(-c6ccc(-c7cccc(-c8cccc(-c9cccc(-c%10ccc%11c(c%10)C%10(c%12ccccc%12-c%12ccccc%12%10)c%10ccccc%10-%11)c9)c8)c7)cc6)n5)cc4)c3)c2)cc1 ; c1ccc(-c2cccc(-c3cccc(-c4ccc(-c5nc(-c6ccc(-c7cccc(-c8cccc(-c9cccc(-c%10ccccc%10)c9)c8)c7)cc6)nc(-c6ccc(-c7cccc(-c8cccc(-c9cccc(-c%10cccc(-c%11ccc%12c(c%11)C%11(c%13ccccc%13-c%13ccccc%13%11)c%11ccccc%11-%12)c%10)c9)c8)c7)cc6)n5)cc4)c3)c2)cc1]

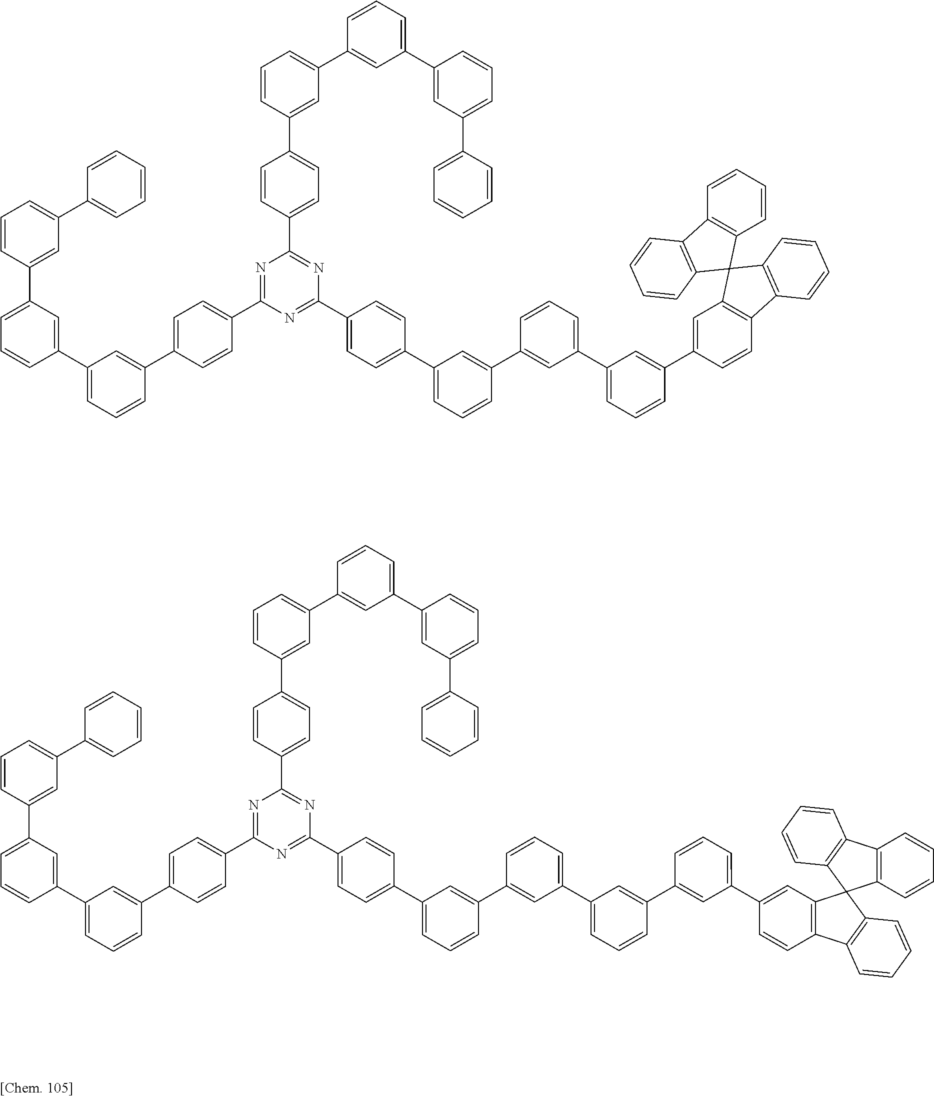

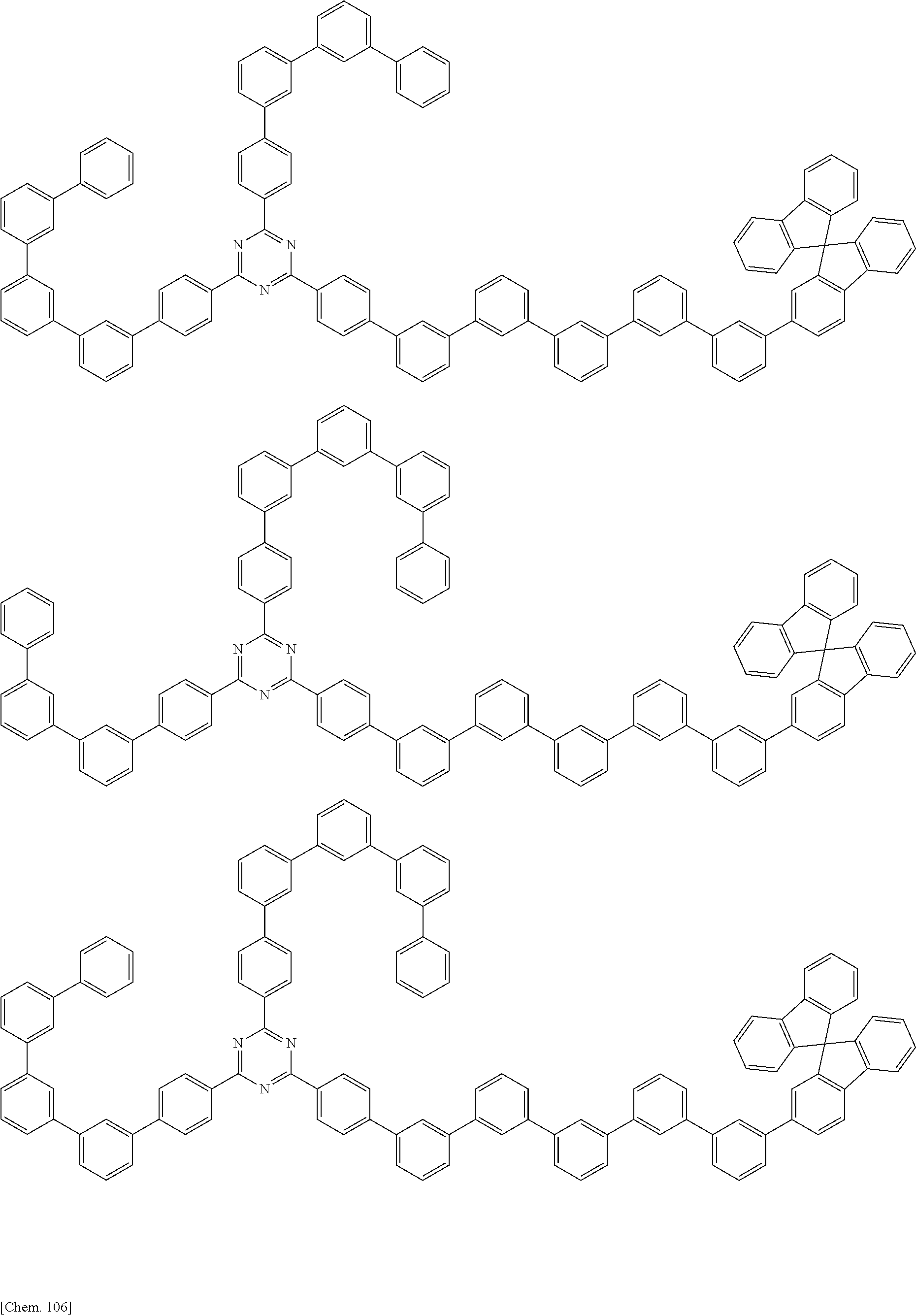

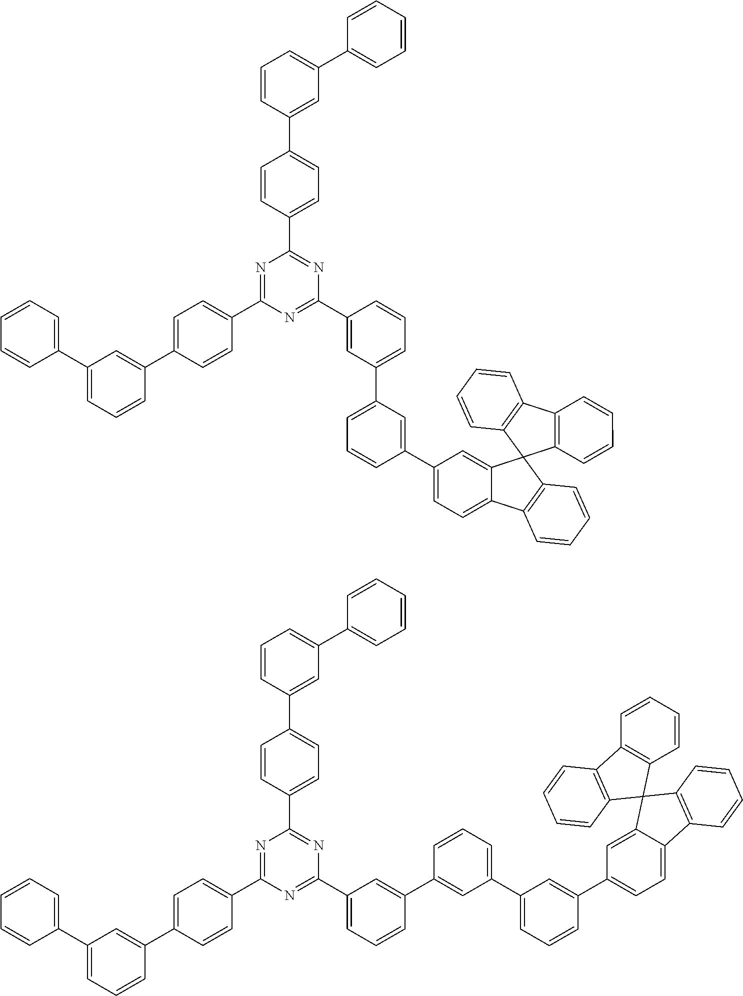 [SMILES: c1ccc(-c2cccc(-c3ccc(-c4nc(-c5ccc(-c6cccc(-c7ccccc7)c6)cc5)nc(-c5cccc(-c6cccc(-c7ccc8c(c7)C7(c9ccccc9-c9ccccc97)c7ccccc7-8)c6)c5)n4)cc3)c2)cc1 ; c1ccc(-c2cccc(-c3ccc(-c4nc(-c5ccc(-c6cccc(-c7ccccc7)c6)cc5)nc(-c5cccc(-c6cccc(-c7cccc(-c8ccc9c(c8)C8(c%10ccccc%10-c%10ccccc%108)c8ccccc8-9)c7)c6)c5)n4)cc3)c2)cc1]

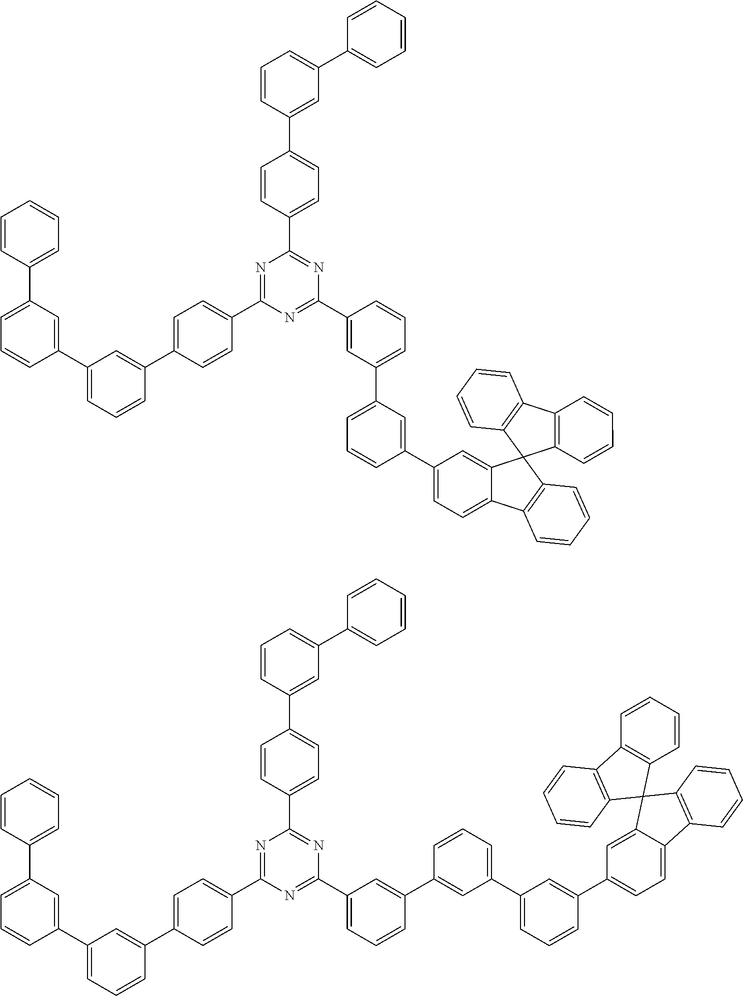 [SMILES: c1ccc(-c2cccc(-c3ccc(-c4nc(-c5ccc(-c6cccc(-c7cccc(-c8ccccc8)c7)c6)cc5)nc(-c5cccc(-c6cccc(-c7ccc8c(c7)C7(c9ccccc9-c9ccccc97)c7ccccc7-8)c6)c5)n4)cc3)c2)cc1 ; c1ccc(-c2cccc(-c3ccc(-c4nc(-c5ccc(-c6cccc(-c7cccc(-c8ccccc8)c7)c6)cc5)nc(-c5cccc(-c6cccc(-c7cccc(-c8ccc9c(c8)C8(c%10ccccc%10-c%10ccccc%108)c8ccccc8-9)c7)c6)c5)n4)cc3)c2)cc1]

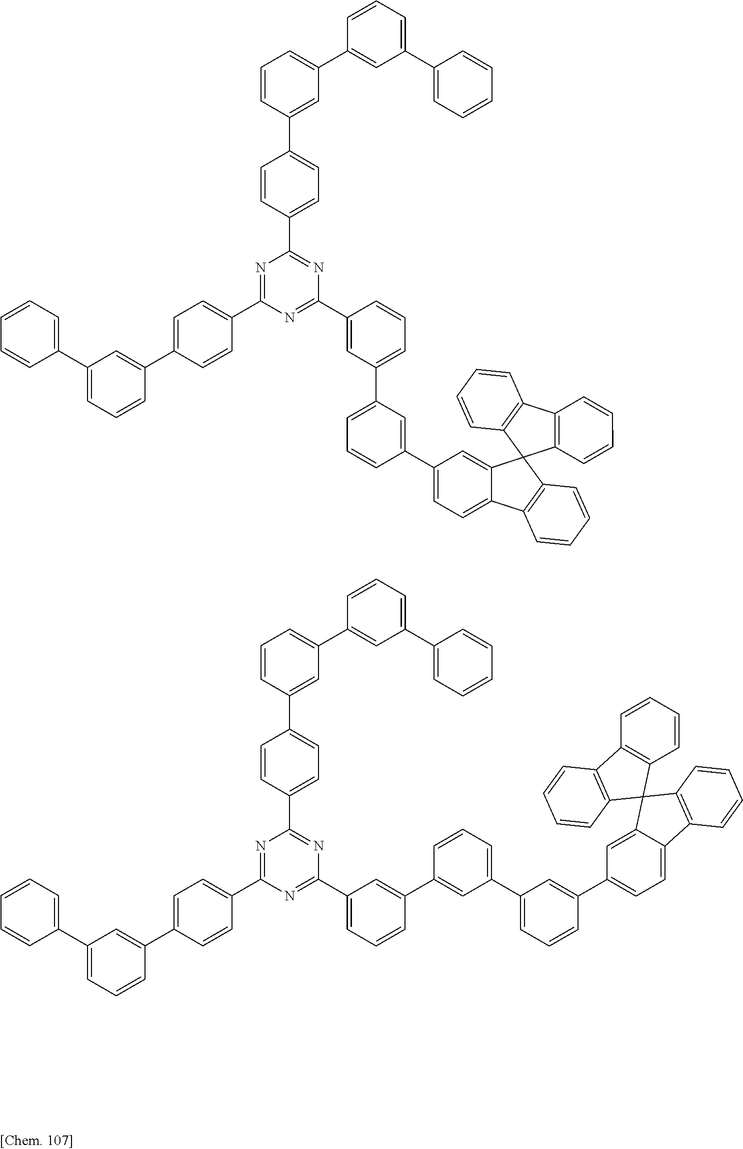 [SMILES: c1ccc(-c2cccc(-c3ccc(-c4nc(-c5ccc(-c6cccc(-c7cccc(-c8ccccc8)c7)c6)cc5)nc(-c5cccc(-c6cccc(-c7ccc8c(c7)C7(c9ccccc9-c9ccccc97)c7ccccc7-8)c6)c5)n4)cc3)c2)cc1 ; c1ccc(-c2cccc(-c3ccc(-c4nc(-c5ccc(-c6cccc(-c7cccc(-c8ccccc8)c7)c6)cc5)nc(-c5cccc(-c6cccc(-c7cccc(-c8ccc9c(c8)C8(c%10ccccc%10-c%10ccccc%108)c8ccccc8-9)c7)c6)c5)n4)cc3)c2)cc1]

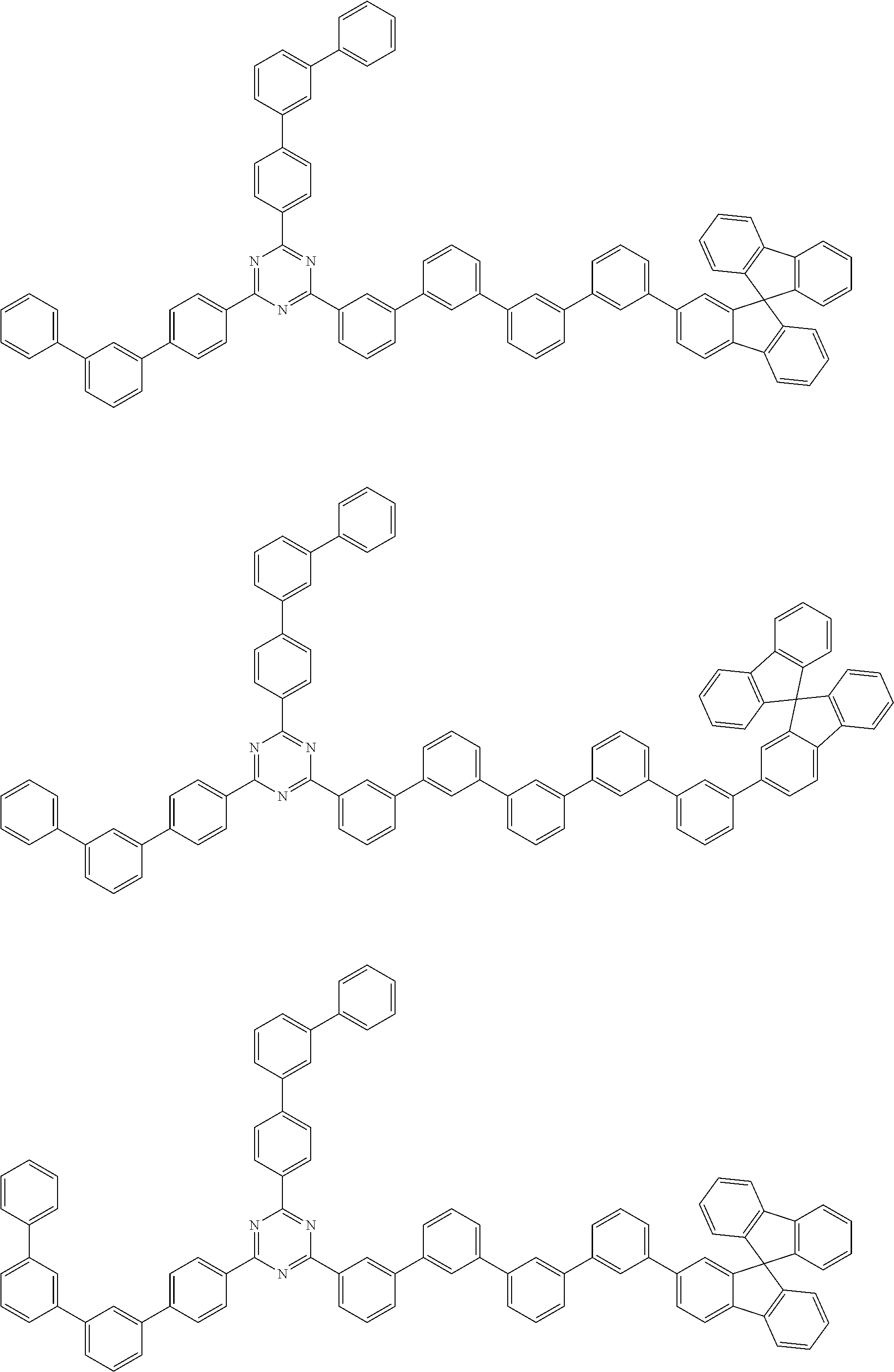

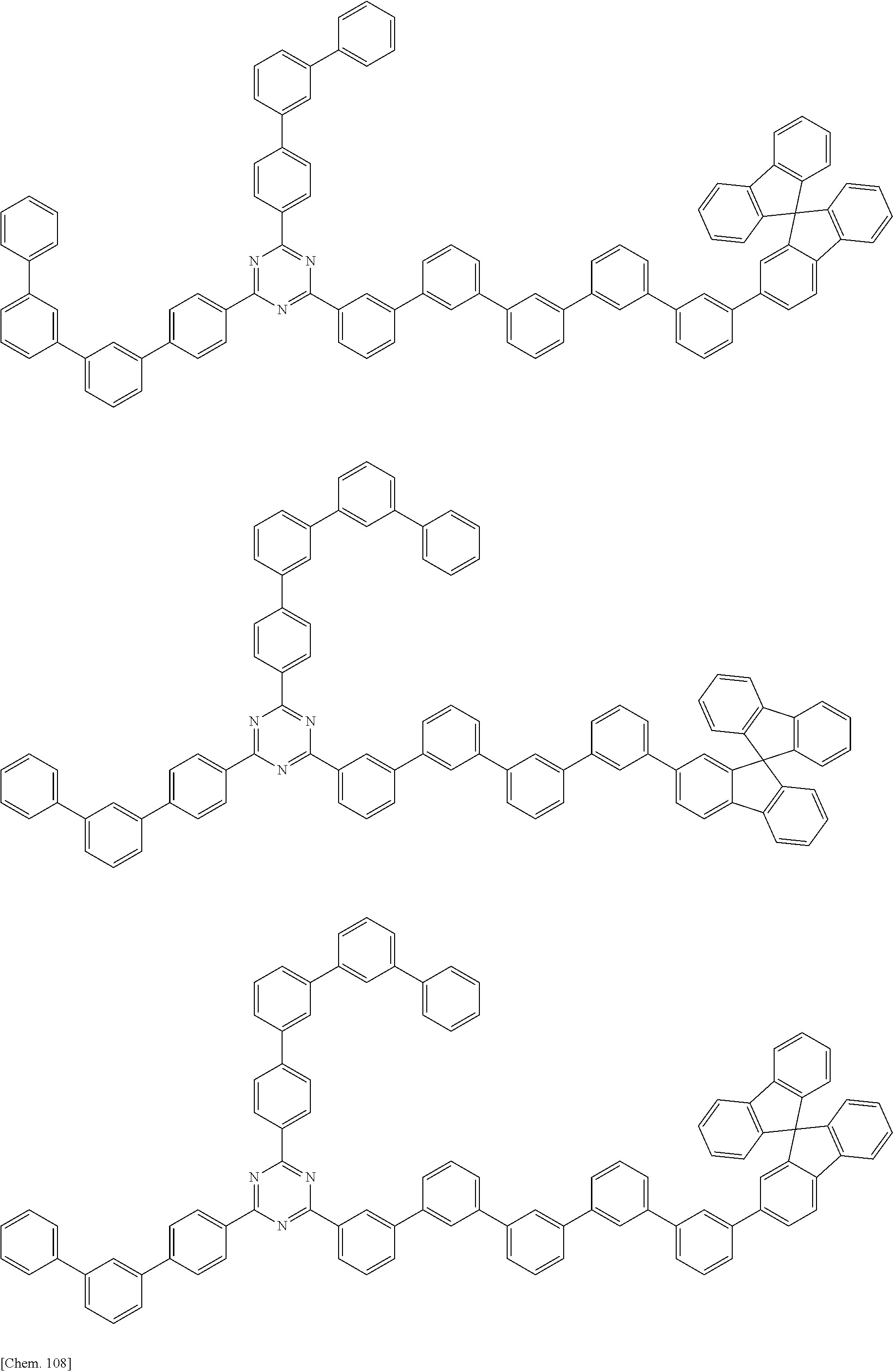

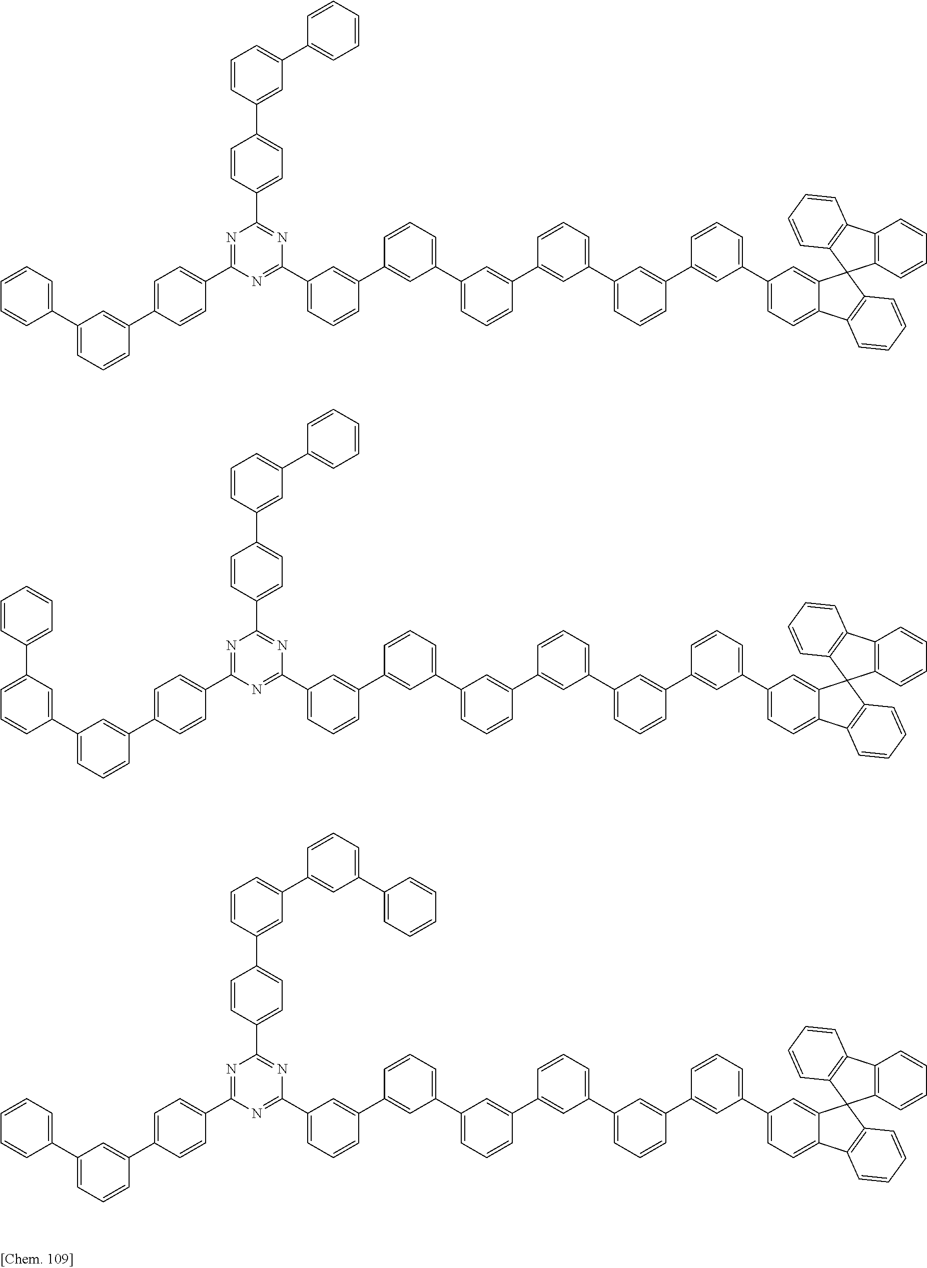

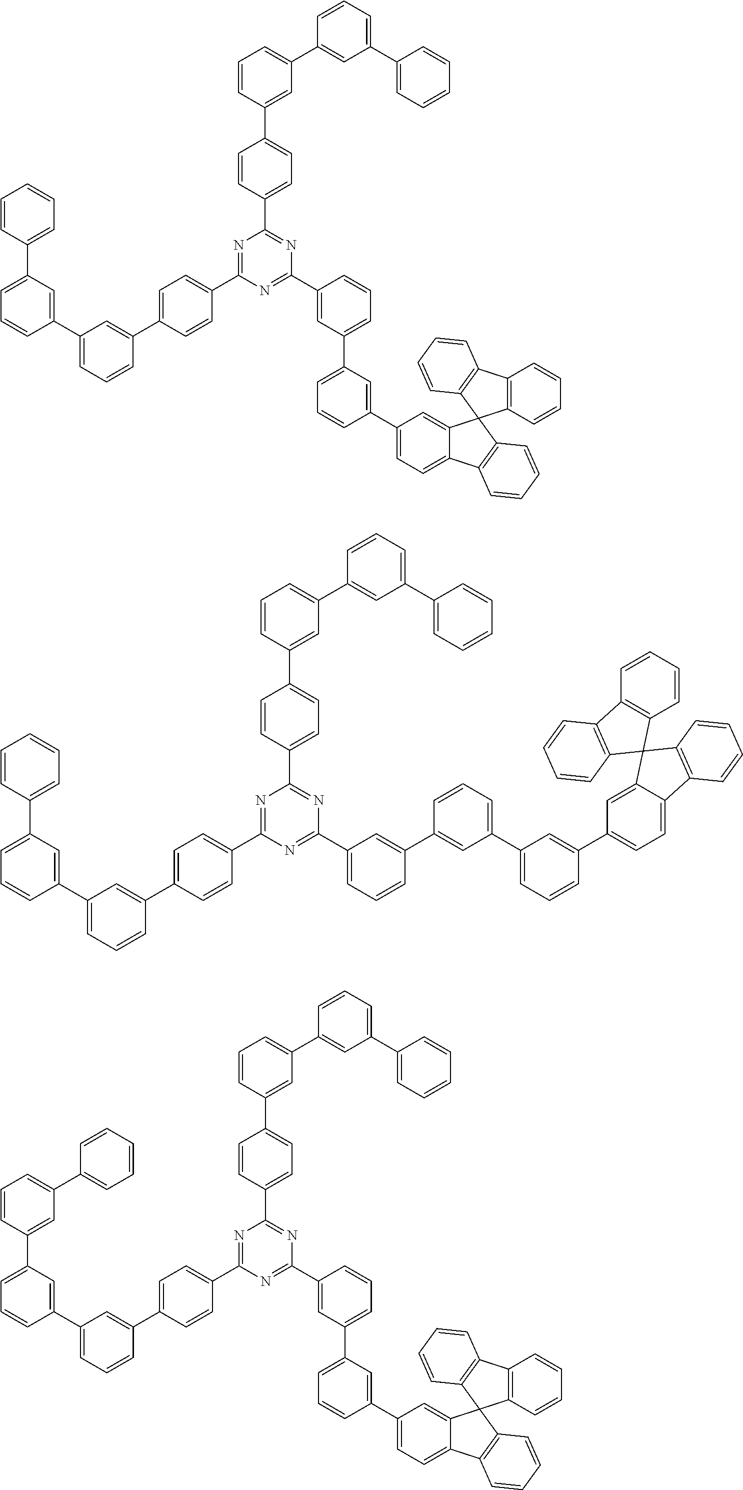

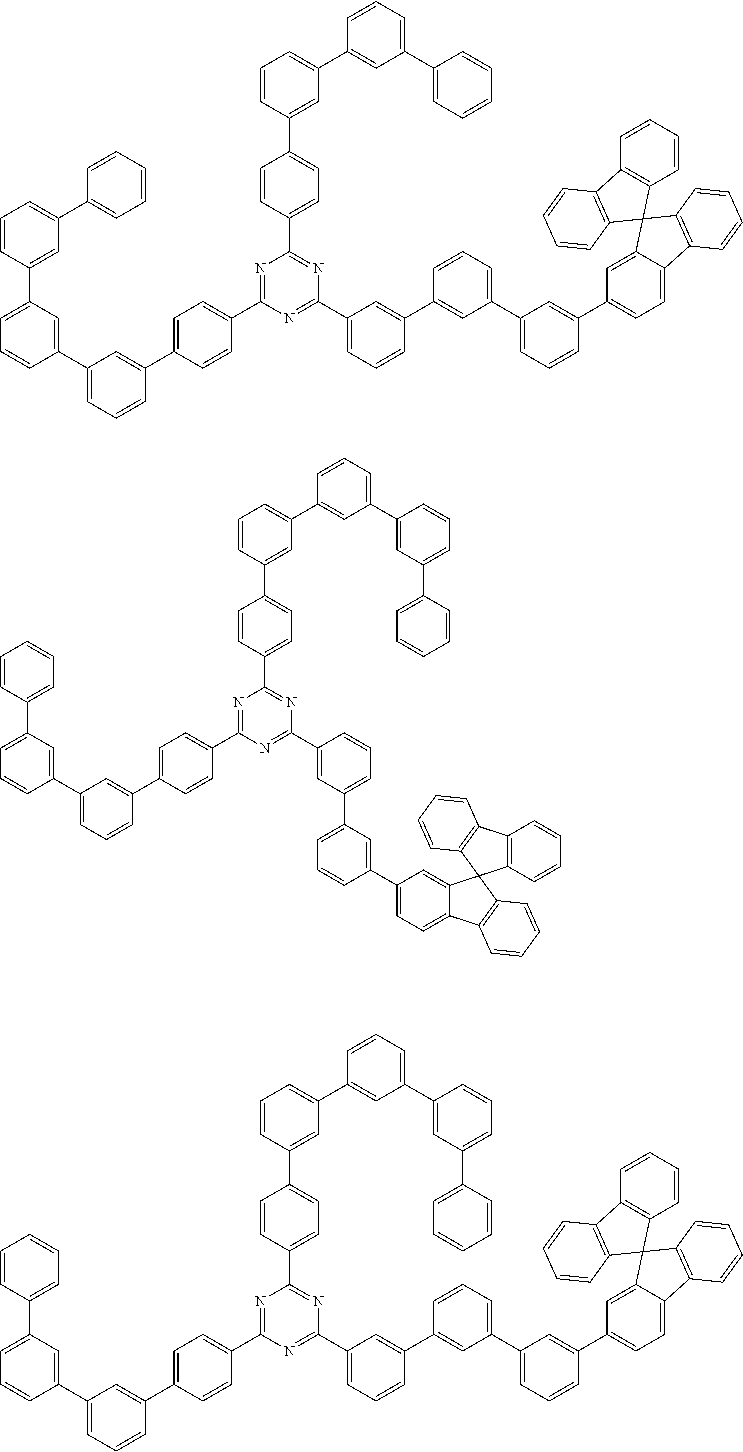

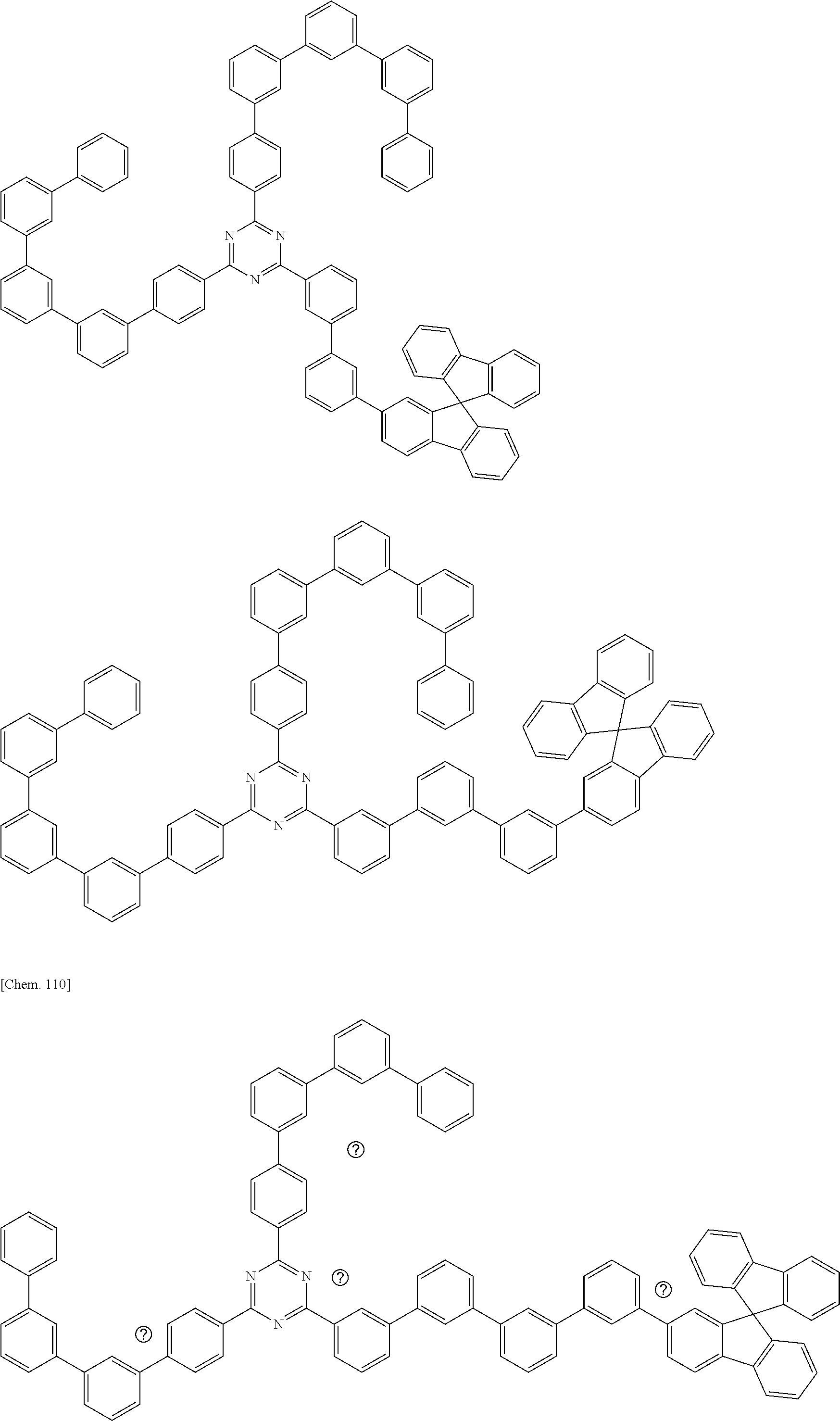

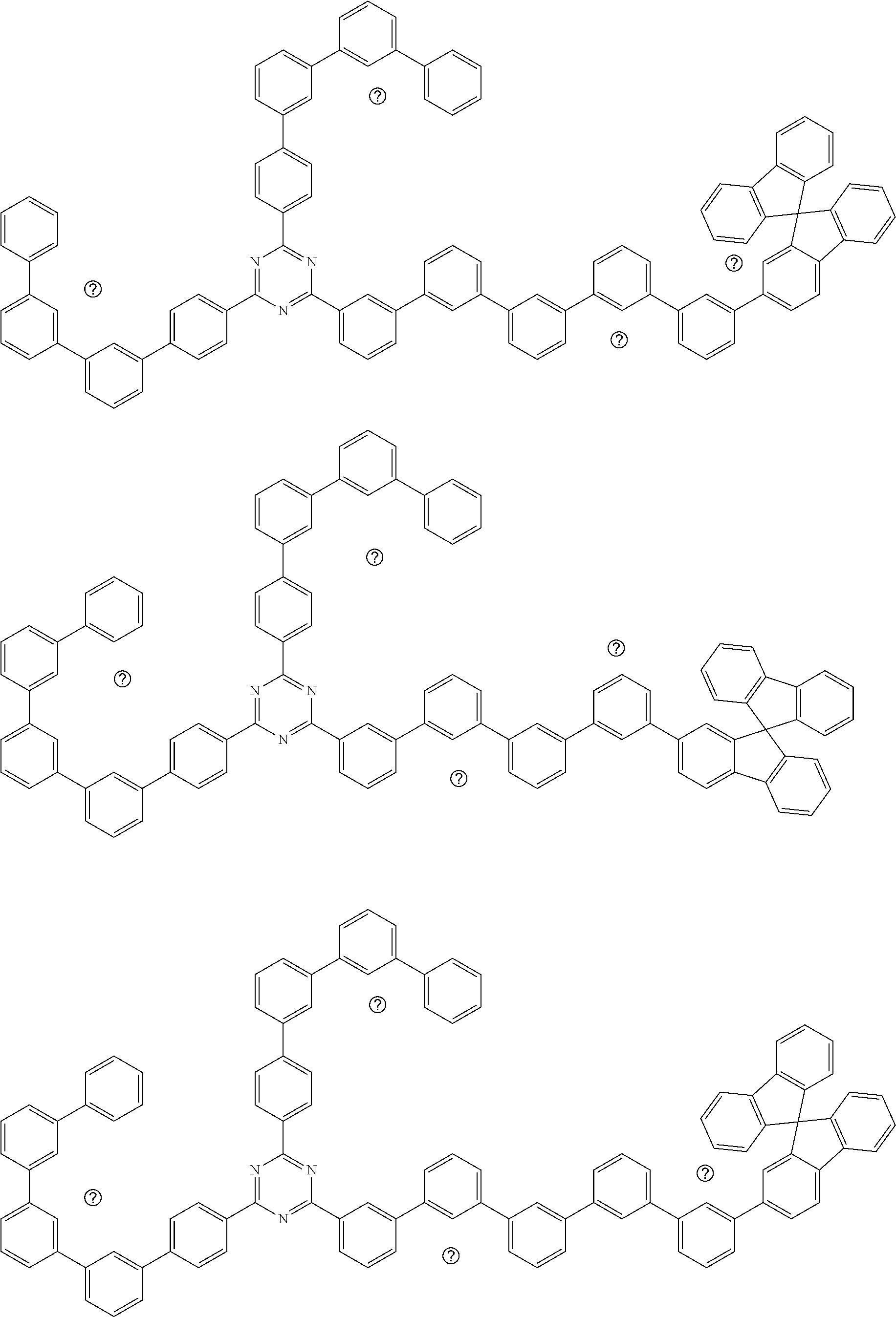

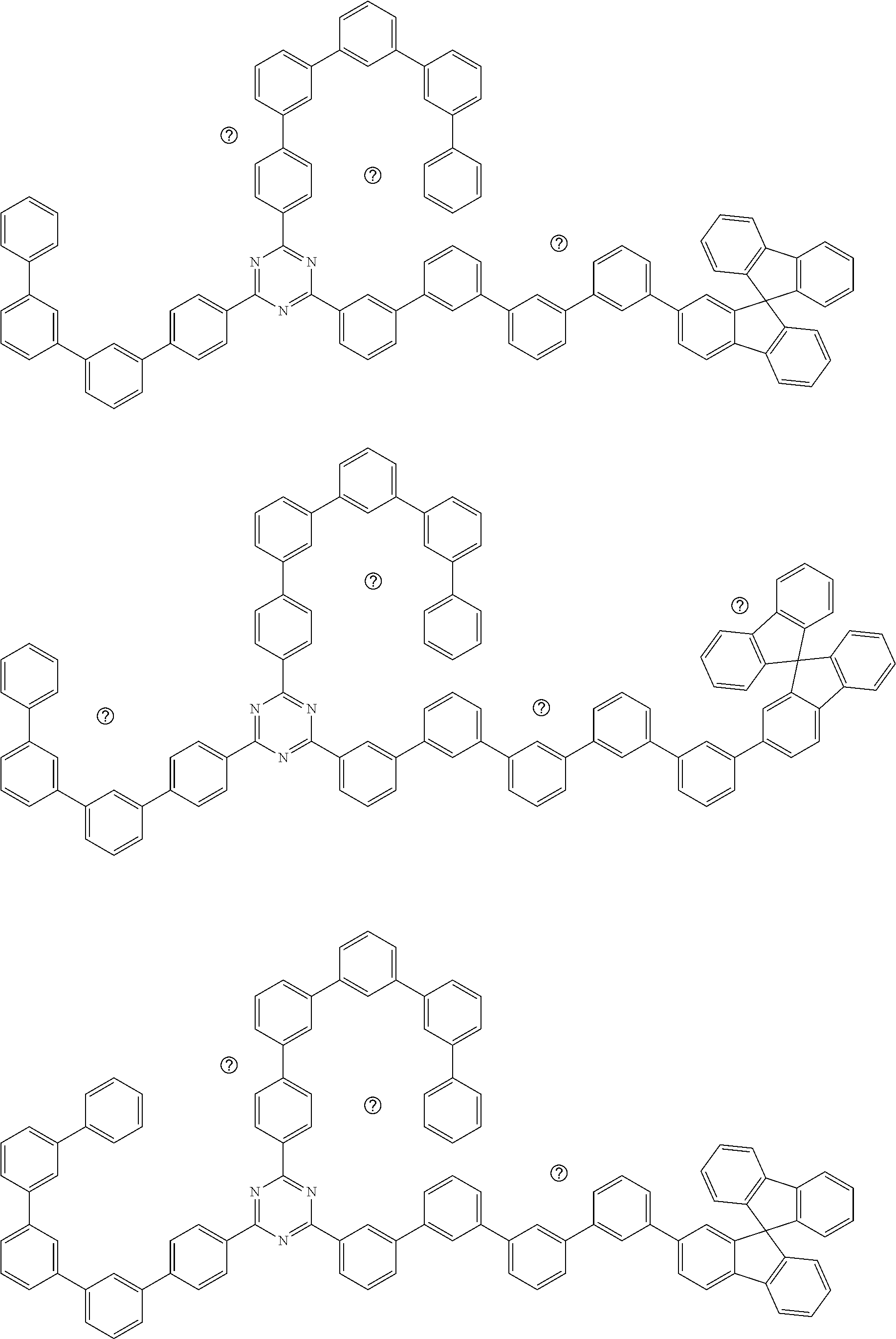

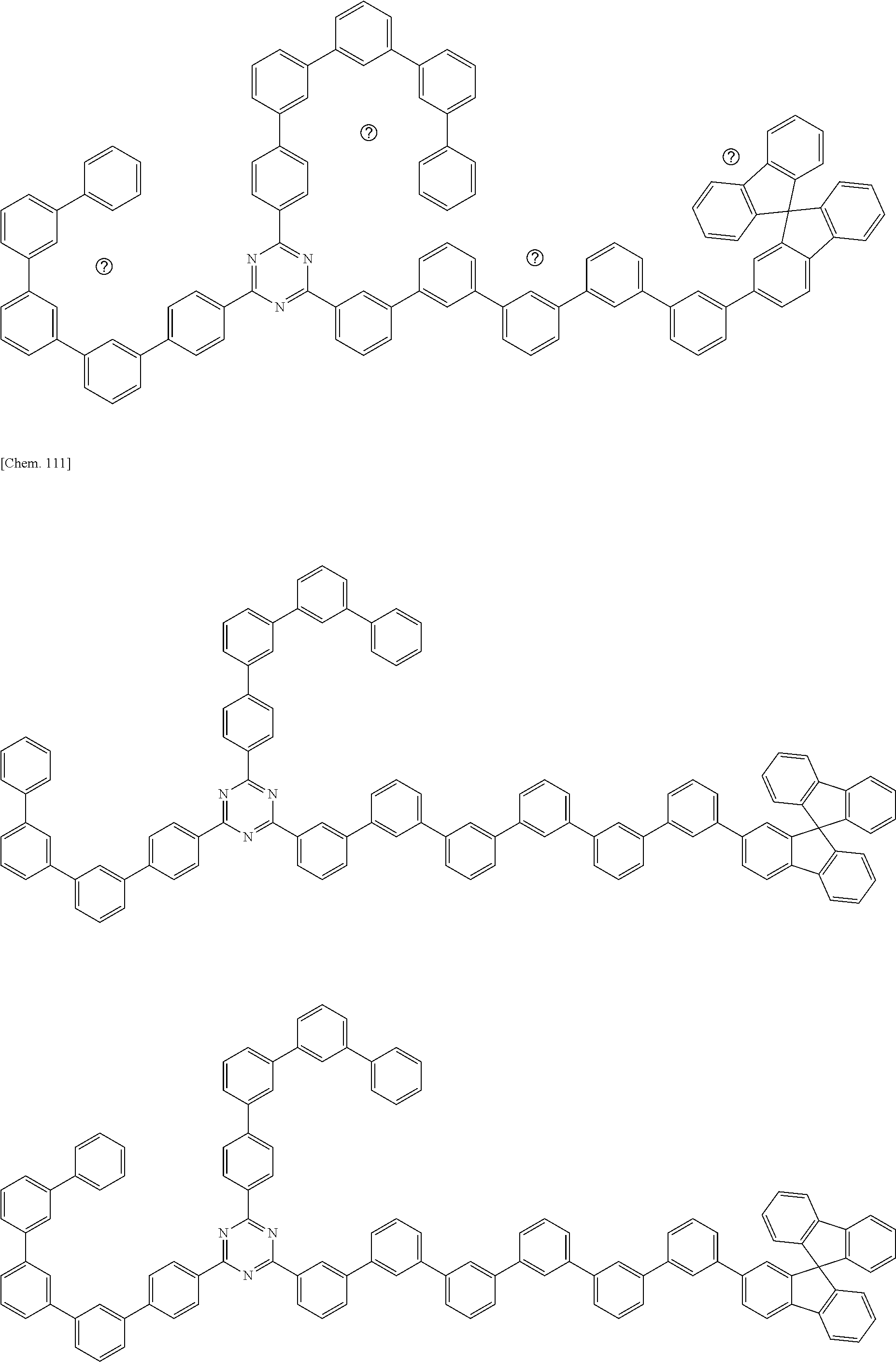

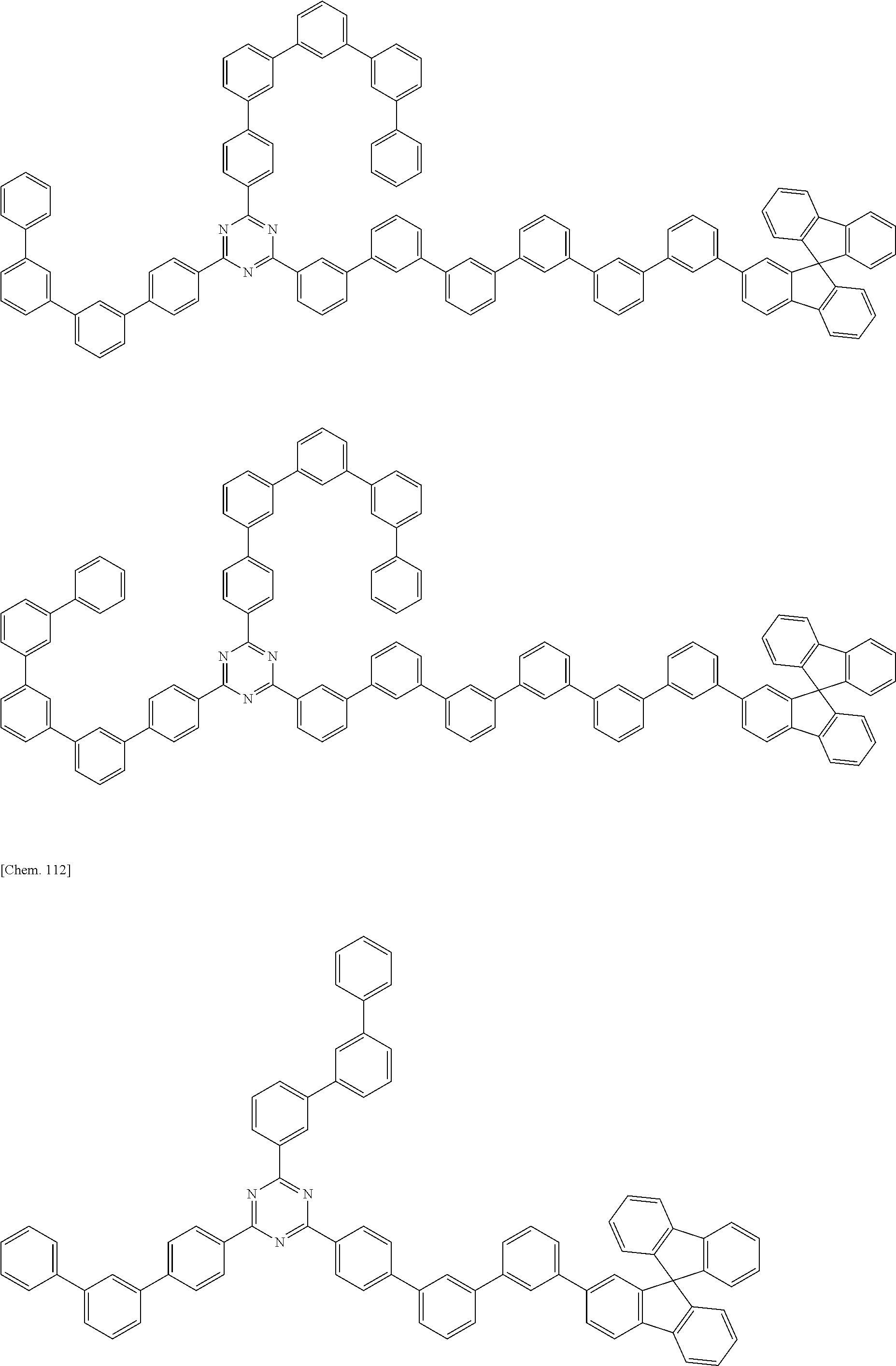

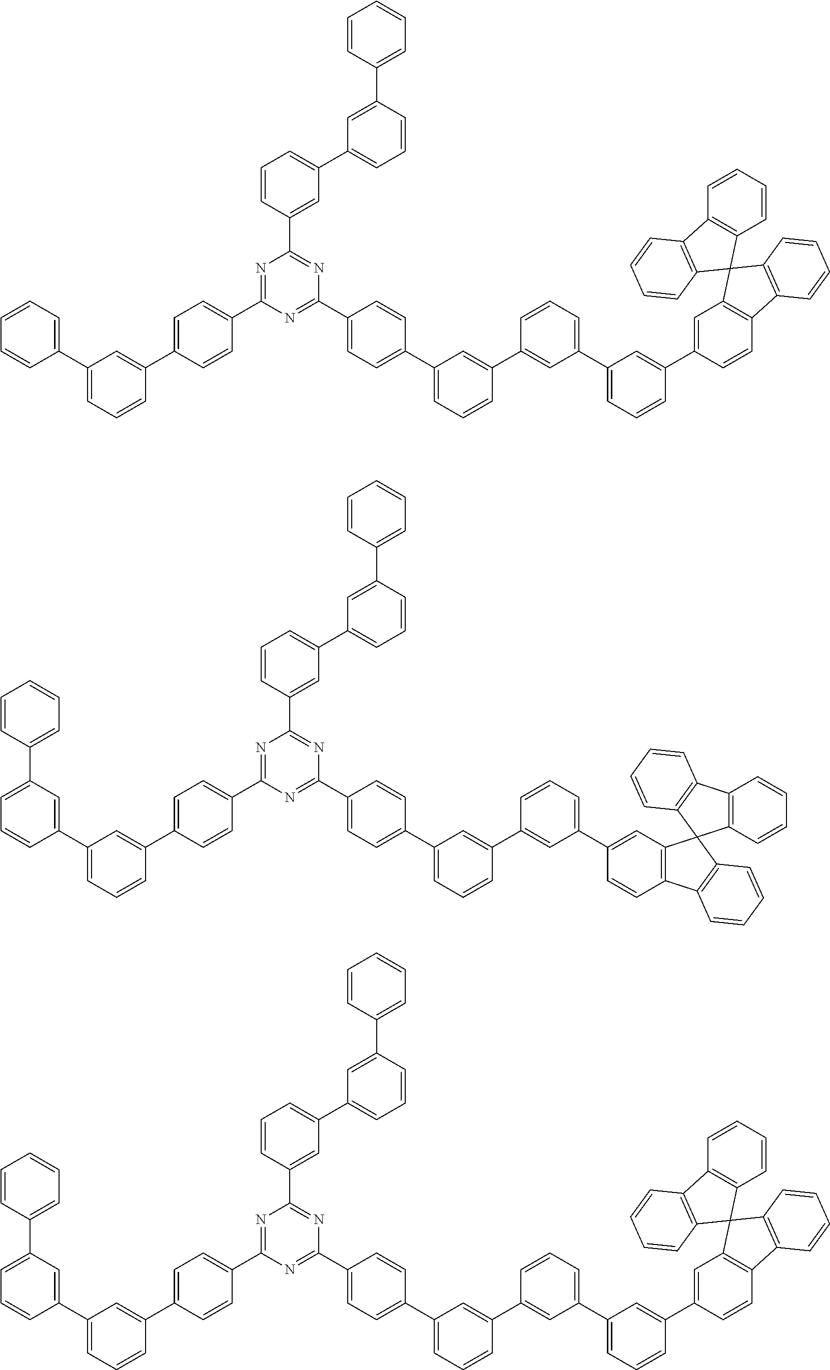

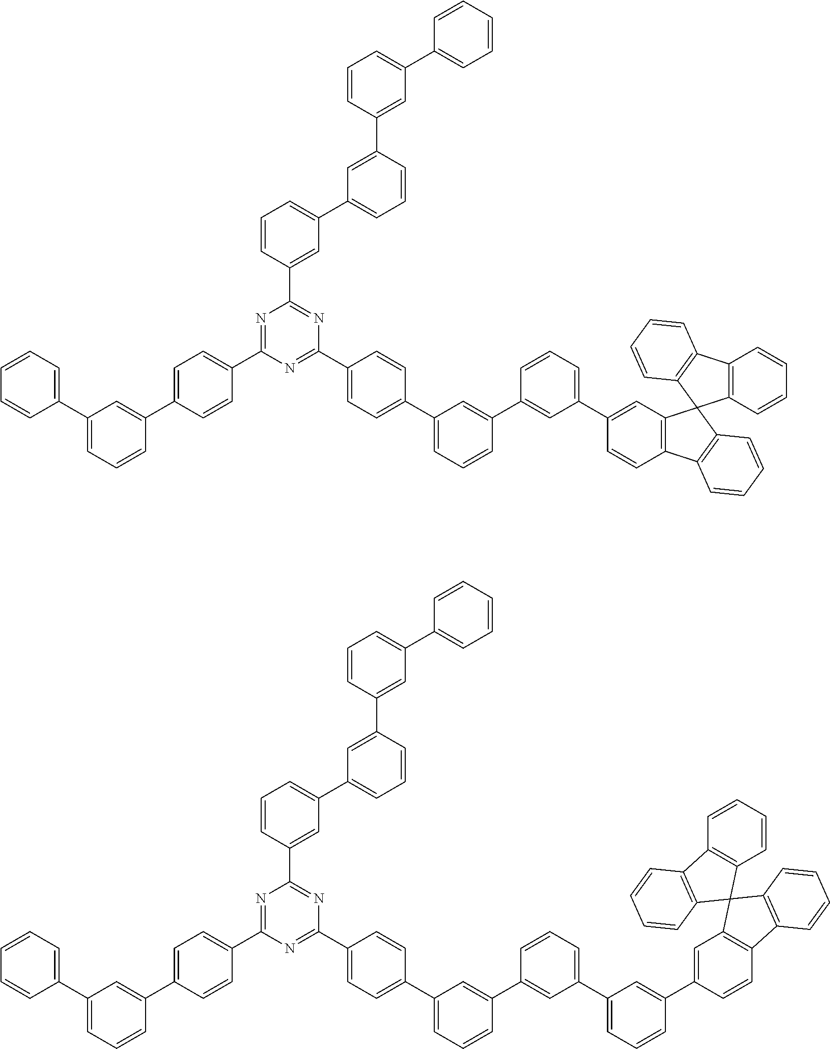 [SMILES: c1ccc(-c2cccc(-c3ccc(-c4nc(-c5ccc(-c6cccc(-c7cccc(-c8ccc9c(c8)C8(c%10ccccc%10-c%10ccccc%108)c8ccccc8-9)c7)c6)cc5)nc(-c5cccc(-c6cccc(-c7cccc(-c8ccccc8)c7)c6)c5)n4)cc3)c2)cc1 ; c1ccc(-c2cccc(-c3ccc(-c4nc(-c5ccc(-c6cccc(-c7cccc(-c8cccc(-c9ccc%10c(c9)C9(c%11ccccc%11-c%11ccccc%119)c9ccccc9-%10)c8)c7)c6)cc5)nc(-c5cccc(-c6cccc(-c7cccc(-c8ccccc8)c7)c6)c5)n4)cc3)c2)cc1]

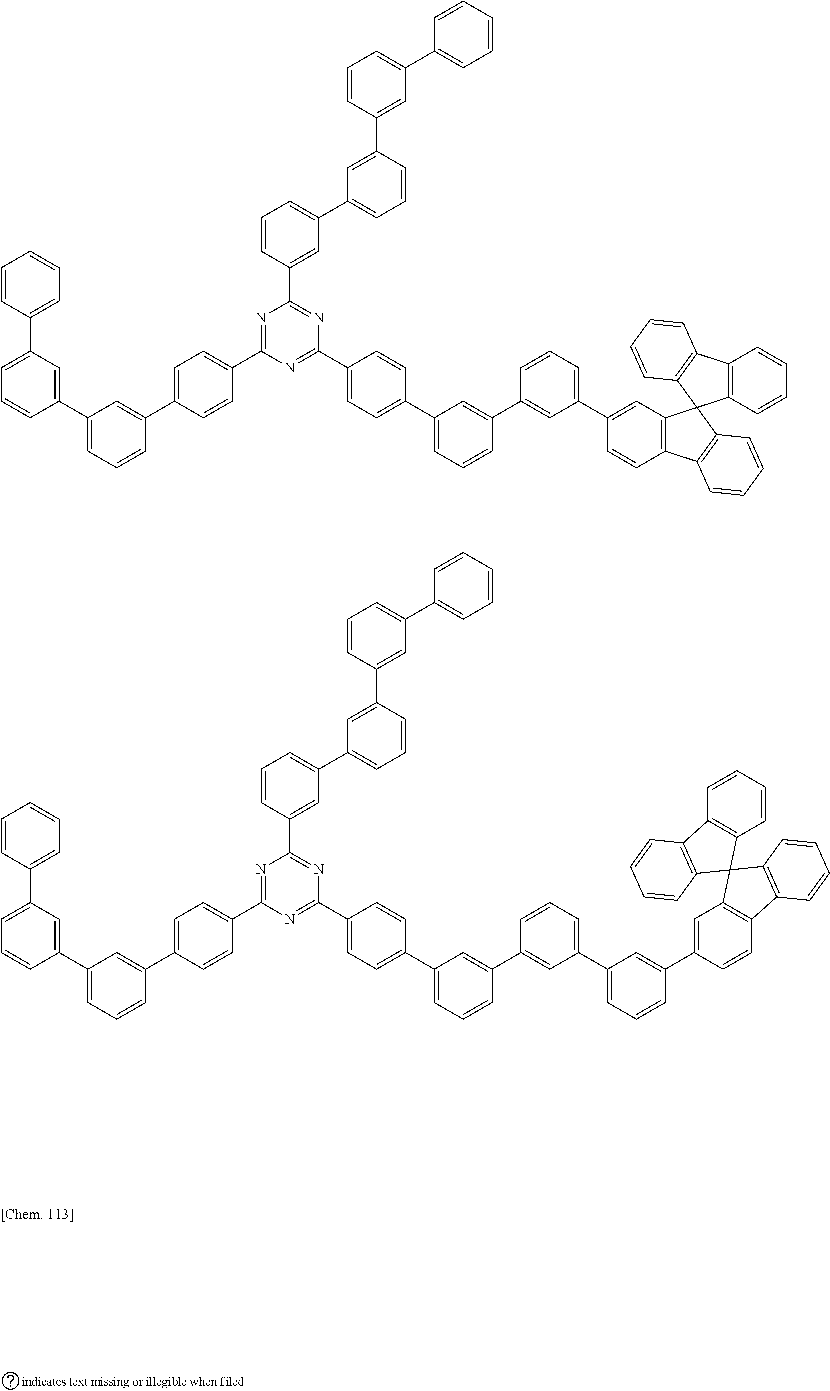 [SMILES: c1ccc(-c2cccc(-c3cccc(-c4ccc(-c5nc(-c6ccc(-c7cccc(-c8cccc(-c9ccc%10c(c9)C9(c%11ccccc%11-c%11ccccc%119)c9ccccc9-%10)c8)c7)cc6)nc(-c6cccc(-c7cccc(-c8cccc(-c9ccccc9)c8)c7)c6)n5)cc4)c3)c2)cc1 ; c1ccc(-c2cccc(-c3cccc(-c4ccc(-c5nc(-c6ccc(-c7cccc(-c8cccc(-c9cccc(-c%10ccc%11c(c%10)C%10(c%12ccccc%12-c%12ccccc%12%10)c%10ccccc%10-%11)c9)c8)c7)cc6)nc(-c6cccc(-c7cccc(-c8cccc(-c9ccccc9)c8)c7)c6)n5)cc4)c3)c2)cc1]

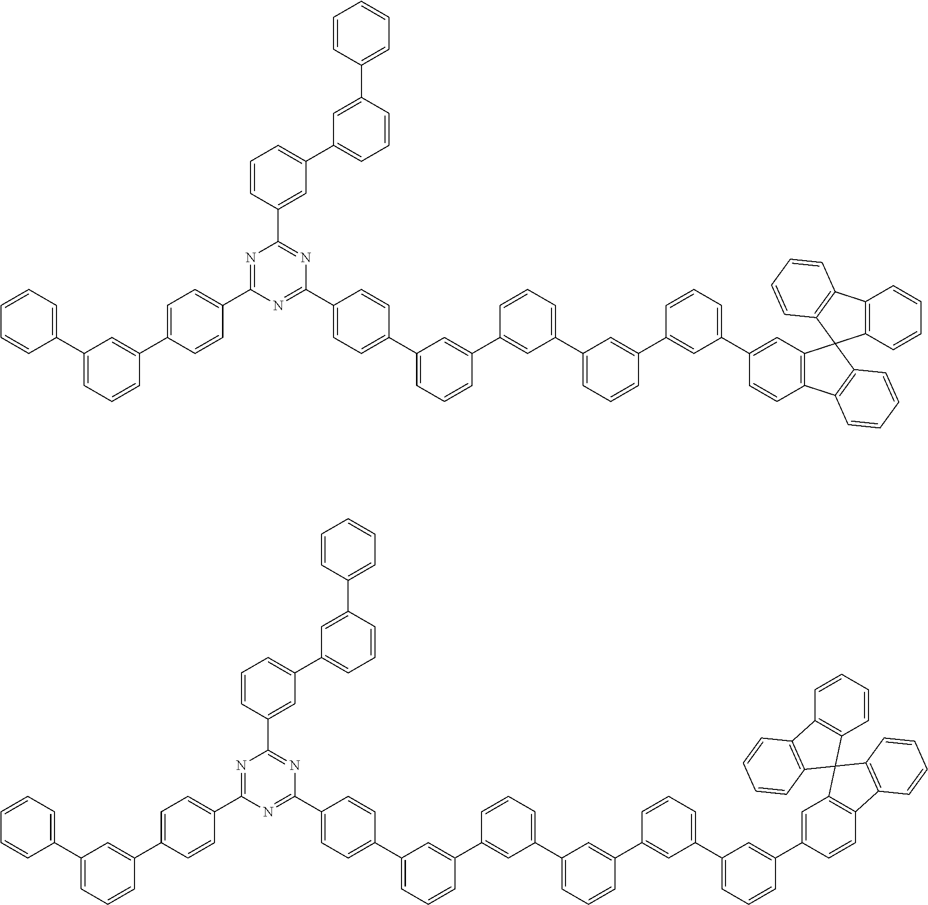 [SMILES: c1ccc(-c2cccc(-c3ccc(-c4nc(-c5ccc(-c6cccc(-c7cccc(-c8cccc(-c9cccc(-c%10ccc%11c(c%10)C%10(c%12ccccc%12-c%12ccccc%12%10)c%10ccccc%10-%11)c9)c8)c7)c6)cc5)nc(-c5cccc(-c6cccc(-c7ccccc7)c6)c5)n4)cc3)c2)cc1 ; c1ccc(-c2cccc(-c3ccc(-c4nc(-c5ccc(-c6cccc(-c7cccc(-c8cccc(-c9cccc(-c%10cccc(-c%11ccc%12c(c%11)C%11(c%13ccccc%13-c%13ccccc%13%11)c%11ccccc%11-%12)c%10)c9)c8)c7)c6)cc5)nc(-c5cccc(-c6cccc(-c7ccccc7)c6)c5)n4)cc3)c2)cc1]

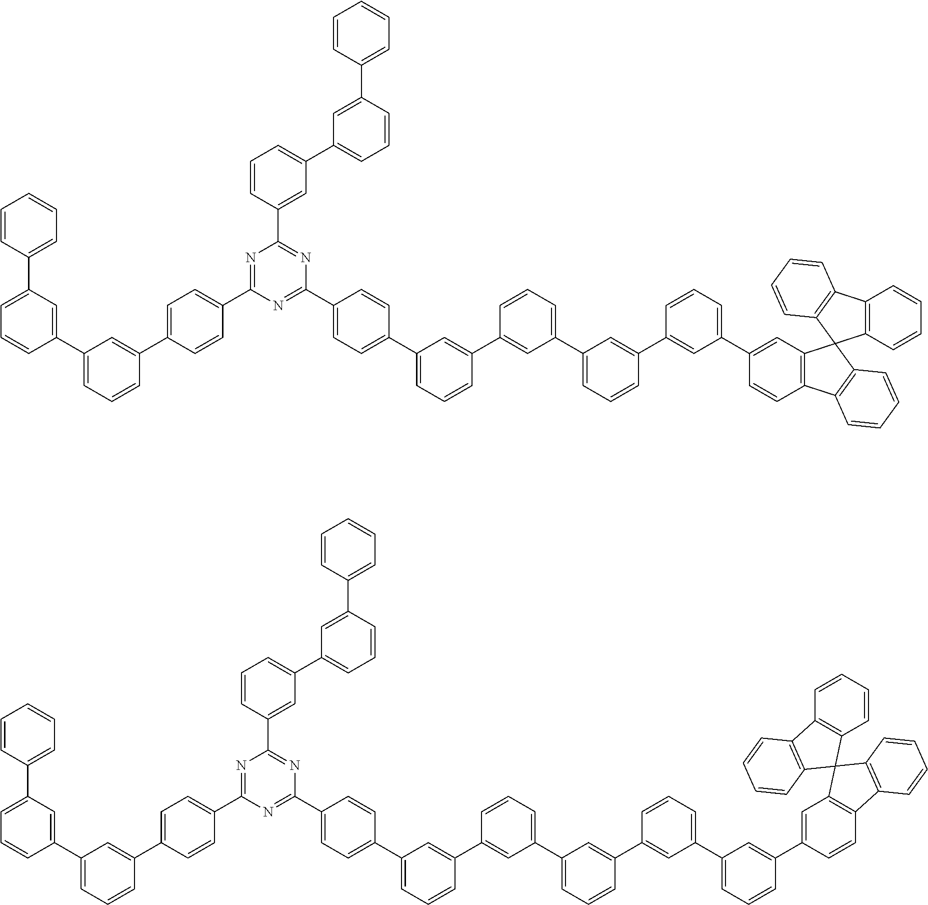 [SMILES: c1ccc(-c2cccc(-c3cccc(-c4ccc(-c5nc(-c6ccc(-c7cccc(-c8cccc(-c9cccc(-c%10cccc(-c%11ccc%12c(c%11)C%11(c%13ccccc%13-c%13ccccc%13%11)c%11ccccc%11-%12)c%10)c9)c8)c7)cc6)nc(-c6cccc(-c7cccc(-c8ccccc8)c7)c6)n5)cc4)c3)c2)cc1 ; c1ccc(-c2cccc(-c3cccc(-c4ccc(-c5nc(-c6ccc(-c7cccc(-c8cccc(-c9cccc(-c%10cccc(-c%11cccc(-c%12ccc%13c(c%12)C%12(c%14ccccc%14-c%14ccccc%14%12)c%12ccccc%12-%13)c%11)c%10)c9)c8)c7)cc6)nc(-c6cccc(-c7cccc(-c8ccccc8)c7)c6)n5)cc4)c3)c2)cc1]

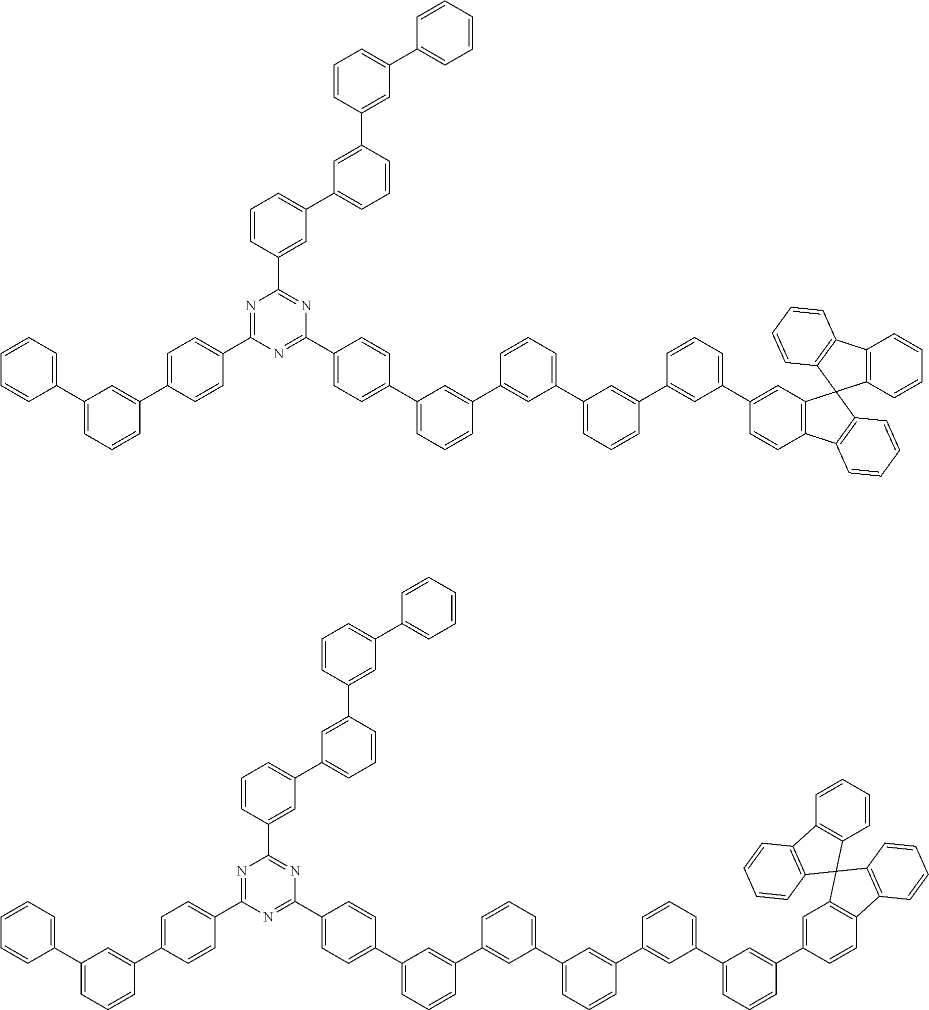 [SMILES: c1ccc(-c2cccc(-c3ccc(-c4nc(-c5ccc(-c6cccc(-c7cccc(-c8cccc(-c9cccc(-c%10ccc%11c(c%10)C%10(c%12ccccc%12-c%12ccccc%12%10)c%10ccccc%10-%11)c9)c8)c7)c6)cc5)nc(-c5cccc(-c6cccc(-c7cccc(-c8ccccc8)c7)c6)c5)n4)cc3)c2)cc1 ; c1ccc(-c2cccc(-c3ccc(-c4nc(-c5ccc(-c6cccc(-c7cccc(-c8cccc(-c9cccc(-c%10cccc(-c%11ccc%12c(c%11)C%11(c%13ccccc%13-c%13ccccc%13%11)c%11ccccc%11-%12)c%10)c9)c8)c7)c6)cc5)nc(-c5cccc(-c6cccc(-c7cccc(-c8ccccc8)c7)c6)c5)n4)cc3)c2)cc1]

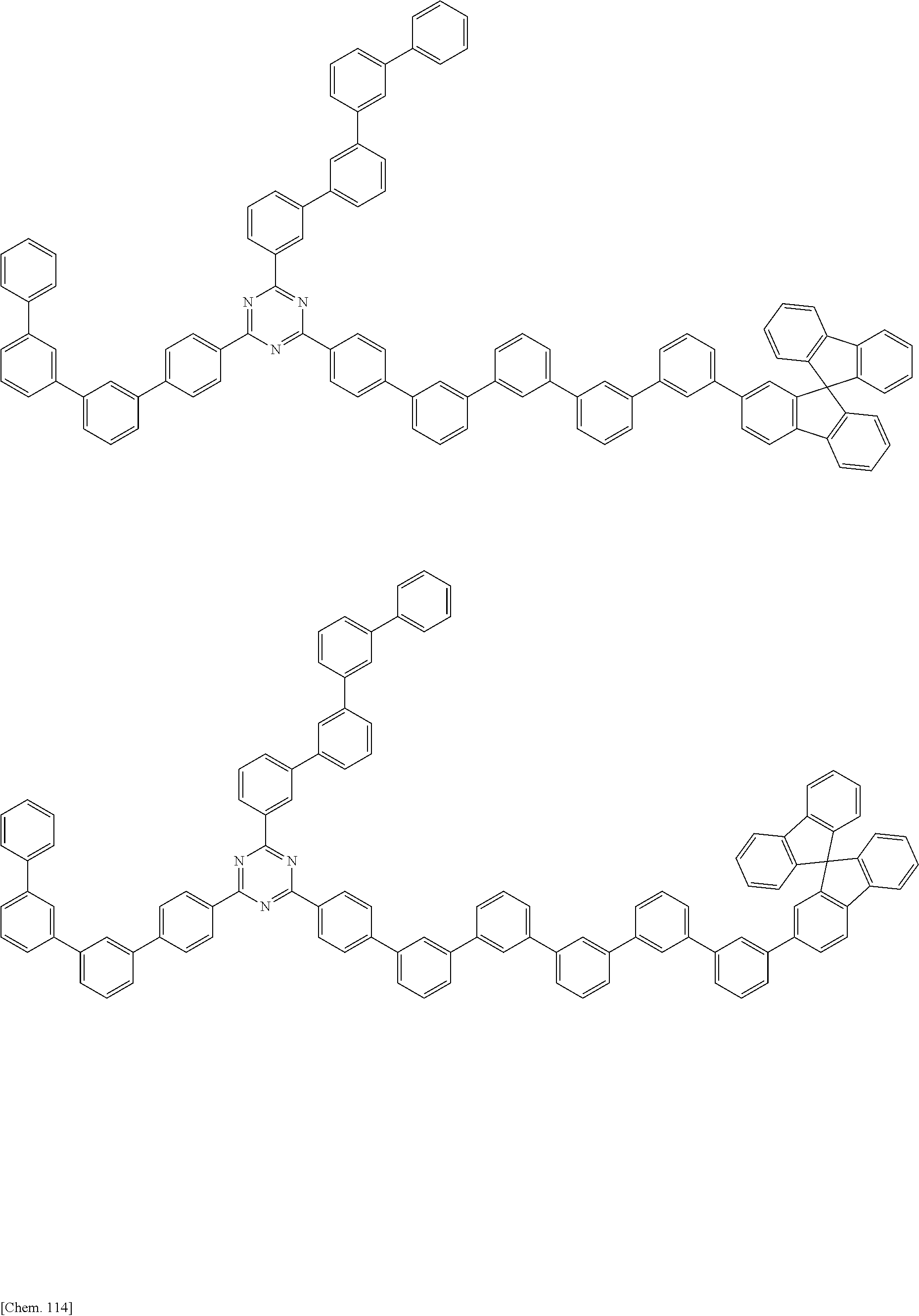 [SMILES: c1ccc(-c2cccc(-c3cccc(-c4ccc(-c5nc(-c6ccc(-c7cccc(-c8cccc(-c9cccc(-c%10cccc(-c%11ccc%12c(c%11)C%11(c%13ccccc%13-c%13ccccc%13%11)c%11ccccc%11-%12)c%10)c9)c8)c7)cc6)nc(-c6cccc(-c7cccc(-c8cccc(-c9ccccc9)c8)c7)c6)n5)cc4)c3)c2)cc1 ; c1ccc(-c2cccc(-c3cccc(-c4ccc(-c5nc(-c6ccc(-c7cccc(-c8cccc(-c9cccc(-c%10cccc(-c%11cccc(-c%12ccc%13c(c%12)C%12(c%14ccccc%14-c%14ccccc%14%12)c%12ccccc%12-%13)c%11)c%10)c9)c8)c7)cc6)nc(-c6cccc(-c7cccc(-c8cccc(-c9ccccc9)c8)c7)c6)n5)cc4)c3)c2)cc1]

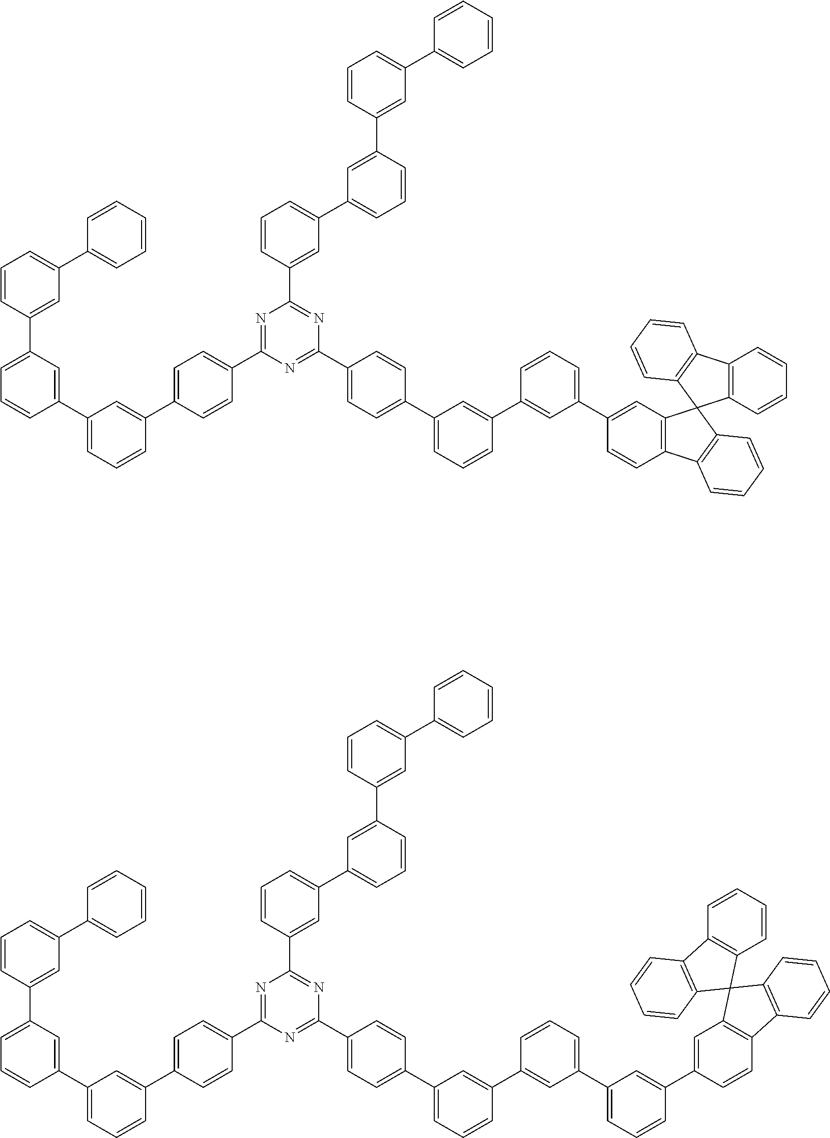 [SMILES: c1ccc(-c2cccc(-c3cccc(-c4cccc(-c5ccc(-c6nc(-c7ccc(-c8cccc(-c9cccc(-c%10ccc%11c(c%10)C%10(c%12ccccc%12-c%12ccccc%12%10)c%10ccccc%10-%11)c9)c8)cc7)nc(-c7cccc(-c8cccc(-c9cccc(-c%10ccccc%10)c9)c8)c7)n6)cc5)c4)c3)c2)cc1 ; c1ccc(-c2cccc(-c3cccc(-c4cccc(-c5ccc(-c6nc(-c7ccc(-c8cccc(-c9cccc(-c%10cccc(-c%11ccc%12c(c%11)C%11(c%13ccccc%13-c%13ccccc%13%11)c%11ccccc%11-%12)c%10)c9)c8)cc7)nc(-c7cccc(-c8cccc(-c9cccc(-c%10ccccc%10)c9)c8)c7)n6)cc5)c4)c3)c2)cc1]

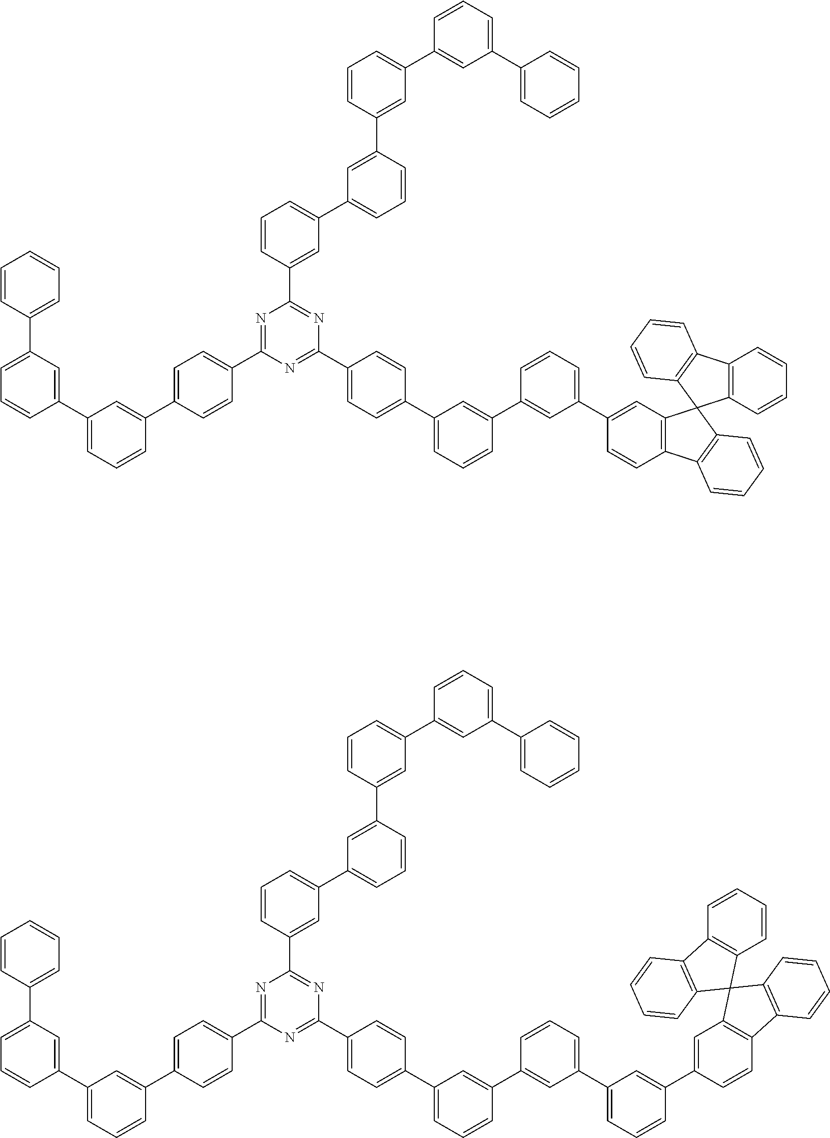 [SMILES: c1ccc(-c2cccc(-c3cccc(-c4ccc(-c5nc(-c6ccc(-c7cccc(-c8cccc(-c9ccc%10c(c9)C9(c%11ccccc%11-c%11ccccc%119)c9ccccc9-%10)c8)c7)cc6)nc(-c6cccc(-c7cccc(-c8cccc(-c9cccc(-c%10ccccc%10)c9)c8)c7)c6)n5)cc4)c3)c2)cc1 ; c1ccc(-c2cccc(-c3cccc(-c4ccc(-c5nc(-c6ccc(-c7cccc(-c8cccc(-c9cccc(-c%10ccc%11c(c%10)C%10(c%12ccccc%12-c%12ccccc%12%10)c%10ccccc%10-%11)c9)c8)c7)cc6)nc(-c6cccc(-c7cccc(-c8cccc(-c9cccc(-c%10ccccc%10)c9)c8)c7)c6)n5)cc4)c3)c2)cc1]

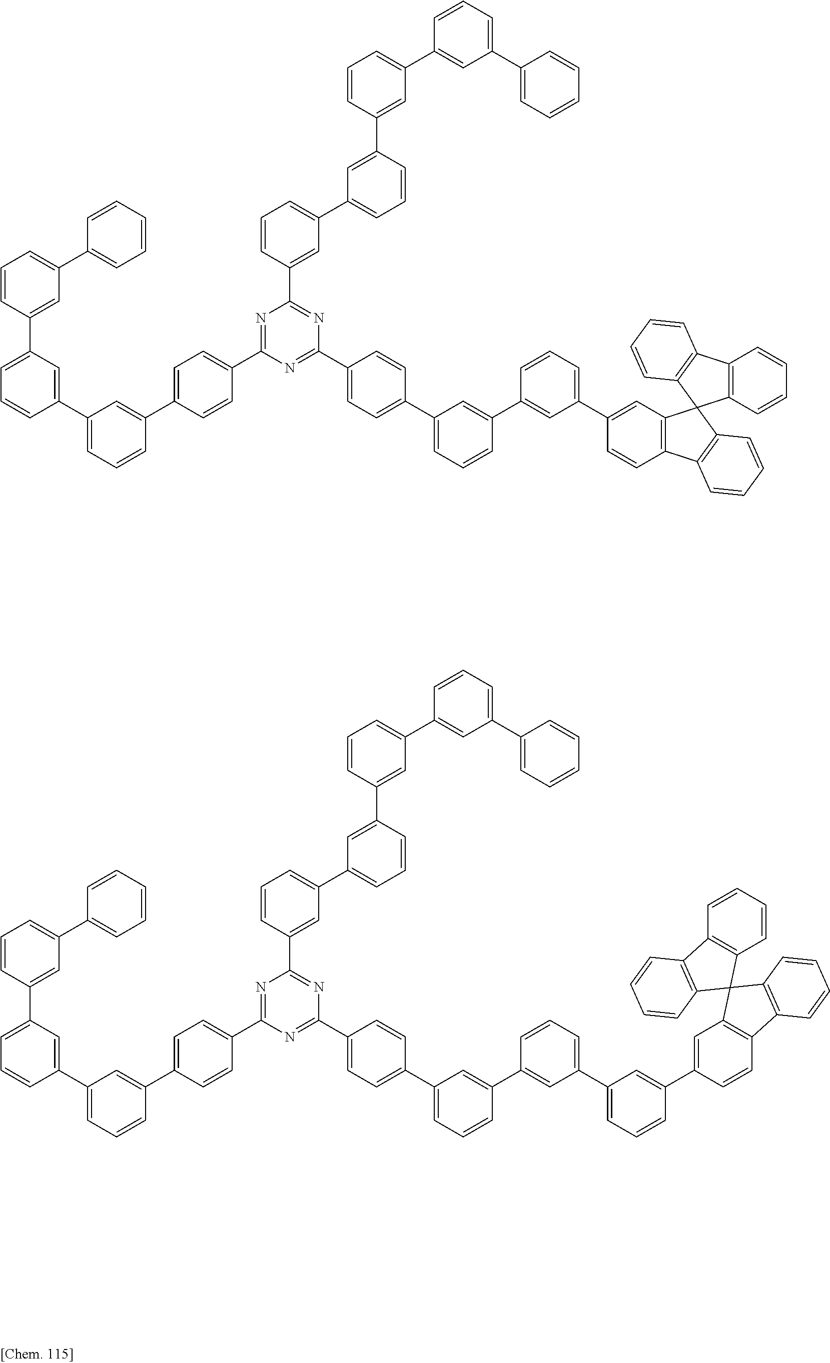 [SMILES: c1ccc(-c2cccc(-c3cccc(-c4cccc(-c5ccc(-c6nc(-c7ccc(-c8cccc(-c9cccc(-c%10ccc%11c(c%10)C%10(c%12ccccc%12-c%12ccccc%12%10)c%10ccccc%10-%11)c9)c8)cc7)nc(-c7cccc(-c8cccc(-c9cccc(-c%10cccc(-c%11ccccc%11)c%10)c9)c8)c7)n6)cc5)c4)c3)c2)cc1 ; c1ccc(-c2cccc(-c3cccc(-c4cccc(-c5ccc(-c6nc(-c7ccc(-c8cccc(-c9cccc(-c%10cccc(-c%11ccc%12c(c%11)C%11(c%13ccccc%13-c%13ccccc%13%11)c%11ccccc%11-%12)c%10)c9)c8)cc7)nc(-c7cccc(-c8cccc(-c9cccc(-c%10cccc(-c%11ccccc%11)c%10)c9)c8)c7)n6)cc5)c4)c3)c2)cc1]

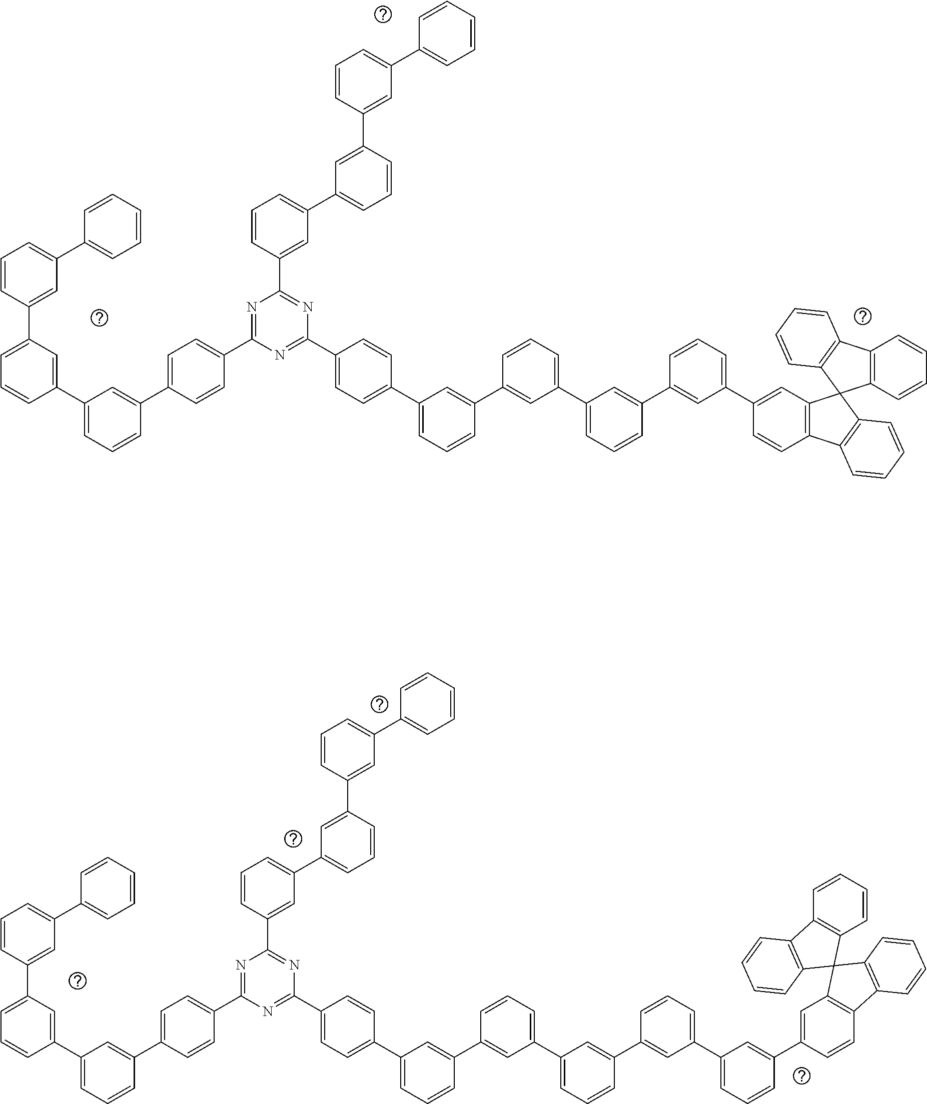

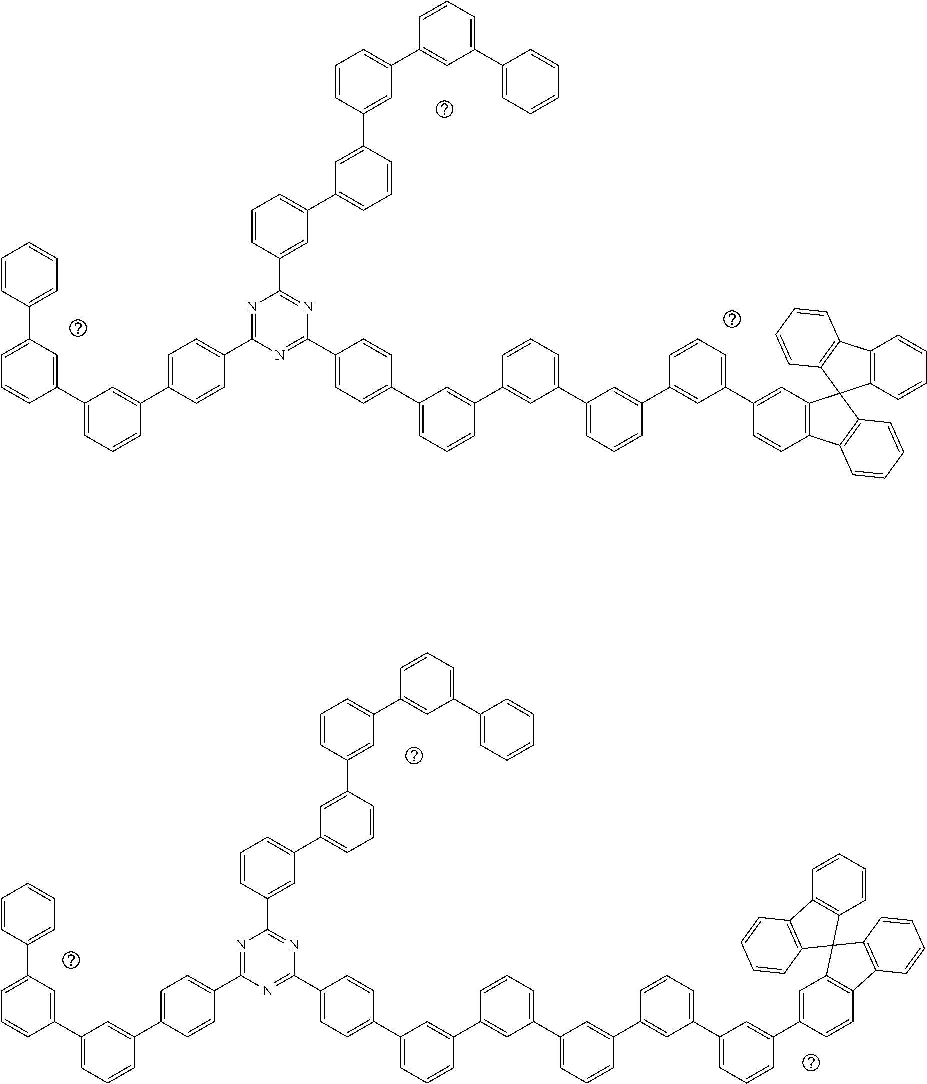 [SMILES: c1ccc(-c2cccc(-c3cccc(-c4ccc(-c5nc(-c6ccc(-c7cccc(-c8cccc(-c9cccc(-c%10cccc(-c%11ccc%12c(c%11)C%11(c%13ccccc%13-c%13ccccc%13%11)c%11ccccc%11-%12)c%10)c9)c8)c7)cc6)nc(-c6cccc(-c7cccc(-c8cccc(-c9cccc(-c%10ccccc%10)c9)c8)c7)c6)n5)cc4)c3)c2)cc1 ; c1ccc(-c2cccc(-c3cccc(-c4ccc(-c5nc(-c6ccc(-c7cccc(-c8cccc(-c9cccc(-c%10cccc(-c%11cccc(-c%12ccc%13c(c%12)C%12(c%14ccccc%14-c%14ccccc%14%12)c%12ccccc%12-%13)c%11)c%10)c9)c8)c7)cc6)nc(-c6cccc(-c7cccc(-c8cccc(-c9cccc(-c%10ccccc%10)c9)c8)c7)c6)n5)cc4)c3)c2)cc1]

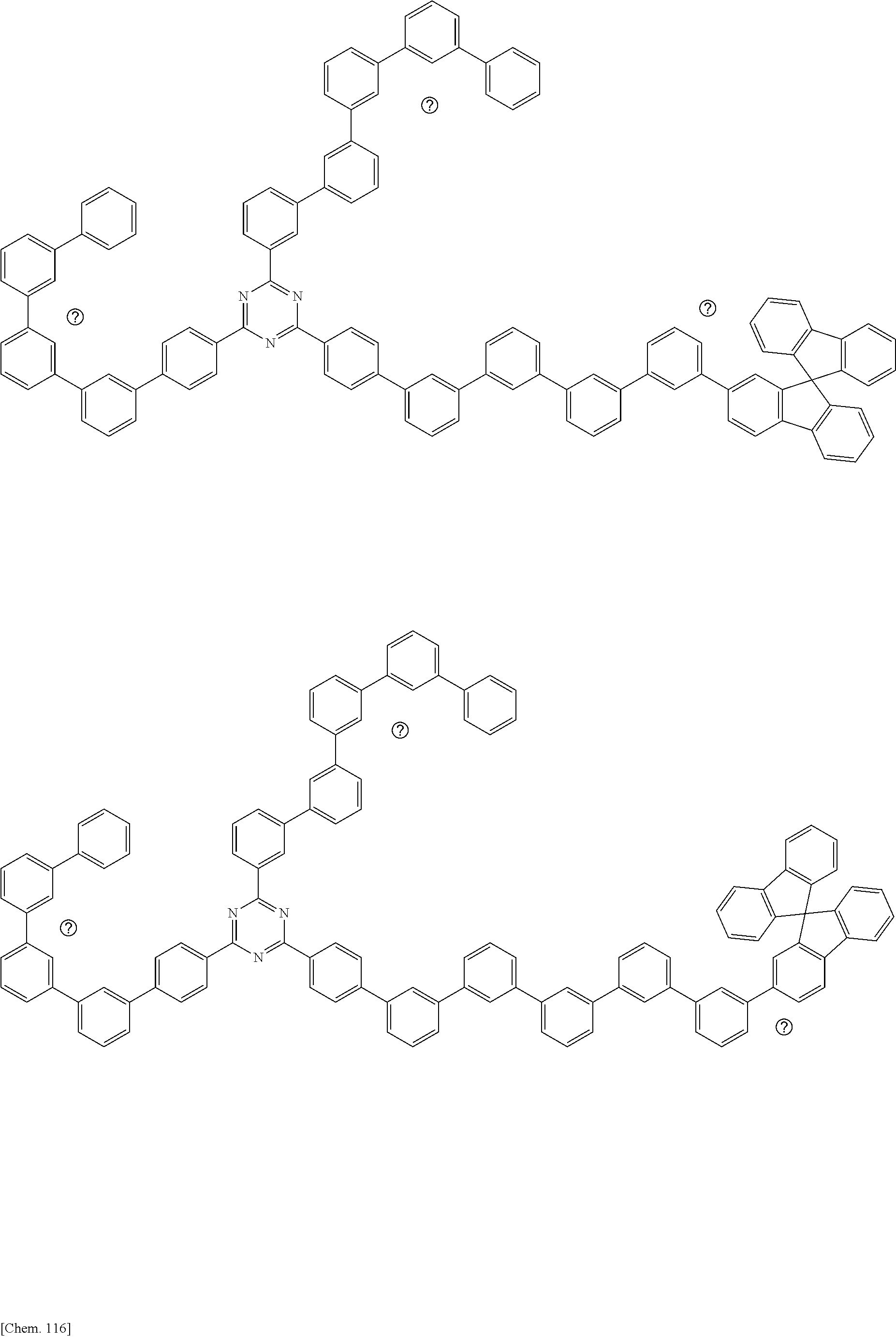

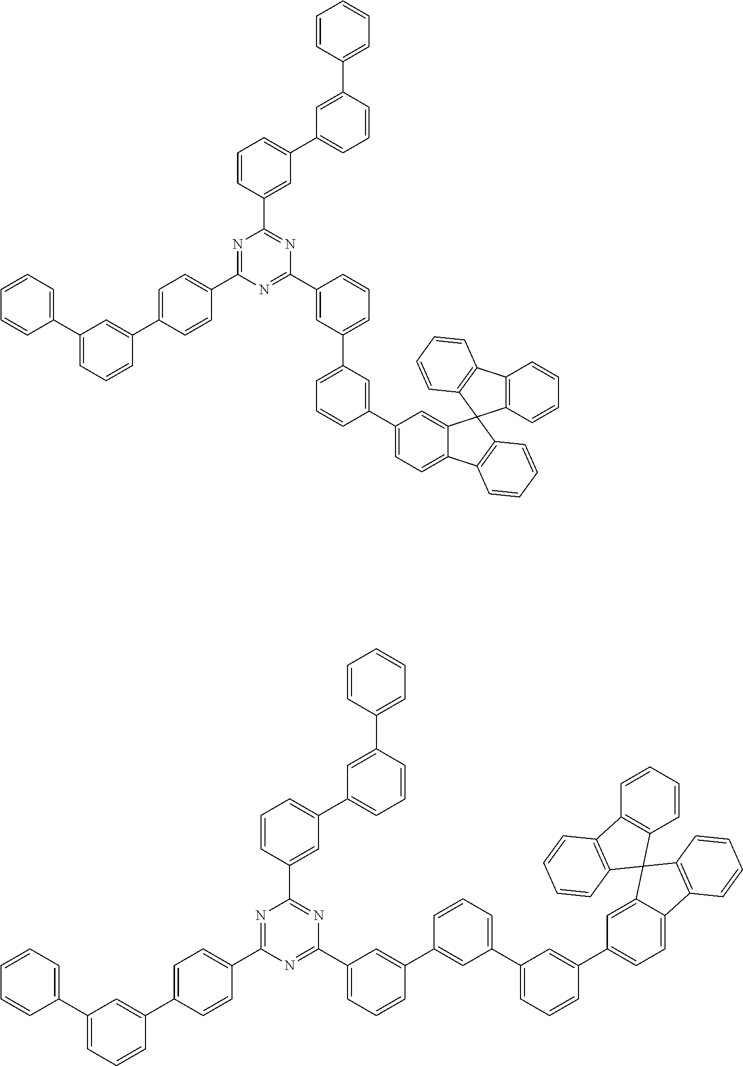 [SMILES: c1ccc(-c2cccc(-c3ccc(-c4nc(-c5cccc(-c6cccc(-c7ccccc7)c6)c5)nc(-c5cccc(-c6cccc(-c7ccc8c(c7)C7(c9ccccc9-c9ccccc97)c7ccccc7-8)c6)c5)n4)cc3)c2)cc1 ; c1ccc(-c2cccc(-c3ccc(-c4nc(-c5cccc(-c6cccc(-c7ccccc7)c6)c5)nc(-c5cccc(-c6cccc(-c7cccc(-c8ccc9c(c8)C8(c%10ccccc%10-c%10ccccc%108)c8ccccc8-9)c7)c6)c5)n4)cc3)c2)cc1]

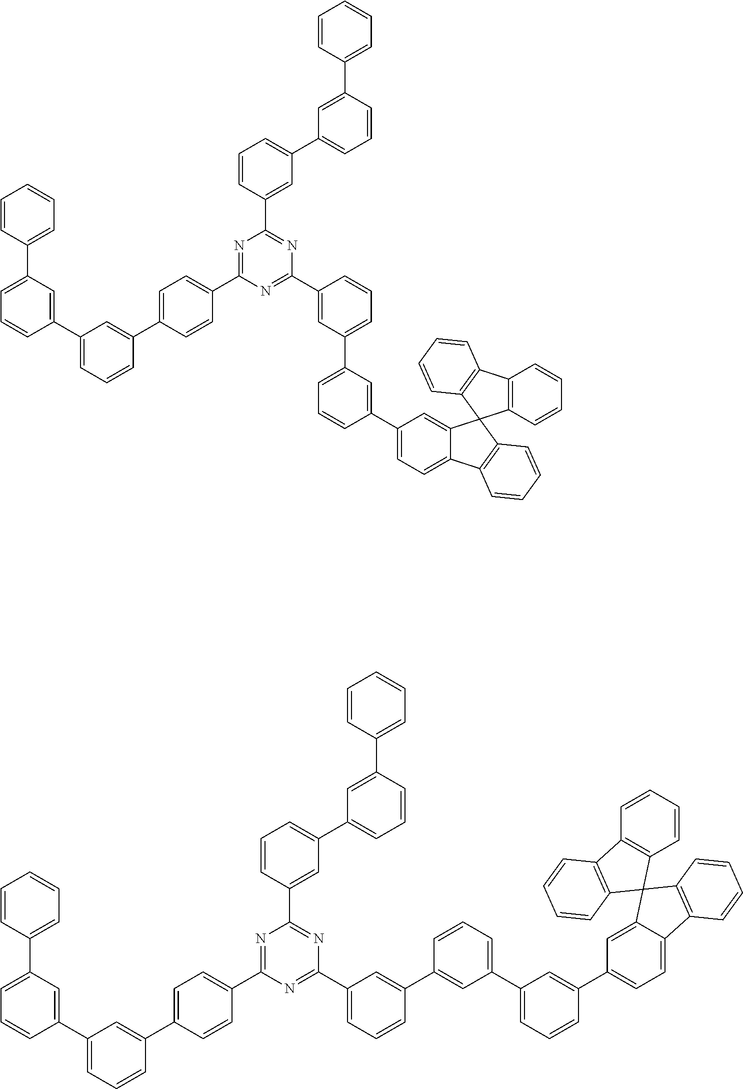 [SMILES: c1ccc(-c2cccc(-c3cccc(-c4ccc(-c5nc(-c6cccc(-c7cccc(-c8ccccc8)c7)c6)nc(-c6cccc(-c7cccc(-c8ccc9c(c8)C8(c%10ccccc%10-c%10ccccc%108)c8ccccc8-9)c7)c6)n5)cc4)c3)c2)cc1 ; c1ccc(-c2cccc(-c3cccc(-c4ccc(-c5nc(-c6cccc(-c7cccc(-c8ccccc8)c7)c6)nc(-c6cccc(-c7cccc(-c8cccc(-c9ccc%10c(c9)C9(c%11ccccc%11-c%11ccccc%119)c9ccccc9-%10)c8)c7)c6)n5)cc4)c3)c2)cc1]

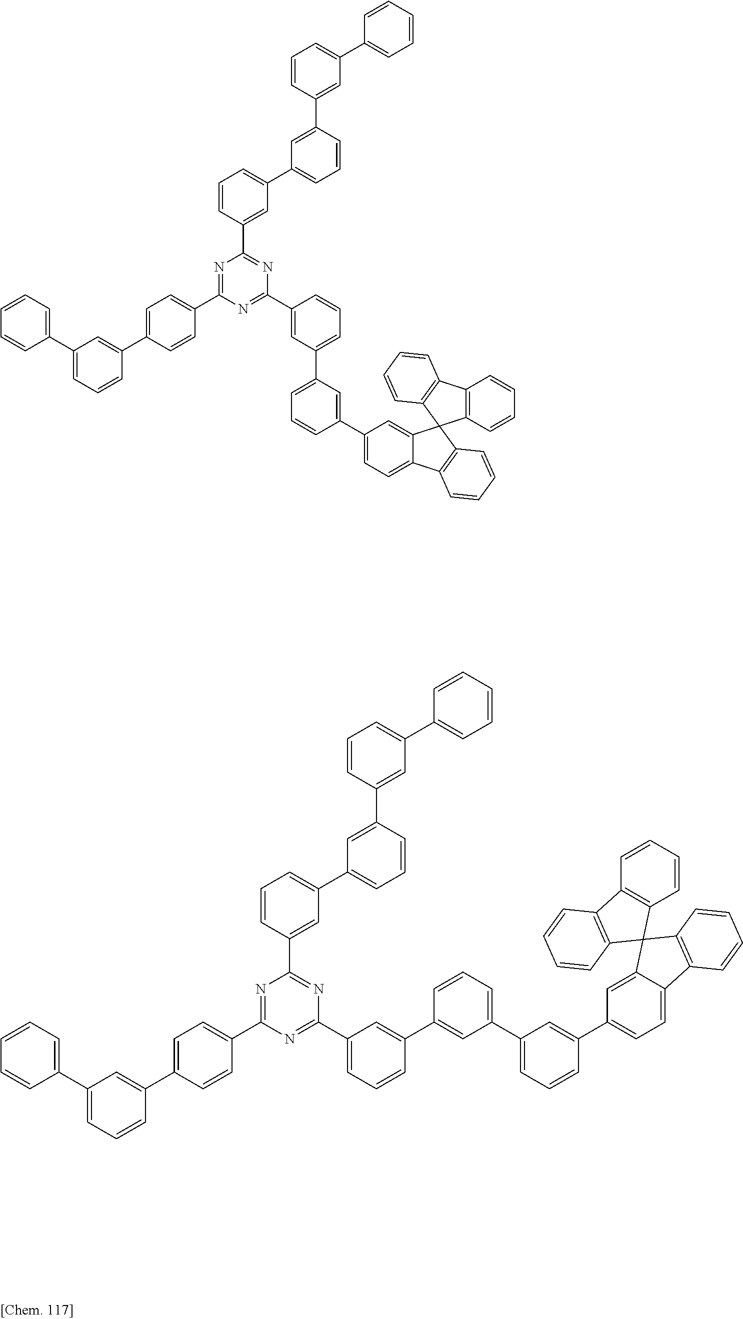 [SMILES: c1ccc(-c2cccc(-c3ccc(-c4nc(-c5cccc(-c6cccc(-c7cccc(-c8ccccc8)c7)c6)c5)nc(-c5cccc(-c6cccc(-c7ccc8c(c7)C7(c9ccccc9-c9ccccc97)c7ccccc7-8)c6)c5)n4)cc3)c2)cc1 ; c1ccc(-c2cccc(-c3ccc(-c4nc(-c5cccc(-c6cccc(-c7cccc(-c8ccccc8)c7)c6)c5)nc(-c5cccc(-c6cccc(-c7cccc(-c8ccc9c(c8)C8(c%10ccccc%10-c%10ccccc%108)c8ccccc8-9)c7)c6)c5)n4)cc3)c2)cc1]

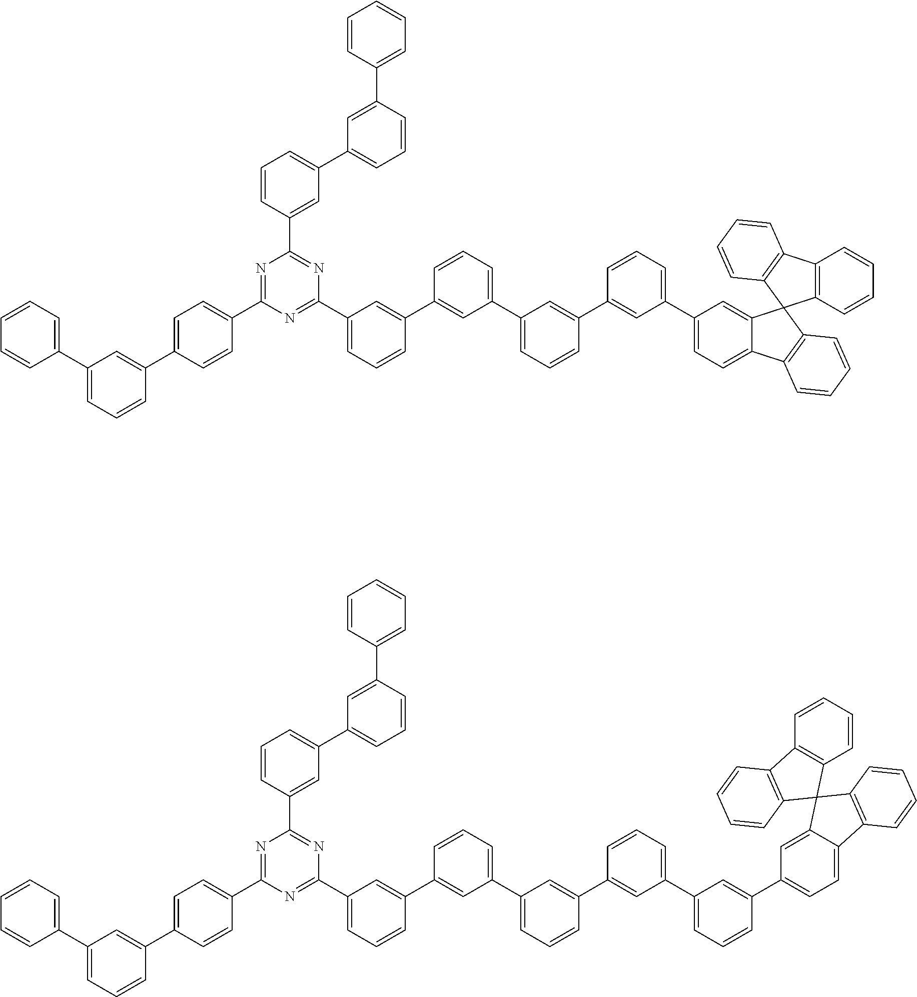 [SMILES: c1ccc(-c2cccc(-c3ccc(-c4nc(-c5cccc(-c6cccc(-c7ccccc7)c6)c5)nc(-c5cccc(-c6cccc(-c7cccc(-c8cccc(-c9ccc%10c(c9)C9(c%11ccccc%11-c%11ccccc%119)c9ccccc9-%10)c8)c7)c6)c5)n4)cc3)c2)cc1 ; c1ccc(-c2cccc(-c3ccc(-c4nc(-c5cccc(-c6cccc(-c7ccccc7)c6)c5)nc(-c5cccc(-c6cccc(-c7cccc(-c8cccc(-c9cccc(-c%10ccc%11c(c%10)C%10(c%12ccccc%12-c%12ccccc%12%10)c%10ccccc%10-%11)c9)c8)c7)c6)c5)n4)cc3)c2)cc1]

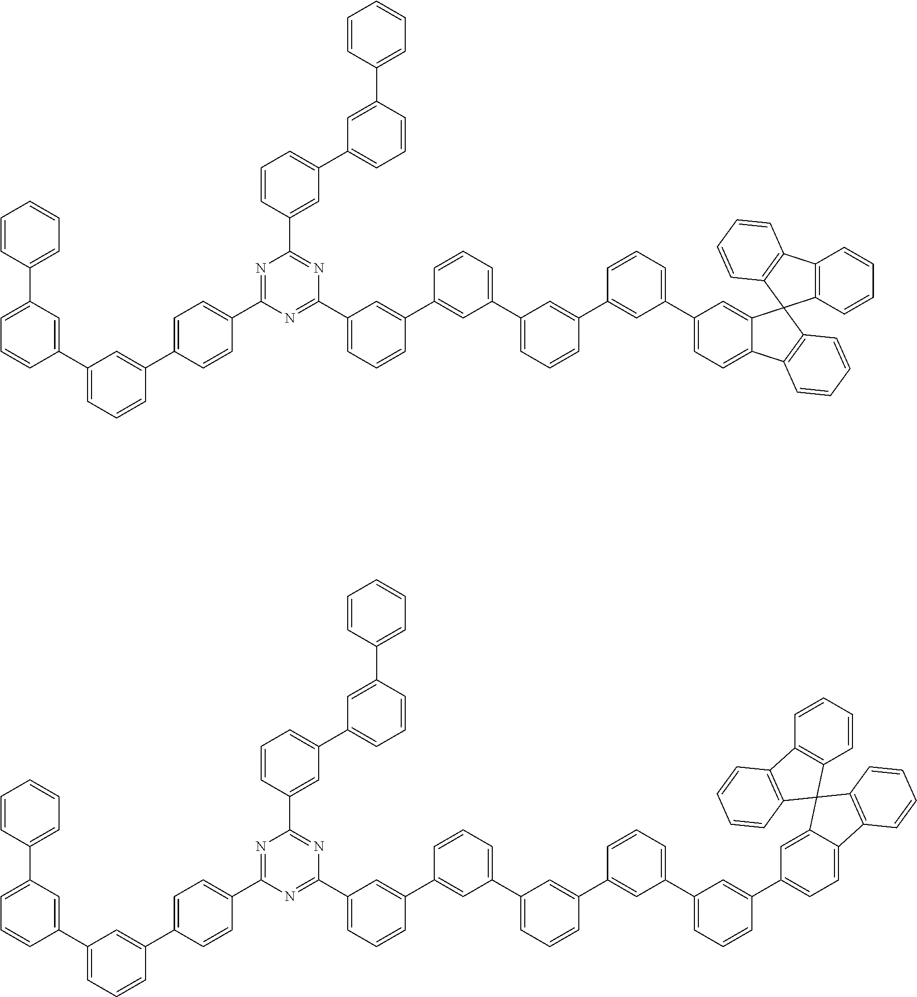 [SMILES: c1ccc(-c2cccc(-c3cccc(-c4ccc(-c5nc(-c6cccc(-c7cccc(-c8ccccc8)c7)c6)nc(-c6cccc(-c7cccc(-c8cccc(-c9cccc(-c%10ccc%11c(c%10)C%10(c%12ccccc%12-c%12ccccc%12%10)c%10ccccc%10-%11)c9)c8)c7)c6)n5)cc4)c3)c2)cc1 ; c1ccc(-c2cccc(-c3cccc(-c4ccc(-c5nc(-c6cccc(-c7cccc(-c8ccccc8)c7)c6)nc(-c6cccc(-c7cccc(-c8cccc(-c9cccc(-c%10cccc(-c%11ccc%12c(c%11)C%11(c%13ccccc%13-c%13ccccc%13%11)c%11ccccc%11-%12)c%10)c9)c8)c7)c6)n5)cc4)c3)c2)cc1]

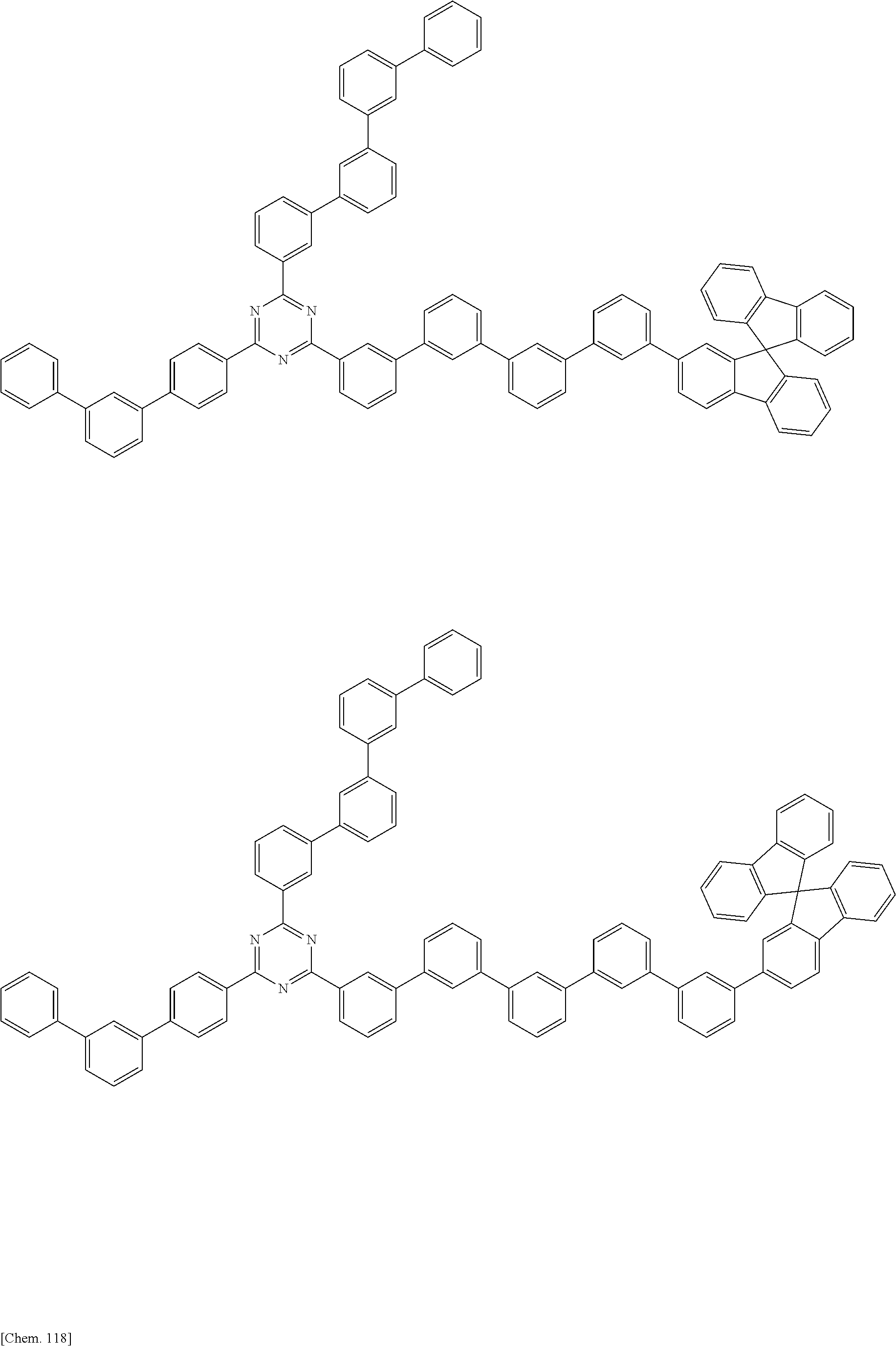 [SMILES: c1ccc(-c2cccc(-c3ccc(-c4nc(-c5cccc(-c6cccc(-c7cccc(-c8ccccc8)c7)c6)c5)nc(-c5cccc(-c6cccc(-c7cccc(-c8cccc(-c9ccc%10c(c9)C9(c%11ccccc%11-c%11ccccc%119)c9ccccc9-%10)c8)c7)c6)c5)n4)cc3)c2)cc1 ; c1ccc(-c2cccc(-c3ccc(-c4nc(-c5cccc(-c6cccc(-c7cccc(-c8ccccc8)c7)c6)c5)nc(-c5cccc(-c6cccc(-c7cccc(-c8cccc(-c9cccc(-c%10ccc%11c(c%10)C%10(c%12ccccc%12-c%12ccccc%12%10)c%10ccccc%10-%11)c9)c8)c7)c6)c5)n4)cc3)c2)cc1]

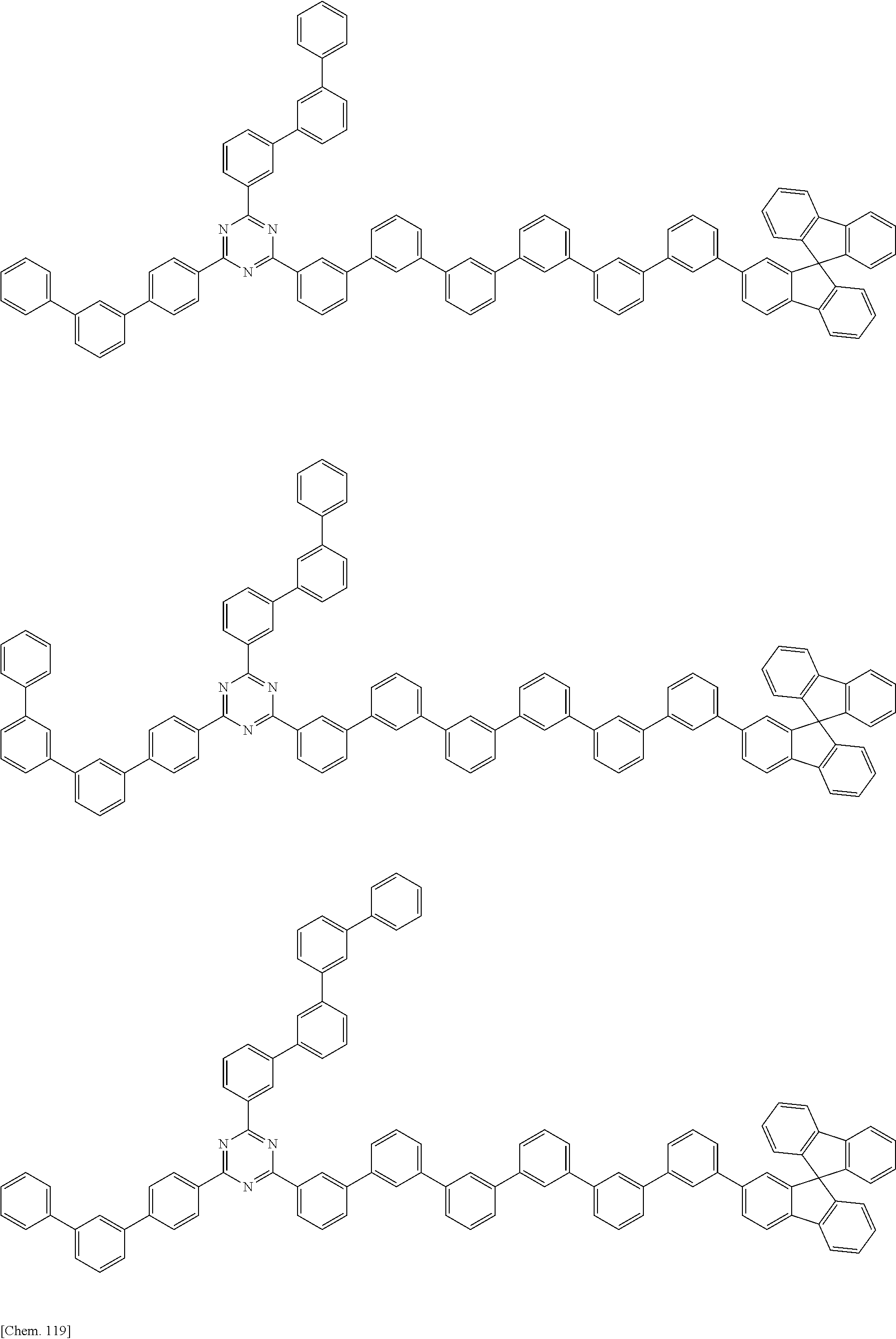

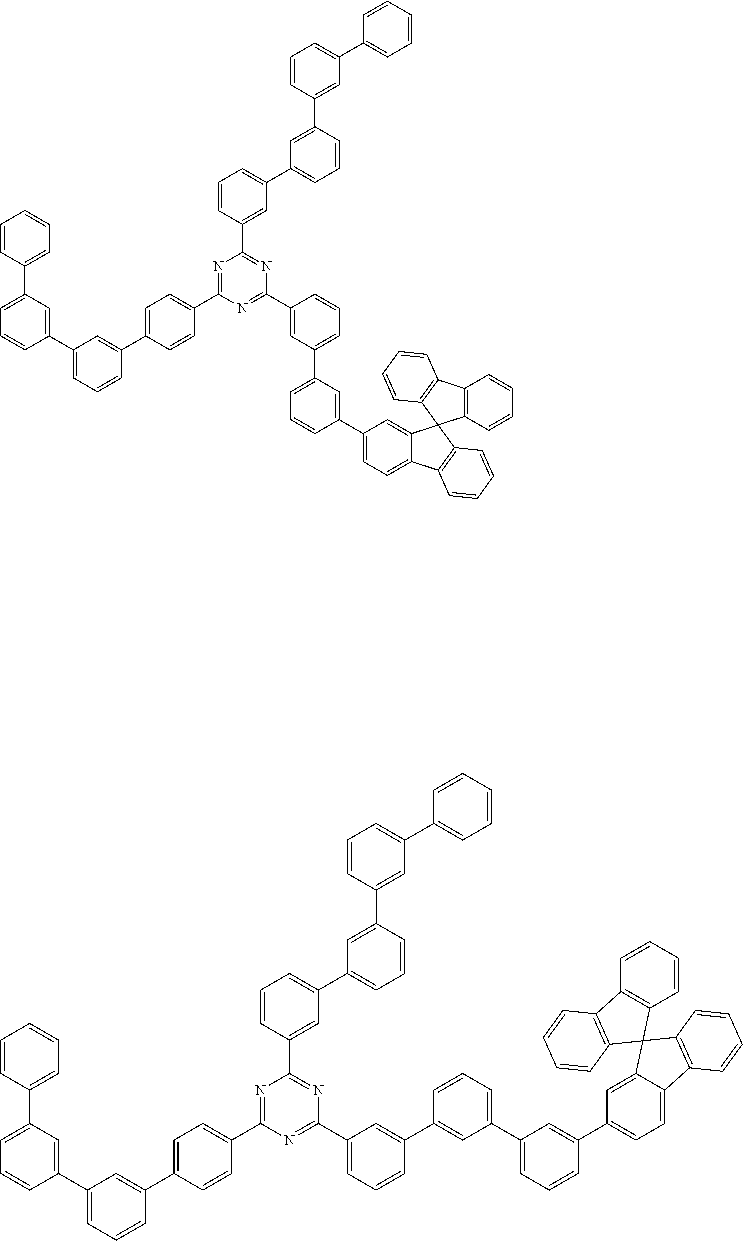 [SMILES: c1ccc(-c2cccc(-c3cccc(-c4ccc(-c5nc(-c6cccc(-c7cccc(-c8cccc(-c9ccccc9)c8)c7)c6)nc(-c6cccc(-c7cccc(-c8ccc9c(c8)C8(c%10ccccc%10-c%10ccccc%108)c8ccccc8-9)c7)c6)n5)cc4)c3)c2)cc1 ; c1ccc(-c2cccc(-c3cccc(-c4ccc(-c5nc(-c6cccc(-c7cccc(-c8cccc(-c9ccccc9)c8)c7)c6)nc(-c6cccc(-c7cccc(-c8cccc(-c9ccc%10c(c9)C9(c%11ccccc%11-c%11ccccc%119)c9ccccc9-%10)c8)c7)c6)n5)cc4)c3)c2)cc1]

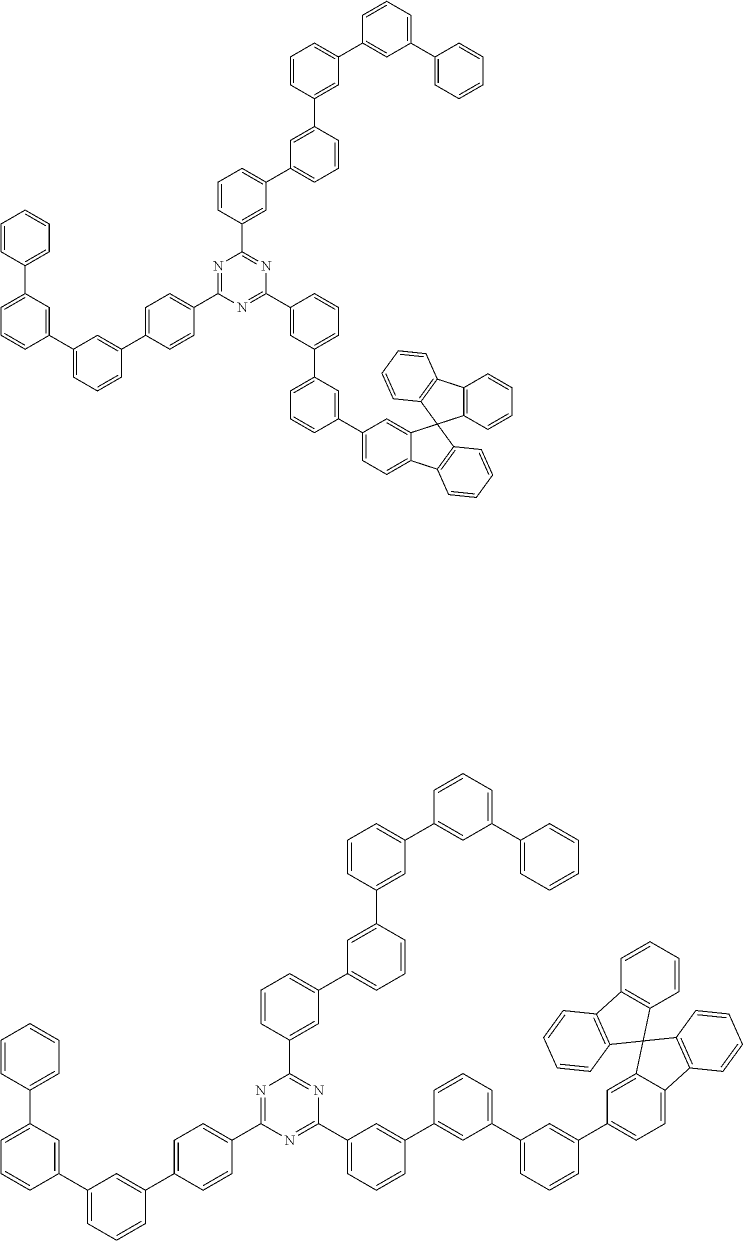 [SMILES: c1ccc(-c2cccc(-c3cccc(-c4ccc(-c5nc(-c6cccc(-c7cccc(-c8cccc(-c9cccc(-c%10ccccc%10)c9)c8)c7)c6)nc(-c6cccc(-c7cccc(-c8ccc9c(c8)C8(c%10ccccc%10-c%10ccccc%108)c8ccccc8-9)c7)c6)n5)cc4)c3)c2)cc1 ; c1ccc(-c2cccc(-c3cccc(-c4ccc(-c5nc(-c6cccc(-c7cccc(-c8cccc(-c9cccc(-c%10ccccc%10)c9)c8)c7)c6)nc(-c6cccc(-c7cccc(-c8cccc(-c9ccc%10c(c9)C9(c%11ccccc%11-c%11ccccc%119)c9ccccc9-%10)c8)c7)c6)n5)cc4)c3)c2)cc1]

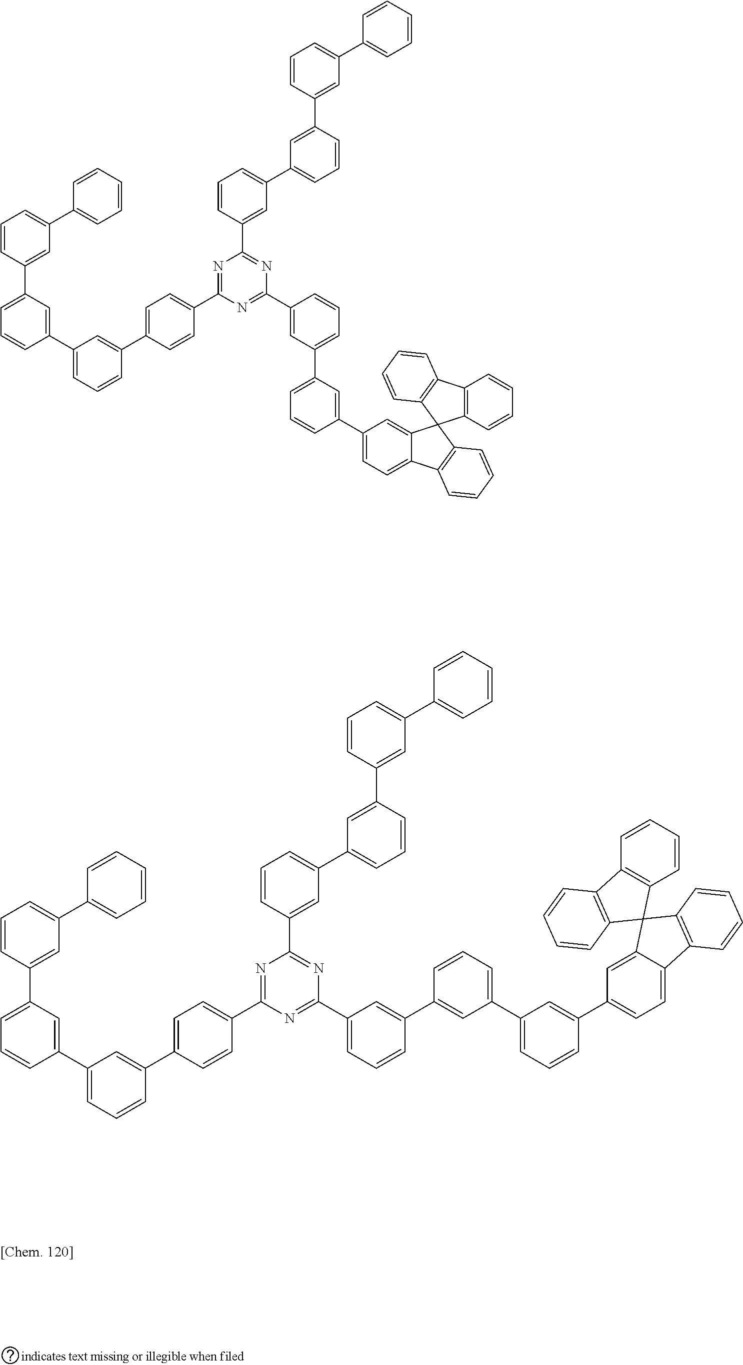 [SMILES: c1ccc(-c2cccc(-c3cccc(-c4cccc(-c5ccc(-c6nc(-c7cccc(-c8cccc(-c9cccc(-c%10ccccc%10)c9)c8)c7)nc(-c7cccc(-c8cccc(-c9ccc%10c(c9)C9(c%11ccccc%11-c%11ccccc%119)c9ccccc9-%10)c8)c7)n6)cc5)c4)c3)c2)cc1 ; c1ccc(-c2cccc(-c3cccc(-c4cccc(-c5ccc(-c6nc(-c7cccc(-c8cccc(-c9cccc(-c%10ccccc%10)c9)c8)c7)nc(-c7cccc(-c8cccc(-c9cccc(-c%10ccc%11c(c%10)C%10(c%12ccccc%12-c%12ccccc%12%10)c%10ccccc%10-%11)c9)c8)c7)n6)cc5)c4)c3)c2)cc1]

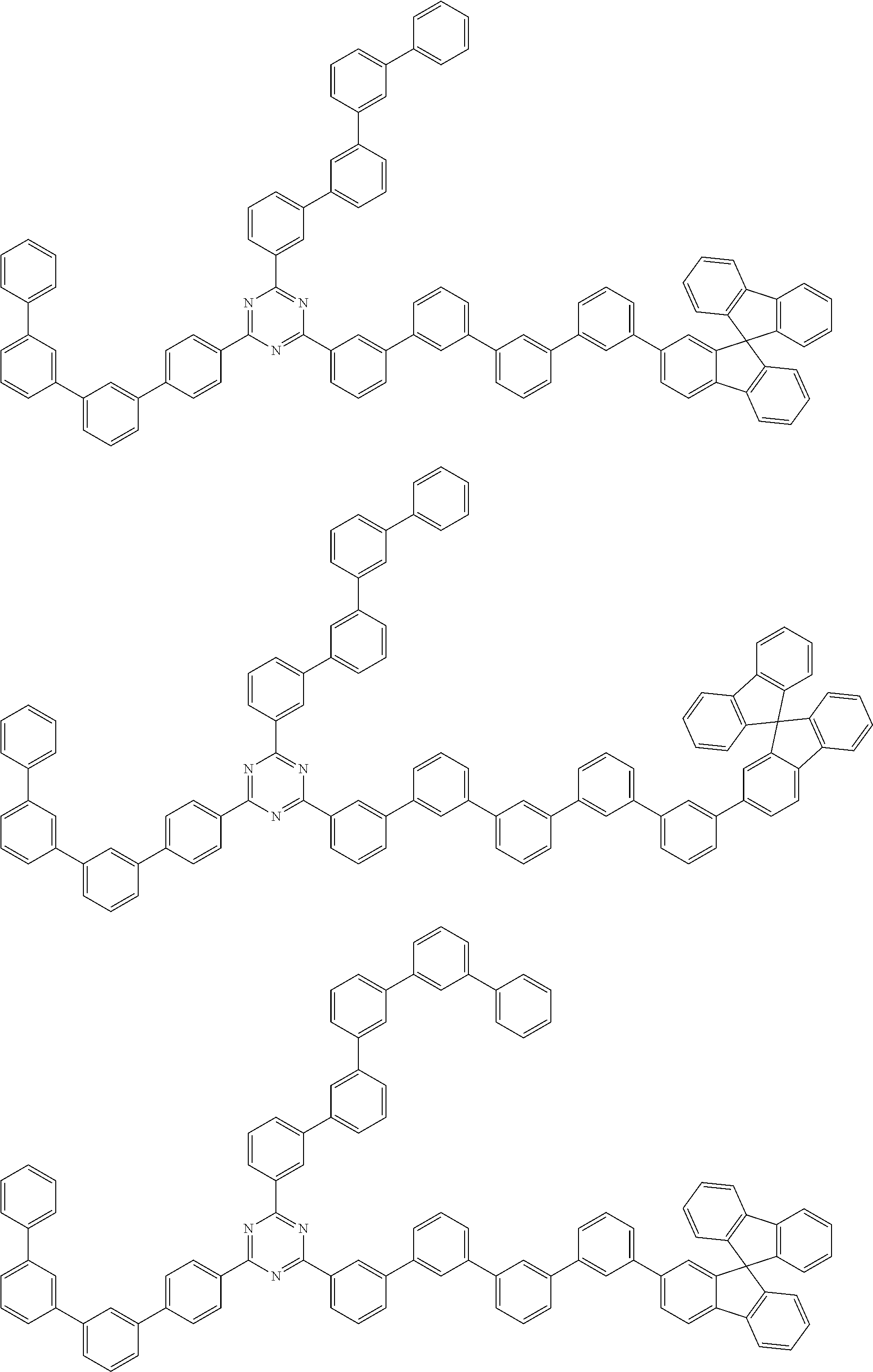

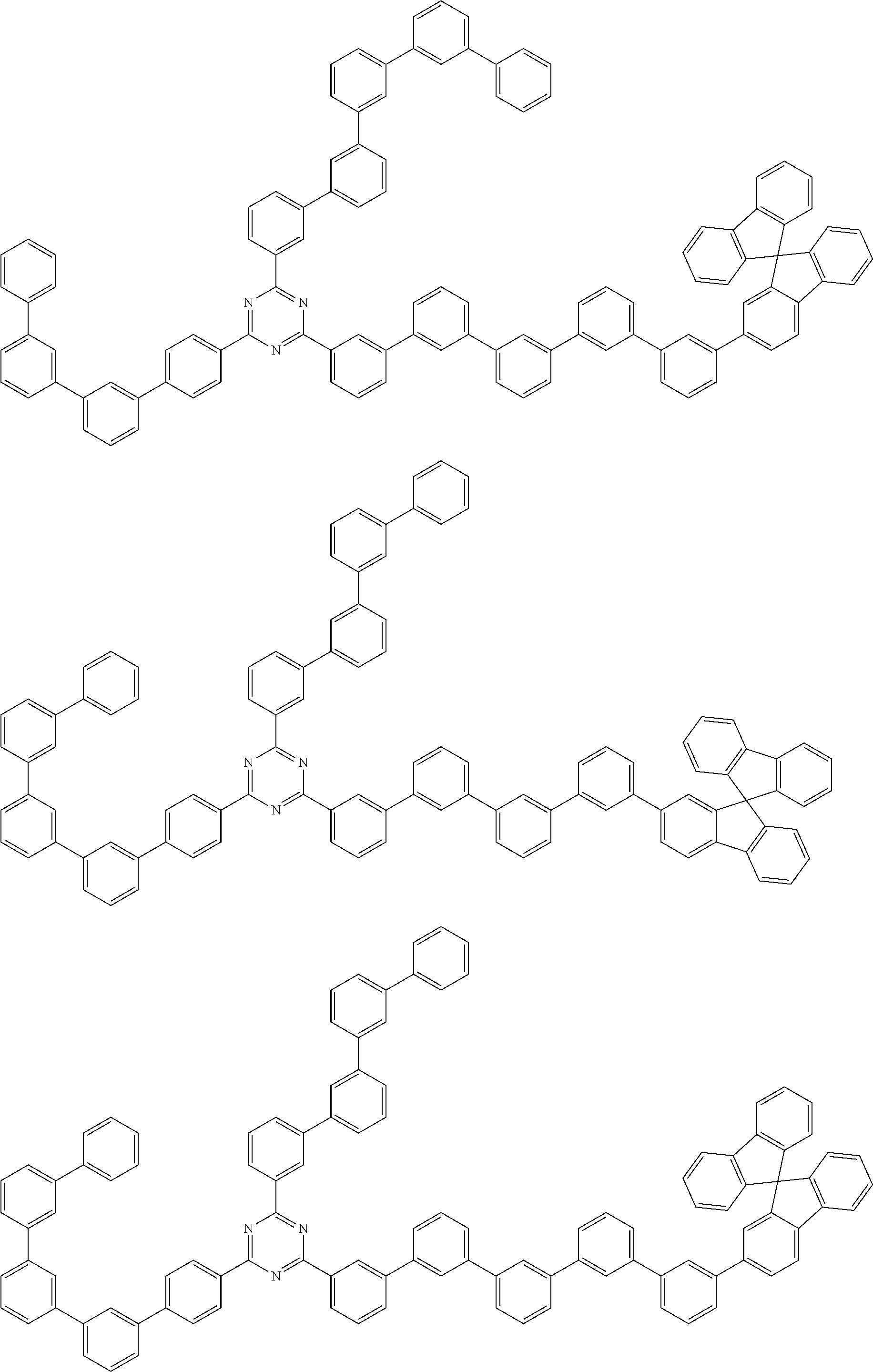

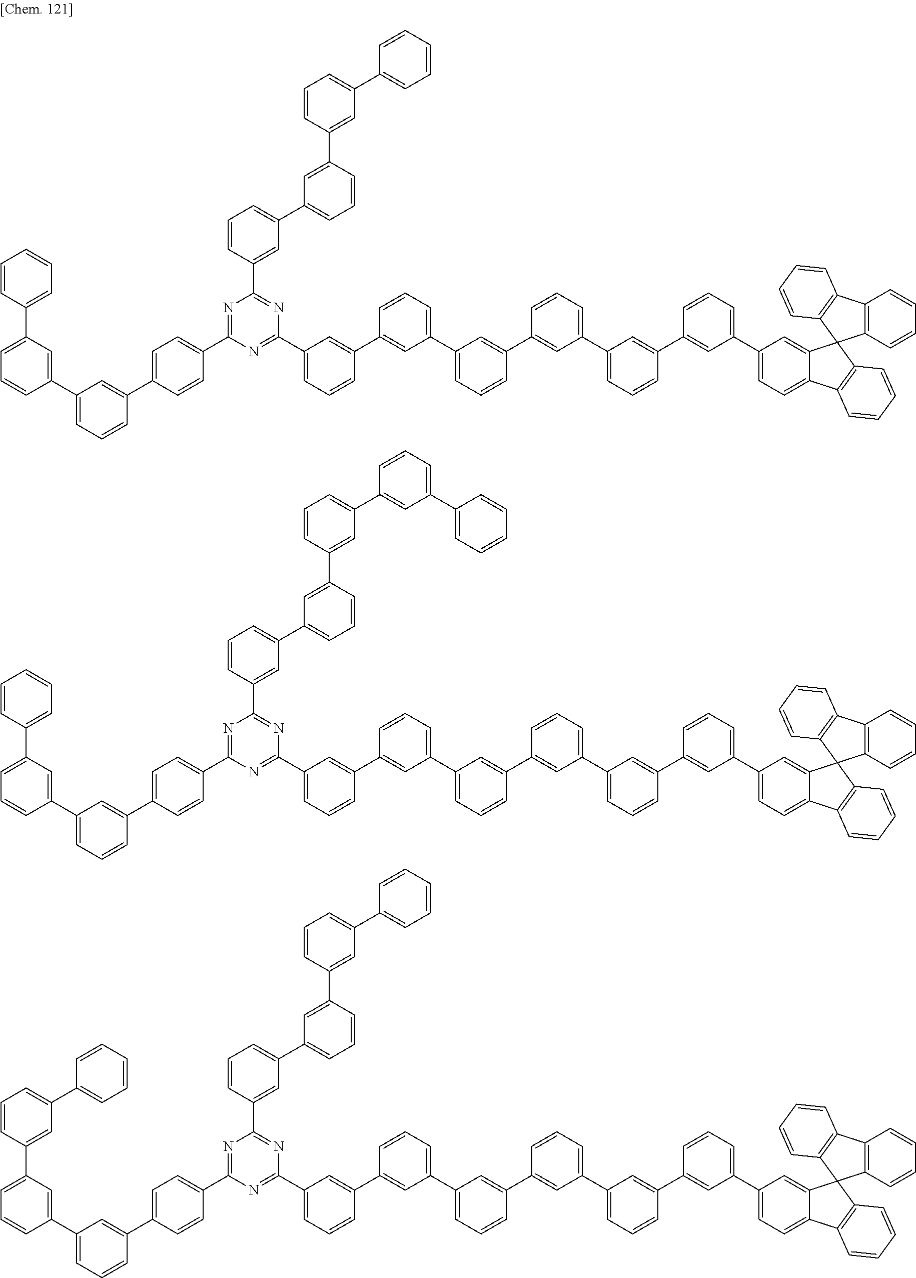

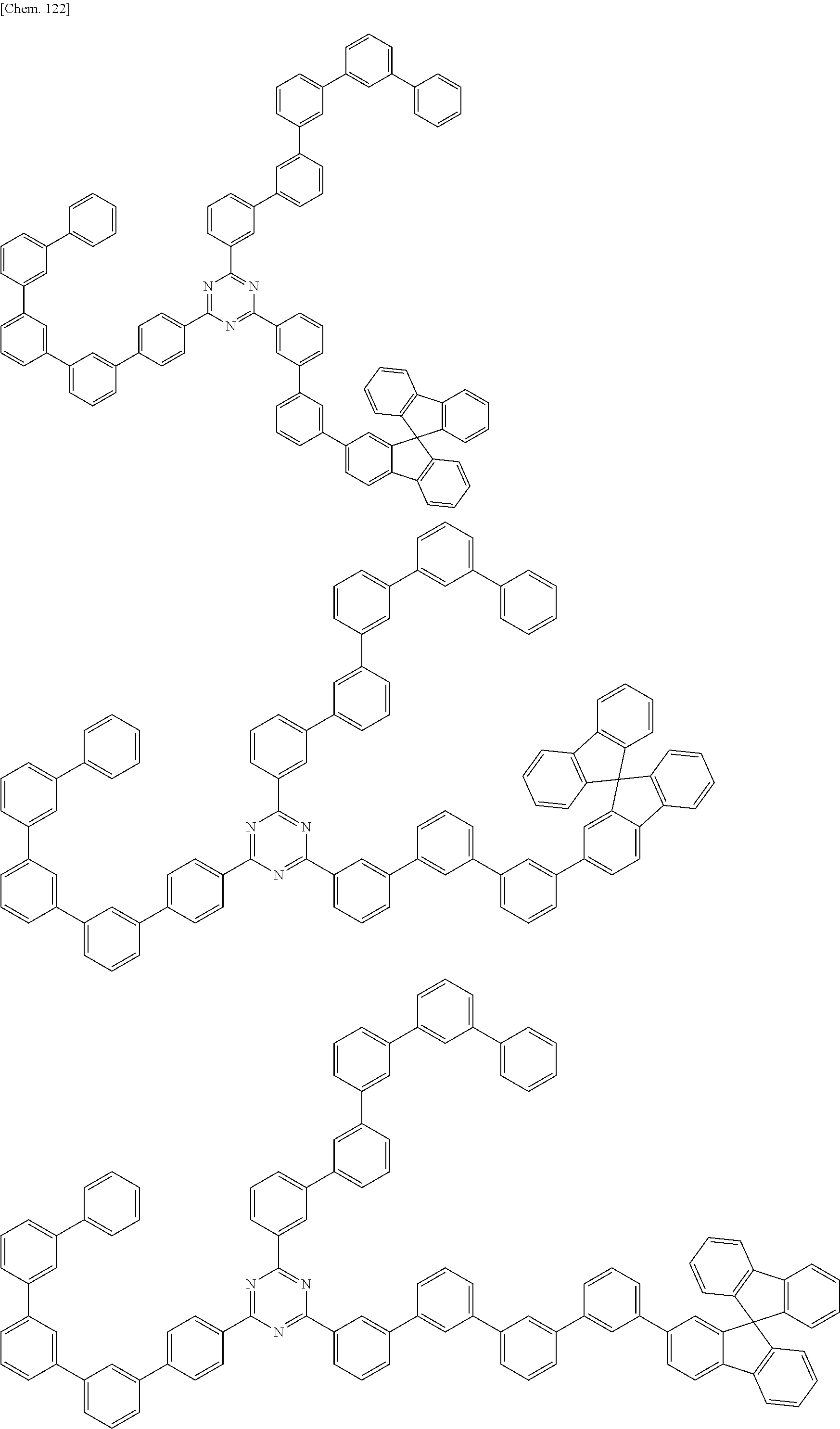

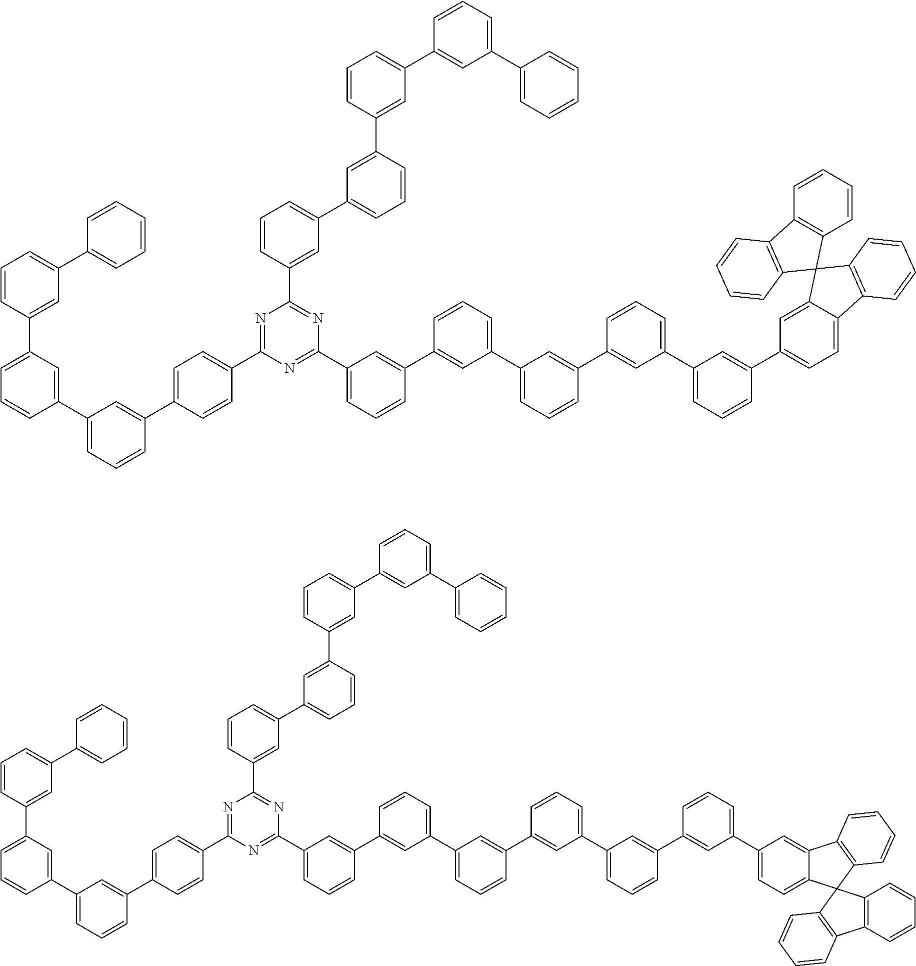

### Compound Represented by Formula (1-1) and Compound Represented by Formula (1-2)]

### <Substituent>

A substituent, which a 1,3-phenylene group, a 1,4-phenylene group, a phenyl group, or an N-carbazolyl group in the later-described formula (1-1) or (1-2) may have, is selected from the substituent group Z2.

R¹¹ in the later-described formula (1-1) or (1-2) is as follows.

### <R¹¹>

R¹¹ in the formula (1-1) or the formula (1-2) each independently represents a hydrogen atom or a substituent. Examples of R¹¹ which is a substituent other than a hydrogen atom include a group selected from the above substituent group Z2. Also in the substituent group Z2, an aromatic hydrocarbon group having 6 to 30 carbon atoms which may have a substituent, or an aromatic heterocyclic group having 3 to 30 carbon atoms which may have a substituent is preferable. From the viewpoint of improvement in durability and charge transportability, an aromatic hydrocarbon group which may have a substituent is more preferable. In a case where there are a plurality of R¹¹ in the formula (1-1) or the formula (1-2) as a substituent, the plurality of R¹¹ may be the same as or different from each other.

The substituent which the aromatic hydrocarbon group having 6 to 30 carbon atoms may have, the substituent which the aromatic heterocyclic group having 3 to 30 carbon atoms may have, and a substituent which R¹¹ as a substituent may have can be selected from the above substituent group Z2.

### Compound (1-1)]

The compound (1-1) is a compound represented by the following formula (1-1).

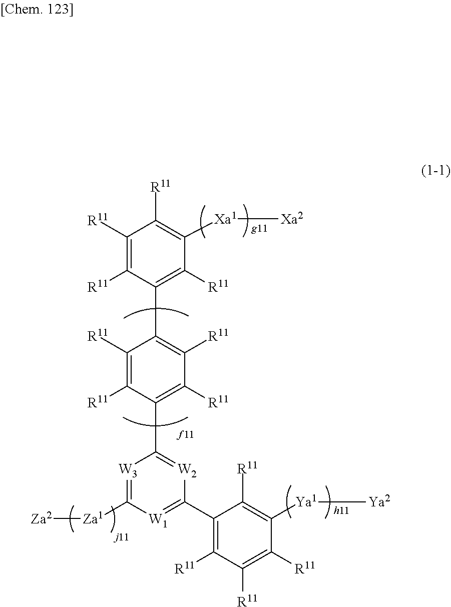

(In the formula (1-1),
W₁, W₂, and W₃ each independently represent —CH or a nitrogen atom, and at least one of W₁, W₂, and W₃ represents a nitrogen atom,
Xa¹, Ya¹, and Za¹ each independently represent a 1,3-phenylene group which may have a substituent, or a 1,4-phenylene group which may have a substituent,
at least one of Za¹ is a 1,3-phenylene group,
Xa² and Ya² each independently represent a phenyl group which may have a substituent,
Za² represents an N-carbazolyl group which may have a substituent,
f11 is 1 or 2,
g11 is an integer of 1 to 5,
h11 is an integer of 2 to 5,
j11 is an integer of 1 to 6,
f11+g11+h11+j11 is 5 or more, and
R¹¹ each independently represents a hydrogen atom or a substituent).
   <W₁, W₂, and W₃>

W₁, W₂, and W₃ in the formula (1-1) each independently represent —CH or a nitrogen atom, and at least one of W₁, W₂, and W₃ is a nitrogen atom. From the viewpoint of electron transportability and electron durability, it is preferable that at least W₁ is a nitrogen atom, more preferable that at least W₁ and W₂ are nitrogen atoms, and most preferable that W₁, W₂, and W₃ are all nitrogen atoms.

That is, from the viewpoint of improving the electron transportability, a structure in which a group bonded to a para position which has two or three benzene rings linked at the para position to expand a conjugate and W₁ is a nitrogen atom is preferable, a pyrimidine structure in which one of W₂ and W₃ is a nitrogen atom in addition to W₁ is more preferable, and a triazine structure in which W₁, W₂, and W₃ are all nitrogen atoms is most preferable.

<—(Xa¹)_{g11}—Xa²>

In the formula (1-1), at least one of Xaⁱ is preferably a 1,3-phenylene group. Among those, —(Xa¹)_{g11}—Xa² is more preferably selected from the structure group of the following formula (Xa-1).

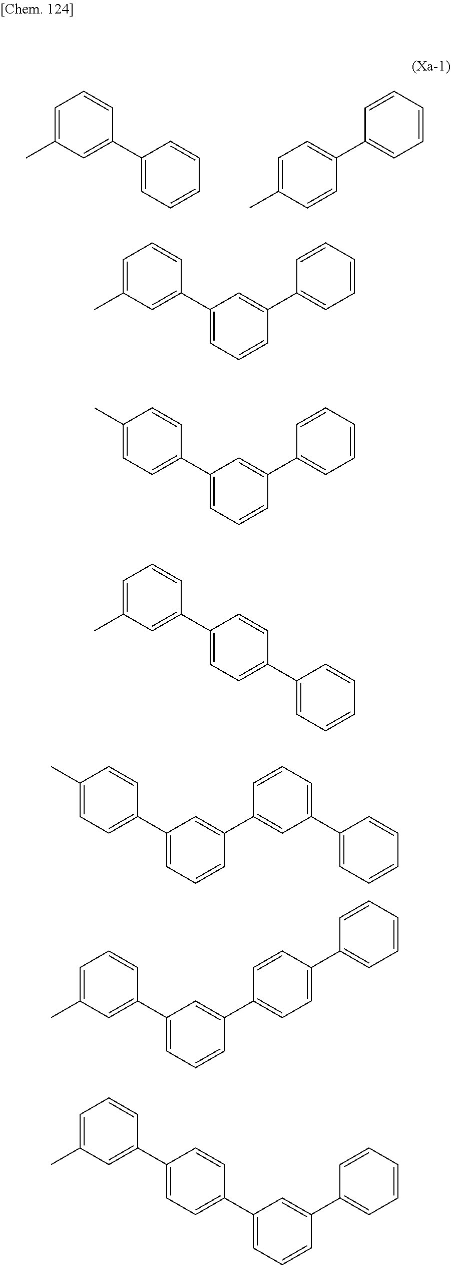

In these structures, a hydrogen atom may be substituted with a substituent selected from the substituent group Z2. A structure in which a hydrogen atom is not substituted is preferable.

<—(Ya¹)ₕ₁₁—Ya²>

In the formula (1-1), at least one of Yaⁱ is preferably a 1,3-phenylene group. Among those, —(Ya¹)ₕ₁—Ya² is more preferably selected from the structure group of the following formula (Ya-1).

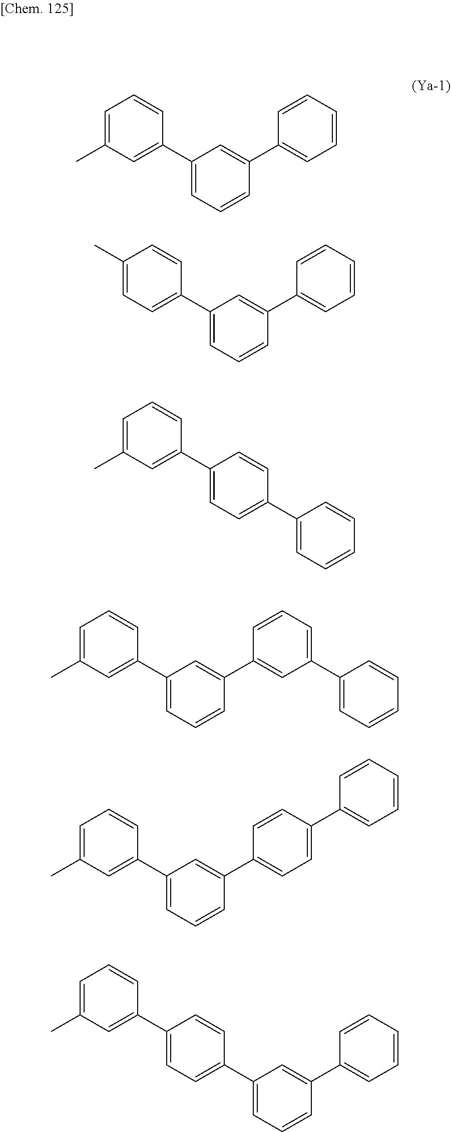

In these structures, a hydrogen atom may be substituted with a substituent selected from the substituent group Z2. A structure in which a hydrogen atom is not substituted is preferable.

—(Za¹)ⱼ₁₁—Za²>

In the formula (1-1), at least one of Za¹ is preferably a 1,3-phenylene group. Among those, —(Za¹)ⱼ₁₁—Za² is more preferably selected from the structure group of the following formula (Za-1).

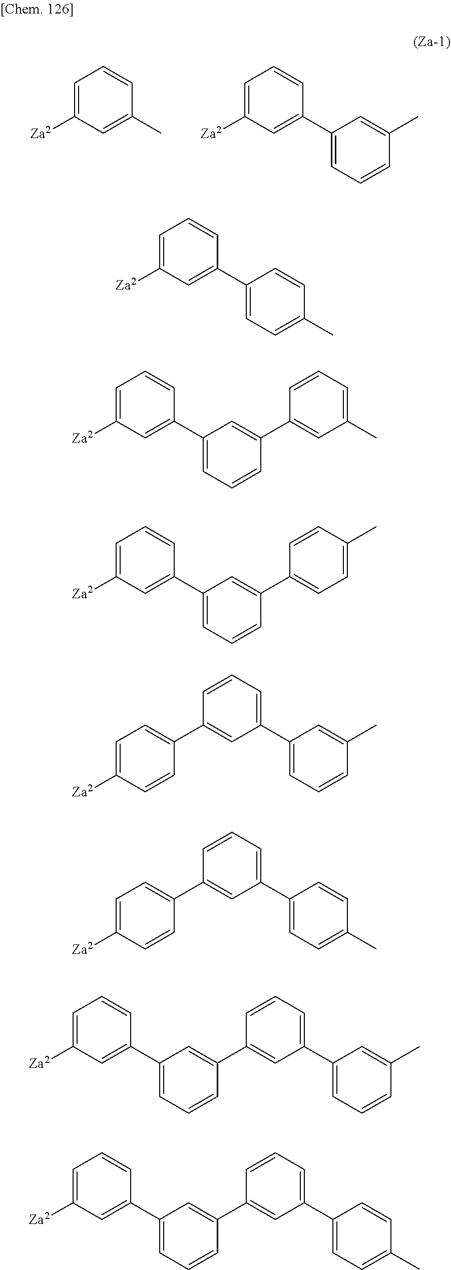

In these structures, a hydrogen atom may be substituted with a substituent selected from the substituent group Z2. A structure in which a hydrogen atom is not substituted is preferable.

### <Molecular Weight of Compound (1-1)>

The molecular weight of the compound (1-1) is generally 5,000 or less, preferably 3,000 or less, more preferably 2,500 or less, particularly preferably 2,000 or less, and most preferably 1,800 or less. A lower limit of the molecular weight of the compound (1-1) is preferably 930 or more, more preferably 1,000 or more, and particularly preferably 1,200 or more.

### Specific Examples of Compound (1-1)

A specific structure of the compound (1-1) is not particularly limited, and examples thereof include the following compounds.

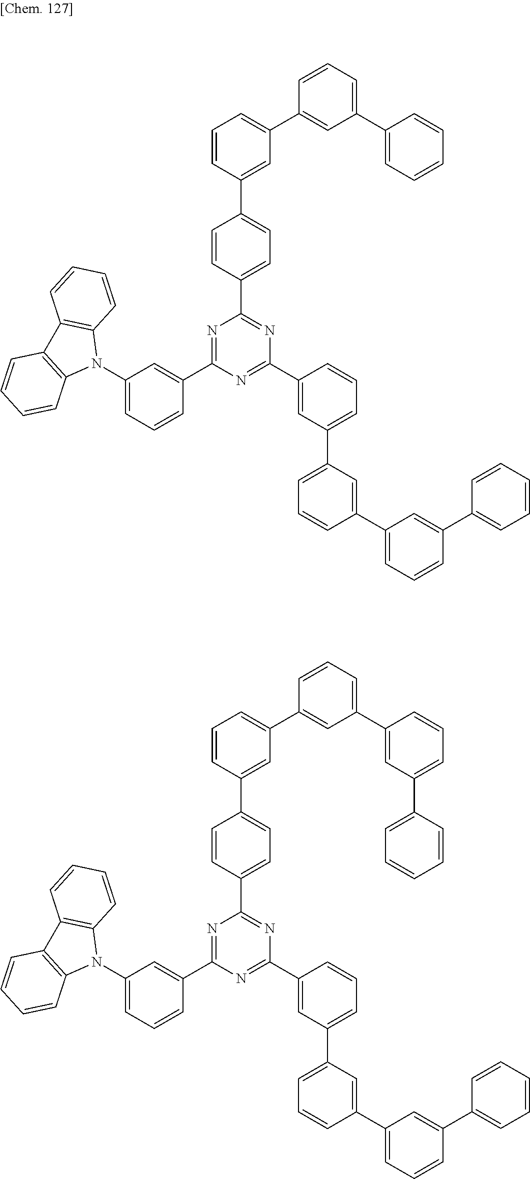 [SMILES: c1ccc(-c2cccc(-c3cccc(-c4ccc(-c5nc(-c6cccc(-c7cccc(-c8cccc(-c9ccccc9)c8)c7)c6)nc(-c6cccc(-n7c8ccccc8c8ccccc87)c6)n5)cc4)c3)c2)cc1 ; c1ccc(-c2cccc(-c3cccc(-c4cccc(-c5ccc(-c6nc(-c7cccc(-c8cccc(-c9cccc(-c%10ccccc%10)c9)c8)c7)nc(-c7cccc(-n8c9ccccc9c9ccccc98)c7)n6)cc5)c4)c3)c2)cc1]

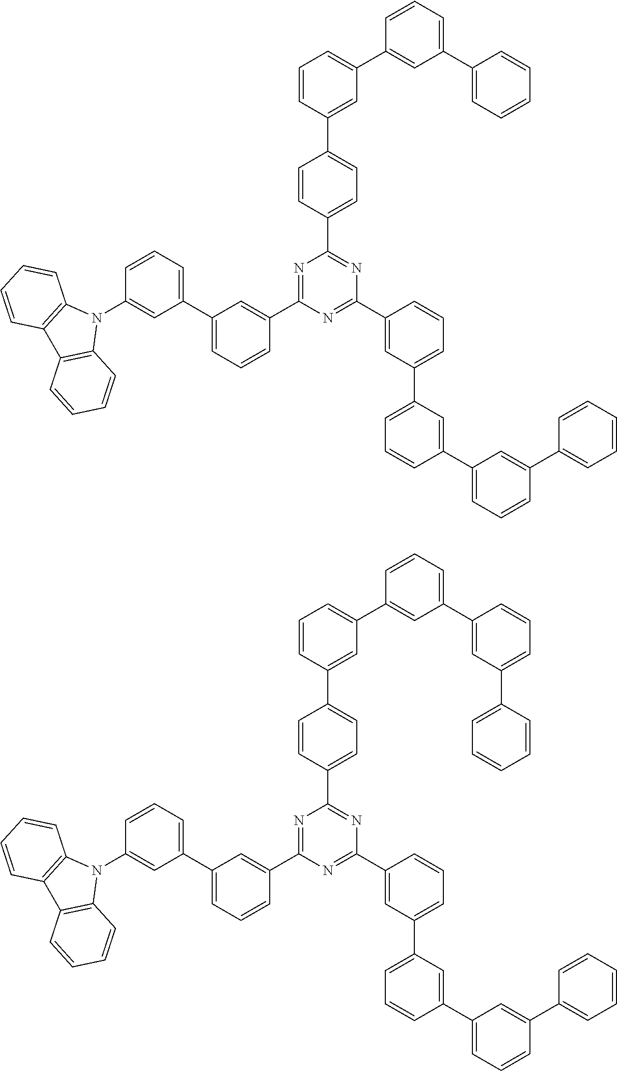 [SMILES: c1ccc(-c2cccc(-c3cccc(-c4ccc(-c5nc(-c6cccc(-c7cccc(-c8cccc(-c9ccccc9)c8)c7)c6)nc(-c6cccc(-c7cccc(-n8c9ccccc9c9ccccc98)c7)c6)n5)cc4)c3)c2)cc1 ; c1ccc(-c2cccc(-c3cccc(-c4cccc(-c5ccc(-c6nc(-c7cccc(-c8cccc(-c9cccc(-c%10ccccc%10)c9)c8)c7)nc(-c7cccc(-c8cccc(-n9c%10ccccc%10c%10ccccc%109)c8)c7)n6)cc5)c4)c3)c2)cc1]

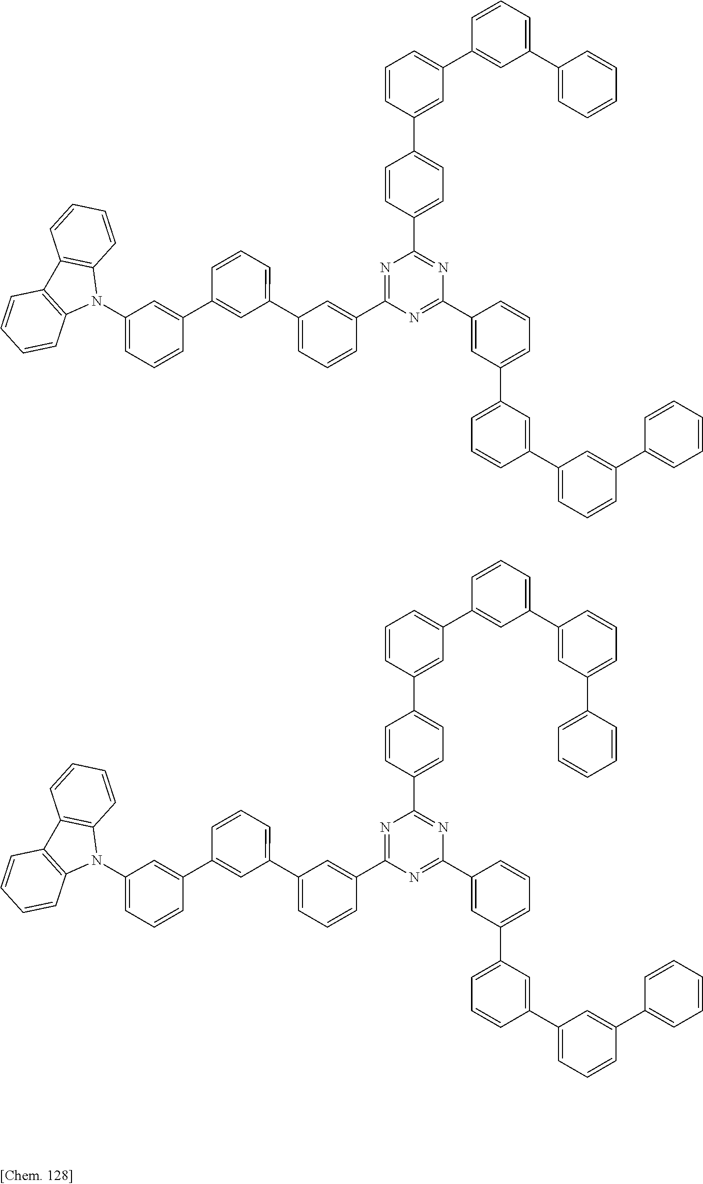 [SMILES: c1ccc(-c2cccc(-c3cccc(-c4ccc(-c5nc(-c6cccc(-c7cccc(-c8cccc(-c9ccccc9)c8)c7)c6)nc(-c6cccc(-c7cccc(-c8cccc(-n9c%10ccccc%10c%10ccccc%109)c8)c7)c6)n5)cc4)c3)c2)cc1 ; c1ccc(-c2cccc(-c3cccc(-c4cccc(-c5ccc(-c6nc(-c7cccc(-c8cccc(-c9cccc(-c%10ccccc%10)c9)c8)c7)nc(-c7cccc(-c8cccc(-c9cccc(-n%10c%11ccccc%11c%11ccccc%11%10)c9)c8)c7)n6)cc5)c4)c3)c2)cc1]

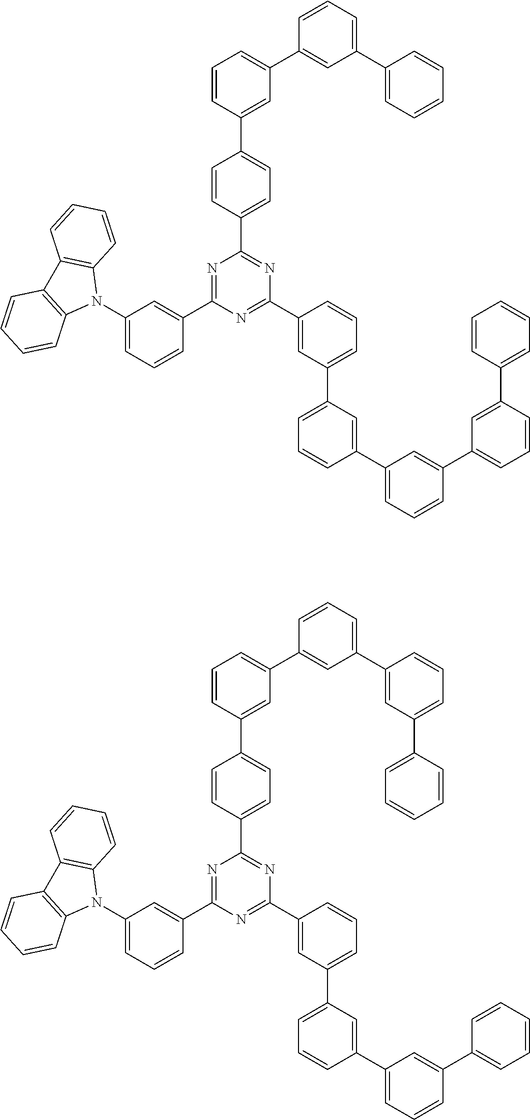 [SMILES: c1ccc(-c2cccc(-c3cccc(-c4ccc(-c5nc(-c6cccc(-c7cccc(-c8cccc(-c9cccc(-c%10ccccc%10)c9)c8)c7)c6)nc(-c6cccc(-n7c8ccccc8c8ccccc87)c6)n5)cc4)c3)c2)cc1 ; c1ccc(-c2cccc(-c3cccc(-c4cccc(-c5ccc(-c6nc(-c7cccc(-c8cccc(-c9cccc(-c%10ccccc%10)c9)c8)c7)nc(-c7cccc(-n8c9ccccc9c9ccccc98)c7)n6)cc5)c4)c3)c2)cc1]

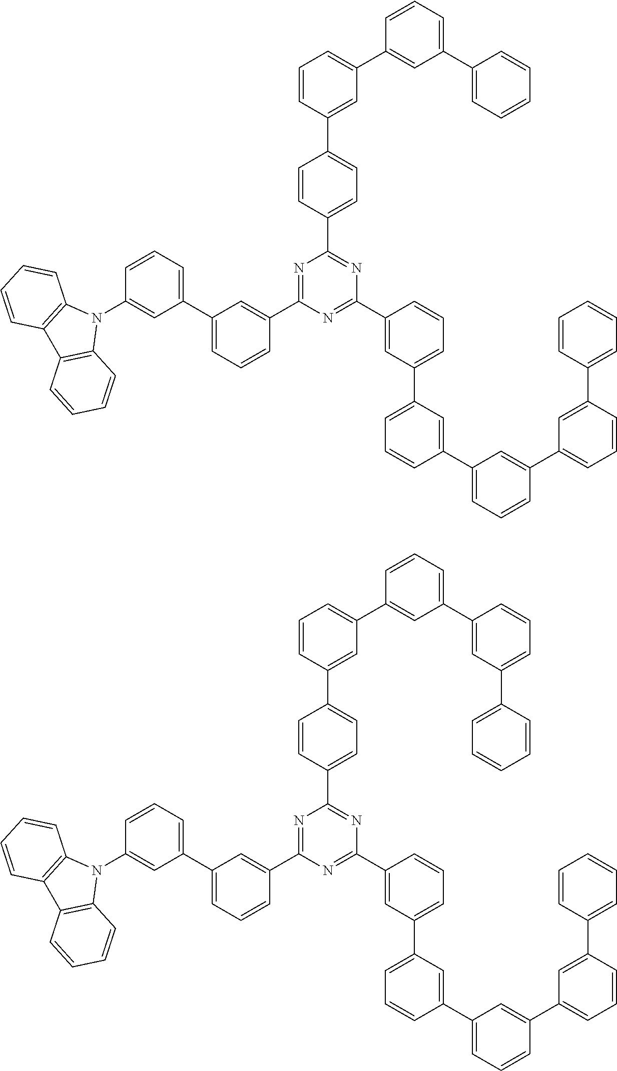 [SMILES: c1ccc(-c2cccc(-c3cccc(-c4ccc(-c5nc(-c6cccc(-c7cccc(-c8cccc(-c9cccc(-c%10ccccc%10)c9)c8)c7)c6)nc(-c6cccc(-c7cccc(-n8c9ccccc9c9ccccc98)c7)c6)n5)cc4)c3)c2)cc1 ; c1ccc(-c2cccc(-c3cccc(-c4cccc(-c5ccc(-c6nc(-c7cccc(-c8cccc(-c9cccc(-c%10cccc(-c%11ccccc%11)c%10)c9)c8)c7)nc(-c7cccc(-c8cccc(-n9c%10ccccc%10c%10ccccc%109)c8)c7)n6)cc5)c4)c3)c2)cc1]

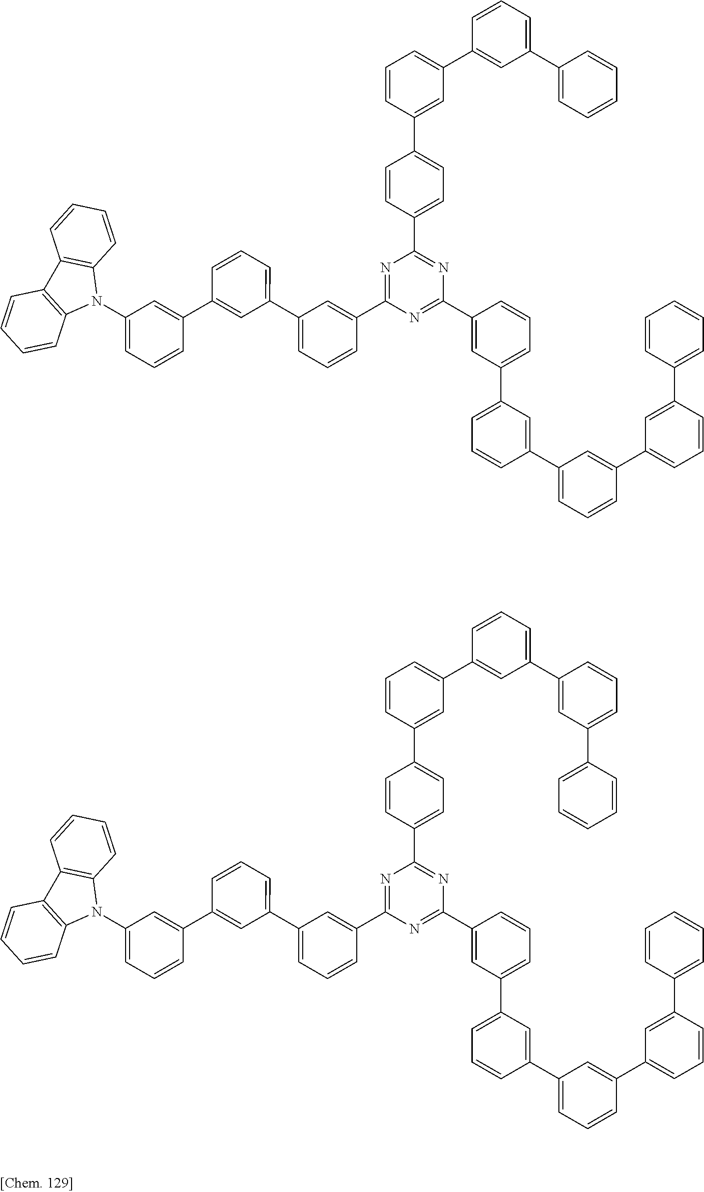 [SMILES: c1ccc(-c2cccc(-c3cccc(-c4ccc(-c5nc(-c6cccc(-c7cccc(-c8cccc(-c9cccc(-c%10ccccc%10)c9)c8)c7)c6)nc(-c6cccc(-c7cccc(-c8cccc(-n9c%10ccccc%10c%10ccccc%109)c8)c7)c6)n5)cc4)c3)c2)cc1 ; c1ccc(-c2cccc(-c3cccc(-c4cccc(-c5ccc(-c6nc(-c7cccc(-c8cccc(-c9cccc(-c%10cccc(-c%11ccccc%11)c%10)c9)c8)c7)nc(-c7cccc(-c8cccc(-c9cccc(-n%10c%11ccccc%11c%11ccccc%11%10)c9)c8)c7)n6)cc5)c4)c3)c2)cc1]

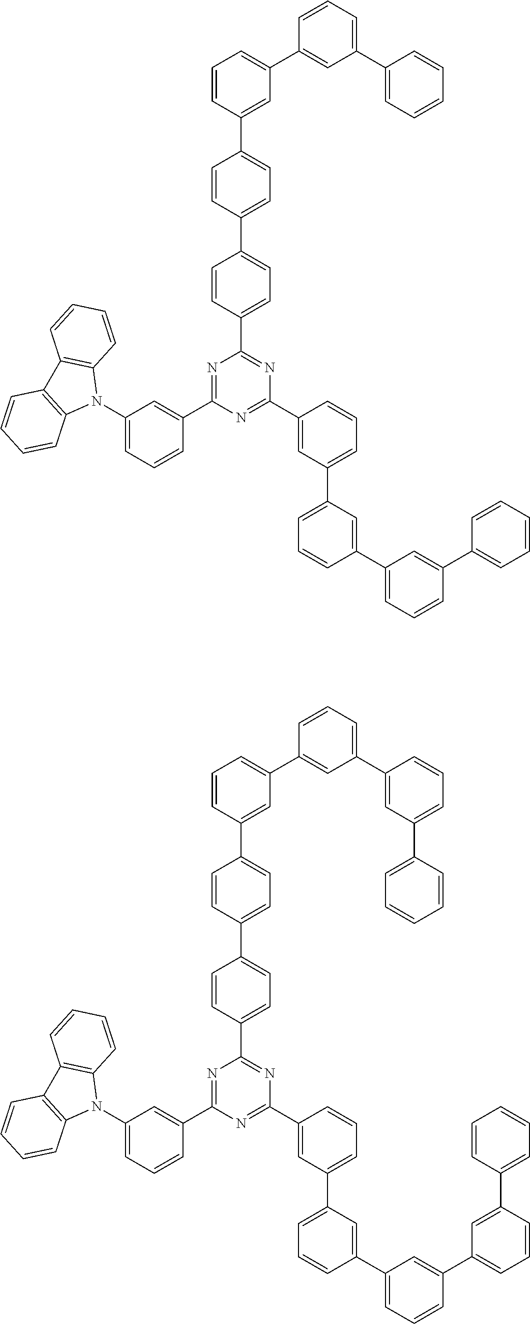 [SMILES: c1ccc(-c2cccc(-c3cccc(-c4ccc(-c5ccc(-c6nc(-c7cccc(-c8cccc(-c9cccc(-c%10ccccc%10)c9)c8)c7)nc(-c7cccc(-n8c9ccccc9c9ccccc98)c7)n6)cc5)cc4)c3)c2)cc1 ; c1ccc(-c2cccc(-c3cccc(-c4cccc(-c5ccc(-c6ccc(-c7nc(-c8cccc(-c9cccc(-c%10cccc(-c%11cccc(-c%12ccccc%12)c%11)c%10)c9)c8)nc(-c8cccc(-n9c%10ccccc%10c%10ccccc%109)c8)n7)cc6)cc5)c4)c3)c2)cc1]

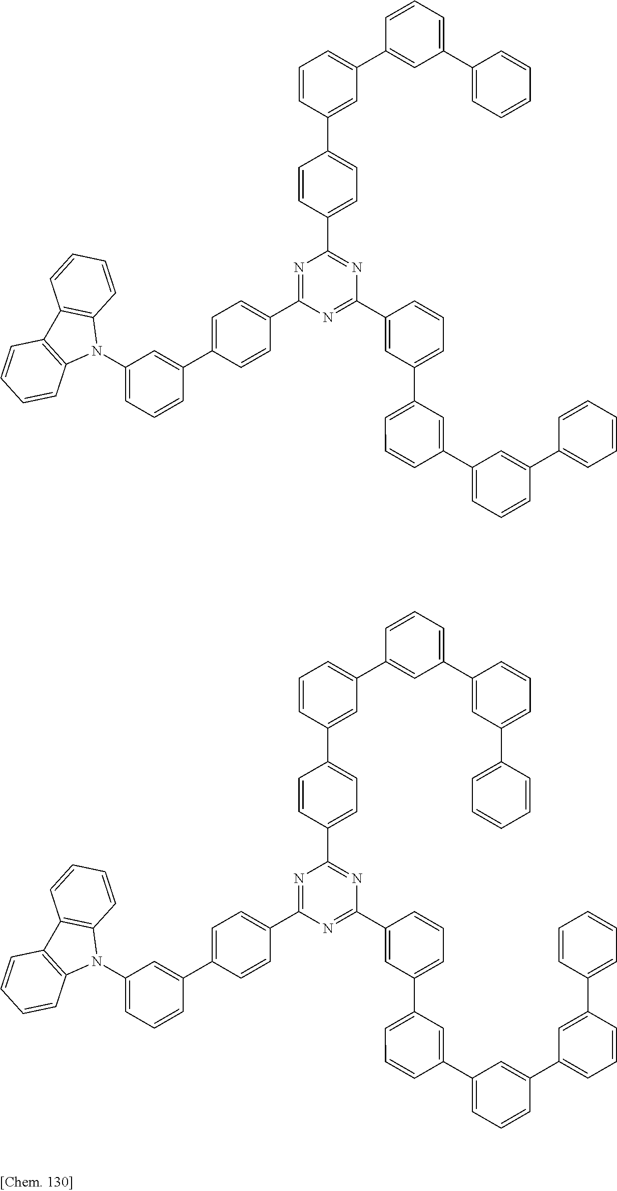 [SMILES: c1ccc(-c2cccc(-c3cccc(-c4ccc(-c5nc(-c6ccc(-c7cccc(-n8c9ccccc9c9ccccc98)c7)cc6)nc(-c6cccc(-c7cccc(-c8cccc(-c9ccccc9)c8)c7)c6)n5)cc4)c3)c2)cc1 ; c1ccc(-c2cccc(-c3cccc(-c4cccc(-c5ccc(-c6nc(-c7ccc(-c8cccc(-n9c%10ccccc%10c%10ccccc%109)c8)cc7)nc(-c7cccc(-c8cccc(-c9cccc(-c%10cccc(-c%11ccccc%11)c%10)c9)c8)c7)n6)cc5)c4)c3)c2)cc1]

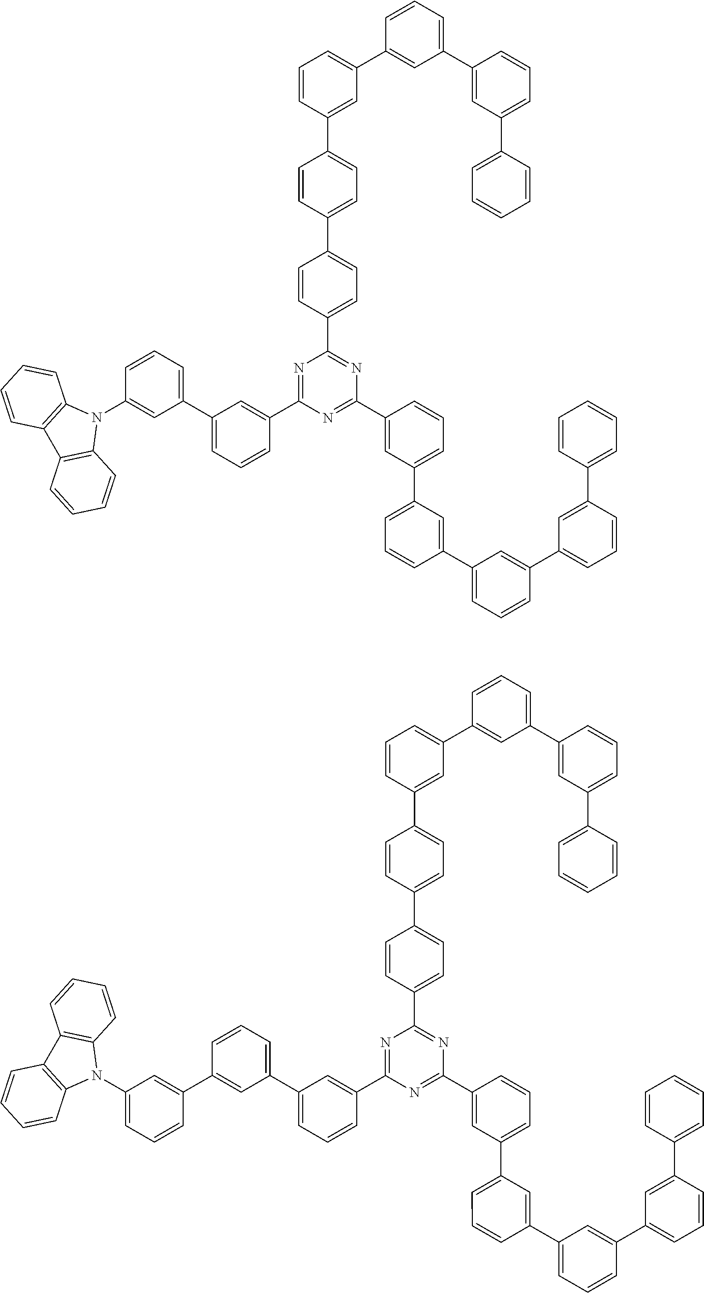 [SMILES: c1ccc(-c2cccc(-c3cccc(-c4cccc(-c5ccc(-c6ccc(-c7nc(-c8cccc(-c9cccc(-c%10cccc(-c%11cccc(-c%12ccccc%12)c%11)c%10)c9)c8)nc(-c8cccc(-c9cccc(-n%10c%11ccccc%11c%11ccccc%11%10)c9)c8)n7)cc6)cc5)c4)c3)c2)cc1 ; c1ccc(-c2cccc(-c3cccc(-c4cccc(-c5ccc(-c6ccc(-c7nc(-c8cccc(-c9cccc(-c%10cccc(-c%11cccc(-c%12ccccc%12)c%11)c%10)c9)c8)nc(-c8cccc(-c9cccc(-c%10cccc(-n%11c%12ccccc%12c%12ccccc%12%11)c%10)c9)c8)n7)cc6)cc5)c4)c3)c2)cc1]

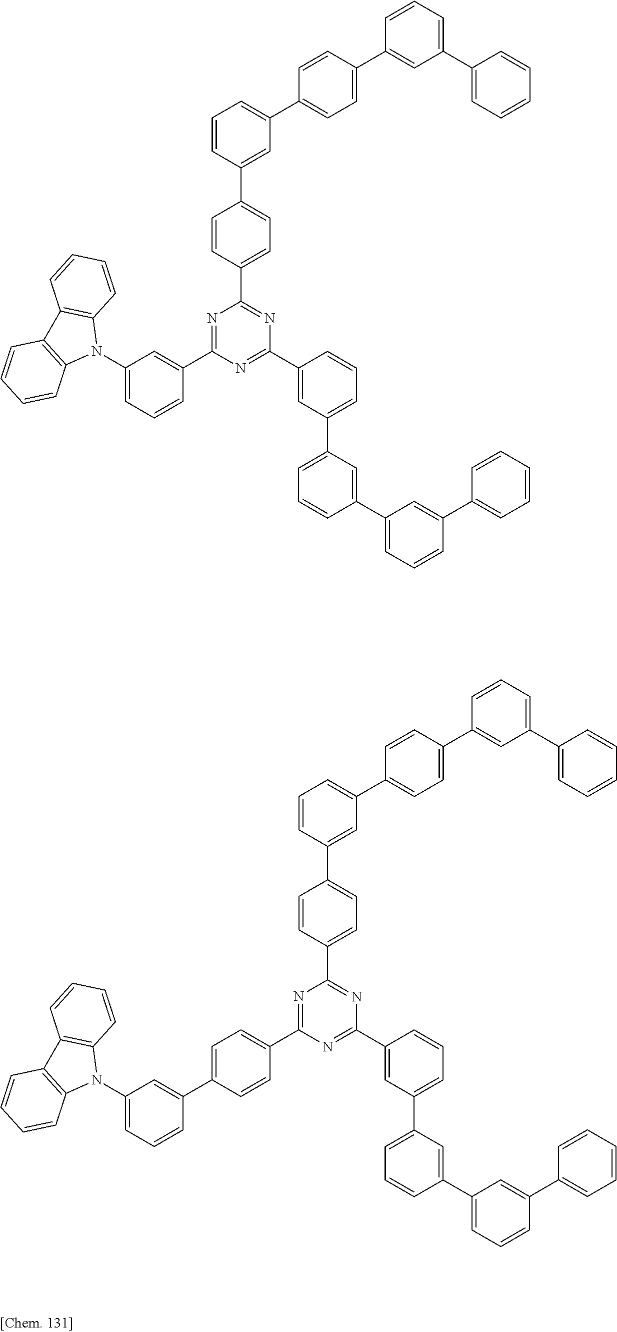 [SMILES: c1ccc(-c2cccc(-c3ccc(-c4cccc(-c5ccc(-c6nc(-c7cccc(-c8cccc(-c9cccc(-c%10ccccc%10)c9)c8)c7)nc(-c7cccc(-n8c9ccccc9c9ccccc98)c7)n6)cc5)c4)cc3)c2)cc1 ; c1ccc(-c2cccc(-c3ccc(-c4cccc(-c5ccc(-c6nc(-c7ccc(-c8cccc(-n9c%10ccccc%10c%10ccccc%109)c8)cc7)nc(-c7cccc(-c8cccc(-c9cccc(-c%10ccccc%10)c9)c8)c7)n6)cc5)c4)cc3)c2)cc1]

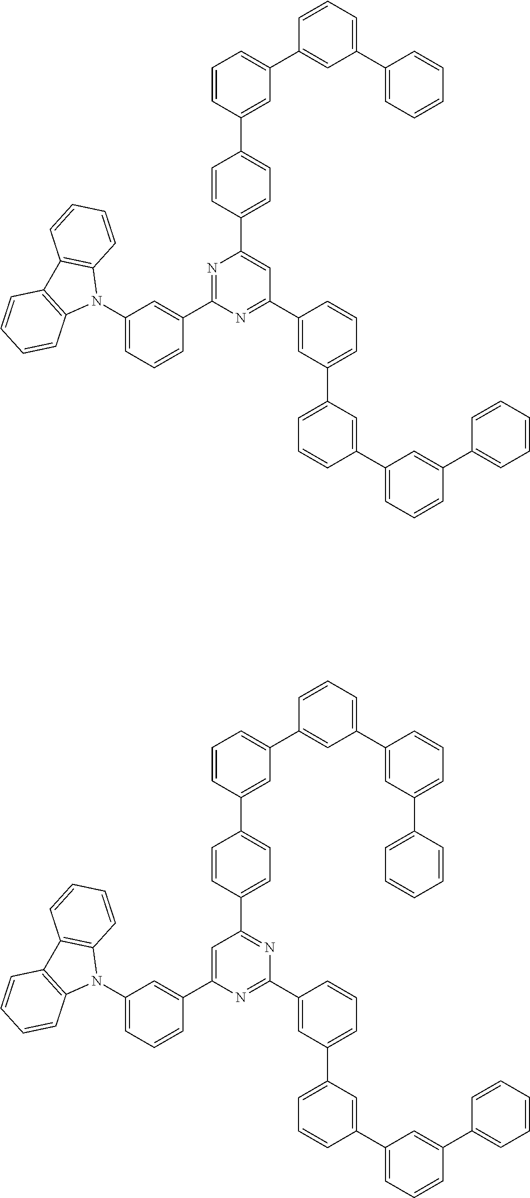 [SMILES: c1ccc(-c2cccc(-c3cccc(-c4ccc(-c5cc(-c6cccc(-c7cccc(-c8cccc(-c9ccccc9)c8)c7)c6)nc(-c6cccc(-n7c8ccccc8c8ccccc87)c6)n5)cc4)c3)c2)cc1 ; c1ccc(-c2cccc(-c3cccc(-c4cccc(-c5ccc(-c6cc(-c7cccc(-n8c9ccccc9c9ccccc98)c7)nc(-c7cccc(-c8cccc(-c9cccc(-c%10ccccc%10)c9)c8)c7)n6)cc5)c4)c3)c2)cc1]

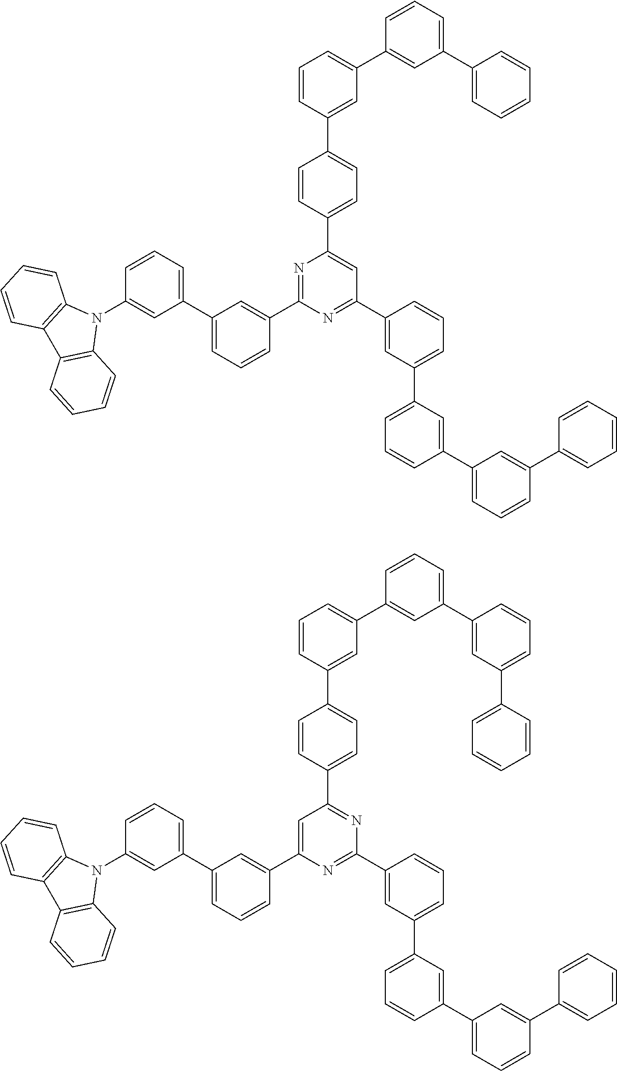 [SMILES: c1ccc(-c2cccc(-c3cccc(-c4ccc(-c5cc(-c6cccc(-c7cccc(-c8cccc(-c9ccccc9)c8)c7)c6)nc(-c6cccc(-c7cccc(-n8c9ccccc9c9ccccc98)c7)c6)n5)cc4)c3)c2)cc1 ; c1ccc(-c2cccc(-c3cccc(-c4cccc(-c5ccc(-c6cc(-c7cccc(-c8cccc(-n9c%10ccccc%10c%10ccccc%109)c8)c7)nc(-c7cccc(-c8cccc(-c9cccc(-c%10ccccc%10)c9)c8)c7)n6)cc5)c4)c3)c2)cc1]

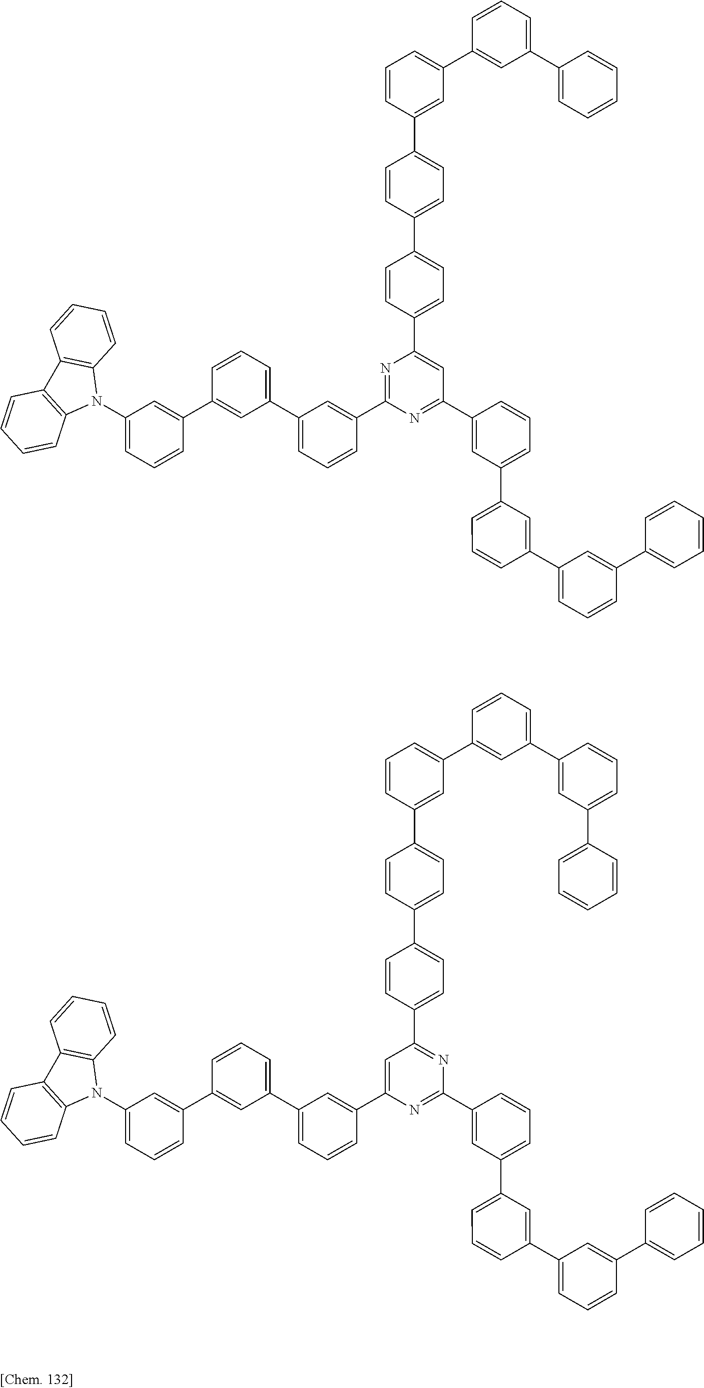 [SMILES: c1ccc(-c2cccc(-c3cccc(-c4ccc(-c5ccc(-c6cc(-c7cccc(-c8cccc(-c9cccc(-c%10ccccc%10)c9)c8)c7)nc(-c7cccc(-c8cccc(-c9cccc(-n%10c%11ccccc%11c%11ccccc%11%10)c9)c8)c7)n6)cc5)cc4)c3)c2)cc1 ; c1ccc(-c2cccc(-c3cccc(-c4cccc(-c5ccc(-c6ccc(-c7cc(-c8cccc(-c9cccc(-c%10cccc(-n%11c%12ccccc%12c%12ccccc%12%11)c%10)c9)c8)nc(-c8cccc(-c9cccc(-c%10cccc(-c%11ccccc%11)c%10)c9)c8)n7)cc6)cc5)c4)c3)c2)cc1]

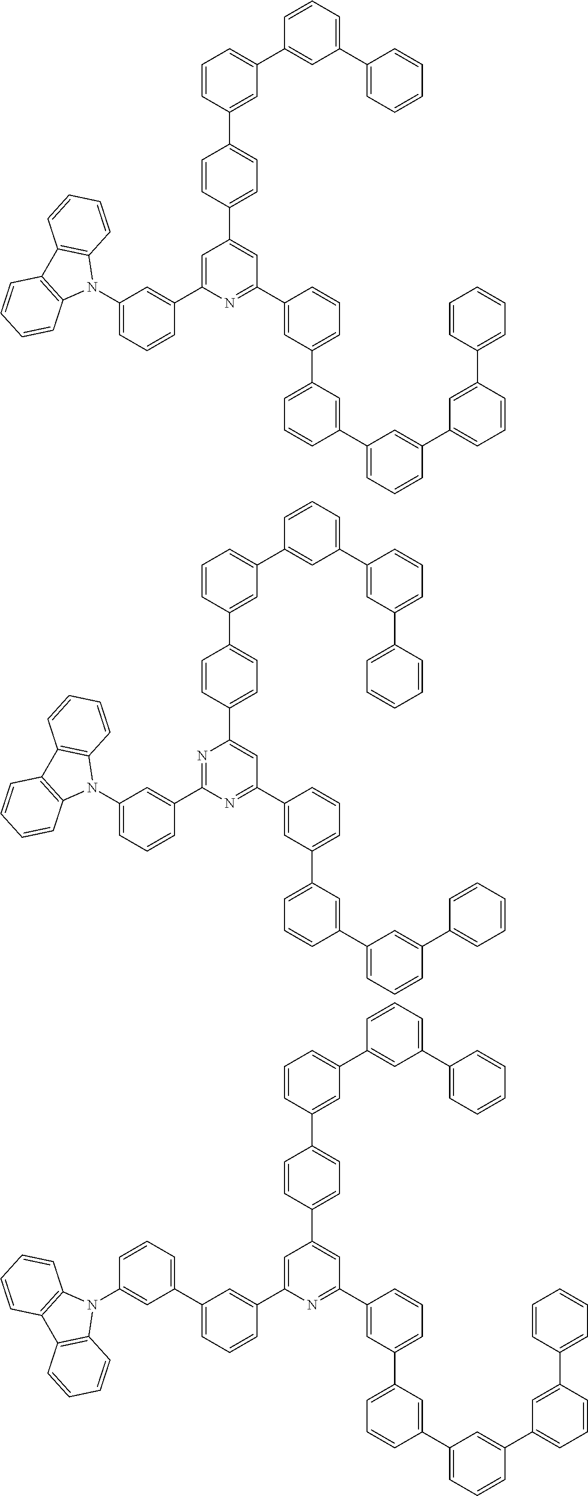

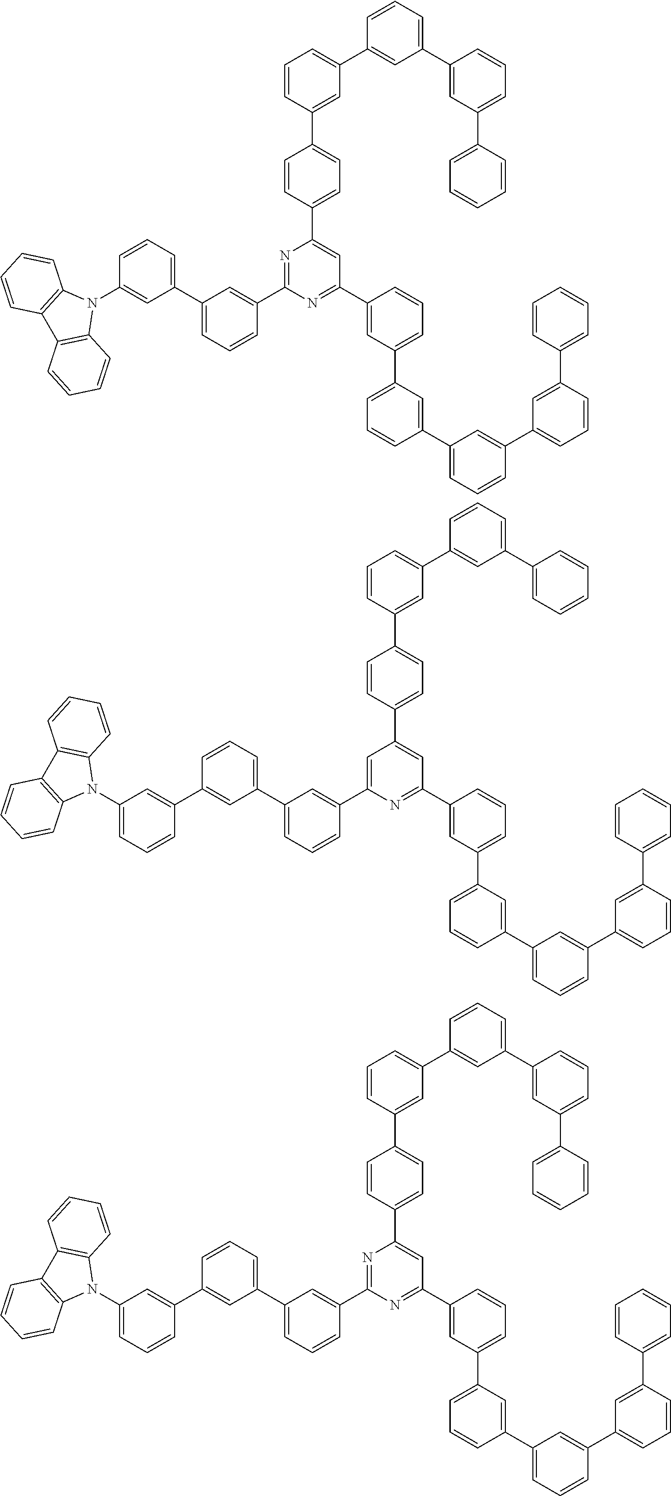

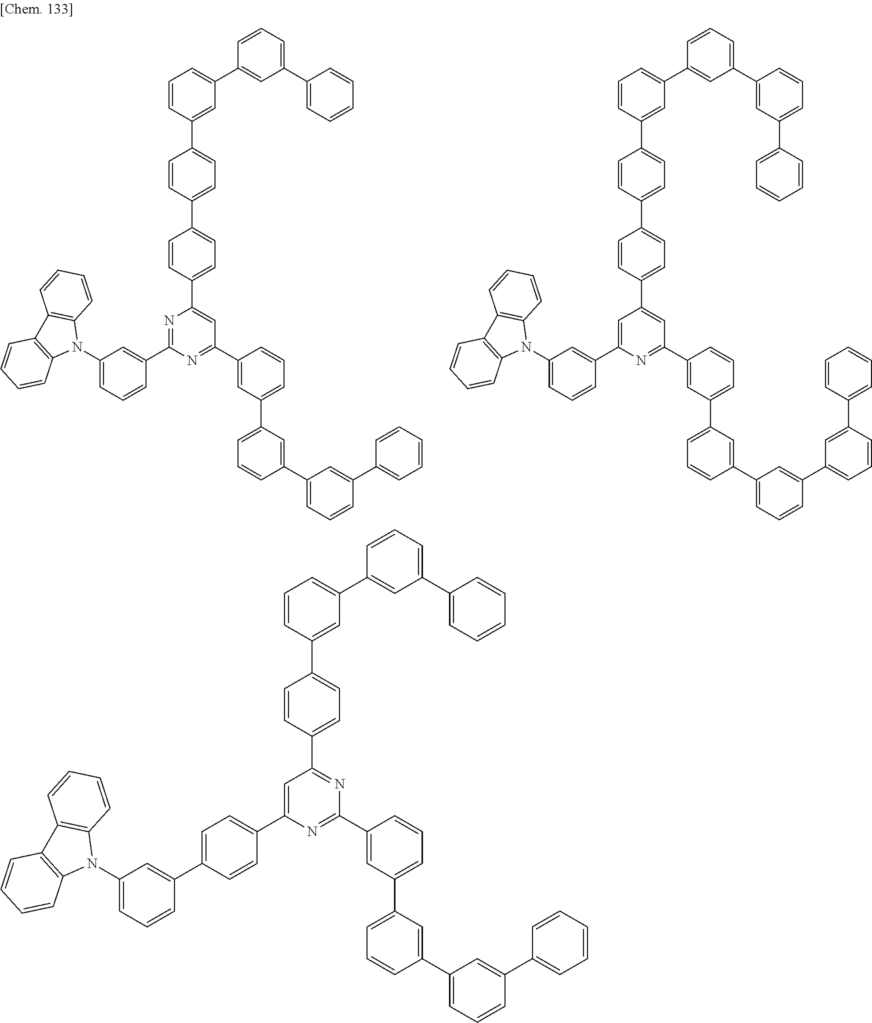 [SMILES: c1ccc(-c2cccc(-c3cccc(-c4ccc(-c5ccc(-c6cc(-c7cccc(-c8cccc(-c9cccc(-c%10ccccc%10)c9)c8)c7)nc(-c7cccc(-n8c9ccccc9c9ccccc98)c7)n6)cc5)cc4)c3)c2)cc1 ; c1ccc(-c2cccc(-c3cccc(-c4cccc(-c5ccc(-c6ccc(-c7cc(-c8cccc(-c9cccc(-c%10cccc(-c%11cccc(-c%12ccccc%12)c%11)c%10)c9)c8)nc(-c8cccc(-n9c%10ccccc%10c%10ccccc%109)c8)c7)cc6)cc5)c4)c3)c2)cc1 ; c1ccc(-c2cccc(-c3cccc(-c4ccc(-c5cc(-c6ccc(-c7cccc(-n8c9ccccc9c9ccccc98)c7)cc6)nc(-c6cccc(-c7cccc(-c8cccc(-c9ccccc9)c8)c7)c6)n5)cc4)c3)c2)cc1]

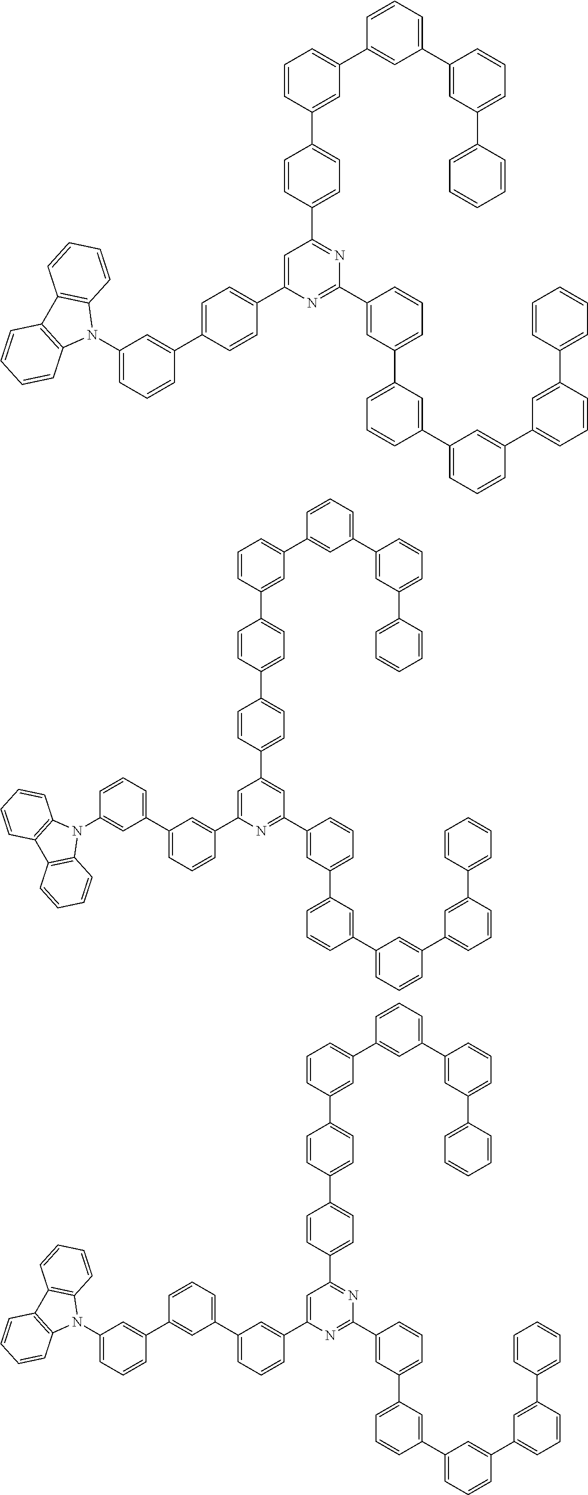

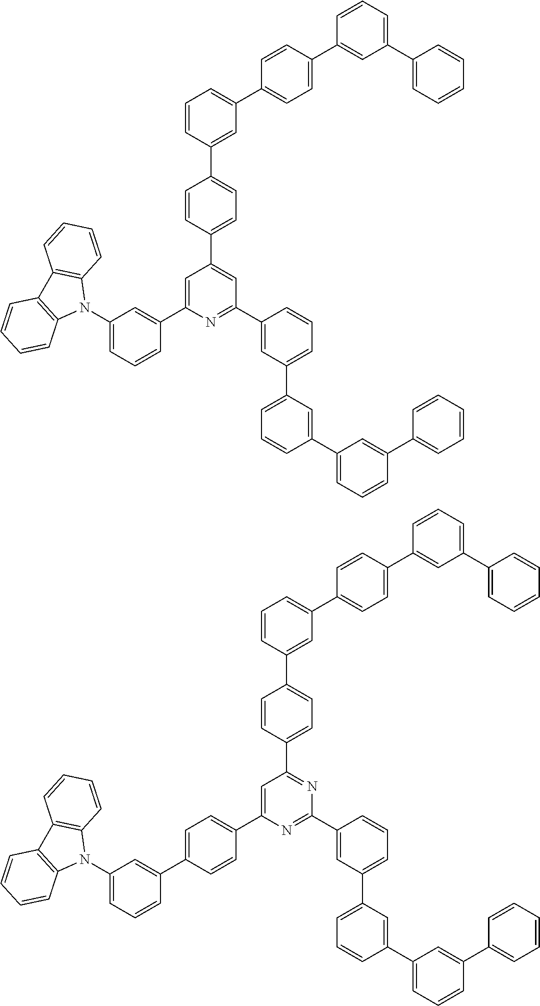 [SMILES: c1ccc(-c2cccc(-c3ccc(-c4cccc(-c5ccc(-c6cc(-c7cccc(-c8cccc(-c9cccc(-c%10ccccc%10)c9)c8)c7)nc(-c7cccc(-n8c9ccccc9c9ccccc98)c7)c6)cc5)c4)cc3)c2)cc1 ; c1ccc(-c2cccc(-c3ccc(-c4cccc(-c5ccc(-c6cc(-c7ccc(-c8cccc(-n9c%10ccccc%10c%10ccccc%109)c8)cc7)nc(-c7cccc(-c8cccc(-c9cccc(-c%10ccccc%10)c9)c8)c7)n6)cc5)c4)cc3)c2)cc1]

### <Reason why Compound (1-1) Exhibits Effect>

In the compound (1-1), a group bonded to the para position of W₁ has two or three benzene rings linked at the para position to spread a conjugate, LUMO is distributed therein, and thus the compound (1-1) is considered to be excellent in electron transportability. In addition, since there are three or less benzene rings that are conjugated and linked to the para position of W₁, the conjugate is not too long and a wide energy gap is obtained, and it is considered that in a case where the compound is used as a matrix material of the emission layer, the luminescent material is unlikely to be quenched, which is preferable. Since the compound (1-1) has at least one carbazolyl group, the compound (1-1) has excellent resistance to an alcohol-based solvent after the film formation.

In a nitrogen-containing six-membered ring containing W₁, W₂, and W₃ of the compound (1-1), a group bonded to a para position of W₃ is a 1,3-phenylene group and thus is not conjugated. Therefore, it is considered that in a case where the compound (1-1) has a wide energy gap and is used as a matrix material of the emission layer, the luminescent material is hardly quenched, which is preferable.

Since at least one of Za¹ of the compound (1-1) is a 1,3-phenylene group, conjugation with Za² which is a carbazolyl group does not occur. Therefore, it is considered that in a case where the compound (1-1) has a wide energy gap and is used as a matrix material of the emission layer, the luminescent material is hardly quenched, which is preferable.

Further, when —(Xa¹)_{g11}—Xa², —(Ya¹)ₕ₁₁—Ya², and —(Za¹)ⱼ₁₁—Za² represent the above preferred structures, a wide energy gap is obtained, and in a case where they are used as matrix materials of the emission layer, the luminescent material is hardly quenched.

The compound (1-1) has excellent solubility because the compound (1-1) contains an appropriately large amount of 1,3-phenylene group, and does not contain a 1,4-phenylene linkage structure longer than a terphenylene group. On the other hand, since f11+g11+h11+j11 is 5 or more, it is considered that after film formation, the compound (1-1) is difficult to dissolve in an alcohol-based solvent, that is, the compound (1-1) has solvent resistance. f11+g11+h11+j11 is preferably 7 or more and more preferably 9 or more from the viewpoint of solvent resistance to an alcohol-based solvent after film formation, and is preferably 15 or less from the viewpoint of stability.

In addition, since the compound (1-1) has an N-carbazolyl group in Za², an intermolecular interaction is enhanced, the solvent resistance is excellent, and particularly high solvent resistance to an alcohol-based solvent is exhibited.

### Compound (1-2)]

The compound (1-2) is a compound represented by the following formula (1-2).

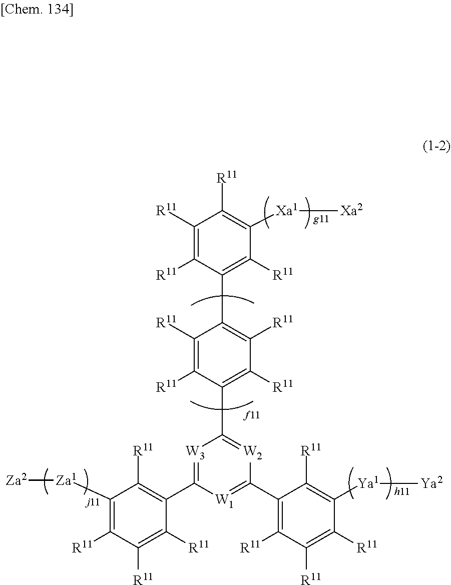

(In the formula (1-2),
W₁, W₂, and W₃ each independently represent —CH or a nitrogen atom, and at least one of W₁, W₂, and W₃ is a nitrogen atom,
Xa¹, Ya¹, and Za¹ each independently represent a 1,3-phenylene group which may have a substituent, or a 1,4-phenylene group which may have a substituent,
at least one of Ya^{l} and Za¹ is a 1,3-phenylene group which may have a substituent,
Xa² represents a phenyl group which may have a substituent,
Ya² and Za² each independently represent an N-carbazolyl group which may have a substituent,
f11 is 1 or 2,
g11 is an integer of 1 to 5,
h11 is an integer of 2 to 5,
j11 is an integer of 2 to 5,
f11+g11+h11+j11 is 6 or more, and
R¹¹ each independently represents a hydrogen atom or a substituent).
   <W₁, W₂, and W₃>

W₁, W₂, and W₃ in the formula (1-2) each independently represent —CH or a nitrogen atom, and at least one of W₁, W₂, and W₃ is a nitrogen atom. From the viewpoint of electron transportability and electron durability, it is preferable that at least W₁ is a nitrogen atom, more preferable that at least W₁ and W₂ are nitrogen atoms, and still more preferable that W₁, W₂, and W₃ are all nitrogen atoms.

That is, from the viewpoint of improving the electron transportability, a structure in which a group bonded to a para position which has two or three benzene rings linked at the para position to expand a conjugate and W₁ is a nitrogen atom is preferable, a pyrimidine structure in which one of W₂ and W₃ is a nitrogen atom in addition to W₁ is more preferable, and a triazine structure in which W₁, W₂, and W₃ are all nitrogen atoms is most preferable.

The material for an emission layer and a composition for forming an emission layer according to the present invention include at least one compound selected from the compound represented by the formula (1-1) and the compound represented by the formula (1-2), and it is preferable that all of W₁, W₂, and W₃ in the at least one compound are nitrogen atoms.

<—(Xa¹)_{g11}—Xa²>

In the formula (1-2), at least one of Xa^{l} is preferably a 1,3-phenylene group. Among those, —(Xa¹)_{g11}—Xa² is more preferably selected from the structure group of the following formula (Xa-2).

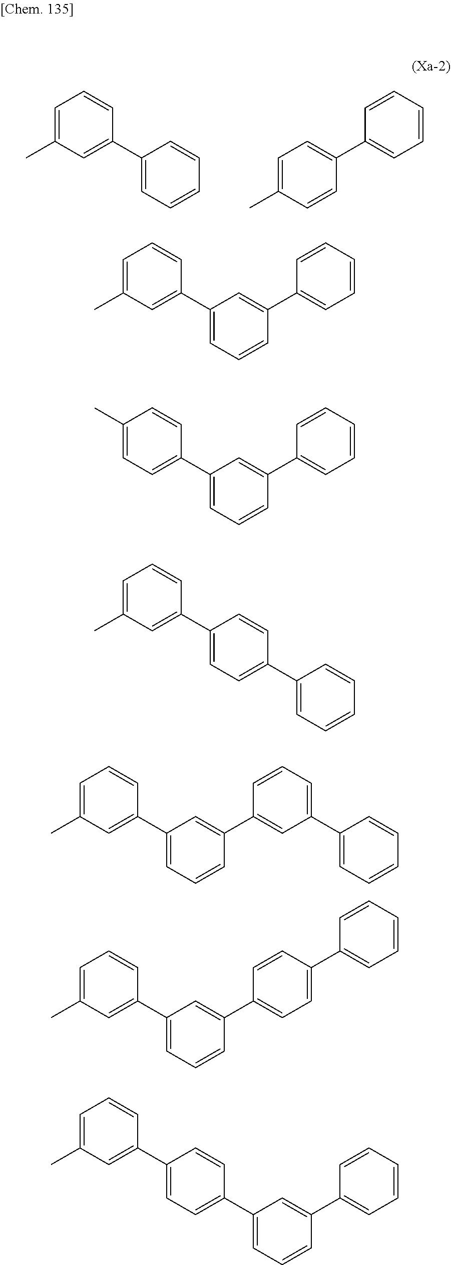

In these structures, a hydrogen atom may be substituted with a substituent selected from the substituent group Z2. A structure in which a hydrogen atom is not substituted is preferable.

<—(Ya¹)ₕ₁₁—Ya²>

In the formula (1-2), at least one of Ya¹ is preferably a 1,3-phenylene group. Among those, —(Ya¹)ₕ₁₁—Ya² is more preferably selected from the structure group of the following formula (Ya-2).

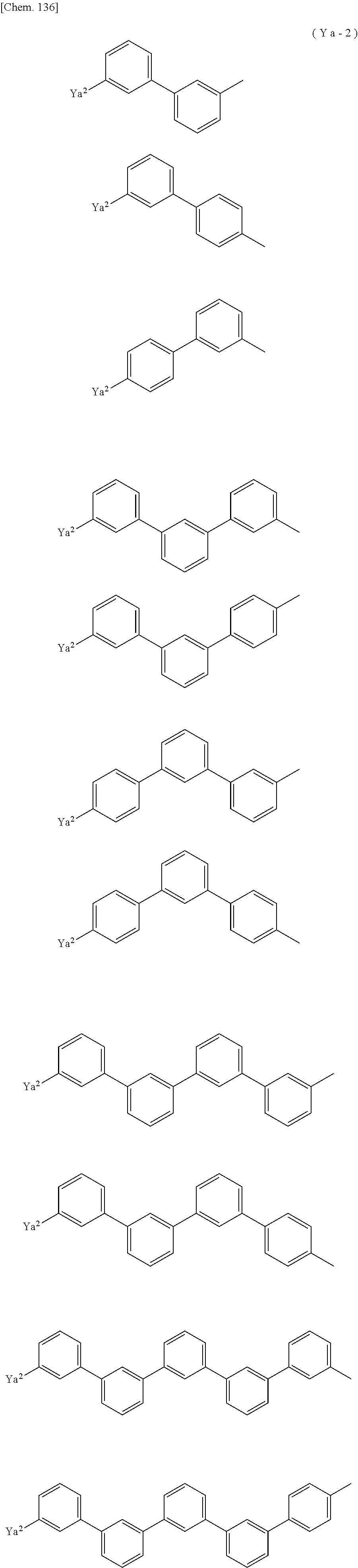

In these structures, hydrogen atoms on all benzene rings including a hydrogen atom on a benzene ring of an N-carbazolyl group of Ya² may be substituted with substituents selected from the substituent group Z2. A structure in which a hydrogen atom is not substituted is preferable.

<—(Za¹)ⱼ₁₁—Za²>

In the formula (1-2), at least one of Za¹ is preferably a 1,3-phenylene group. Among those, —(Za¹)ⱼ₁₁—Za² is more preferably selected from the structure group of the following formula (Za-2).

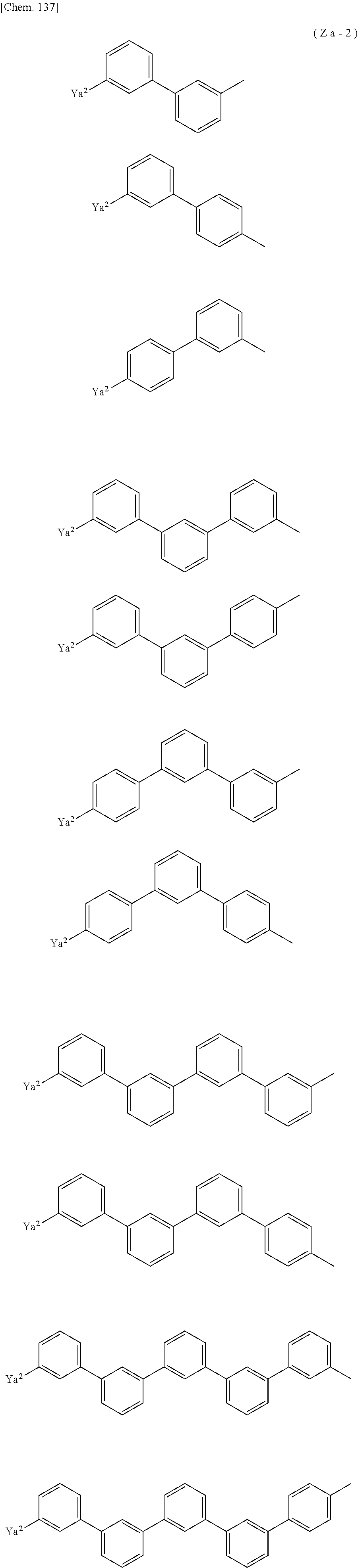

In these structures, hydrogen atoms on all benzene rings including a hydrogen atom on a benzene ring of an N-carbazolyl group of Za² may be substituted with substituents selected from the substituent group Z2. A structure in which a hydrogen atom is not substituted is preferable.

### <Preferred Structure of Compound (1-2)>

In the formula (1-2), h11 is preferably 2 or more, and preferably 2 or 4.

In addition, j11 is preferably 2 or more, and preferably 2 or 4.

When h11 and j11 are the above lower limits or more, the solubility is good and the stability is also good.

In the formula (1-2), it is preferable that at least one of Xa¹ is a 1,3-phenylene group, and more preferable that all Xa¹ are 1,3-phenylene groups. When Xa¹ is a 1,3-phenylene group, the conjugate is broken and the solubility is increased.

In addition, in the formula (1-2), it is preferable that at least one of Ya¹ is a 1,3-phenylene group, and more preferable that all Ya¹ are 1,3-phenylene groups. When Ya¹ is a 1,3-phenylene group, the conjugate is broken and the solubility is increased.

Further, in the formula (1-2), it is preferable that at least one of Za¹ is a 1,3-phenylene group, and more preferable that all Za¹ are 1,3-phenylene groups. When Za¹ is a 1,3-phenylene group, the conjugate is broken and the solubility is increased.

Further. in the formula (1-21. it is preferable that at least one of Ya¹ is a 1.3-phenylene group and at least one of Za¹ is a 1,3-phenylene group.

### <Molecular Weight of Compound (1-2)>

The molecular weight of the compound (1-2) is generally 5,000 or less, preferably 3,000 or less, more preferably 2,500 or less, particularly preferably 2,000 or less, and most preferably 1,800 or less. A lower limit of the molecular weight of the compound (1-2) is preferably 930 or more, more preferably 1,000 or more, and particularly preferably 1,200 or more.

### Specific Examples of Compound (1-2)

A specific structure of the compound (1-2) is not particularly limited, and examples thereof include the following compounds.

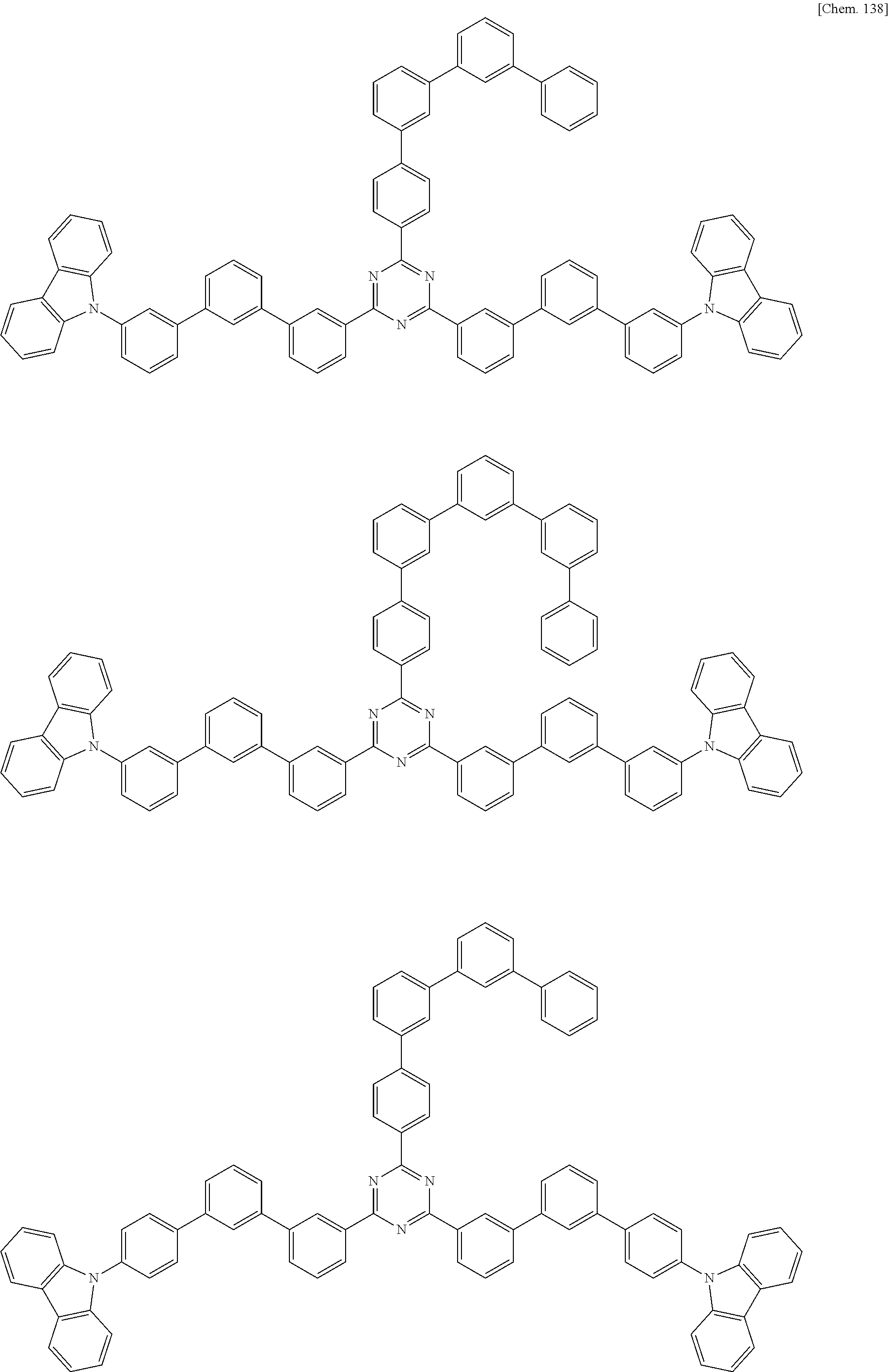

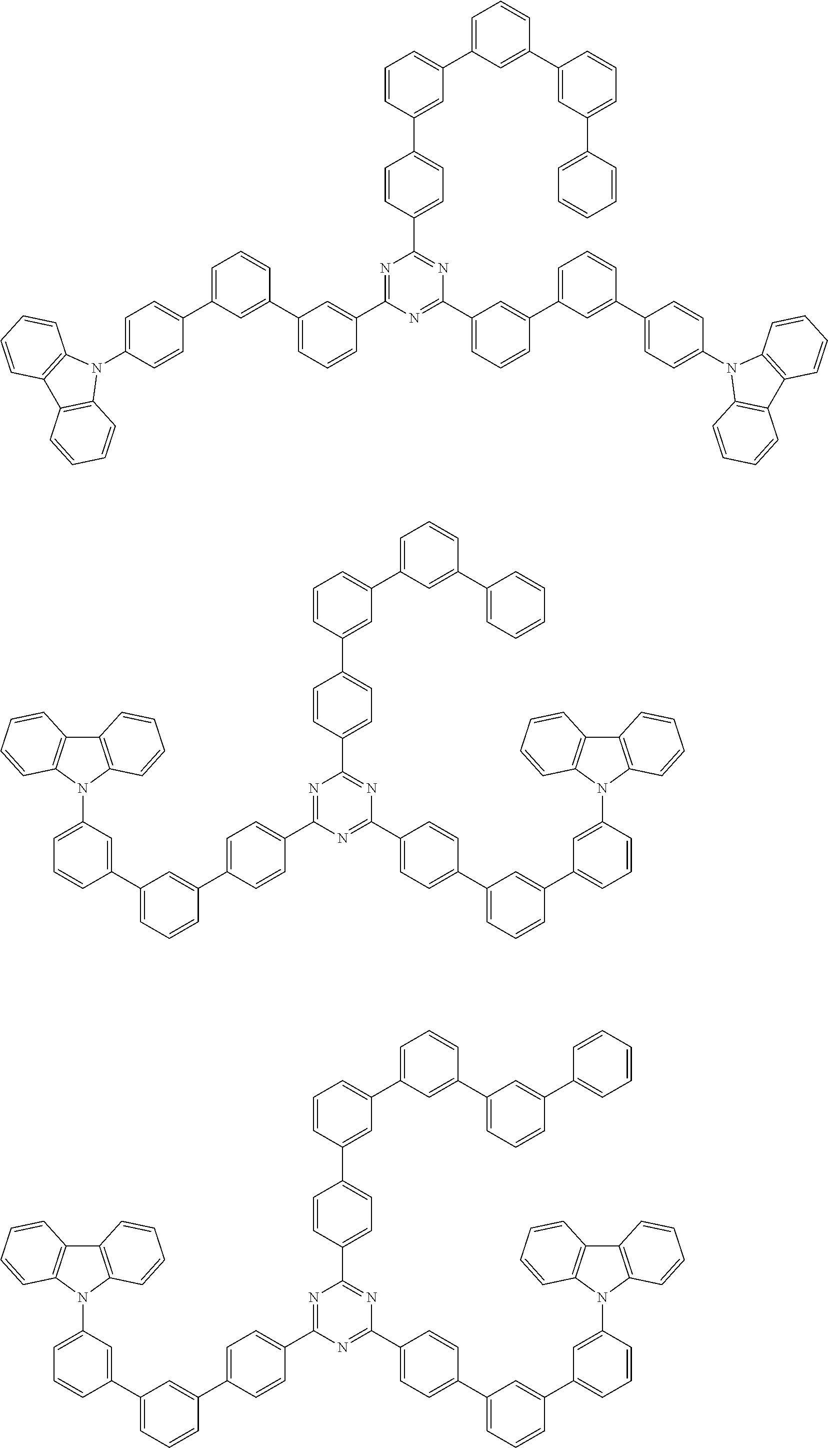

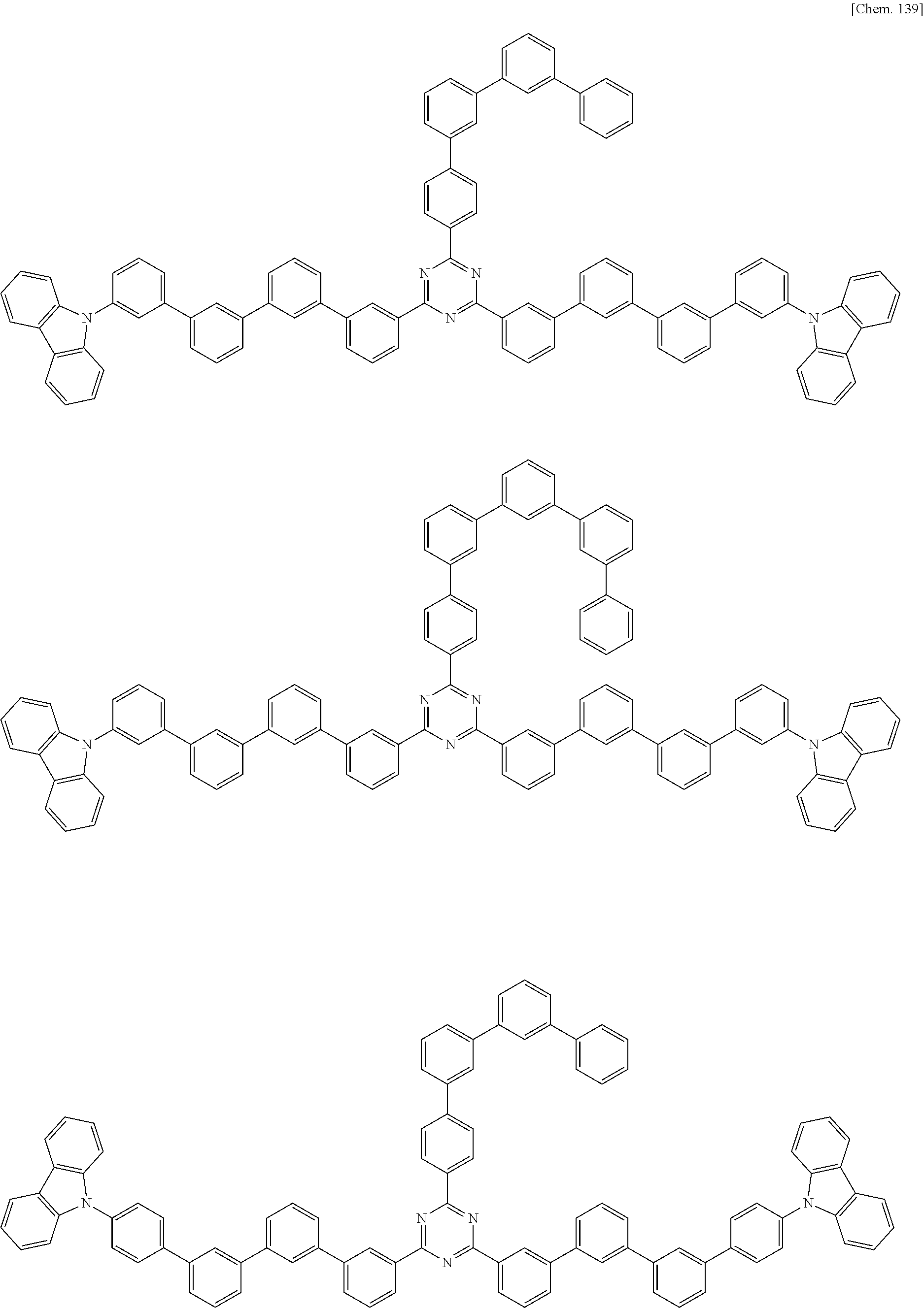

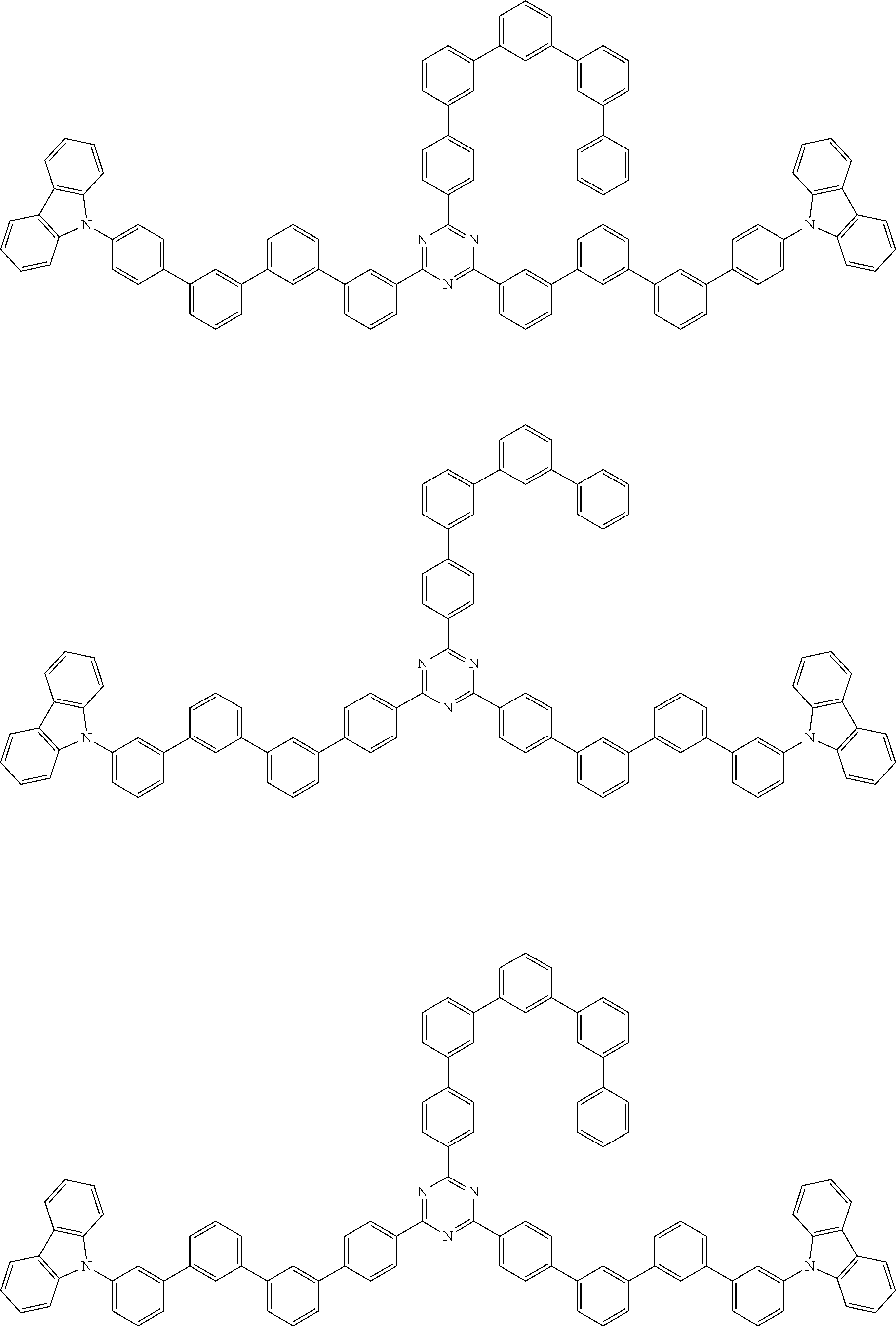

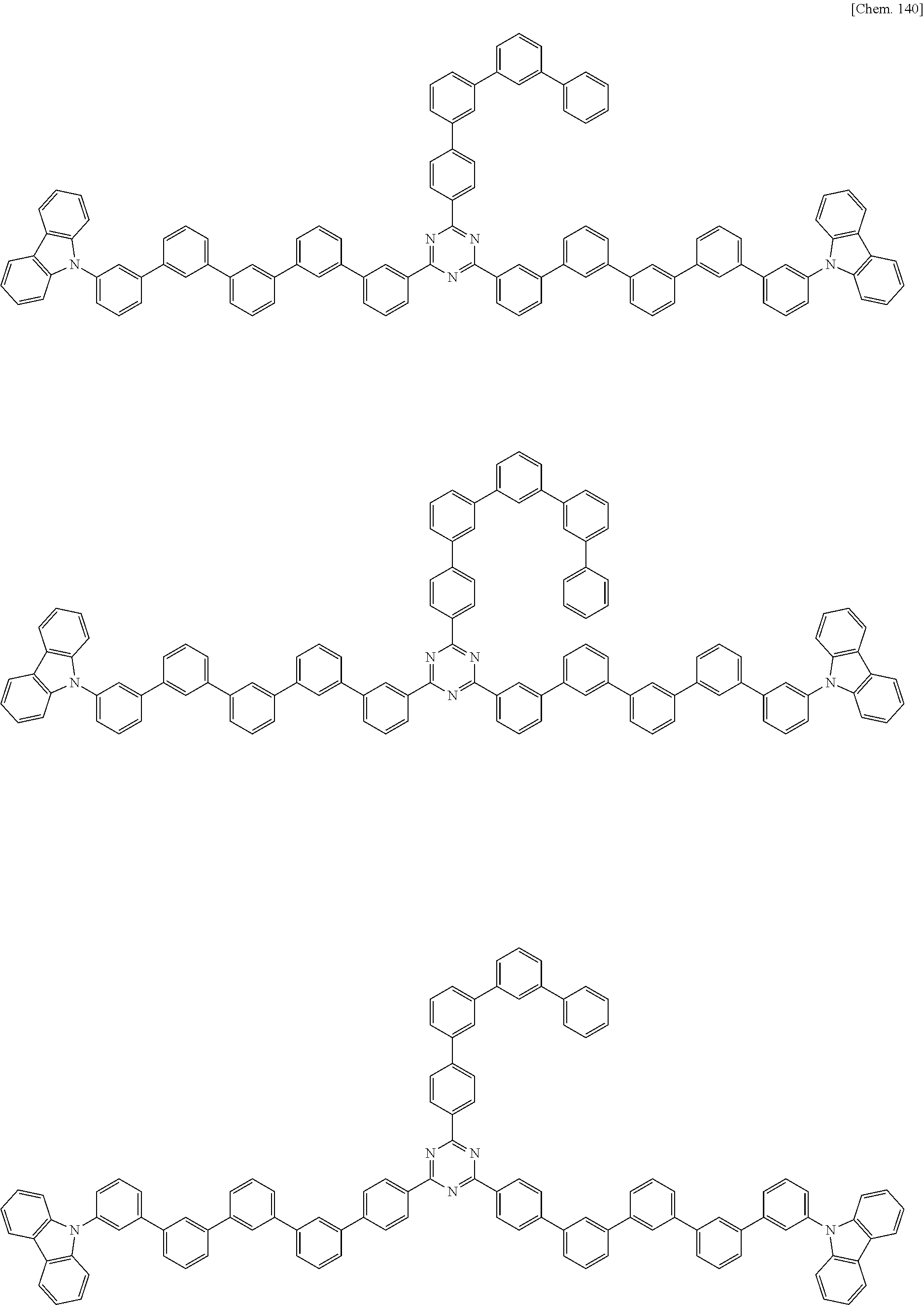

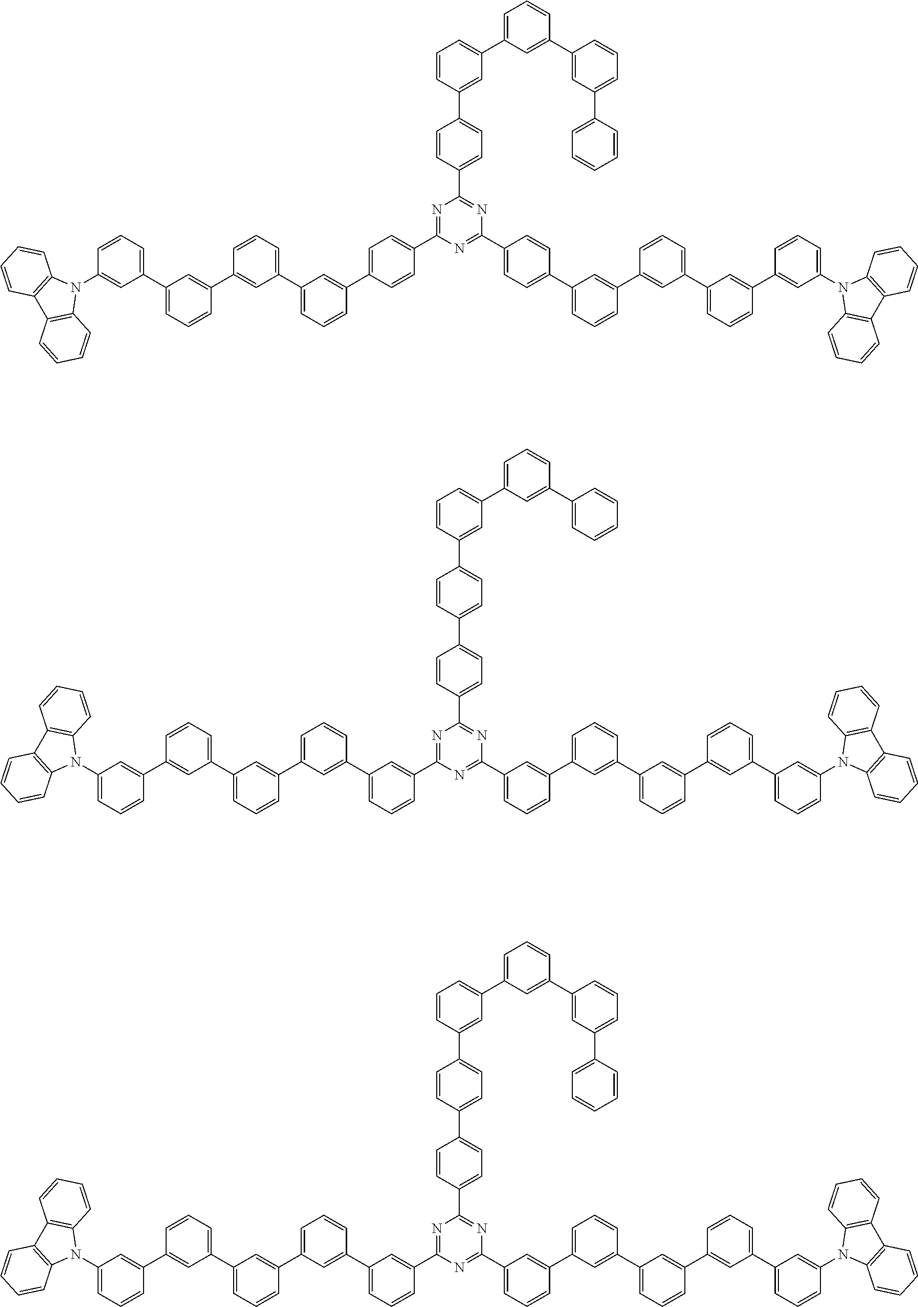

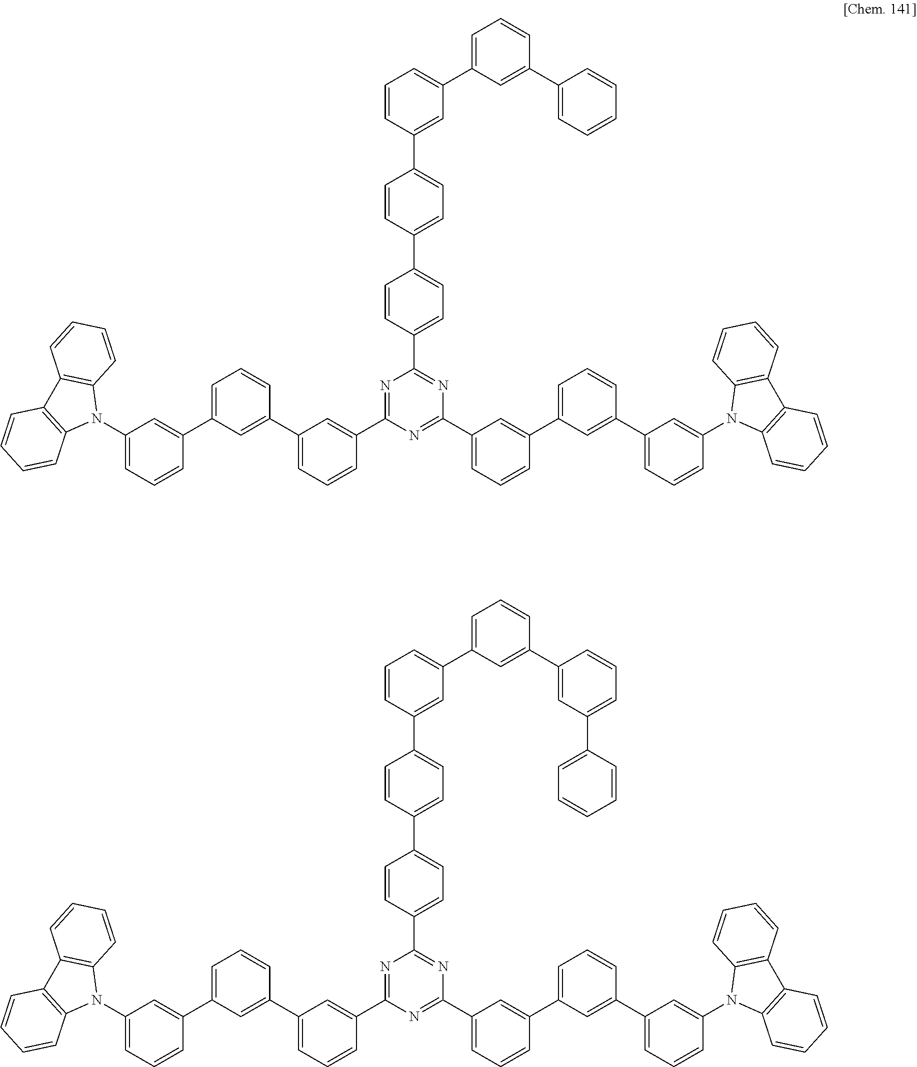 [SMILES: c1ccc(-c2cccc(-c3cccc(-c4ccc(-c5ccc(-c6nc(-c7cccc(-c8cccc(-c9cccc(-n%10c%11ccccc%11c%11ccccc%11%10)c9)c8)c7)nc(-c7cccc(-c8cccc(-c9cccc(-n%10c%11ccccc%11c%11ccccc%11%10)c9)c8)c7)n6)cc5)cc4)c3)c2)cc1 ; c1ccc(-c2cccc(-c3cccc(-c4cccc(-c5ccc(-c6ccc(-c7nc(-c8cccc(-c9cccc(-c%10cccc(-n%11c%12ccccc%12c%12ccccc%12%11)c%10)c9)c8)nc(-c8cccc(-c9cccc(-c%10cccc(-n%11c%12ccccc%12c%12ccccc%12%11)c%10)c9)c8)n7)cc6)cc5)c4)c3)c2)cc1]

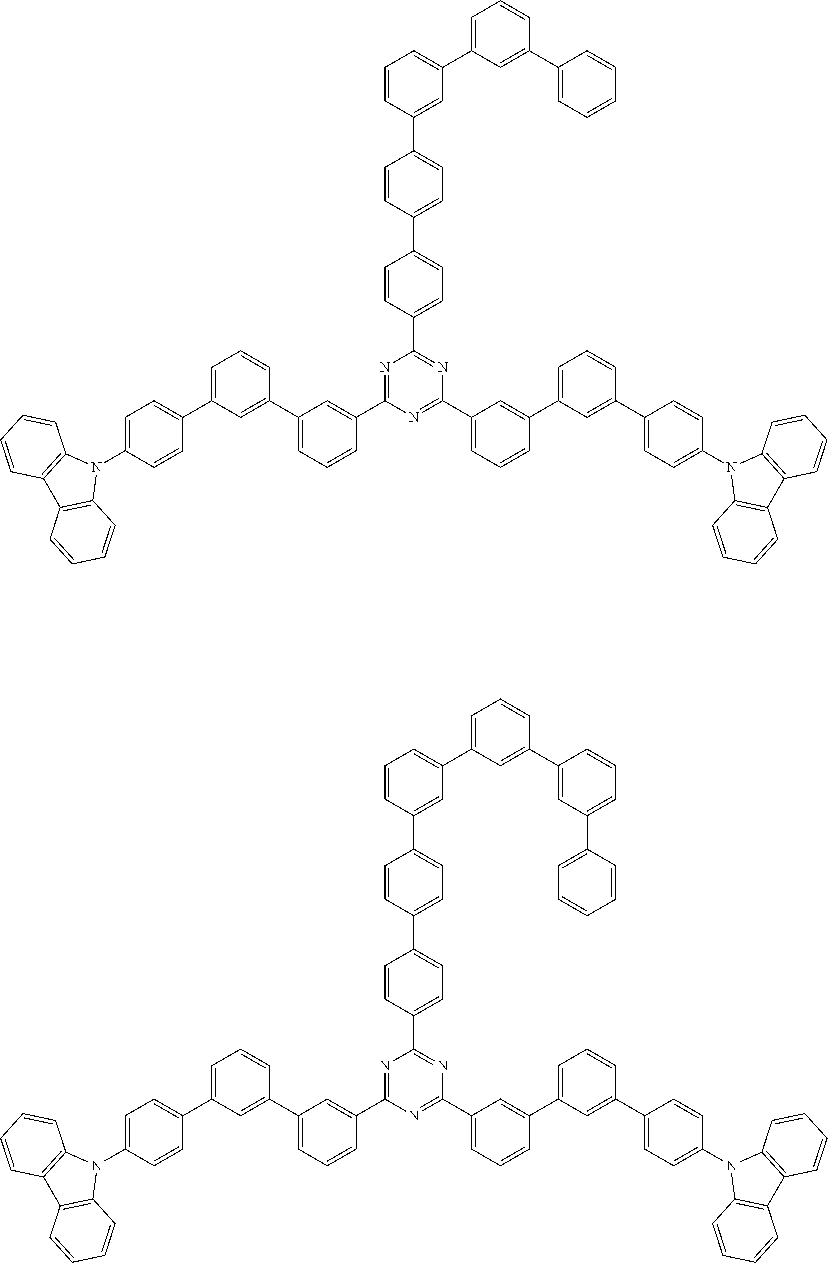 [SMILES: c1ccc(-c2cccc(-c3cccc(-c4ccc(-c5ccc(-c6nc(-c7cccc(-c8cccc(-c9ccc(-n%10c%11ccccc%11c%11ccccc%11%10)cc9)c8)c7)nc(-c7cccc(-c8cccc(-c9ccc(-n%10c%11ccccc%11c%11ccccc%11%10)cc9)c8)c7)n6)cc5)cc4)c3)c2)cc1 ; c1ccc(-c2cccc(-c3cccc(-c4cccc(-c5ccc(-c6ccc(-c7nc(-c8cccc(-c9cccc(-c%10ccc(-n%11c%12ccccc%12c%12ccccc%12%11)cc%10)c9)c8)nc(-c8cccc(-c9cccc(-c%10ccc(-n%11c%12ccccc%12c%12ccccc%12%11)cc%10)c9)c8)n7)cc6)cc5)c4)c3)c2)cc1]

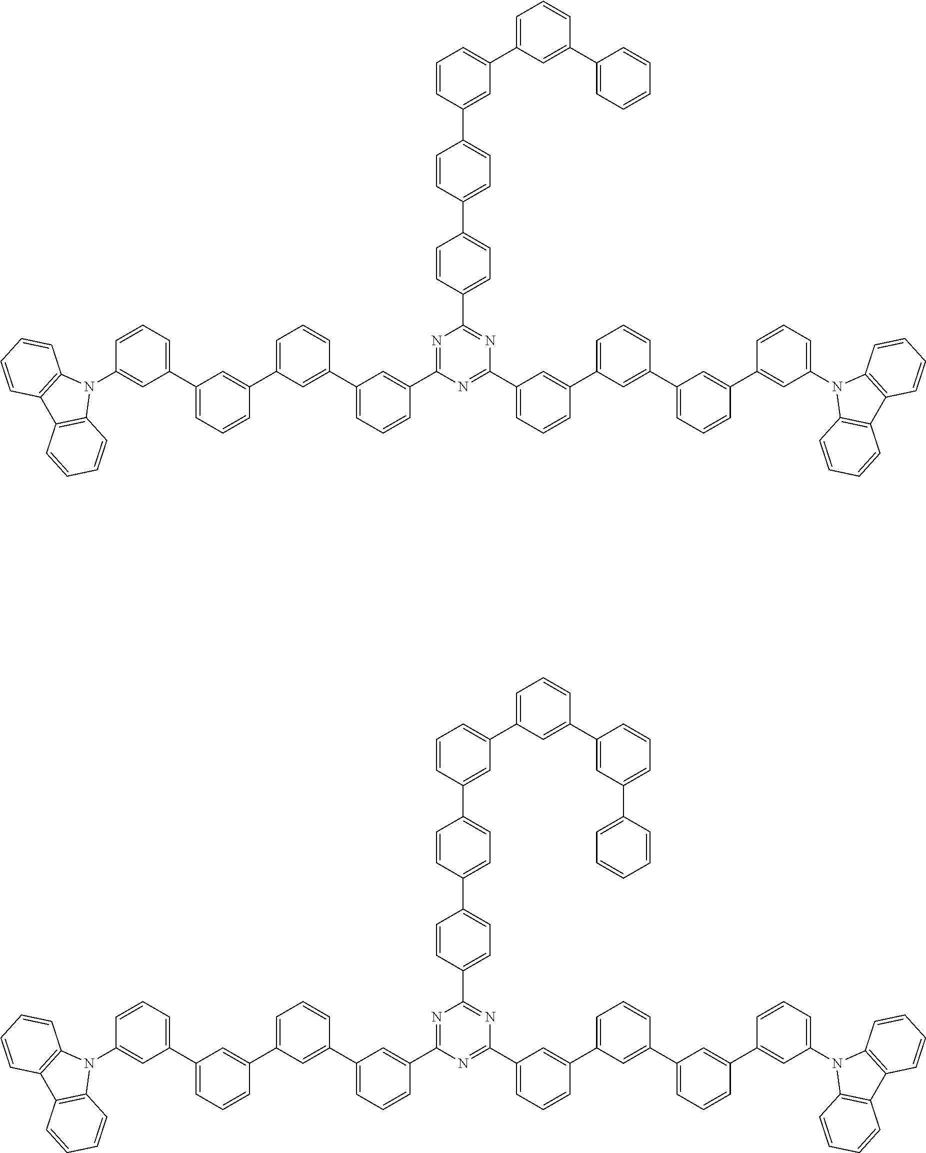 [SMILES: c1ccc(-c2cccc(-c3cccc(-c4ccc(-c5ccc(-c6nc(-c7cccc(-c8cccc(-c9cccc(-c%10cccc(-n%11c%12ccccc%12c%12ccccc%12%11)c%10)c9)c8)c7)nc(-c7cccc(-c8cccc(-c9cccc(-c%10cccc(-n%11c%12ccccc%12c%12ccccc%12%11)c%10)c9)c8)c7)n6)cc5)cc4)c3)c2)cc1 ; c1ccc(-c2cccc(-c3cccc(-c4cccc(-c5ccc(-c6ccc(-c7nc(-c8cccc(-c9cccc(-c%10cccc(-c%11cccc(-n%12c%13ccccc%13c%13ccccc%13%12)c%11)c%10)c9)c8)nc(-c8cccc(-c9cccc(-c%10cccc(-c%11cccc(-n%12c%13ccccc%13c%13ccccc%13%12)c%11)c%10)c9)c8)n7)cc6)cc5)c4)c3)c2)cc1]

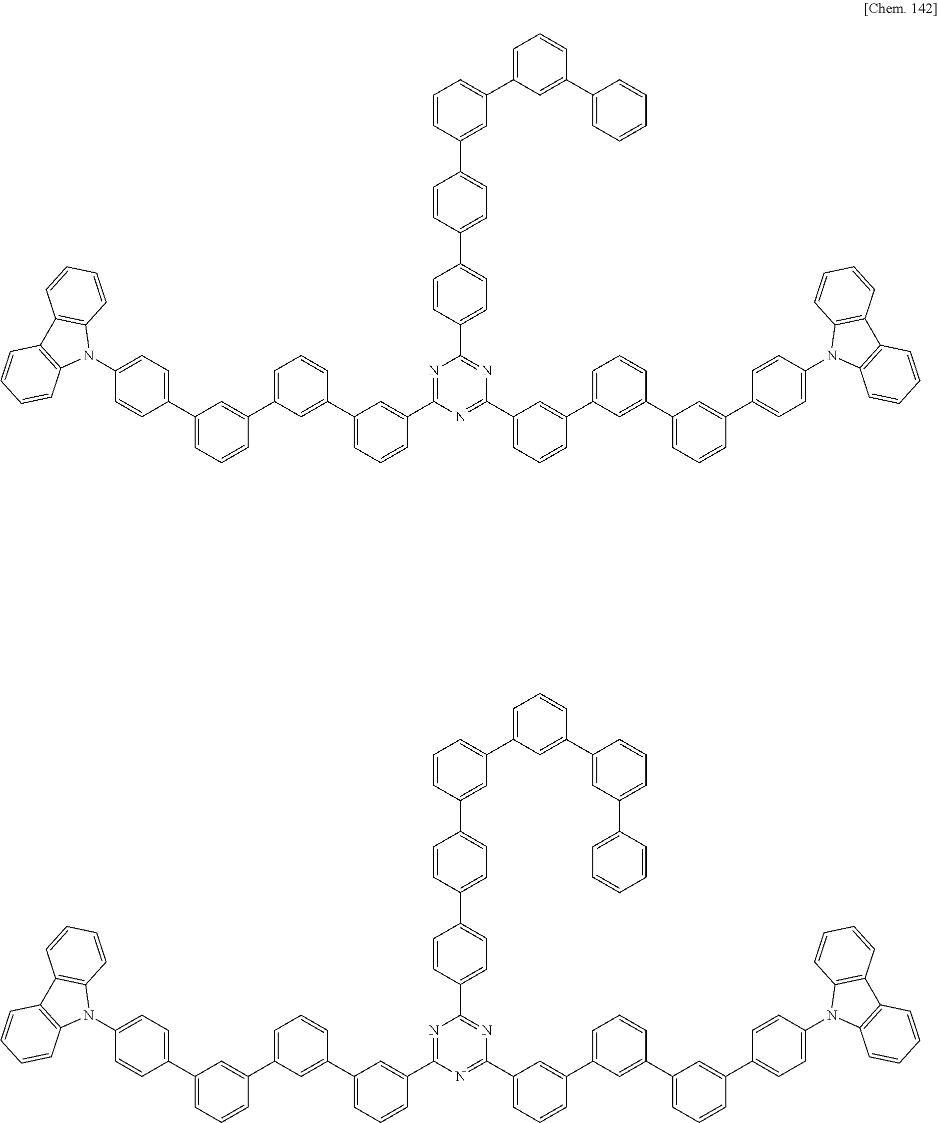 [SMILES: c1ccc(-c2cccc(-c3cccc(-c4ccc(-c5ccc(-c6nc(-c7cccc(-c8cccc(-c9cccc(-c%10ccc(-n%11c%12ccccc%12c%12ccccc%12%11)cc%10)c9)c8)c7)nc(-c7cccc(-c8cccc(-c9cccc(-c%10ccc(-n%11c%12ccccc%12c%12ccccc%12%11)cc%10)c9)c8)c7)n6)cc5)cc4)c3)c2)cc1 ; c1ccc(-c2cccc(-c3cccc(-c4cccc(-c5ccc(-c6ccc(-c7nc(-c8cccc(-c9cccc(-c%10cccc(-c%11ccc(-n%12c%13ccccc%13c%13ccccc%13%12)cc%11)c%10)c9)c8)nc(-c8cccc(-c9cccc(-c%10cccc(-c%11ccc(-n%12c%13ccccc%13c%13ccccc%13%12)cc%11)c%10)c9)c8)n7)cc6)cc5)c4)c3)c2)cc1]

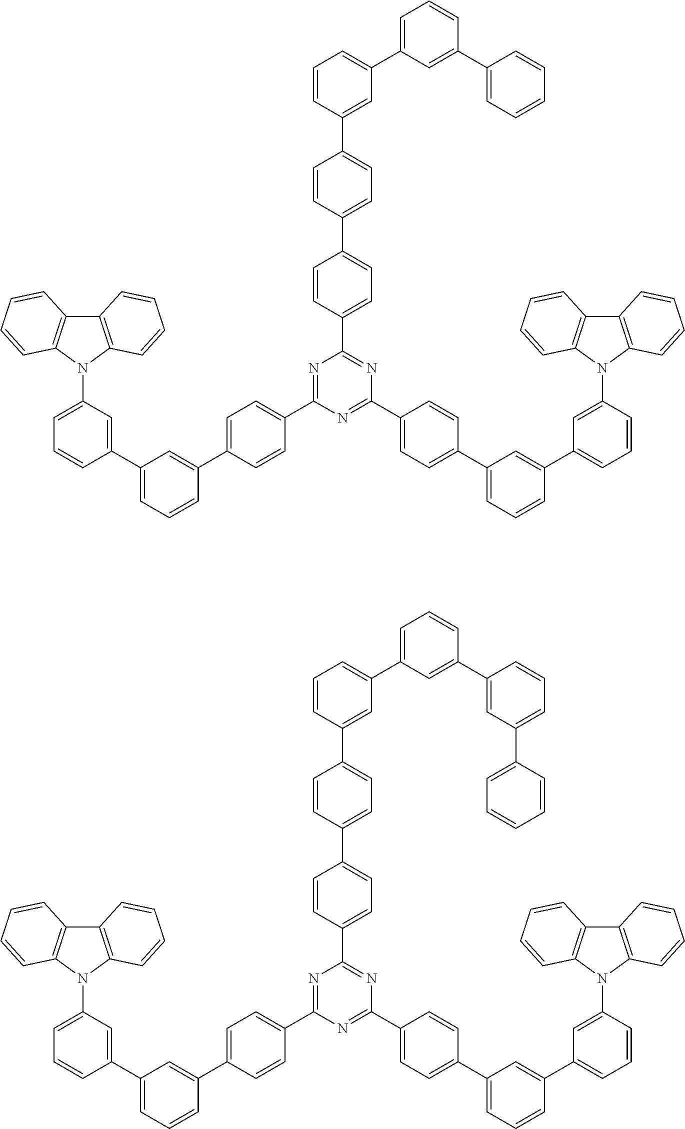 [SMILES: c1ccc(-c2cccc(-c3cccc(-c4ccc(-c5ccc(-c6nc(-c7ccc(-c8cccc(-c9cccc(-n%10c%11ccccc%11c%11ccccc%11%10)c9)c8)cc7)nc(-c7ccc(-c8cccc(-c9cccc(-n%10c%11ccccc%11c%11ccccc%11%10)c9)c8)cc7)n6)cc5)cc4)c3)c2)cc1 ; c1ccc(-c2cccc(-c3cccc(-c4cccc(-c5ccc(-c6ccc(-c7nc(-c8ccc(-c9cccc(-c%10cccc(-n%11c%12ccccc%12c%12ccccc%12%11)c%10)c9)cc8)nc(-c8ccc(-c9cccc(-c%10cccc(-n%11c%12ccccc%12c%12ccccc%12%11)c%10)c9)cc8)n7)cc6)cc5)c4)c3)c2)cc1]

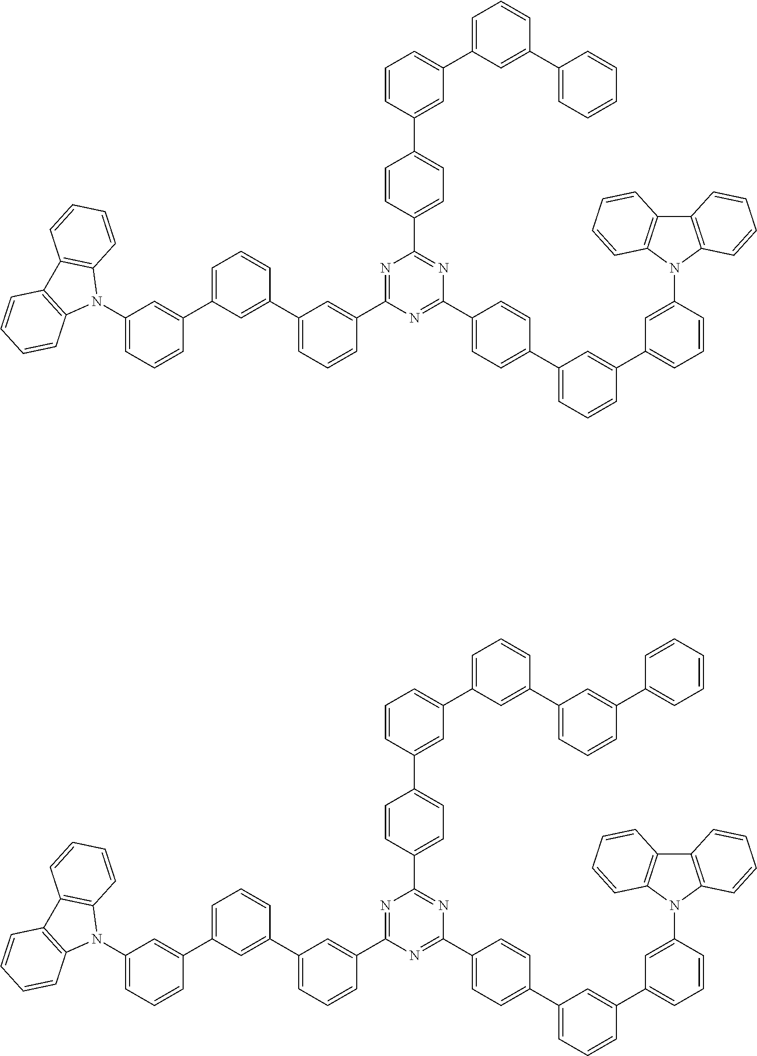 [SMILES: c1ccc(-c2cccc(-c3cccc(-c4ccc(-c5nc(-c6ccc(-c7cccc(-c8cccc(-n9c%10ccccc%10c%10ccccc%109)c8)c7)cc6)nc(-c6cccc(-c7cccc(-c8cccc(-n9c%10ccccc%10c%10ccccc%109)c8)c7)c6)n5)cc4)c3)c2)cc1 ; c1ccc(-c2cccc(-c3cccc(-c4cccc(-c5ccc(-c6nc(-c7ccc(-c8cccc(-c9cccc(-n%10c%11ccccc%11c%11ccccc%11%10)c9)c8)cc7)nc(-c7cccc(-c8cccc(-c9cccc(-n%10c%11ccccc%11c%11ccccc%11%10)c9)c8)c7)n6)cc5)c4)c3)c2)cc1]

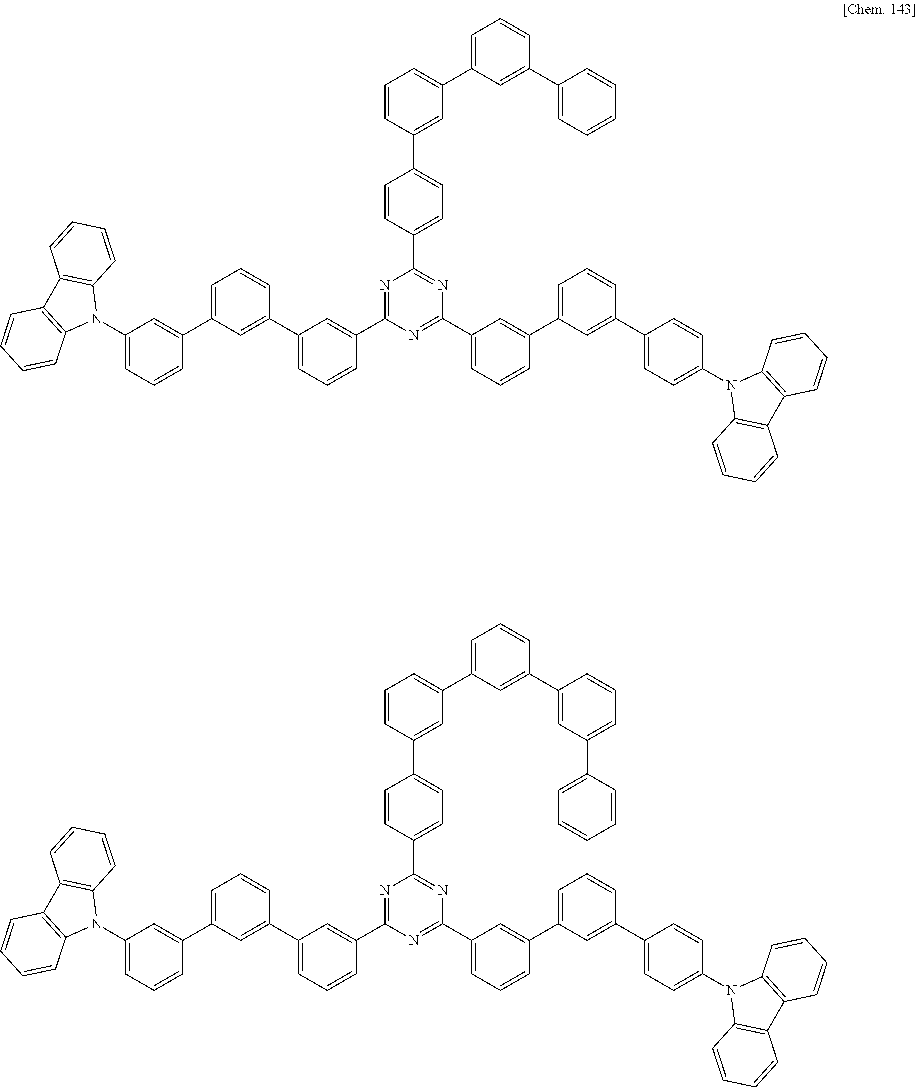 [SMILES: c1ccc(-c2cccc(-c3cccc(-c4ccc(-c5nc(-c6cccc(-c7cccc(-c8ccc(-n9c%10ccccc%10c%10ccccc%109)cc8)c7)c6)nc(-c6cccc(-c7cccc(-c8cccc(-n9c%10ccccc%10c%10ccccc%109)c8)c7)c6)n5)cc4)c3)c2)cc1 ; c1ccc(-c2cccc(-c3cccc(-c4cccc(-c5ccc(-c6nc(-c7cccc(-c8cccc(-c9ccc(-n%10c%11ccccc%11c%11ccccc%11%10)cc9)c8)c7)nc(-c7cccc(-c8cccc(-c9cccc(-n%10c%11ccccc%11c%11ccccc%11%10)c9)c8)c7)n6)cc5)c4)c3)c2)cc1]

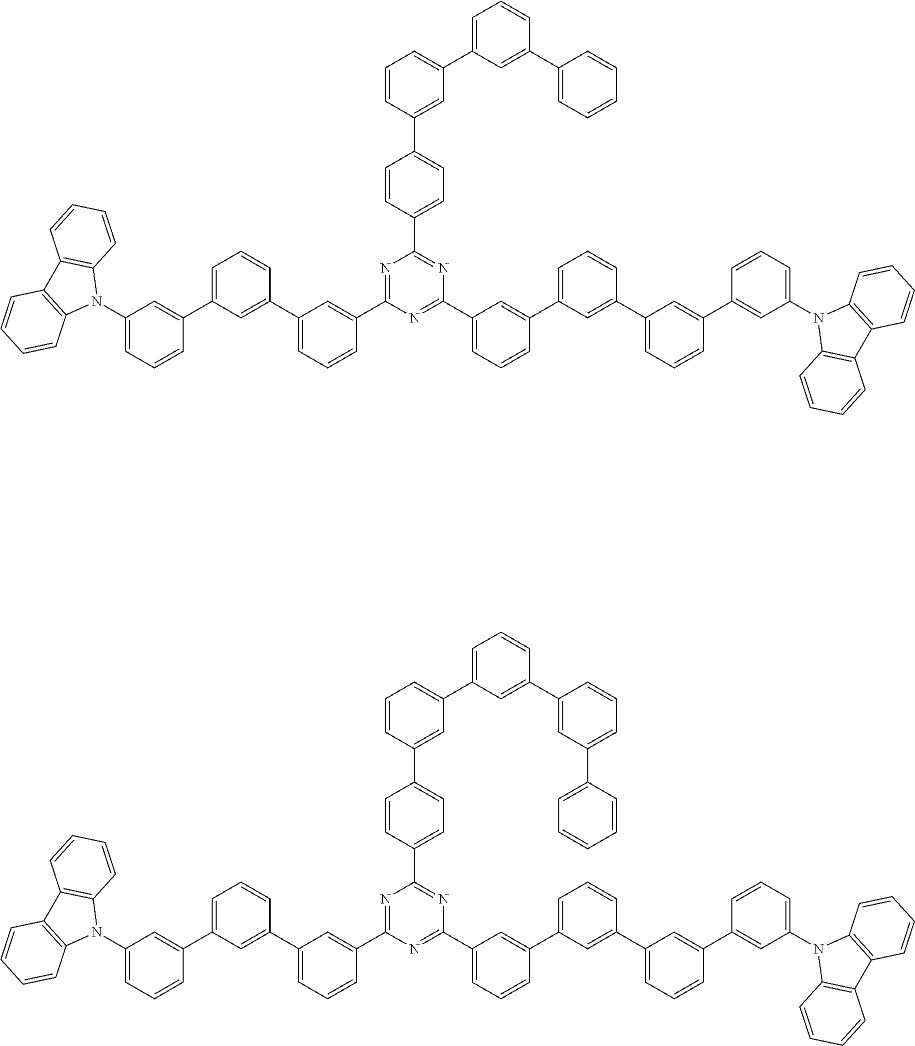 [SMILES: c1ccc(-c2cccc(-c3cccc(-c4ccc(-c5nc(-c6cccc(-c7cccc(-c8cccc(-c9cccc(-n%10c%11ccccc%11c%11ccccc%11%10)c9)c8)c7)c6)nc(-c6cccc(-c7cccc(-c8cccc(-n9c%10ccccc%10c%10ccccc%109)c8)c7)c6)n5)cc4)c3)c2)cc1 ; c1ccc(-c2cccc(-c3cccc(-c4cccc(-c5ccc(-c6nc(-c7cccc(-c8cccc(-c9cccc(-c%10cccc(-n%11c%12ccccc%12c%12ccccc%12%11)c%10)c9)c8)c7)nc(-c7cccc(-c8cccc(-c9cccc(-n%10c%11ccccc%11c%11ccccc%11%10)c9)c8)c7)n6)cc5)c4)c3)c2)cc1]

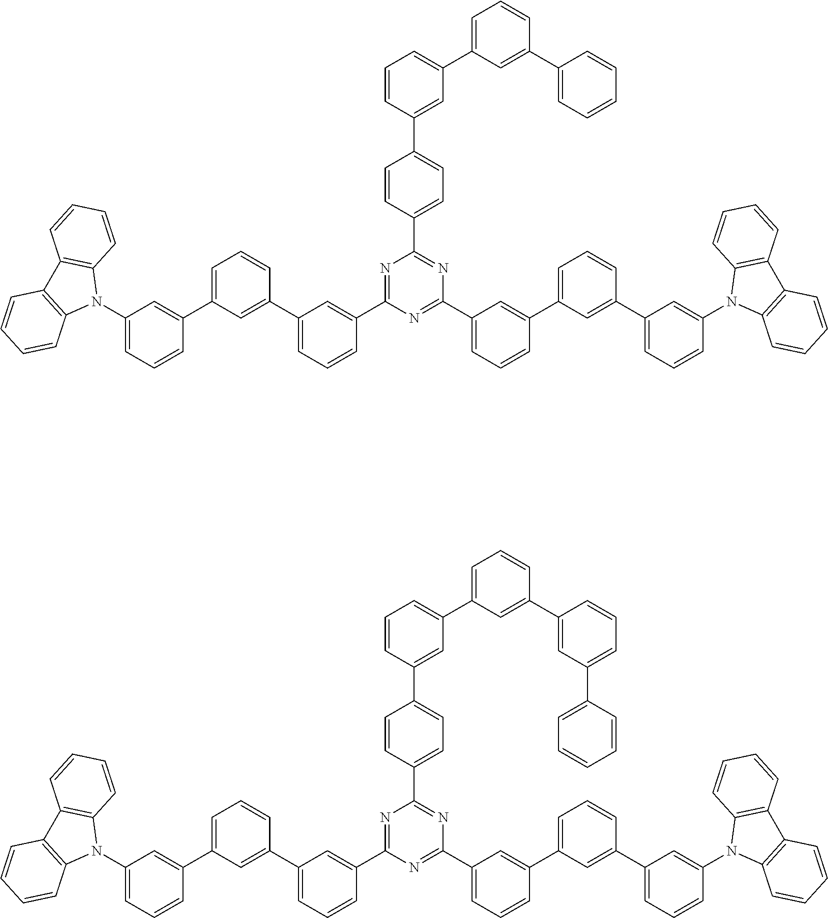 [SMILES: c1ccc(-c2cccc(-c3cccc(-c4ccc(-c5nc(-c6cccc(-c7cccc(-c8cccc(-n9c%10ccccc%10c%10ccccc%109)c8)c7)c6)nc(-c6cccc(-c7cccc(-c8cccc(-n9c%10ccccc%10c%10ccccc%109)c8)c7)c6)n5)cc4)c3)c2)cc1 ; c1ccc(-c2cccc(-c3cccc(-c4cccc(-c5ccc(-c6nc(-c7cccc(-c8cccc(-c9cccc(-n%10c%11ccccc%11c%11ccccc%11%10)c9)c8)c7)nc(-c7cccc(-c8cccc(-c9cccc(-n%10c%11ccccc%11c%11ccccc%11%10)c9)c8)c7)n6)cc5)c4)c3)c2)cc1]

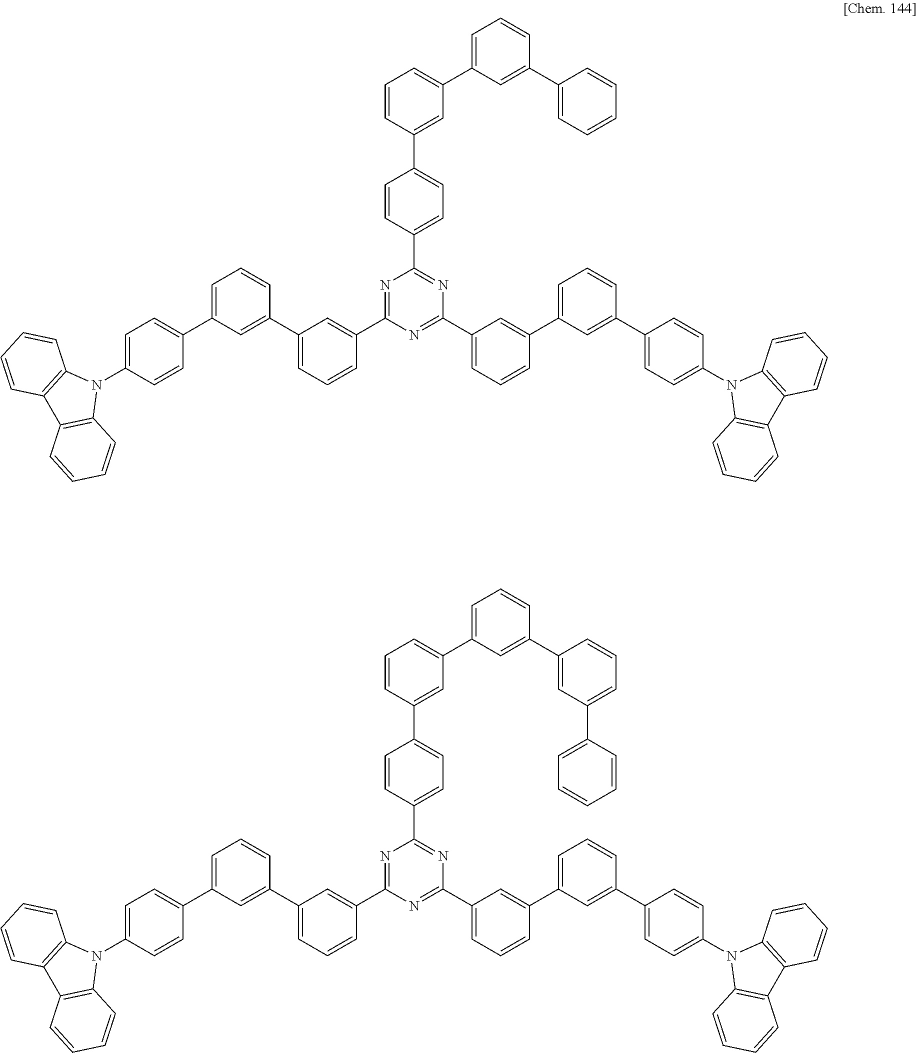 [SMILES: c1ccc(-c2cccc(-c3cccc(-c4ccc(-c5nc(-c6cccc(-c7cccc(-c8ccc(-n9c%10ccccc%10c%10ccccc%109)cc8)c7)c6)nc(-c6cccc(-c7cccc(-c8ccc(-n9c%10ccccc%10c%10ccccc%109)cc8)c7)c6)n5)cc4)c3)c2)cc1 ; c1ccc(-c2cccc(-c3cccc(-c4cccc(-c5ccc(-c6nc(-c7cccc(-c8cccc(-c9ccc(-n%10c%11ccccc%11c%11ccccc%11%10)cc9)c8)c7)nc(-c7cccc(-c8cccc(-c9ccc(-n%10c%11ccccc%11c%11ccccc%11%10)cc9)c8)c7)n6)cc5)c4)c3)c2)cc1]

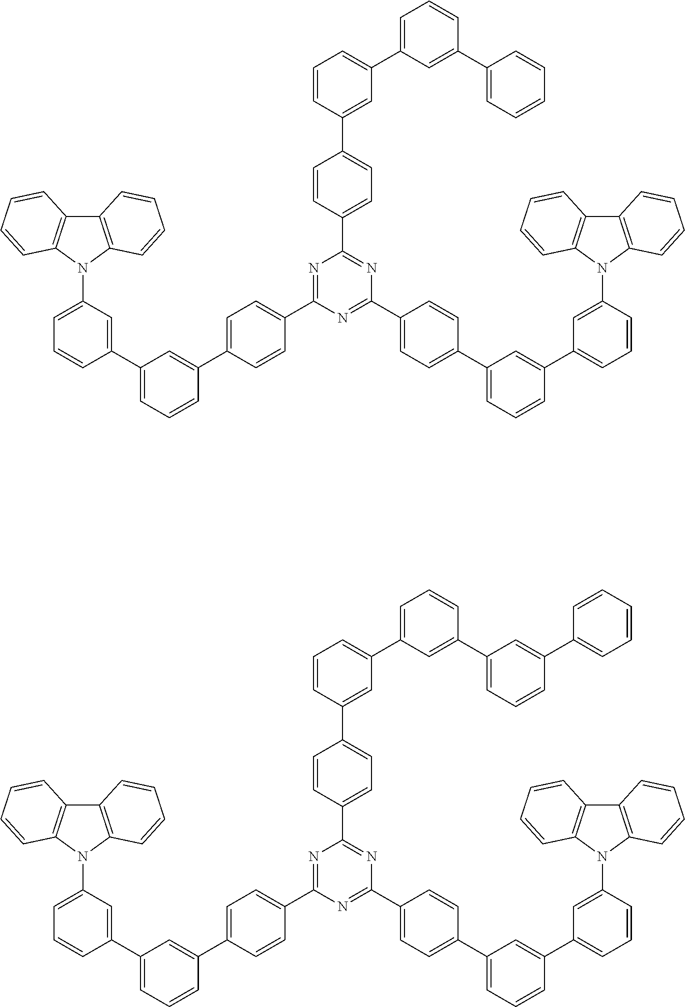 [SMILES: c1ccc(-c2cccc(-c3cccc(-c4ccc(-c5nc(-c6ccc(-c7cccc(-c8cccc(-n9c%10ccccc%10c%10ccccc%109)c8)c7)cc6)nc(-c6ccc(-c7cccc(-c8cccc(-n9c%10ccccc%10c%10ccccc%109)c8)c7)cc6)n5)cc4)c3)c2)cc1 ; c1ccc(-c2cccc(-c3cccc(-c4cccc(-c5ccc(-c6nc(-c7ccc(-c8cccc(-c9cccc(-n%10c%11ccccc%11c%11ccccc%11%10)c9)c8)cc7)nc(-c7ccc(-c8cccc(-c9cccc(-n%10c%11ccccc%11c%11ccccc%11%10)c9)c8)cc7)n6)cc5)c4)c3)c2)cc1]

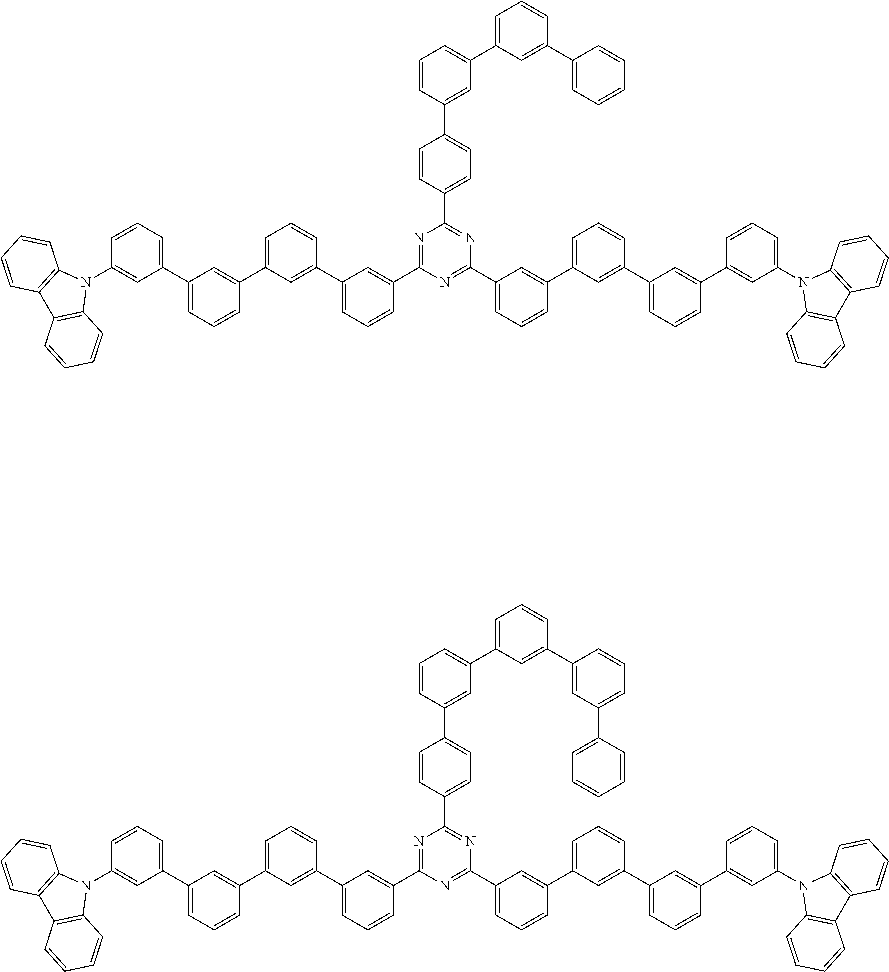 [SMILES: c1ccc(-c2cccc(-c3cccc(-c4ccc(-c5nc(-c6cccc(-c7cccc(-c8cccc(-c9cccc(-n%10c%11ccccc%11c%11ccccc%11%10)c9)c8)c7)c6)nc(-c6cccc(-c7cccc(-c8cccc(-c9cccc(-n%10c%11ccccc%11c%11ccccc%11%10)c9)c8)c7)c6)n5)cc4)c3)c2)cc1 ; c1ccc(-c2cccc(-c3cccc(-c4cccc(-c5ccc(-c6nc(-c7cccc(-c8cccc(-c9cccc(-c%10cccc(-n%11c%12ccccc%12c%12ccccc%12%11)c%10)c9)c8)c7)nc(-c7cccc(-c8cccc(-c9cccc(-c%10cccc(-n%11c%12ccccc%12c%12ccccc%12%11)c%10)c9)c8)c7)n6)cc5)c4)c3)c2)cc1]

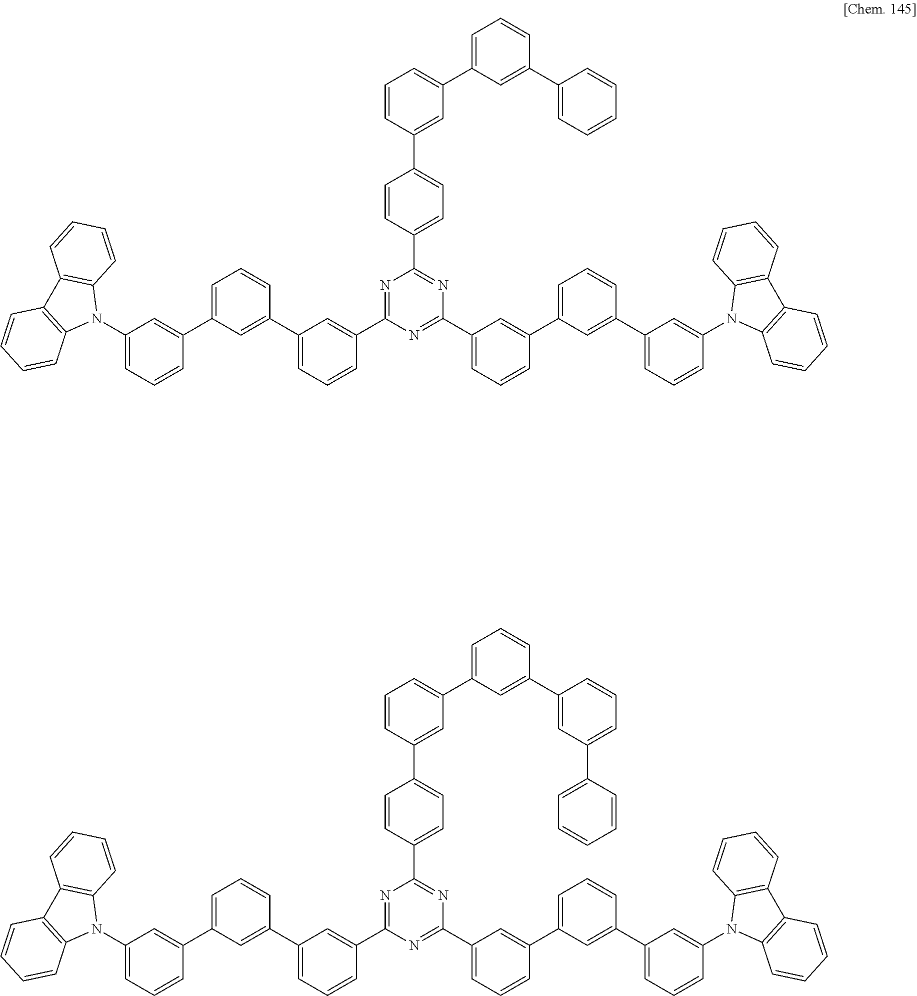 [SMILES: c1ccc(-c2cccc(-c3cccc(-c4ccc(-c5nc(-c6cccc(-c7cccc(-c8cccc(-n9c%10ccccc%10c%10ccccc%109)c8)c7)c6)nc(-c6cccc(-c7cccc(-c8cccc(-n9c%10ccccc%10c%10ccccc%109)c8)c7)c6)n5)cc4)c3)c2)cc1 ; c1ccc(-c2cccc(-c3cccc(-c4cccc(-c5ccc(-c6nc(-c7cccc(-c8cccc(-c9cccc(-n%10c%11ccccc%11c%11ccccc%11%10)c9)c8)c7)nc(-c7cccc(-c8cccc(-c9cccc(-n%10c%11ccccc%11c%11ccccc%11%10)c9)c8)c7)n6)cc5)c4)c3)c2)cc1]

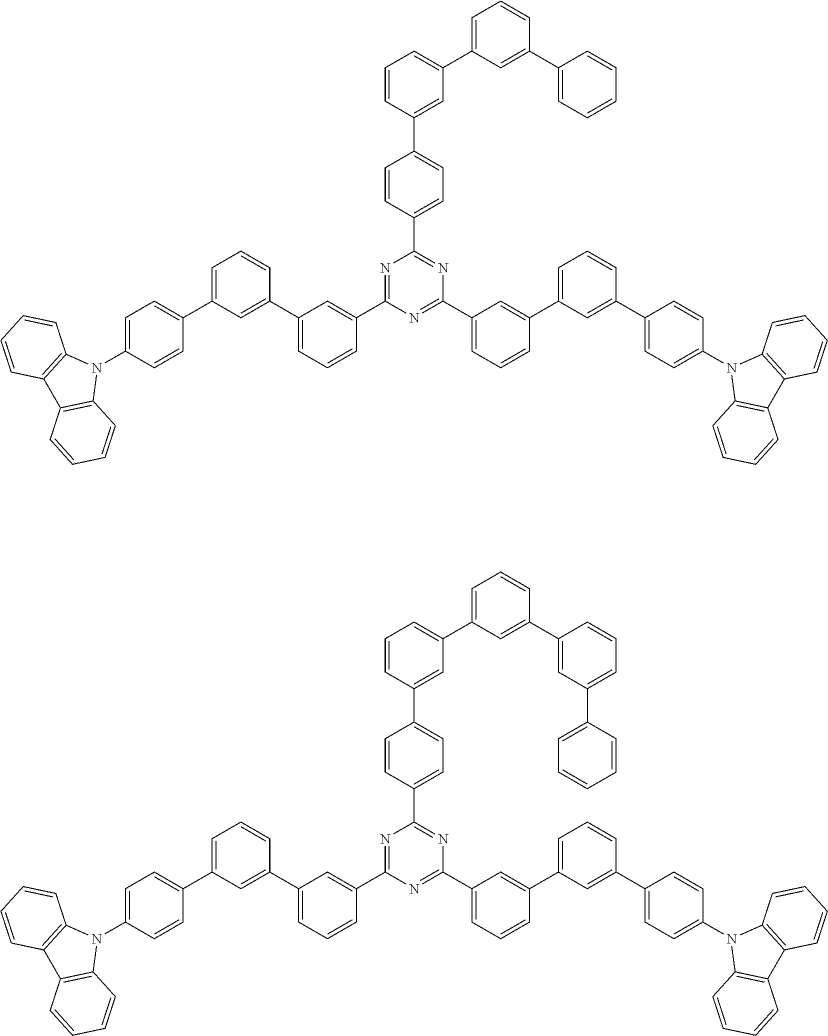 [SMILES: c1ccc(-c2cccc(-c3cccc(-c4ccc(-c5nc(-c6cccc(-c7cccc(-c8ccc(-n9c%10ccccc%10c%10ccccc%109)cc8)c7)c6)nc(-c6cccc(-c7cccc(-c8ccc(-n9c%10ccccc%10c%10ccccc%109)cc8)c7)c6)n5)cc4)c3)c2)cc1 ; c1ccc(-c2cccc(-c3cccc(-c4cccc(-c5ccc(-c6nc(-c7cccc(-c8cccc(-c9ccc(-n%10c%11ccccc%11c%11ccccc%11%10)cc9)c8)c7)nc(-c7cccc(-c8cccc(-c9ccc(-n%10c%11ccccc%11c%11ccccc%11%10)cc9)c8)c7)n6)cc5)c4)c3)c2)cc1]

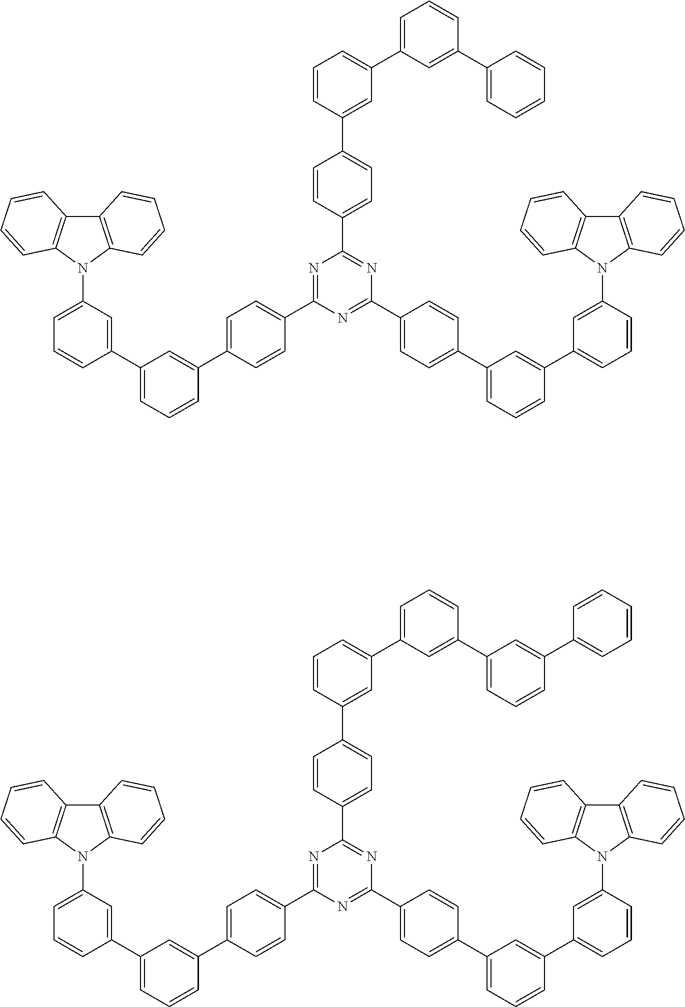 [SMILES: c1ccc(-c2cccc(-c3cccc(-c4ccc(-c5nc(-c6ccc(-c7cccc(-c8cccc(-n9c%10ccccc%10c%10ccccc%109)c8)c7)cc6)nc(-c6ccc(-c7cccc(-c8cccc(-n9c%10ccccc%10c%10ccccc%109)c8)c7)cc6)n5)cc4)c3)c2)cc1 ; c1ccc(-c2cccc(-c3cccc(-c4cccc(-c5ccc(-c6nc(-c7ccc(-c8cccc(-c9cccc(-n%10c%11ccccc%11c%11ccccc%11%10)c9)c8)cc7)nc(-c7ccc(-c8cccc(-c9cccc(-n%10c%11ccccc%11c%11ccccc%11%10)c9)c8)cc7)n6)cc5)c4)c3)c2)cc1]

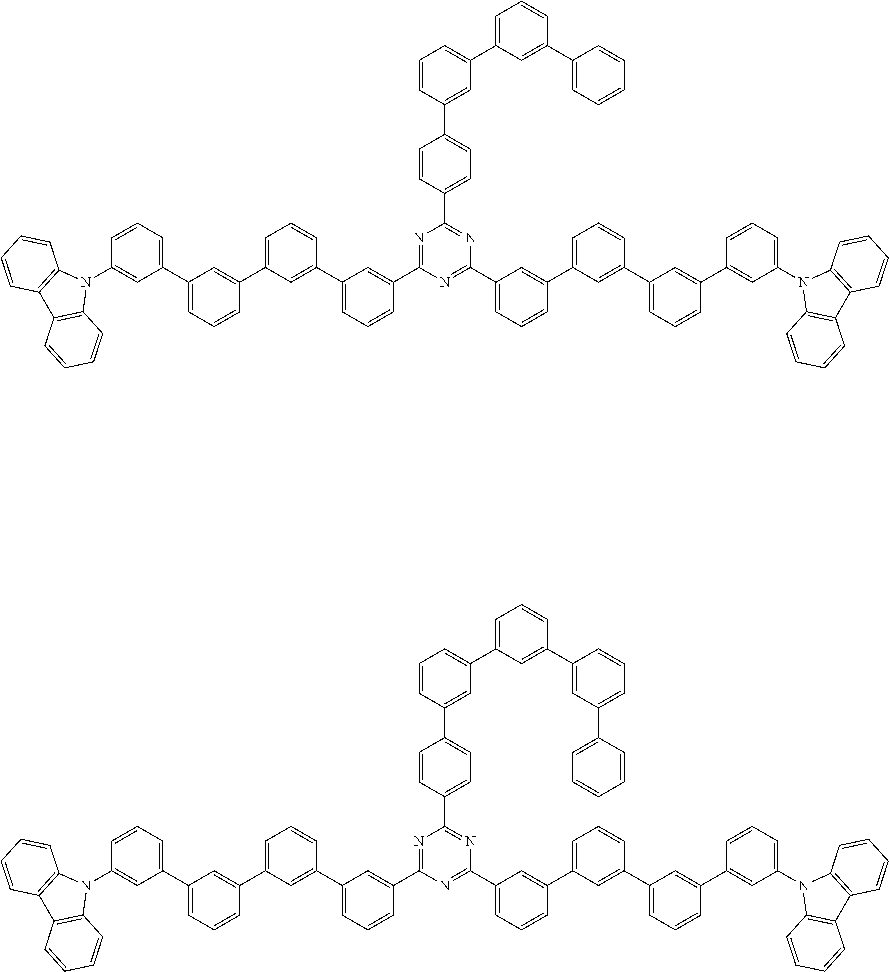 [SMILES: c1ccc(-c2cccc(-c3cccc(-c4ccc(-c5nc(-c6cccc(-c7cccc(-c8cccc(-c9cccc(-n%10c%11ccccc%11c%11ccccc%11%10)c9)c8)c7)c6)nc(-c6cccc(-c7cccc(-c8cccc(-c9cccc(-n%10c%11ccccc%11c%11ccccc%11%10)c9)c8)c7)c6)n5)cc4)c3)c2)cc1 ; c1ccc(-c2cccc(-c3cccc(-c4cccc(-c5ccc(-c6nc(-c7cccc(-c8cccc(-c9cccc(-c%10cccc(-n%11c%12ccccc%12c%12ccccc%12%11)c%10)c9)c8)c7)nc(-c7cccc(-c8cccc(-c9cccc(-c%10cccc(-n%11c%12ccccc%12c%12ccccc%12%11)c%10)c9)c8)c7)n6)cc5)c4)c3)c2)cc1]

### <Reason why Compound (1-2) Exhibits Effect>

In the compound (1-2), since a group bonded to the para position of W₁ is a group in which two or three benzene rings are linked at the para position, a conjugate is spread, LUMO is distributed therein, and thus the compound (1-2) is considered to be excellent in electron transportability. In addition, since there are three or less benzene rings that are conjugated and linked to the para position of W₁, the conjugate is not too long and a wide energy gap is obtained, and it is considered that in a case where the compound is used as a matrix material of the emission layer, the luminescent material is unlikely to be quenched, which is preferable. Since the compound (1-2) has at least one carbazolyl group, the compound (1-2) has excellent resistance to an alcohol-based solvent after the film formation.

In a nitrogen-containing six-membered ring containing W₁, W₂, and W₃ of the compound (1-2), a group bonded to a para position of W₃ is a 1,3-phenylene group and thus is not conjugated. Therefore, it is considered that in a case where the compound (1-2) has a wide energy gap and is used as a matrix material of the emission layer, the luminescent material is hardly quenched, which is preferable.

Since at least one of Ya^{l} and Za¹ of the compound (1-2) is a 1,3-phenylene group, conjugation with Ya² or Za² which is an N-carbazolyl group does not occur. Therefore, it is considered that in a case where the compound (1-2) has a wide energy gap and is used as a matrix material of the emission layer, the luminescent material is hardly quenched, which is preferable.

Further, when —(Xa¹)_{g11}—Xa², —(Ya¹)ₕ₁₁—Ya², and —(Za¹)ⱼ₁₁—Za² represent the above preferred structures, a wide energy gap is obtained, and in a case where they are used as matrix materials of the emission layer, the luminescent material is hardly quenched.

The compound (1-2) has excellent solubility because the compound (1-2) has three or more phenylene groups between the nitrogen-containing six-membered ring containing W₁, W₂, and W₃ and the carbazolyl group, contains an appropriately large amount of 1,3-phenylene group, and does not contain a 1,4-phenylene linkage structure longer than a terphenylene group. On the other hand, since f11+g11+h11+j11 is 6 or more, it is considered that after film formation, the compound (1-1) is difficult to dissolve in an alcohol-based solvent, that is, the compound (1-1) has solvent resistance. f11+g11+h11+j11 is preferably 7 or more and more preferably 9 or more from the viewpoint of solvent resistance to an alcohol-based solvent after film formation, and is preferably 15 or less from the viewpoint of stability.

In addition, since the compound (1-2) has N-carbazolyl groups in Ya² and Za², an intermolecular interaction is enhanced, the solvent resistance is excellent, and particularly high solvent resistance to an alcohol-based solvent is exhibited.

### (Molecular Weight)

In a case where the emission layer 5 is formed by a wet-process film formation method, since the emission layer is hardly affected when a layer in contact with a cathode side of the emission layer is formed by the wet-process film formation method, molecular weights of matrix compounds, that is, compounds contained as the compound of the (group A), the (group B), or the (group C) are all preferably 1,200 or more, more preferably 1,400 or more, and still more preferably 1,600 or more.

In addition, molecular weights of the matrix compounds, that is, the compounds contained as the compound of the (group A), the (group B), or the (group C), and the luminescent material are all preferably 1,200 or more, more preferably 1,400 or more, and still more preferably 1,600 or more. Upper limits of the molecular weights of the matrix compounds and the luminescent material are not particularly limited, and are preferably 5,000 or less, more preferably 4,000 or less, and still more preferably 3,000 or less in terms of ease of purification. As described above, the luminescent material is preferably a phosphorescent compound.

### [Second Organic Solvent]

The second organic solvent contained in the composition for forming an emission layer according to the present invention is a volatile liquid component used for forming a layer containing the compound according to the present invention by wet-process film formation.

The organic solvent is preferably an organic solvent capable of satisfactorily dissolving the compound according to the present invention as a solute and the luminescent material.

Preferred organic solvents as the second organic solvent include: alkanes such as n-decane, cyclohexane, ethylcyclohexane, decalin, and bicyclohexane; aromatic hydrocarbons such as toluene, xylene, mesitylene, phenylcyclohexane, tetralin, and methylnaphthalene; halogenated aromatic hydrocarbons such as chlorobenzene, dichlorobenzene, and trichlorobenzene; aromatic ethers such as 1,2-dimethoxybenzene, 1,3-dimethoxybenzene, anisole, phenetole, 2-methoxytoluene, 3-methoxytoluene, 4-methoxytoluene, 2,3-dimethylanisole, 2,4-dimethylanisole, and diphenylether; aromatic esters such as phenyl acetate, phenyl propionate, methyl benzoate, ethyl benzoate, propyl benzoate, and n-butyl benzoate; alicyclic ketones such as cyclohexanone, cyclooctanone, and fenchone; alicyclic alcohols such as cyclohexanol and cyclooctanol; aliphatic ketones such as methyl ethyl ketone and dibutyl ketone; aliphatic alcohols such as butanol and hexanol; and aliphatic ethers such as ethylene glycol dimethyl ether, ethylene glycol diethyl ether, and propylene glycol-1-monomethyl ether acetate (PGMEA).

Among those, alkanes, aromatic hydrocarbons, aromatic ethers, and aromatic esters are preferable, aromatic hydrocarbons, aromatic ethers, and aromatic esters are more preferable, and aromatic hydrocarbons and aromatic esters are particularly preferable, from the viewpoint of viscosity and boiling point.

One kind of these organic solvents may be used alone, or two or more kinds thereof may be used in any combination and ratio.

The boiling point of the organic solvent used as the second organic solvent is generally 80° C. or higher, preferably 100° C. or higher, more preferably 120° C. or higher, still more preferably 150° C. or higher, particularly preferably 200° C. or higher, and is generally 380° C. or lower, preferably 350° C. or lower, more preferably 330° C. or lower. When the boiling point of the organic solvent is lower than this range, there is a possibility that film formation stability is reduced due to solvent evaporation from the composition during wet-process film formation. When the boiling point of the organic solvent exceeds this range, there is a possibility that the film formation stability is reduced due to residual solvent after film formation during wet-process film formation.

As the second organic solvent, it is particularly preferable to combine two or more kinds of organic solvents having a boiling point of 150° C. or higher among the above organic solvents because a uniform coating film can be thus prepared. When the number of kinds of the organic solvent having a boiling point of 150° C. or higher is 1 or less, it is considered that a uniform film may not be formed during coating.

As the wet-process film formation method for forming the emission layer 5, an inkjet method is preferable. Forming the emission layer 5 by an inkjet method is preferable because a film can be formed by the inkjet method continuously with an organic layer formed using the composition for layer formation according to the present invention. The method for forming an emission layer by an inkjet method is the same as the method for coating and forming an organic layer by an inkjet method.

In a case where the composition for forming an emission layer is subjected to wet-film formation by an inkjet method, it is preferable that the second organic solvent is a solvent containing at least two kinds of organic solvents among the above organic solvents, and the boiling point of at least one kind of the organic solvents is 200° C. or higher, from the viewpoint of easily forming a coating film having good flatness.

A film thickness of the emission layer 5 is optional. The film thickness of the emission layer 5 is generally 5 nm or more, preferably 10 nm or more, and is generally 100 nm or less, preferably 90 nm or less.

### [Hole Blocking Layer]

The hole blocking layer 6 may be provided between the emission layer 5 and an electron injection layer 8 to be described later. The hole blocking layer 6 is a layer that also plays a role of blocking holes which are further moving from the anode 2 in the electron transport layer from reaching the cathode 9. The hole blocking layer 6 is a layer laminated on the emission layer 5 so as to be in contact with an interface on the cathode 9 side of the emission layer 5.

The hole blocking layer 6 plays a role of blocking holes which are moving from the anode 2 from reaching the cathode 9 and a role of efficiently transporting electrons injected from the cathode 9 toward the emission layer 5.

Examples of properties required of a material for constituting the hole blocking layer 6 include: having a high electron mobility and a low hole mobility; having a large energy gap (difference between HOMO and LUMO); and having a high excited triplet energy level (T1). Examples of the material of the hole blocking layer 6 satisfying such requirements include metal complexes such as mixed-ligand complexes such as bis(2-methyl-8-quinolinolato)(phenolato)aluminum and bis(2-methyl-8-quinolinolato)(triphenylsinolato)aluminum, and dinuclear metal complexes such as bis(2-methyl-8-quinolato)aluminum-μ-oxo-bis-(2-methyl-8-quinolinolato)aluminum, styryl compounds such as distyrylbiphenyl derivatives (JP-A-11-242996), triazole derivatives such as 3-(4-biphenylyl)-4-phenyl-5(4-tert-butylphenyl)-1,2,4-triazole (JP-A-7-41759), and phenanthroline derivatives such as bathocuproine (JP-A-10-79297). Further, the compound disclosed in International Publication WO 2005-022962 which has at least one pyridine ring substituted at the 2—, 4-, and 6-sites is also preferred as the material of the hole blocking layer 6.

In a case where the hole blocking layer 6 is present, the hole blocking layer 6 is formed by coating and forming the composition for layer formation according to the present invention containing the material of the hole blocking layer as a functional material by an inkjet method.

A film thickness of the hole blocking layer 6 is optional. The film thickness of the hole blocking layer 6 is generally 0.3 nm or more, preferably 0.5 nm or more, and is generally 100 nm or less, preferably 50 nm or less.

### [Electron Transport Layer]

The electron transport layer 7 is a layer provided between the emission layer 5 and the cathode 9 for transporting electrons.

As an electron-transporting compound of the electron transport layer 7, a compound is generally used with which efficiency of electron injection from the cathode 9 or an adjacent layer on the cathode 9 side is rendered high and which has high electron mobility and is capable of efficiently transporting injected electrons. Examples of the compound satisfying such requirements include metal complexes such as an aluminum complex of 8-hydroxyquinoline and a lithium complex (JP-A-59-194393), metal complexes of 10-hydroxybenzo[h]quinoline, oxadiazole derivatives, distyrylbiphenyl derivatives, silole derivatives, 3-hydroxyflavone metal complexes, 5-hydroxyflavone metal complexes, benzoxazole metal complexes, benzothiazole metal complexes, trisbenzimidazolylbenzene (U.S. Pat. No. 5,645,948), quinoxaline compounds (JP-A-6-207169), phenanthroline derivatives (JP-A-5-331459), 2-t-butyl-9,10-N,N′-dicyanoanthraquinone diimine, triazine compound derivatives, and perylenetetracarboxylic acid imide compound derivatives.

In the method for producing an organic electroluminescent element according to the present invention, it is preferable that the above-described hole blocking layer 6 does not exist and the layer in contact with the cathode 9 side of the emission layer 5 is the electron transport layer 7. In this case, the electron transport layer 7 is formed by applying the composition for layer formation according to the present invention containing the electron-transporting compound as a functional material on a surface of the emission layer 5 by an inkjet method.

A film thickness of the electron transport layer 7 is optional as long as the effect of the present invention is not significantly impaired. The film thickness of the electron transport layer 7 is generally 1 nm or more, preferably 5 nm or more, and is generally 300 nm or less, preferably 100 nm or less.

### [Electron Injection Layer]

In order to efficiently inject electrons injected from the cathode 9 into the emission layer 5, the electron injection layer 8 may be provided between the electron transport layer 7 and the cathode 9 to be described later. The electron injection layer 8 is made of an inorganic salt or the like.

Examples of a material of the electron injection layer 8 include lithium fluoride (LiF), magnesium fluoride (MgF₂), lithium oxide (Li₂O), and cesium carbonate (II) (CsCO₃) (see Applied Physics Letters, 1997, Vol. 70, pp. 152; JP-A-10-74586; IEEE Transactions on Electron Devices, 1997, Vol. 44, pp. 1245; SID 04 Digest, pp. 154, and the like).

Since the electron injection layer 8 does not have charge transportability in many cases, the electron injection layer 8 is preferably used as an extremely thin film in order to efficiently inject electrons, and a film thickness thereof is generally 0.1 nm or more, and is preferably 5 nm or less.

### [Cathode]

The cathode 9 is an electrode that plays a role of injecting electrons into a layer on the emission layer 5 side.

Examples of a material of the cathode 9 generally include a metal such as aluminum, gold, silver, nickel, palladium, and platinum; a metal oxide such as an oxide of indium and/or tin; a metal halide such as copper iodide; and a conductive polymer such as carbon black, poly(3-methylthiophene), polypyrrole, and polyaniline. Among those, in order to efficiently inject electrons, a metal having a low work function is preferable, and for example, an appropriate metal such as tin, magnesium, indium, calcium, aluminum, and silver, or an alloy thereof is used. Specific examples thereof include electrodes of alloys having a low work function, such as magnesium-silver alloys, magnesium-indium alloys, and aluminum-lithium alloys.

One kind of material of the cathode 9 may be used, or two or more kinds thereof may be used in any combination and ratio.

A film thickness of the cathode 9 is different depending on required transparency. In a case where the transparency is required, visible light transmittance is generally 60% or more, preferably 80% or more. In this case, the thickness of the cathode 9 is generally 5 nm or more, preferably 10 nm or more, and is generally 1,000 nm or less, preferably 500 nm or less. In a case where the cathode 9 may be non-transparent, the thickness of the cathode 9 is optional, and the cathode may be the same as the substrate.

A different conductive material may be superposed on the cathode 9.

For example, in order to protect a cathode made of a metal having a low work function, such as an alkali metal including sodium and cesium or an alkaline earth metal including barium and calcium, it is preferable that a metal layer having a high work function and is stable to the air is further laminated thereon because the stability of the element is thus increased. For this purpose, metals such as aluminum, silver, copper, nickel, chromium, gold, and platinum are used. One kind of these materials may be used, or two or more kinds thereof may be used in any combination and ratio.

### [Other Layers]

The organic electroluminescent element according to the present invention may have another structure without departing from the gist thereof. For example, as long as the performance thereof is not impaired, any layer may be provided between the anode 2 and the cathode 9 in addition to the layers described above, and an unnecessary layer among the layers described above may be omitted.

In the layer configuration described above, components other than the substrate may be laminated in reverse order. For example, in the case of the layer configuration of the FIGURE, other components may be provided on the substrate 1 in the order of the cathode 9, the electron injection layer 8, the electron transport layer 7, the hole blocking layer 6, the emission layer 5, the hole transport layer 4, the hole injection layer 3, and the anode 2.

The organic electroluminescent element according to the present invention may be configured as a single organic electroluminescent element, may be applied to a configuration in which a plurality of organic electroluminescent elements are arranged in an array, or may be applied to a configuration in which anodes and cathodes are arranged in an X-Y matrix.

Each of the above-described layers may contain components other than those described as the material.

### [Organic Electroluminescent Element]

The present invention relates to an organic electroluminescent element including at least an anode, a cathode, and an emission layer located between the anode and the cathode, in which the emission layer contains the above-described material for an emission layer.

The present invention also relates to an organic electroluminescent element obtained by the above-described method for producing an organic electroluminescent element.

Specific examples and preferred embodiments of the layer configuration included in the organic electroluminescent element according to the present invention, and the compound included in each layer are as described above.

### <Method for Producing Display Device and Display Device>

The present invention also relates to a method for producing a display device, including the above-described method for producing an organic electroluminescent element as one step. Specific examples and preferred embodiments of the method for producing an organic electroluminescent element included as one step of the method for producing a display device are as described above.

The present invention also relates to a display device obtained by the above-described method for producing a display device.

A type and a structure of the display device obtained in the present invention are not particularly limited, and the display device can be assembled in accordance with an ordinary method using the organic electroluminescent element obtained by the method for producing an organic electroluminescent element according to the present invention.

For example, the display device can be formed by a method such as that described in “Organic EL Display” (Ohmsha, Ltd., published on Aug. 20, 2004, written by TOKITO Shizuo, ADACHI Chihaya, and MURATA Hideyuki).

### <Method for Producing Illuminator and Illuminator>

The present invention also relates to a method for producing an illuminator, including the above-described method for producing an organic electroluminescent element as one step. Specific examples and preferred embodiments of the method for producing an organic electroluminescent element included as one step of the method for producing an illuminator are as described above.

The present invention also relates to an illuminator obtained by the above-described method for producing an illuminator.

A type and a structure of the illuminator obtained in the present invention are not particularly limited, and the illuminator can be assembled in accordance with an ordinary method using the organic electroluminescent element obtained by the method for producing an organic electroluminescent element according to the present invention.

### EXAMPLES

### Example 1

An organic electroluminescent element was prepared by the following method. An indium tin oxide (ITO) transparent conductive film deposited on a glass substrate in a thickness of 50 nm (a sputtered film product manufactured by GEOMATEC Co., Ltd.) was patterned into stripes having a width of 2 mm using an ordinary photolithography technique and hydrochloric acid etching to form an anode. The substrate on which the ITO was patterned in this manner was subjected to ultrasonic cleaning with a surfactant aqueous solution, washing with ultrapure water, ultrasonic cleaning with ultrapure water, and washing with ultrapure water in this order, then dried with compressed air, and finally subjected to ultraviolet/ozone cleaning. As a composition for forming a hole injection layer, a composition was prepared by dissolving 3.0 wt % of a hole transporting polymer compound having a repeating structure represented by the following formula (P-1) and 0.6 wt % of an electron-accepting compound (HI-1) in ethyl benzoate.

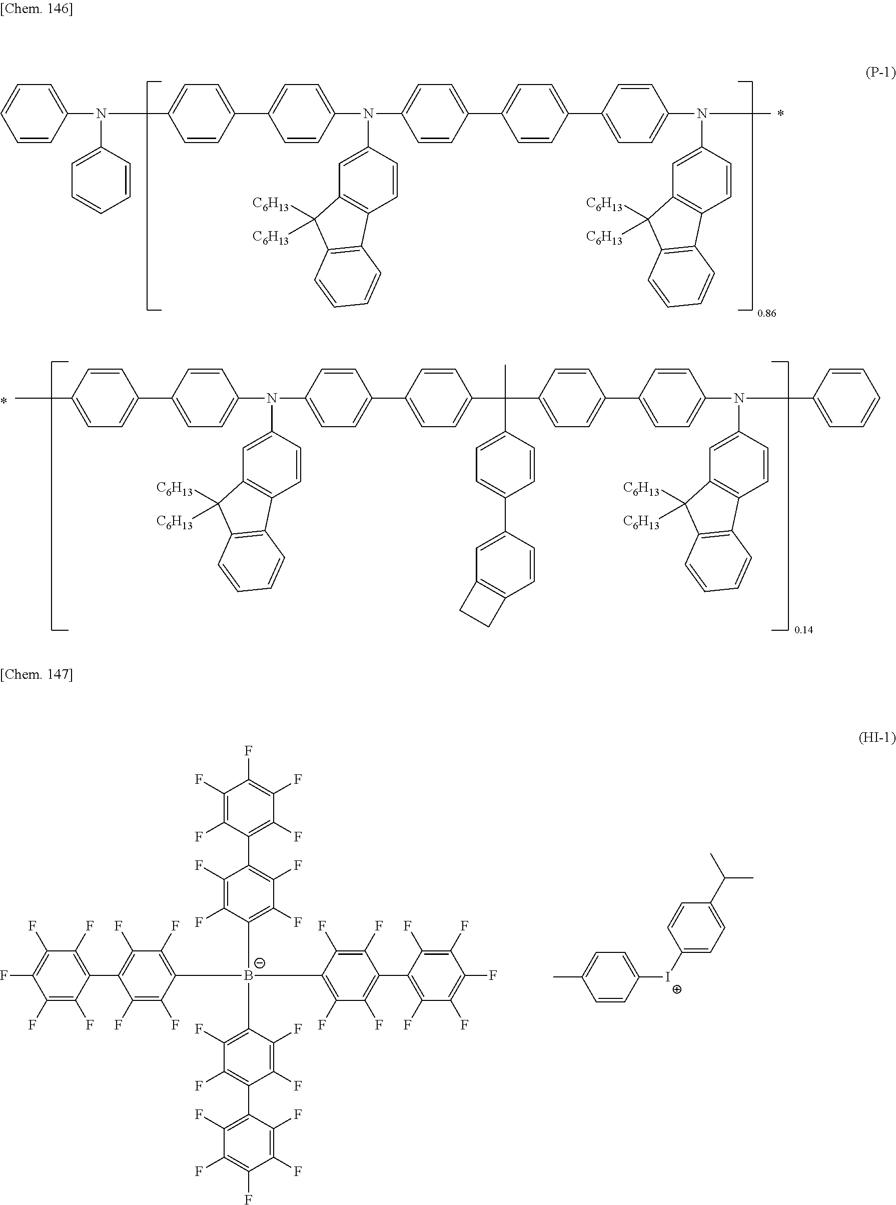

This solution was applied on the substrate by spin coating in the air, and dried on a hot plate in the air at 240° C. for 30 minutes to form a uniform thin film having a film thickness of 40 nm, thereby forming a hole injection layer.

Next, a charge-transporting polymer compound having the following structural formula (HT-1) was dissolved in 1,3,5-trimethylbenzene to prepare a 2.0 wt % solution. This solution was applied, by spin coating, on the substrate on which the above hole injection layer was coated and formed in a nitrogen glove box, and dried on a hot plate in the nitrogen glove box at 230° C. for 30 minutes to form a uniform thin film having a film thickness of 40 nm, thereby forming a hole transport layer.

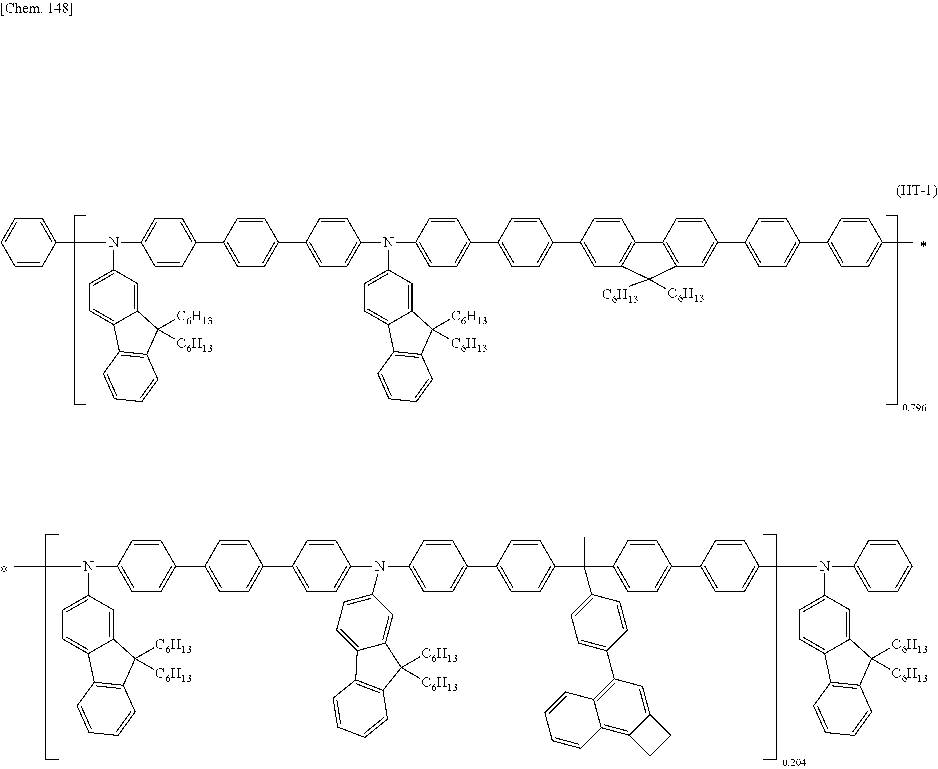

Subsequently, as a material of the emission layer, a compound (A-1) of the present invention contained in the group A having the following structure at a concentration of 2.7 wt %, a compound (C-1) of the present invention contained in the group C at a concentration of 2.7 wt %, and a compound (D-1) at a concentration of 1.6 wt % were dissolved in cyclohexylbenzene to prepare a composition for forming an emission layer.

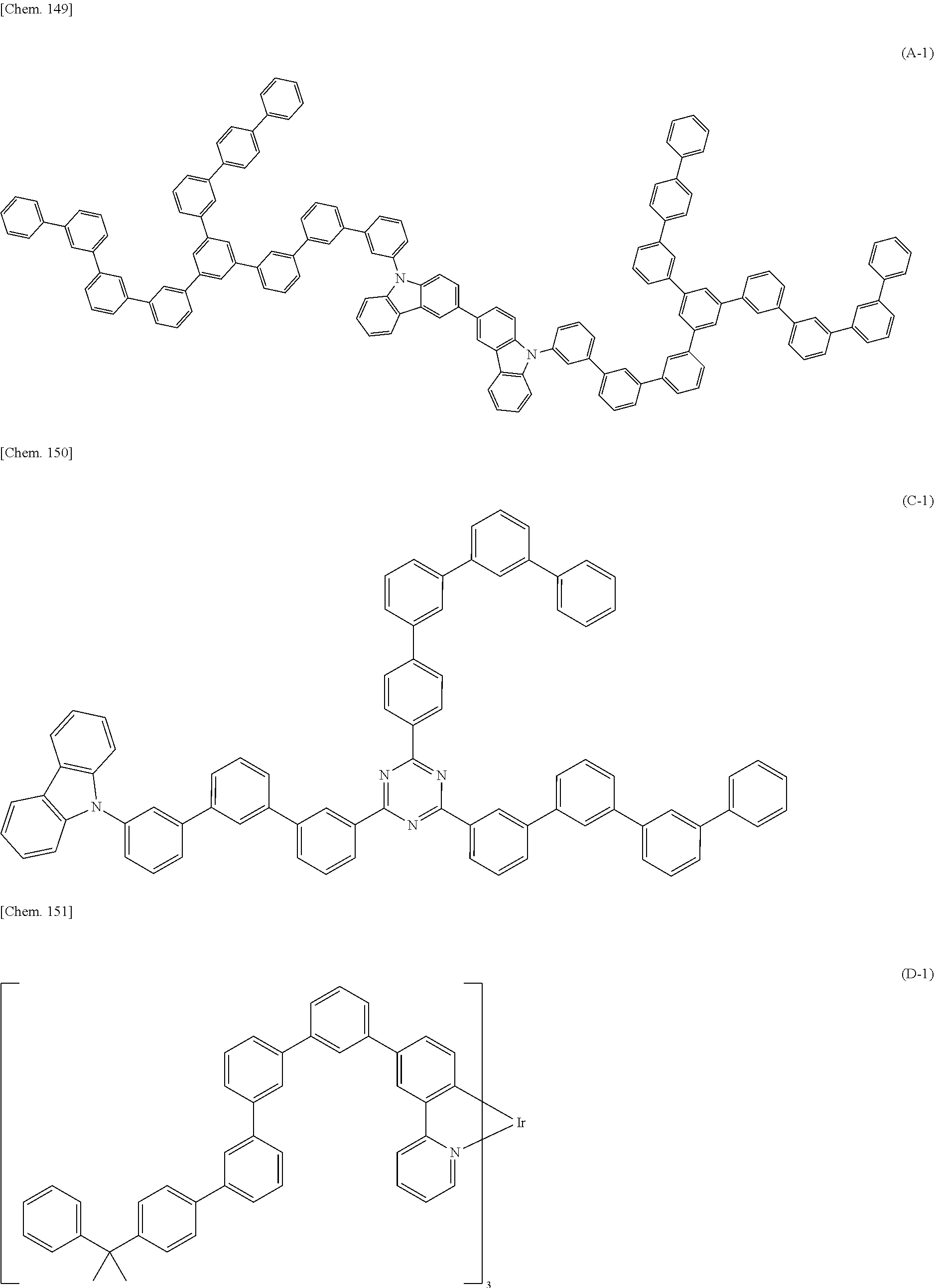

This solution was applied, by spin coating, on the substrate on which the above hole transport layer was coated and formed in a nitrogen glove box, and dried on a hot plate in the nitrogen glove box at 120° C. for 20 minutes to form a uniform thin film having a film thickness of 70 nm, thereby forming an emission layer. The substrate on which layers up to the emission layer were formed was placed in a vacuum deposition device, and the inside of the device was evacuated to 2×10⁻⁴ Pa or lower.

Next, a compound (ET-1) having the following structural formula and 8-hydroxyquinolinolato lithium were co-deposited on the emission layer at a thickness ratio of 2:3 by a vacuum deposition method to form an electron transport layer having a film thickness of 30 nm.

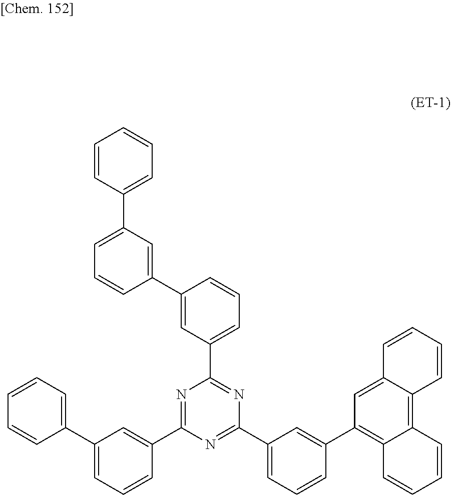 [SMILES: c1ccc(-c2cccc(-c3cccc(-c4nc(-c5cccc(-c6ccccc6)c5)nc(-c5cccc(-c6cc7ccccc7c7ccccc67)c5)n4)c3)c2)cc1]

Subsequently, a shadow-mask in the form of stripes with a width of 2 mm as a mask for cathode deposition was brought into close contact with the substrate such that these stripes were perpendicular to the ITO stripes of the anode, and aluminum was heated by a molybdenum boat to form an aluminum layer having a film thickness of 80 nm, thereby forming a cathode. As described above, an organic electroluminescent element having a luminescence area portion of a size of 2 mm×2 mm was obtained.

### Comparative Example 1

An organic electroluminescent element was prepared in the same manner as in Example 1 except that a comparative compound (CC-1) having the following structure was used instead of the compound (C-1) as the material of the emission layer.

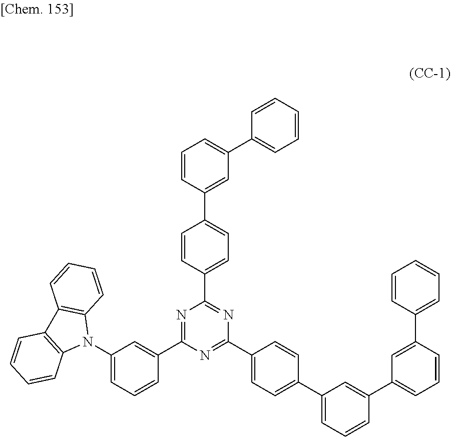 [SMILES: c1ccc(-c2cccc(-c3ccc(-c4nc(-c5ccc(-c6cccc(-c7cccc(-c8ccccc8)c7)c6)cc5)nc(-c5cccc(-n6c7ccccc7c7ccccc76)c5)n4)cc3)c2)cc1]

### Comparative Example 2

An organic electroluminescent element was prepared in the same manner as in Example 1 except that a comparative compound (CC-2) having the following structure was used instead of the compound (A-1) as the material of the emission layer.

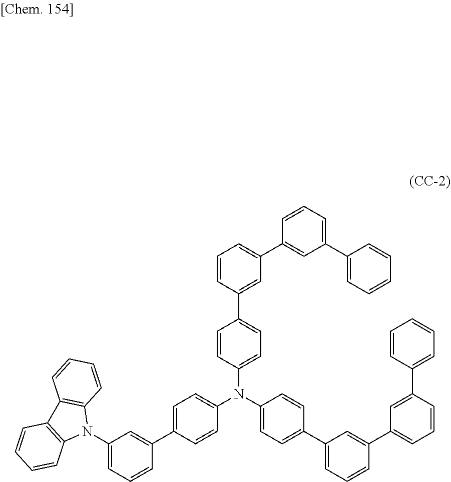 [SMILES: c1ccc(-c2cccc(-c3cccc(-c4ccc(N(c5ccc(-c6cccc(-c7cccc(-c8ccccc8)c7)c6)cc5)c5ccc(-c6cccc(-n7c8ccccc8c8ccccc87)c6)cc5)cc4)c3)c2)cc1]

### [Evaluation of Element]

Current efficiency (cd/A) and external quantum efficiency (%) when the organic electroluminescent elements obtained in Example 1 and Comparative Examples 1 and 2 were caused to emit light at 1,000 cd/m² were measured. Measurement results of those are shown in Table 1. Numerical values in Table 1 are relative values when those in Comparative Example 2 are taken as 1.

From the results of Table 1, it was found that the performance was improved in the organic electroluminescent element using the compound according to the present invention.

TABLE 1

| | Com- | Com- | Com- | | |
|---|---|---|---|---|---|
| | pound | pound | pound | Current | External |
| | contained | contained | contained | effi- | quantum |
| | in group A | in group B | in group C | ciency | efficiency |
| Example 1 | A-1 | — | C-1 | 1.11 | 1.12 |
| Comparative | A-1 | — | — | 1.03 | 1.03 |
| Example 1 | | | | | |
| Comparative | — | — | C-1 | 1 | 1 |
| Example 2 | | | | | |

### Example 2

An organic electroluminescent element was prepared in the same manner as in Example 1 except that a composition for forming an emission layer was used as a material of the emission layer, which was obtained by dissolving, in cyclohexylbenzene, a compound (B-1) of the present invention contained in the group B having the following structure at a concentration of 2.7 wt %, the compound (C-1) of the present invention contained in the group C at a concentration of 2.7 wt %, and the compound (D-1) at a concentration of 1.6 wt %.

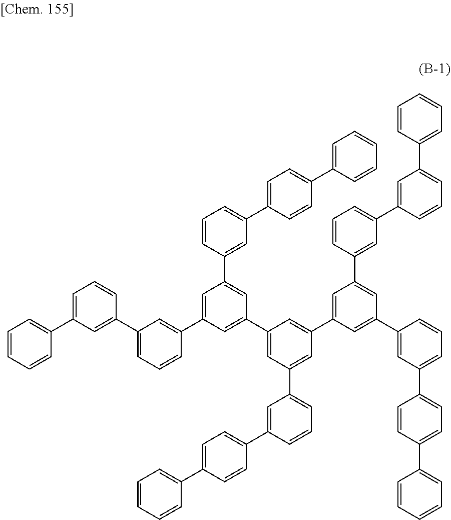 [SMILES: c1ccc(-c2ccc(-c3cccc(-c4cc(-c5cccc(-c6cccc(-c7ccccc7)c6)c5)cc(-c5cc(-c6cccc(-c7ccc(-c8ccccc8)cc7)c6)cc(-c6cc(-c7cccc(-c8ccc(-c9ccccc9)cc8)c7)cc(-c7cccc(-c8cccc(-c9ccccc9)c8)c7)c6)c5)c4)c3)cc2)cc1]

### Comparative Example 3

An organic electroluminescent element was prepared in the same manner as in Example 2 except that a comparative compound (CC-1) was used instead of the compound (C-1) as the material of the emission layer.

### [Evaluation of Element]

Current efficiency (cd/A) and external quantum efficiency (%) when the organic el ectrolumine scent elements obtained in Example 2 and Comparative Examples 2 and 3 were caused to emit light at 1,000 cd/m2 were measured. Measurement results of those are shown in Table 2. Numerical values in Table 2 are relative values when those in Comparative Example 2 are taken as 1.

From the results of Table 2, it was found that the performance was improved in the organic electroluminescent element using the compound according to the present invention.

TABLE 2

| | Com- | Com- | Com- | | |
|---|---|---|---|---|---|
| | pound | pound | pound | Current | External |
| | contained | contained | contained | effi- | quantum |
| | in group A | in group B | in group C | ciency | efficiency |
| Example 2 | — | B-1 | C-1 | 1.09 | 1.09 |
| Comparative | — | B-1 | — | 1.01 | 1.03 |
| Example 3 | | | | | |
| Comparative | — | — | C-1 | 1 | 1 |
| Example 2 | | | | | |

### Example 3

An organic electroluminescent element was prepared in the same manner as in Example 1 except that a composition for forming an emission layer was used as a material of the emission layer, which was obtained by dissolving, in cyclohexylbenzene, the compound (A-1) of the present invention contained in the group A at a concentration of 2.7 wt %, a compound (C-2) of the present invention contained in the group C having the following structure at a concentration of 2.7 wt %, and the compound (D-1) at a concentration of 1.6 wt %.

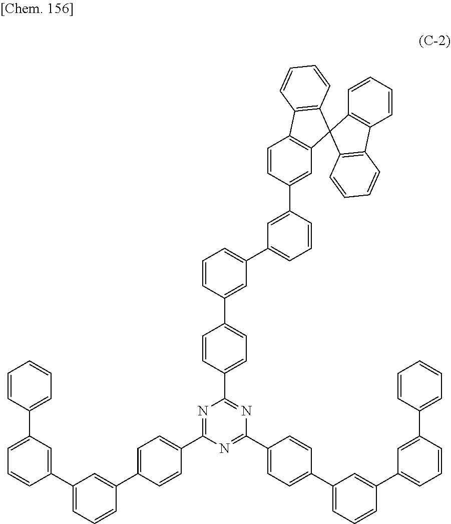 [SMILES: c1ccc(-c2cccc(-c3cccc(-c4ccc(-c5nc(-c6ccc(-c7cccc(-c8cccc(-c9ccccc9)c8)c7)cc6)nc(-c6ccc(-c7cccc(-c8cccc(-c9ccc%10c(c9)C9(c%11ccccc%11-c%11ccccc%119)c9ccccc9-%10)c8)c7)cc6)n5)cc4)c3)c2)cc1]

### Example 4

An organic electroluminescent element was prepared in the same manner as in Example 1 except that a composition for forming an emission laver was used as a material of the emission layer, which was obtained by dissolving, in cyclohexylbenzene, the compound (B-1) of the present invention contained in the group B at a concentration of 2.7 wt %, the compound (C-2) of the present invention contained in the group C at a concentration of 2.7 wt %, and the compound (D-1) at a concentration of 1.6 wt %.

### Comparative Example 4

An organic electroluminescent element was prepared in the same manner as in Example 3 except that the comparative compound (CC-2) was used instead of the compound (A-1) as the material of the emission layer.

### [Evaluation of Element]

Current efficiency (cd/A) and external quantum efficiency (%) when the organic electroluminescent elements obtained in Examples 3 and 4 and Comparative Example 4 were caused to emit light at 1,000 cd/m² were measured. Measurement results of those are shown in Table 3. Numerical values in Table 3 are relative values when those in Comparative Example 4 are taken as 1.

From the results of Table 3, it was found that the performance was improved in the organic electroluminescent element using the compound according to the present invention.

TABLE 3

| | Com- | Com- | Com- | | |
|---|---|---|---|---|---|
| | pound | pound | pound | Current | External |
| | contained | contained | contained | effi- | quantum |
| | in group A | in group B | in group C | ciency | efficiency |
| Example 3 | A-1 | — | C-2 | 1.15 | 1.15 |
| Example 4 | — | B-1 | C-2 | 1.13 | 1.13 |
| Comparative | — | — | C-2 | 1 | 1 |
| Example 4 | | | | | |

### Example 5

An organic electroluminescent element was prepared in the same manner as in Example 1 except that a composition for forming an emission layer was used as a material of the emission layer, which was obtained by dissolving, in cyclohexylbenzene, the compound (A-1) of the present invention contained in the group A at a concentration of 1.6 wt %, the compound (B-1) of the present invention contained in the group B at a concentration of 1.6 wt %, a compound (C-3) of the present invention contained in the group C having the following structure at a concentration of 2.2 wt %, and the compound (D-1) at a concentration of 1.6 wt %.

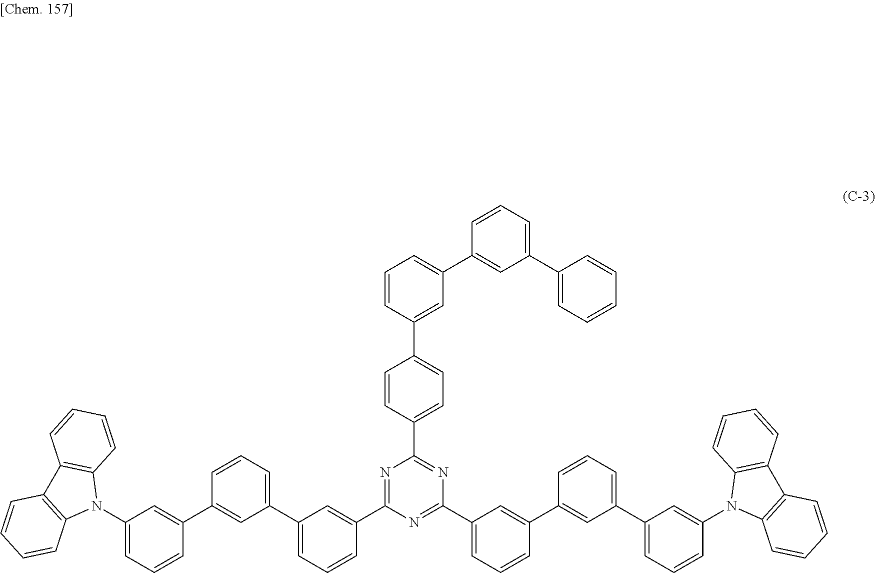 [SMILES: c1ccc(-c2cccc(-c3cccc(-c4ccc(-c5nc(-c6cccc(-c7cccc(-c8cccc(-n9c%10ccccc%10c%10ccccc%109)c8)c7)c6)nc(-c6cccc(-c7cccc(-c8cccc(-n9c%10ccccc%10c%10ccccc%109)c8)c7)c6)n5)cc4)c3)c2)cc1]

### Example 6

An organic electroluminescent element was prepared in the same manner as in Example 1 except that a composition for forming an emission layer was used as a material of the emission layer, which was obtained by dissolving, in cyclohexylbenzene, the compound (B-1) of the present invention contained in the group B at a concentration of 3.2 wt %, the compound (C-3) of the present invention contained in the group C at a concentration of 2.2 wt %, and the compound (D-1) at a concentration of 1.6 wt %.

### Comparative Example 5

An organic electroluminescent element was prepared in the same manner as in Example 6 except that the comparative compound (CC-2) was used instead of the compound (B-1) as the material of the emission layer.

### Comparative Example 6

An organic electroluminescent element was prepared in the same manner as in Example 6 except that the comparative compound (CC-1) was used instead of the compound (C-3) as the material of the emission layer.

### [Evaluation of Element]

Current efficiency (cd/A) and external quantum efficiency (%) when the organic electroluminescent elements obtained in Examples 5 and 6 and Comparative Examples 5 and 6 were caused to emit light at 1,000 cd/m² were measured. Measurement results of those are shown in Table 4. Numerical values in Table 4 are relative values when those in Comparative Example 6 are taken as 1.

From the results of Table 4, it was found that the performance was improved in the organic electroluminescent element using the compound according to the present invention.

TABLE 4

| | Com- | Com- | Com- | | |
|---|---|---|---|---|---|
| | pound | pound | pound | Current | External |
| | contained | contained | contained | effi- | quantum |
| | in group A | in group B | in group C | ciency | efficiency |
| Example 5 | A-1 | B-1 | C-3 | 1.20 | 1.20 |
| Example 6 | — | B-1 | C-3 | 1.14 | 1.14 |
| Comparative | — | — | C-3 | 1.04 | 1.04 |
| Example 5 | | | | | |
| Comparative | — | B-1 | — | 1 | 1 |
| Example 6 | | | | | |

### Example 7

An organic electroluminescent element was prepared in the same manner as in Example 1 except that a composition for forming an emission layer was used as a material of the emission layer, which was obtained by dissolving, in cyclohexylbenzene, the compound (A-1) of the present invention contained in the group A at a concentration of 3.2 wt %, the compound (C-3) of the present invention contained in the group C at a concentration of 2.2 wt %, and the compound (D-1) at a concentration of 1.6 wt %.

### [Evaluation of Element]

Current efficiency (cd/A) and external quantum efficiency (%) when the organic electroluminescent elements obtained in Example 7 and Comparative Example 5 were caused to emit light at 1,000 cd/m² were measured. Measurement results of those are shown in Table 5. Numerical values in Table 5 are relative values when those in Comparative Example 5 are taken as 1. From the results of Table 5, it was found that the performance was improved in the organic electroluminescent element using the compound according to the present invention.

TABLE 5

| | Com- | Com- | Com- | | |
|---|---|---|---|---|---|
| | pound | pound | pound | Current | External |
| | contained | contained | contained | effi- | quantum |
| | in group A | in group B | in group C | ciency | efficiency |
| Example 7 | A-1 | — | C-3 | 1.10 | 1.11 |
| Comparative | — | — | C-3 | 1 | 1 |
| Example 5 | | | | | |

### Example 8

An organic electroluminescent element was prepared in the same manner as in Example 1 except that a composition for forming an emission layer was used as a material of the emission layer, which was obtained by dissolving, in cyclohexylbenzene, the compound (A-1) of the present invention contained in the group A at a concentration of 1.6 wt %, the compound (B-1) of the present invention contained in the group B at a concentration of 1.6 wt %, the compound (CC-1) at a concentration of 2.2 wt %, and the compound (D-1) at a concentration of 1.6 wt %.

### [Evaluation of Element]

Current efficiency (cd/A) and external quantum efficiency (%) when the organic electroluminescent elements obtained in Example 8 and Comparative Example 6 were caused to emit light at 1,000 cd/m² were measured. Measurement results of those are shown in Table 6. Numerical values in Table 6 are relative values when those in Comparative Example 6 are taken as 1.

From the results of Table 6, it was found that the performance was improved in the organic electroluminescent element using the compound according to the present invention.

TABLE 6

| | Com- | Com- | Com- | | |
|---|---|---|---|---|---|
| | pound | pound | pound | Current | External |
| | contained | contained | contained | effi- | quantum |
| | in group A | in group B | in group C | ciency | efficiency |
| Example 8 | A-1 | B-1 | — | 1.06 | 1.07 |
| Comparative | — | B-1 | — | 1 | 1 |
| Example 6 | | | | | |

### Example 9

### [Ejection Performance Test]

A compound (ET1) having the following structure was dissolved in 1-heptanol:2-butyl-1-n-octanol=8:2 (vol./vol.) as a solvent at a concentration of 5 mg/mL to prepare a composition for layer formation.

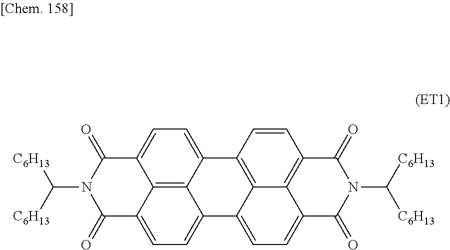

This composition was filled in a cartridge (DMCLCP-11610), and an ejection performance test of the composition was performed using a material printer DMP-2831 manufactured by FUJIFILM Corporation. A case where the composition could be ejected at a piezo voltage of 25 V was evaluated as “good”, and a case where the composition could not be ejected at a piezo voltage of 25 V was evaluated as “poor”.

### [Clogging Test]

After the ejection of the composition was performed for 1 minute in the ejection performance test, the ejection was stopped, and the ejection of the composition was performed again after waiting for 10 minutes. In this case, a case where the composition could be ejected in the same manner as in the ejection performance test was evaluated as “good”, and a case where the composition could not be ejected in the same manner was evaluated as “poor”. The case where the composition could not be ejected in the same manner means that in this case, the composition cannot be ejected at the same voltage as in the ejection performance test, or a trajectory of flight of the composition differs from that in the ejection performance test.

### [Lamination Test]

In performing the lamination test, the compounds (C-2), (A-1), and (D-2) having the following structures were dissolved in cyclohexylbenzene at a weight ratio of 35:35:30 such that a solid content concentration was 7 wt % to prepare a composition. This composition corresponds to the composition for forming an emission layer when forming the organic electroluminescent element having at least the anode, the cathode, and the emission layer located between the anode and the cathode. This composition was applied, by spin coating, on a glass substrate in a nitrogen glove box and baked at 130° C. for 20 minutes to prepare a film for lamination test which was a film assumed as an emission layer having a film thickness of 65 nm.

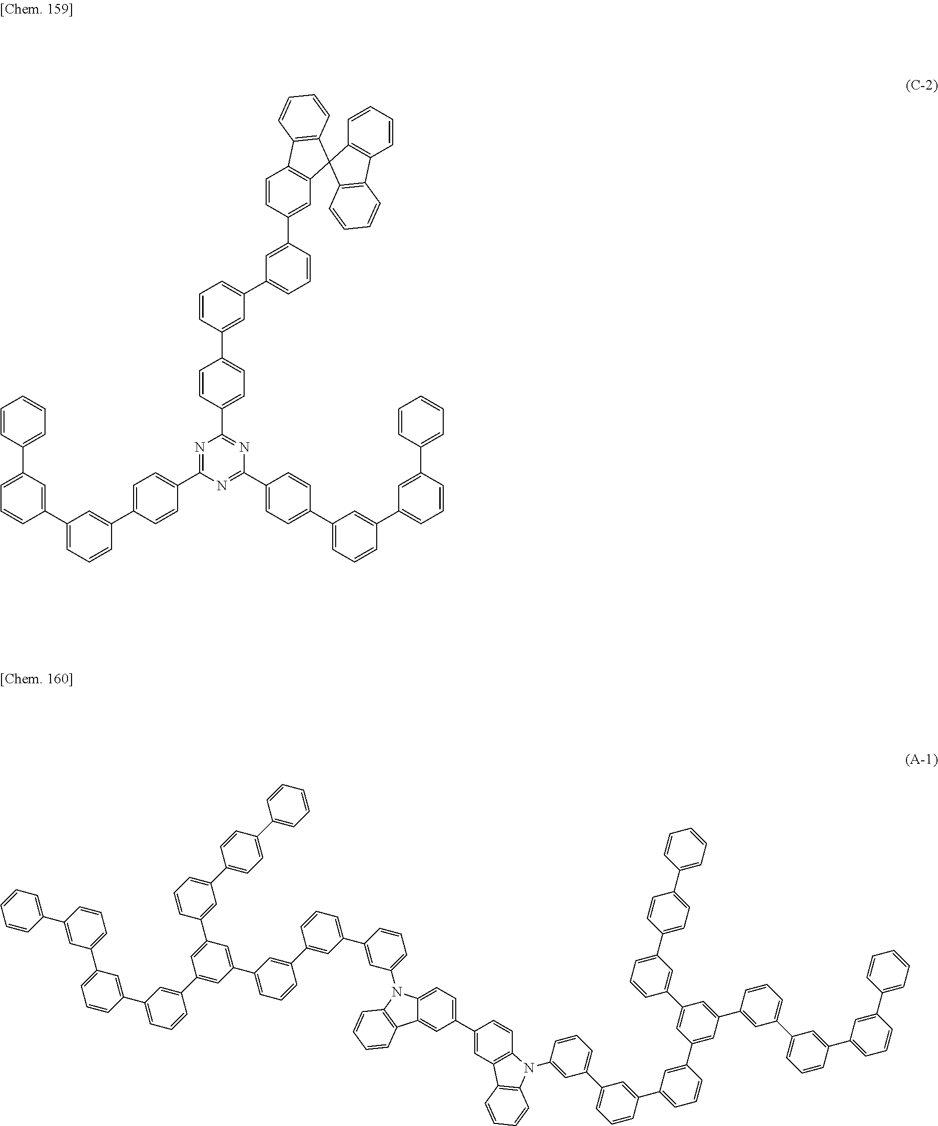

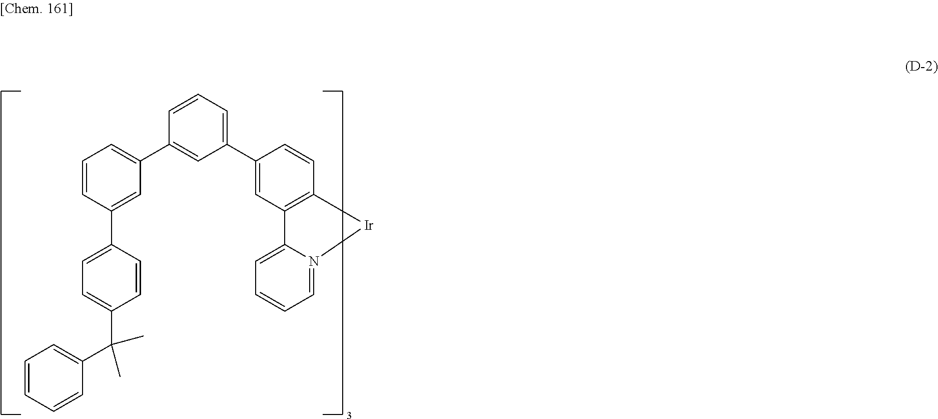

A reflectance of the film for lamination test was measured using a microscopic spectroscopic coating thickness gauge OPTM manufactured by Otsuka Electronics Co.,Ltd. Next, the film for lamination test was set in a spincoater, 500 μL of 1-heptanol:2-butyl-1-n-octanol=8:2 (vol./vol.) was added dropwise onto the film as a test organic solvent, and the film was allowed to stand still for 90 seconds to perform the lamination test. Thereafter, the film for lamination test was spun out at 1,500 rpm for 30 seconds and then at 4,000 rpm for 30 seconds. The film for test was dried in a vacuum dryer for 3 minutes and then on a hot plate in the air at 100° C. for 10 minutes.

The reflectance of the film for test subjected to the lamination test was again measured by a microscopic spectroscopic coating thickness gauge, and a case where a change in reflectance was less than 5% within a wavelength range of 300 nm to 700 nm was evaluated as “good”, and a case where a change in reflectance of 5% or more was observed was evaluated as “poor”. The reflectance reflects flatness of the film. That is, when the film for lamination test is dissolved in the test organic solvent, the flatness of a surface is impaired and the reflectance is changed. When the change in reflectance is less than 5%, the film for lamination test does not dissolve in the test organic solvent and the flatness is good, and a good organic electroluminescent element can be obtained by laminating the composition for layer formation on the emission layer used as the film for lamination test by a wet-process film formation method. On the other hand, when the change in reflectance is 5% or more, it is considered that the film for lamination test was dissolved in the test organic solvent, and when an organic electroluminescent element is prepared, characteristics of the element are reduced, which is not preferable.

### Example 10

An ejection performance test, a clogging test, and a lamination test were performed using an organic solvent composition of 1-butanol:2-butyl-1-n-octanol=8:2 (vol./vol.) instead of the organic solvent composition of 1-heptanol:2-butyl-1-n-octanol=8:2 (vol./vol.) of Example 9.

### Reference Example 1

An ejection performance test, a clogging test, and a lamination test were performed using 1-butanol instead of the organic solvent composition of 1-heptanol:2-butyl-1-n-octanol=8:2 (vol./vol.) of Example 9.

### Reference Example 2

An ejection performance test, a clogging test, and a lamination test were performed using 2-butyl-1-n-octanol instead of the organic solvent composition of 1-heptanol:2-butyl-1-n-octanol=8:2 (vol./vol.) of Example 9.

### Reference Example 3

An ejection performance test, a clogging test, and a lamination test were performed using ethylene glycol instead of the organic solvent composition of 1-heptanol:2-butyl-1-n-octanol=8:2 (vol./vol.) of Example 9.

The organic solvents used in Examples 9 and 10 and Reference Examples 1 to 3 are as follows.
2-butyl-1-n-octanol: manufactured by Tokyo Chemical Industry Co., Ltd., boiling point: 104° C. (pressure: 0.4 kPa) (boiling point calculated by ACD/Labs software: 245° C.)
1-heptanol: manufactured by Tokyo Chemical Industry Co., Ltd., boiling point: 176° C.
1-butanol: manufactured by Tokyo Chemical Industry Co., Ltd., boiling point: 117° C.
Ethylene glycol: manufactured by Tokyo Chemical Industry Co., Ltd., boiling point: 198° C.

Test results obtained in Examples 9 to 10 and Reference Examples 1 to 3 are summarized in Table 7.

TABLE 7

| | Solvent composition | Ejection | | Lami- |
|---|---|---|---|---|
| | and composition | performance | Clogging | nation |
| | ratio (vol./vol.) | test | test | test |
| Example 9 | 1-heptanol:2-butyl-1- | Good | Good | Good |
| | n-octanol = 8:2 | | | |
| Example 10 | 1-butanol:2-butyl-1-n- | Good | Good | Good |
| | octanol = 8:2 | | | |
| Reference | 1-butanol | Good | Poor | Good |
| Example 1 | | | | |
| Reference | 2-butyl-1-n-octanol | Poor | — | — |
| Example 2 | | | | |
| Reference | Ethylene glycol | Poor | — | — |
| Example 3 | | | | |

From the results of Table 7, it was possible to form, on the film assumed as the emission layer by a wet-process film formation method using the composition for forming an emission layer according to the present invention, the organic electroluminescent element by applying a composition for layer formation to a surface of the film assumed as the emission layer by an inkjet method, and laminating a layer in contact with the film assumed as the emission layer, the composition for layer formation being an organic solvent containing a functional material and at least two kinds of organic solvents, and the boiling point of at least one kind of the organic solvents being 200° C. or higher.

Although various embodiments have been described above with reference to the drawing, it goes without saying that the present invention is not limited to such examples. It is clear that those skilled in the art can come up with various changes or modifications within the scope of the claims, and it is understood that these also naturally fall within the technical scope of the present invention. In addition, each of the constituent elements in the above embodiments may be freely combined without departing from the spirit of the present invention.

The present application is based on a Japanese Patent Application (No. 2022-050624) filed on Mar. 25, 2022 and a Japanese Patent Application (No. 2022-089930) filed on Jun. 1, 2022, contents of which are incorporated by reference into the present application.

### INDUSTRIAL APPLICABILITY

According to the present invention, it is possible to provide a material for an emission layer capable of providing an organic electroluminescent element exhibiting high luminescent efficiency in order to achieve a wide energy gap and appropriate charge transportability. Further, according to the present invention, it is possible to provide a method for producing an organic electroluminescent element, a display device, and an illuminator using the material for an emission layer, as well as an organic electroluminescent element, a display device, and an illuminator obtained by the production method.

### REFERENCE SIGNS LIST

1: substrate
2: anode
3: hole injection layer
4: hole transport layer
5: emission layer
6: hole blocking layer
7: electron transport layer
8: electron injection layer
9: cathode
10: organic electroluminescent element

1. A material for an emission layer of an organic electroluminescent element, comprising:
at least a luminescent material and at least two kinds of compounds respectively selected from at least any two groups among three groups represented by the following (group A), (group B), and (group C):
(group A): a group consisting of a compound represented by the following formula (1-A) and a compound represented by the following formula (1-B),
(group B): a compound represented by the following formula (2), and
(group C): a group consisting of a compound represented by the following formula (3), a compound represented by the following formula (1-1), and a compound represented by the following formula (1-2), 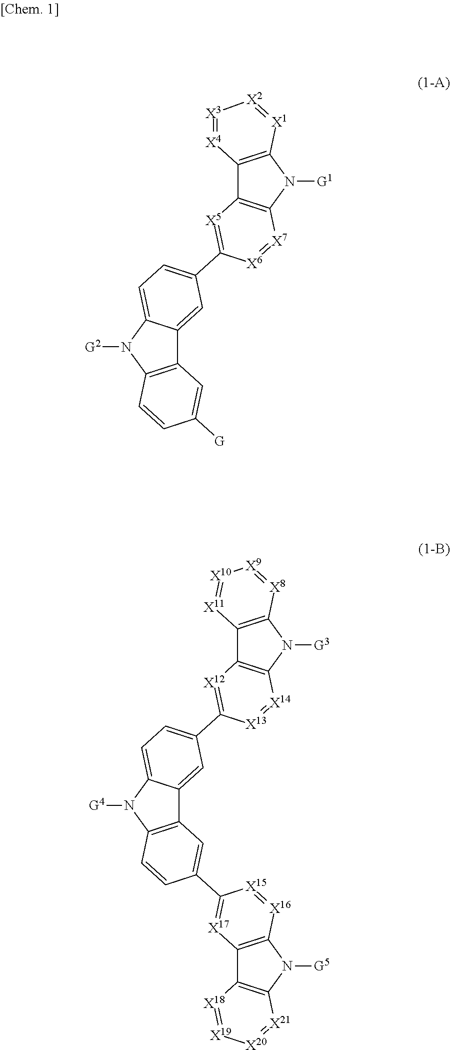
(wherein in the formula (1-A), G¹ and G² each independently represent an aromatic hydrocarbon group, and the total carbon atom number of the number of carbon atoms of G¹ and the number of carbon atoms of G² is 42 or more and 240 or less, or at least one of the number of carbon atoms of G¹ and G² is 54 or more and 240 or less; X¹ to X⁷ each independently represent CR^{1A} or a nitrogen atom, and R^{1A} each independently represent, for each occurrence, a hydrogen atom, a deuterium atom, CN, or an aromatic hydrocarbon group having 6 to 30 carbon atoms which may have a substituent; G represents a hydrogen atom, a deuterium atom, CN, or an aromatic hydrocarbon group having 6 to 30 carbon atoms which may have a substituent;
in the formula (1-B), G³, G⁴, and G⁵ each independently represent an aromatic hydrocarbon group, and the total carbon atom number of the number of carbon atoms of G³, the number of carbon atoms of G⁴, and the number of carbon atoms of G⁵ is 42 or more and 240 or less, or at least one of the number of carbon atoms of G³, G⁴, and G⁵ is 28 or more and 240 or less; and X⁸ to X²¹ each independently represent a CR^{1B} or a nitrogen atom, and R^{1B} each independently represent, for each occurrence, a hydrogen atom, a deuterium atom, a CN, or an aromatic hydrocarbon group having 6 to 30 carbon atoms which may have a substituent), 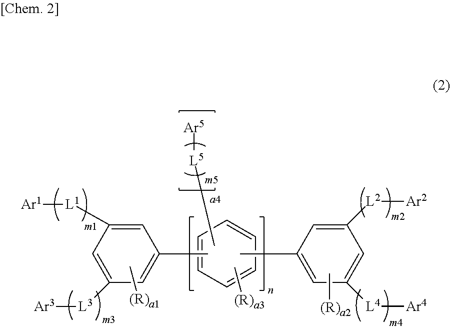
(wherein in the formula (2),
Ar¹ to Ar⁵ each independently represent a hydrogen atom or a monovalent aromatic hydrocarbon group having 6 or more and 60 or less carbon atoms which may have a substituent,
at least one of Ar¹, Ar², and Ar⁵ is represented by the following formula (4) or the following formula (5),
Ar³ and Ar⁴ each independently represent a hydrogen atom or a monovalent aromatic hydrocarbon group having 6 or more and 60 or less carbon atoms which may have a substituent,
L¹ to L⁵ each independently represent a divalent aromatic hydrocarbon group having 6 or more and 60 or less carbon atoms which may have a substituent, R each independently represents a substituent,
m1, m2, and m5 each independently represent an integer of 0 to 5,
m3 and m4 each independently represent an integer of 1 to 5,
n represents an integer of 0 to 10,
a1 and a2 each independently represent an integer of 0 to 3,
a3 represents an integer of 0 to 4, and
a4 represents an integer of 0 or 1,
here, when a3 is 4, a4 is 0, and
in the formula (2), Ar¹—(L¹)ₘ₁—, Ar²—(L²)ₘ₂—, Ar³—(L³)ₘ₃—, and Ar⁴—(L⁴)ₘ₄— do not become hydrogen atoms), 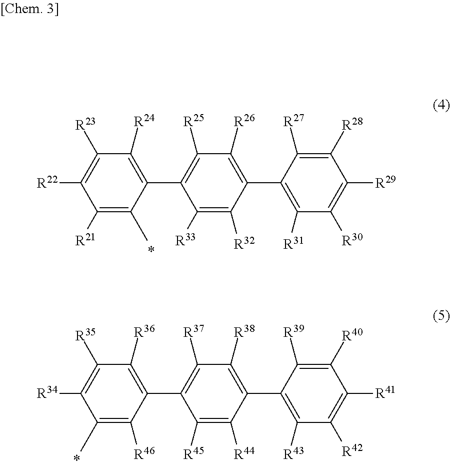
(wherein in the formula (4) or the formula (5),
an asterisk (*) represents a bond to the formula (2), and
R²¹ to R⁴⁶ each independently represent a hydrogen atom or a substituent), 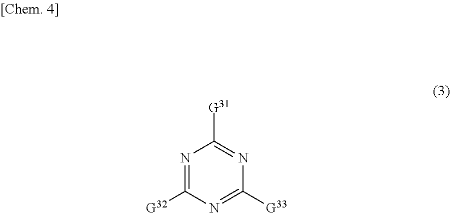
(wherein in the formula (3), G³¹ and G³² each independently represent the following formula (7), and G³³ represents the following formula (8)), 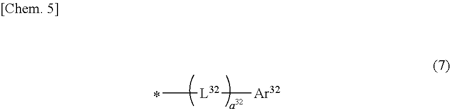
(wherein in the formula (7), an asterisk (*) represents a bond to the formula (3),
L³² represents a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked,
Ar³² represents a monovalent aromatic hydrocarbon group having 60 or less carbon atoms which may have a substituent, a monovalent heteroaromatic group having 60 or less carbon atoms which may have a substituent, or a group in which a plurality of groups selected from the monovalent aromatic hydrocarbon group having 60 or less carbon atoms which may have a substituent and the monovalent heteroaromatic group having 60 or less carbon atoms which may have a substituent are linked, and
a³² represents an integer of 0 to 5), 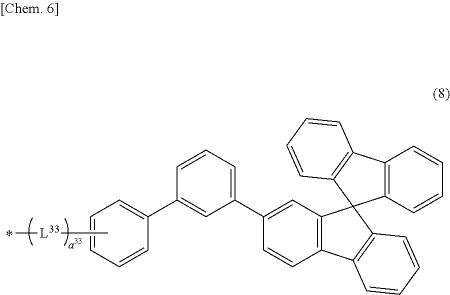
(wherein in the formula (8), an asterisk (*) represents a bond to the formula (3),
L³³ represents a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked, and
a³³ represents an integer of 0 to 5), 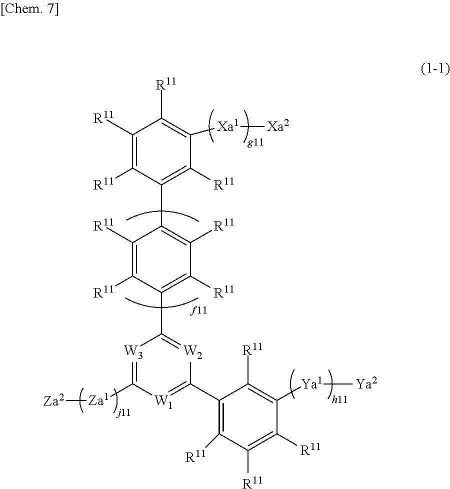
(wherein in the formula (1-1),
W₁, W₂, and W₃ each independently represent —CH or a nitrogen atom, and at least one of W₁, W₂, and W₃ represents a nitrogen atom,
Xa¹, Ya¹, and Za¹ each independently represent a 1,3-phenylene group which may have a substituent, or a 1,4-phenylene group which may have a substituent, at least one of Za¹ is a 1,3-phenylene group,
Xa² and Ya² each independently represent a phenyl group which may have a substituent,
Za² represents an N-carbazolyl group which may have a substituent,
f11 is 1 or 2,
g11 is an integer of 1 to 5,
h11 is an integer of 2 to 5,
j11 is an integer of 1 to 6,
f11+g11+h11+j11 is 5 or more, and
R¹¹ each independently represents a hydrogen atom or a substituent), and 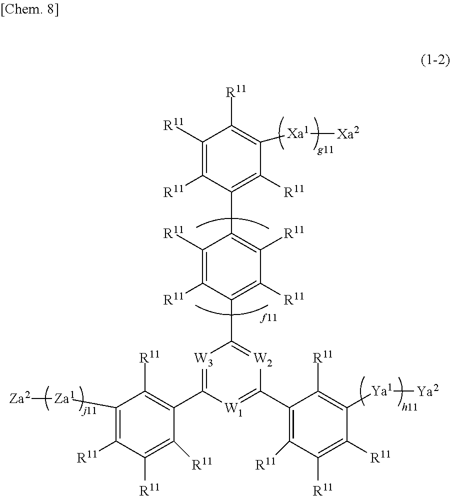
(wherein in the formula (1-2),
W₁, W₂, and W₃ each independently represent —CH or a nitrogen atom, and at least one of W₁, W₂, and W₃ is a nitrogen atom,
Xa¹, Ya¹, and Za¹ each independently represent a 1,3-phenylene group which may have a substituent, or a 1,4-phenylene group which may have a substituent,
at least one of Ya¹ and Za¹ is a 1,3-phenylene group which may have a substituent,
Xa² represents a phenyl group which may have a substituent,
Ya² and Za² each independently represent an N-carbazolyl group which may have a substituent,
f11 is 1 or 2,
g11 is an integer of 1 to 5,
h11 is an integer of 2 to 5,
j11 is an integer of 2 to 5,
f11+g11+h11+j11 is 6 or more, and
R¹¹ each independently represents a hydrogen atom or a substituent).

2. The material for an emission layer according to claim 1, wherein
at least one of G¹ to G⁵ in the formula (1-A) and the formula (1-B) includes at least one substructure selected from the following formulae (11) to (16), 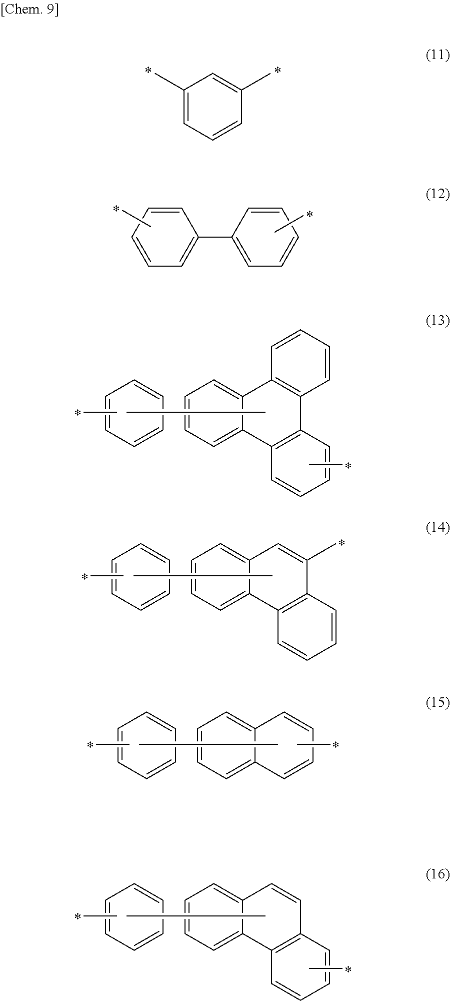
(wherein in each of the formulae (11) to (16), an asterisk (*) represents a bond to an adjacent structure or a hydrogen atom, and at least one of two present *s represents a bonding site to the adjacent structure).

3. The material for an emission layer according to claim 1, wherein
L¹ to L⁵ in the formula (2) each independently represent a phenylene group or a group in which two or more phenylene groups are linked in a directly bonded manner, which may have a substituent.

4. The material for an emission layer according to claim 1, wherein
L¹ to L⁵ in the formula (2) each independently represent a 1,3-phenylene group which may have a substituent.

5. The material for an emission layer according to claim 1, wherein
the compound represented by the formula (2) has a substructure represented by at least one selected from the following formulae (17) to (19), (21), and (22), 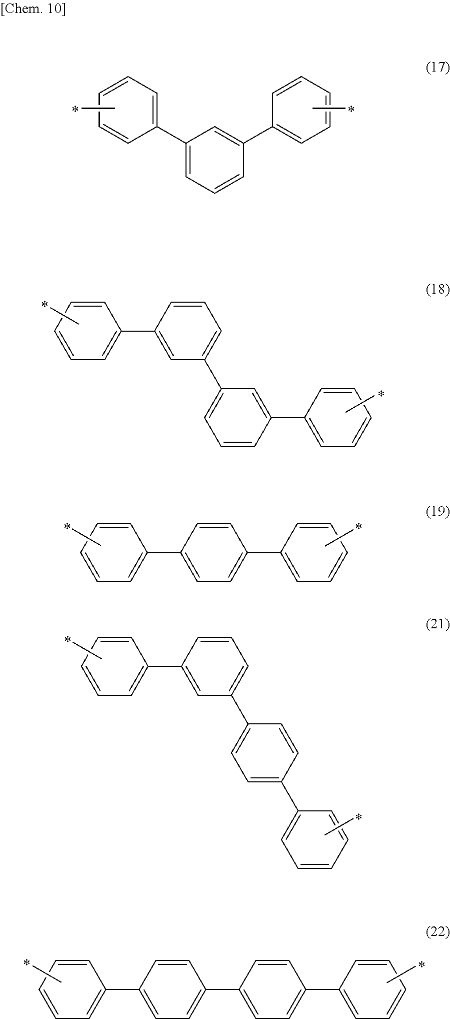
(wherein in each of the formulae (17) to (19), (21), and (22), an asterisk (*) represents a bond to an adjacent structure or a hydrogen atom, and at least one of two present *s represents a bond representing a bonding site to an adjacent structure).

6. The material for an emission layer according to claim 1, wherein
G³¹ in the formula (3) is represented by the following formula (6), 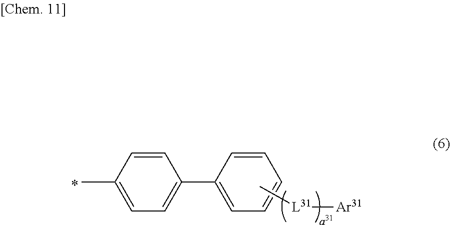
(wherein in the formula (6), an asterisk (*) represents a bond to the formula (3),
L³¹ represents a divalent aromatic hydrocarbon group having 60 or less carbon atoms which may have a substituent, a divalent heteroaromatic group having 60 or less carbon atoms which may have a substituent, or a group in which a plurality of groups selected from the divalent aromatic hydrocarbon group having 60 or less carbon atoms which may have a substituent and the divalent heteroaromatic group having 60 or less carbon atoms which may have a substituent are linked,
Ar³¹ represents a monovalent aromatic hydrocarbon group having 60 or less carbon atoms which may have a substituent, a monovalent heteroaromatic group having 60 or less carbon atoms which may have a substituent, or a group in which a plurality of groups selected from the monovalent aromatic hydrocarbon group having 60 or less carbon atoms which may have a substituent and the monovalent heteroaromatic group having 60 or less carbon atoms which may have a substituent are linked, and
a³¹ represents an integer of 0 to 5).

7. The material for an emission layer according to claim 1, wherein
L³² and L³³ in the formula (7) and the formula (8) each independently represent a phenylene group or a group in which a plurality of phenylene groups are linked in a directly bonded manner.

8. The material for an emission layer according to claim 6, wherein
L³² and L³³ in the formula (7) and the formula (8), as well as L³¹ in the formula (6) each independently represent a phenylene group or a group in which a plurality of phenylene groups are linked in a directly bonded manner.

9. The material for an emission layer according to claim 1, wherein
the compound represented by the formula (3) has a substructure represented by at least one selected from the following formulae (17) to (19), (21), and (22), 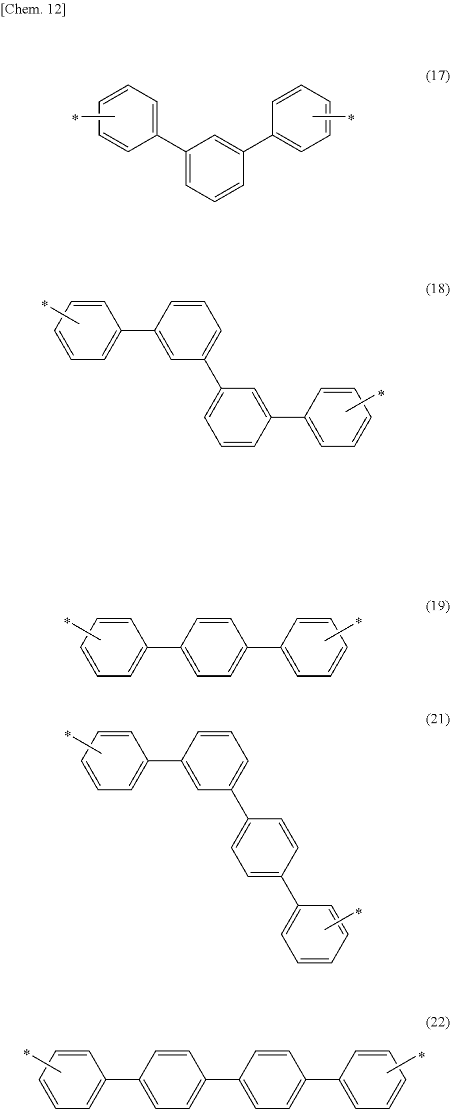
(wherein in each of the formulae (17) to (19), (21), and (22), an asterisk (*) represents a bond to an adjacent structure or a hydrogen atom, and at least one of two present *s represents a bond representing a bonding site to an adjacent structure).

10. The material for an emission layer according to claim 1, wherein
at least one of Ya¹ in the formula (1-2) is a 1,3-phenylene group, and at least one of Za¹ is a 1,3-phenylene group.

11. The material for an emission layer according to claim 1, wherein
at least one of Xa¹ in the formula (1-2) is a 1,3-phenylene group.

12. The material for an emission layer according to claim 1, wherein
in the formula (1-1), —(Xa¹)_{g11}—Xa² is selected from the structure group of the following formula (Xa-1), —(Ya¹)ₕ₁₁—Ya² is selected from the structure group of the following formula (Ya-1), and —(Za¹)ⱼ₁₁—Za² is selected from the structure group of the following formula (Za-1), and
in the formula (1-2), —(Xa¹)_{g11}—Xa² is selected from the structure group of the following formula (Xa-2), —(Ya¹)ₕ₁₁—Ya² is selected from the structure group of the following formula (Ya-2), and —(Za¹)ⱼ₁₁—Za² is selected from the structure group of the following formula

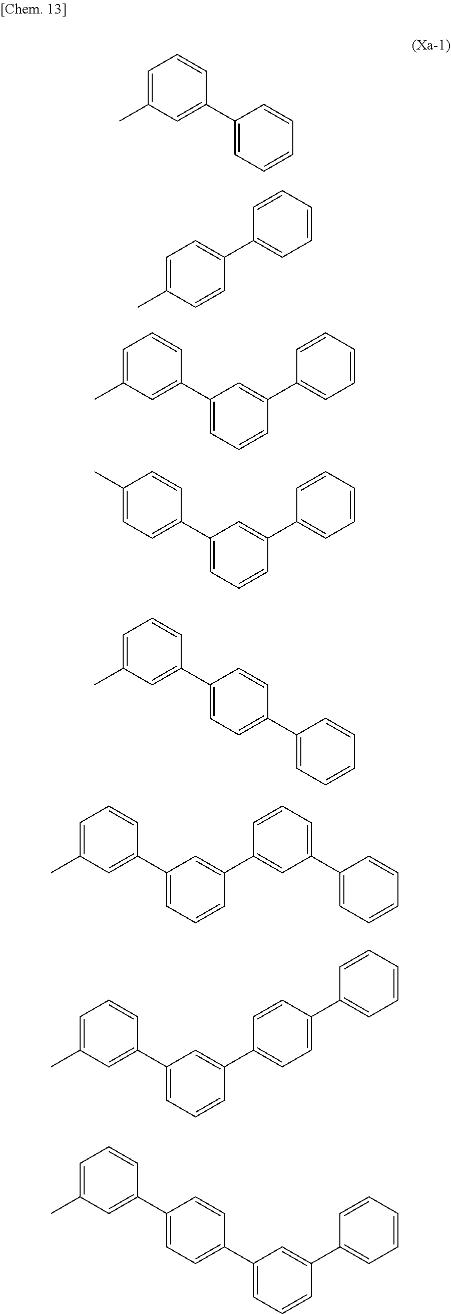

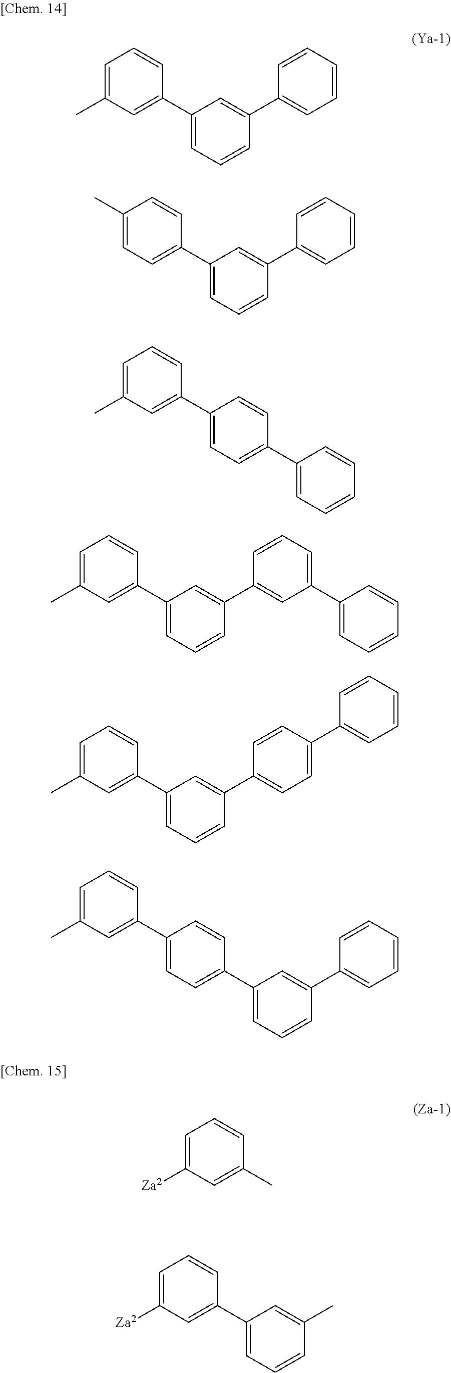

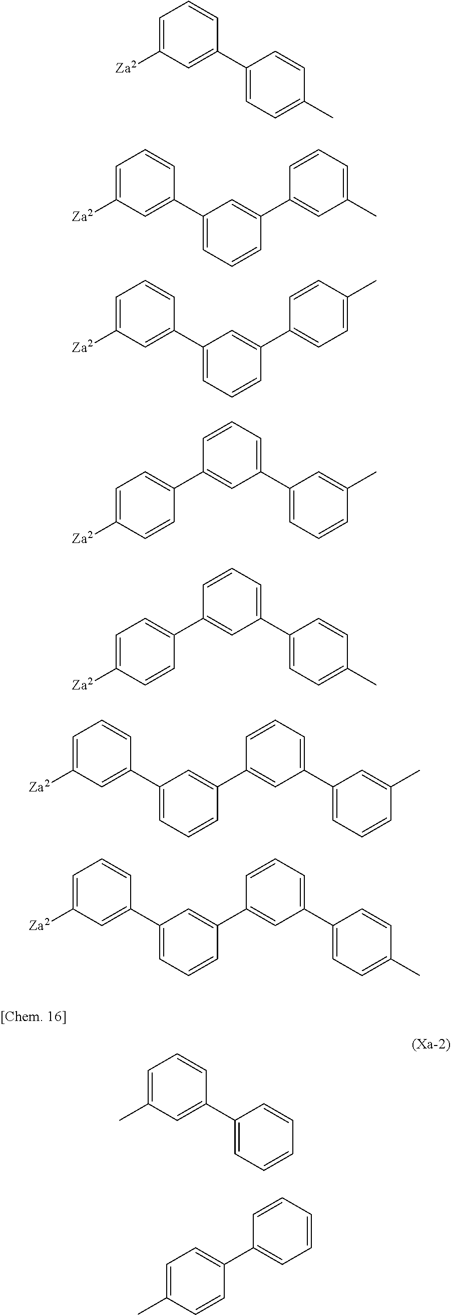

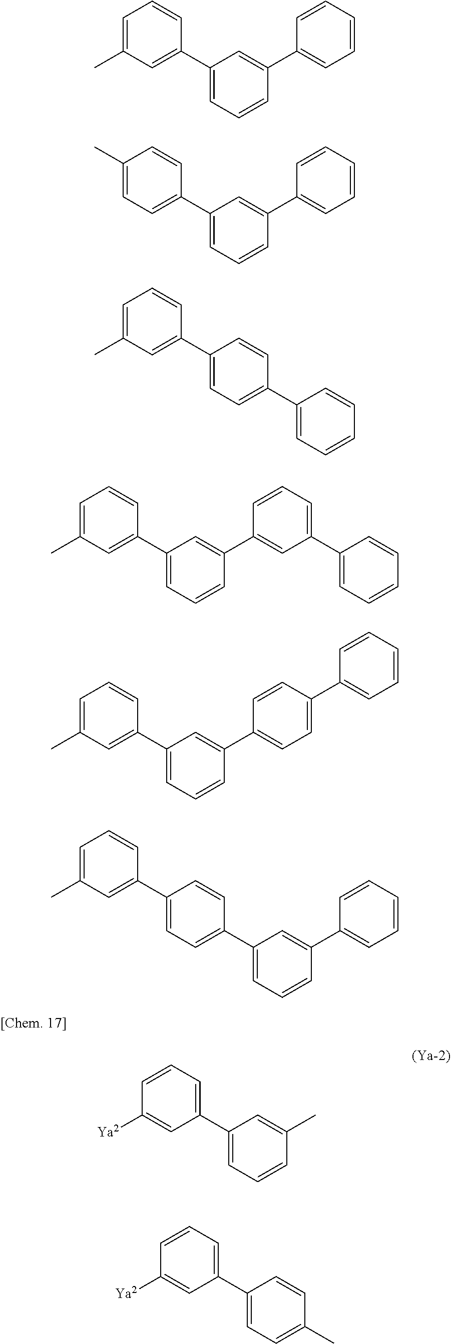

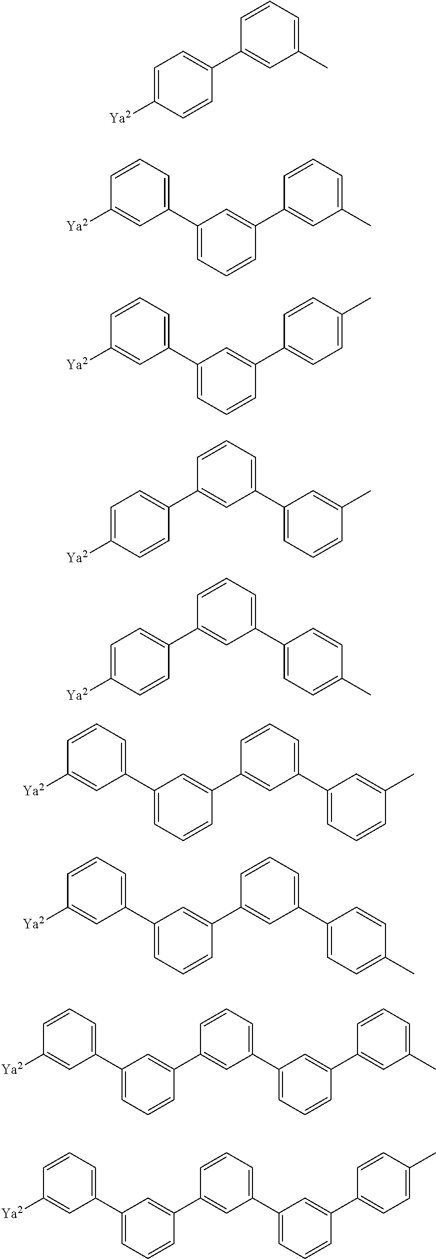

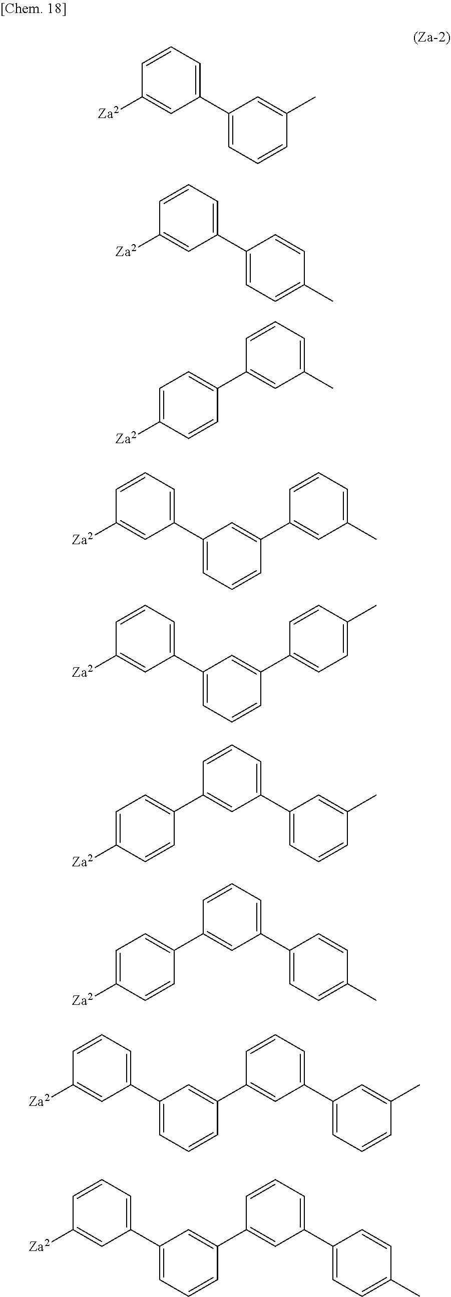

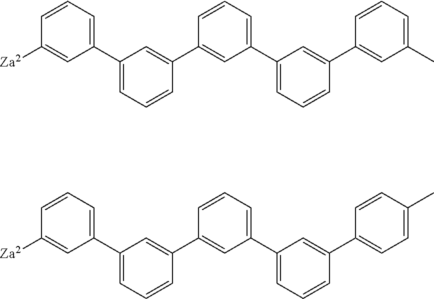

13. The material for an emission layer according to claim 1, comprising:
at least one compound selected from the compound represented by the formula (1-1) and the compound represented by the formula (1-2), wherein
all of W₁, W₂, and W₃ in the at least one compound are nitrogen atoms.

14. The material for an emission layer according to claim 1, wherein
a compound contained as the compound of (group A), (group B), or (group C) and the luminescent material all have a molecular weight of 1,200 or more.

15. An organic electroluminescent element comprising:
at least an anode, a cathode, and an emission layer located between the anode and the cathode, wherein
the emission layer contains the material for an emission layer according to claim 1.

16. A composition for forming an emission layer, comprising:
the material for an emission layer according to claim 1, and
a second organic solvent.

17. The composition for forming an emission layer according to claim 16, wherein
the second organic solvent contains at least two kinds of organic solvents, and
a boiling point of at least one kind of the organic solvents is 200° C. or higher.

18. A method for producing an organic electroluminescent element including at least an anode, a cathode, and an emission layer located between the anode and the cathode, the method comprising:
a step of forming the emission layer by a wet-process film formation method using the composition for forming an emission layer according to claim 16.

19. A method for producing an organic electroluminescent element including at least an anode, a cathode, an emission layer located between the anode and the cathode, and a layer in contact with a cathode side of the emission layer, wherein
the emission layer is formed by a wet-process film formation method using the composition for forming an emission layer according to claim 16, and
a step of forming the layer in contact with the cathode side of the emission layer includes
a step of forming the layer in contact with the cathode side of the emission layer by applying a composition for layer formation to a surface of the emission layer by an inkjet method and a step of drying the layer in contact with the cathode side of the emission layer in this order, the composition for layer formation containing a functional material and a first organic solvent, the first organic solvent containing at least two kinds of organic solvents, and
a boiling point of at least one kind of the organic solvents contained in the first organic solvent being 200° C. or higher.

20. The method for producing an organic electroluminescent element according to claim 19, wherein
the functional material is an electron-transporting compound.

21. The method for producing an organic electroluminescent element according to claim 19, wherein
the boiling point of at least one kind of the organic solvents contained in the first organic solvent is 230° C. or higher.

22. The method for producing an organic electroluminescent element according to claim 19, wherein
the boiling point of at least one kind of the organic solvents contained in the first organic solvent is lower than 200° C.

23. The method for producing an organic electroluminescent element according to claim 19, wherein
at least one kind of the organic solvents contained in the first organic solvent is a protic polar organic solvent.

24. The method for producing an organic electroluminescent element according to claim 19, wherein
at least one kind of the organic solvents contained in the first organic solvent is an alcohol-based organic solvent.
